(19) United States
(12) Patent Application Publication
(10) Pub. No.: US 2024/0215445 A1
(43) Pub. Date: Jun. 27, 2024

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: Yuuki MIYAZAKI, Yokohama (JP); Hirokazu KUWABARA, Yokohama (JP); Ryuhei FURUE, Yokohama (JP); Yoshiro SUGITA, Yokohama (JP); Yuji SUZAKI, Yokohama (JP)

(21) Appl. No.: 18/451,634

(22) Filed: Aug. 17, 2023

(30) Foreign Application Priority Data
Nov. 28, 2022 (KR) 10-2022-0161759

(51) Int. Cl. H10K 85/60; C07F 5/02; C09K 11/06

(52) U.S. Cl. CPC H10K 85/658; C07F 5/027; C09K 11/06; C09K 2211/1018; H10K 50/12

(57) ABSTRACT

A light emitting device includes a first electrode, a second electrode facing the first electrode, and a functional layer disposed between the first electrode and the second electrode, wherein the functional layer includes a first compound represented by Formula 1 below:

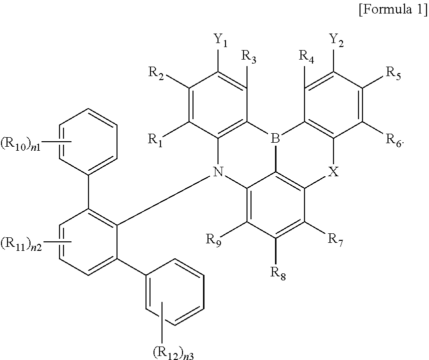

In Formula 1, the substituents are the same as defined in the Detailed Description.

### CROSS-REFERENCE TO RELATED APPLICATION

This application claims priority to and the benefit of Korean Patent Application No. 10-2022-0161759, filed on Nov. 28, 2022, the entire content of which is hereby incorporated by reference.

### BACKGROUND

### 1. Field

The present disclosure herein relates to a light emitting device and a fused polycyclic compound utilized in the light emitting device.

### 2. Description of the Related Art

Recently, the development of an organic electroluminescence display apparatus as an image display apparatus is being actively conducted. Unlike liquid crystal display apparatuses and/or the like, the organic electroluminescence display apparatus is a so-called self-luminescent display apparatus in which holes and electrons injected from a first electrode and a second electrode recombine in an emission layer, and thus a luminescent material including an organic compound in the emission layer emits light to implement display.

In the application of an organic electroluminescence device to a display apparatus, there is a demand or desire for an organic electroluminescence device having a low driving voltage, a high luminous efficiency, and/or a long service life, and the development on materials, for an organic electroluminescence device, capable of stably attaining such characteristics is being continuously pursued.

In recent years, for example, in order to implement a highly efficient organic electroluminescence device, technologies pertaining to phosphorescence emission utilizing triplet state energy or fluorescence emission utilizing triplet-triplet annihilation (TTA) (in which singlet excitons are generated by collision of triplet excitons) are being developed, and thermally activated delayed fluorescence (TADF) materials utilizing delayed fluorescence phenomenon are also being developed.

### SUMMARY

Aspects according to embodiments of the present disclosure are directed toward a light emitting device in which luminous efficiency and a device service life are improved.

Aspects according to embodiments of the present disclosure are directed toward a fused polycyclic compound capable of improving luminous efficiency and a device service life of a light emitting device.

Additional aspects will be set forth in part in the description which follows and, in part, will be apparent from the description, or may be learned by practice of the presented embodiments of the disclosure.

According to an embodiment of the present disclosure, a light emitting device includes a first electrode, a second electrode facing the first electrode, and a functional layer between the first electrode and the second electrode, wherein the functional layer includes a first compound represented by Formula 1:

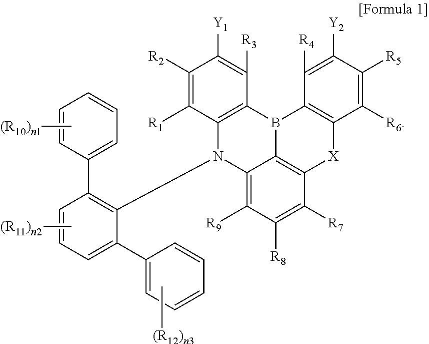

In Formula 1, X may be O, S, or NR₁₃, R₁ to R₉ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted linear or branched alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₁₀ to R₁₃ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, Y₁ and Y₂ may each independently be a hydrogen atom, a deuterium atom, a halogen atom, a cyano group, a hydroxy group, a substituted or unsubstituted oxy group, a substituted or unsubstituted thio group, a substituted or unsubstituted aryl group having 6 to 30 ring-forming carbon atoms, or a substituted or unsubstituted heteroaryl group having 2 to 30 ring-forming carbon atoms, or a substituent represented by Formula 2, n1 and n3 may each independently be an integer of 0 to 5, n2 may be an integer of 0 to 3, and at least one of Y₁ or Y₂ may be represented by Formula 2.

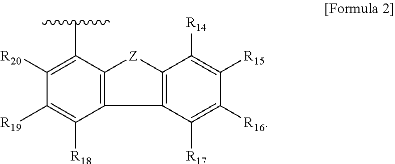

In Formula 2, Z may be O or S, R₁₄ to R₂₀ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and

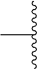

may be a position linked to Formula 1.

In an embodiment, the at least one functional layer may include an emission layer, a hole transport region between the first electrode and the emission layer, and an electron transport region between the emission layer and the second electrode, and the emission layer may include the fused polycyclic compound.

In an embodiment, the emission layer may be to emit delayed fluorescence.

In an embodiment, the emission layer may be to emit light having a luminescence center wavelength of about 430 nm to about 490 nm.

In an embodiment, in Formula 1, Y₁ may be a substituent represented by Formula 2, and Y₂ may be a hydrogen atom, a substituted or unsubstituted aryl group having 6 to 30 ring-forming carbon atoms, a substituted or unsubstituted heteroaryl group having 2 to 30 ring-forming carbon atoms, or a substituent represented by Formula 2.

In an embodiment, in Formula 1, R₁ to R₉ may each independently be a hydrogen atom, a deuterium atom, a halogen atom, a cyano group, a hydroxy group, a substituted or unsubstituted oxy group, or a substituted or unsubstituted linear or branched alkyl group having 1 to 20 carbon atoms.

In an embodiment, in Formula 2, R₁₄ to R₂₀ may each independently be a hydrogen atom, a deuterium atom, a cyano group, a substituted or unsubstituted alkyl group having 1 to 20 carbon atoms, or a substituted or unsubstituted aryl group having 6 to 30 ring-forming carbon atoms.

In an embodiment, the fused polycyclic compound represented by Formula 1 may be represented by Formula 1-1 or Formula 1-2:

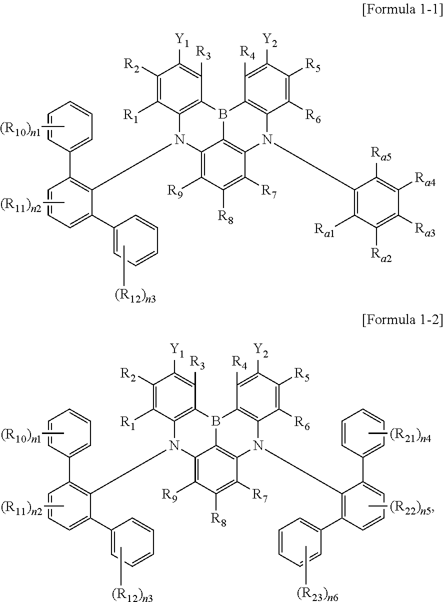

In Formula 1-1 and Formula 1-2, Rₐ₁ to Rₐ₅ may each independently be a hydrogen atom, a deuterium atom, a halogen atom, a cyano group, or a substituted or unsubstituted aryl group having 6 to 30 ring-forming carbon atoms, R₂₁ to R₂₃ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, n4 and n6 may each independently be an integer of 0 to 5, n5 may be an integer of 0 to 3, and Y₁, Y₂, R₁ to R₁₂, and n1 to n3 may each independently be the same as defined in Formula 1.

In an embodiment, the fused polycyclic compound represented by Formula 1 may be represented by Formula 1-3 or Formula 1-4:

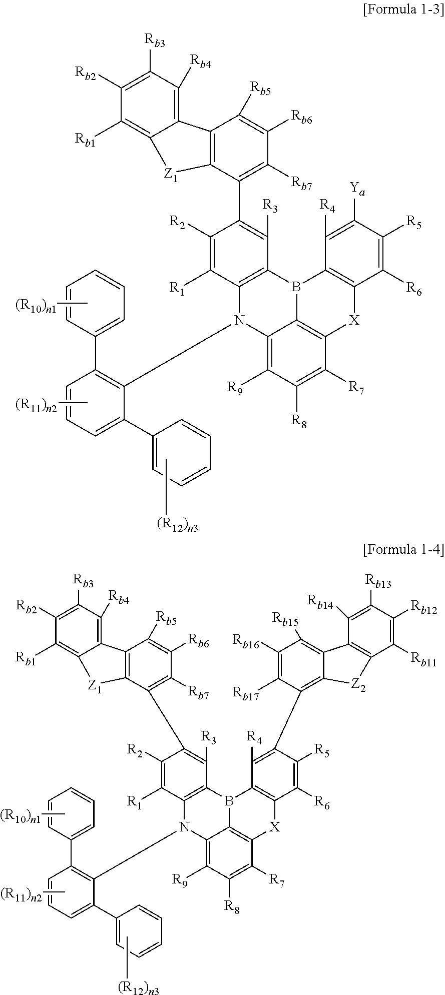

In Formula 1-3 and Formula 1-4, Yₐ may be a hydrogen atom, a substituted or unsubstituted aryl group having 6 to 30 ring-forming carbon atoms, or a substituted or unsubstituted heteroaryl group having 2 to 30 ring-forming carbon atoms, Z₁ and Z₂ may each independently be O or S, R_{b1} to R_{b7}, and R_{b11} to R_{b17} may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and X, R₁ to R₁₂, and n1 to n3 may each independently be the same as defined in Formula 1.

In an embodiment, the fused polycyclic compound represented by Formula 1 may be represented by Formula 1-5:

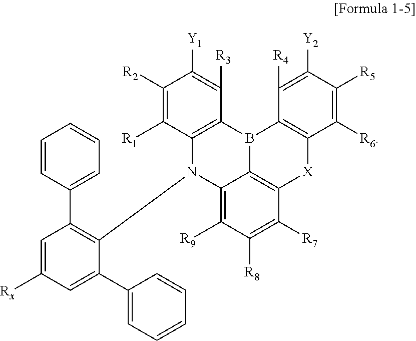

In Formula 1-5, Rx may be a hydrogen atom, a deuterium atom, a cyano group, a substituted or unsubstituted linear or branched alkyl group having 1 to 20 carbon atoms, or a substituted or unsubstituted aryl group having 6 to 30 ring-forming carbon atoms, and X, R₁ to R₉, R₁₃, Y₁, and Y₂ may each independently be the same as defined in Formula 1.

In an embodiment, the fused polycyclic compound represented by Formula 1 may be represented by Formula 1-6:

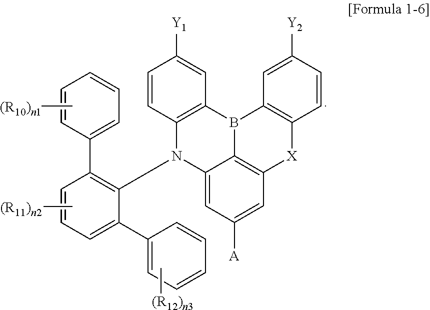

In Formula 1-6, A is a hydrogen atom, a deuterium atom, a cyano group, or a substituted or unsubstituted linear or branched alkyl group having 1 to 20 carbon atoms, and X, R₁₀ to R₁₃, n1 to n3, Y₁, and Y₂ may each independently be the same as defined in Formula 1.

In an embodiment, in Formula 1-6, A may be a substituted or unsubstituted t-butyl group.

In an embodiment of the present disclosure, a fused polycyclic compound may be represented by Formula 1.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view of a display apparatus according to an embodiment of the present disclosure;

FIG. 2 is a cross-sectional view of a display apparatus according to an embodiment of the present disclosure;

FIG. 3 is a cross-sectional view schematically illustrating a light emitting device according to an embodiment of the present disclosure;

FIG. 4 is a cross-sectional view schematically illustrating a light emitting device according to an embodiment of the present disclosure;

FIG. 5 is a cross-sectional view schematically illustrating a light emitting device according to an embodiment of the present disclosure;

FIG. 6 is a cross-sectional view schematically illustrating a light emitting device according to an embodiment of the present disclosure;

FIG. 7 is a cross-sectional view of a display apparatus according to an embodiment;

FIG. 8 is a cross-sectional view of a display apparatus according to an embodiment of the present disclosure;

FIG. 9 is a cross-sectional view illustrating a display apparatus according to an embodiment of the present disclosure;

FIG. 10 is a cross-sectional view illustrating a display apparatus according to an embodiment of the present disclosure; and

FIG. 11 is a view illustrating a vehicle in which display apparatuses are disposed according to embodiments.

### DETAILED DESCRIPTION

The present disclosure may be modified in one or more suitable manners and have many forms, and thus specific embodiments will be shown in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of the drawings, like reference numbers are used for referring to like elements. In the accompanying drawings, the dimensions of each structure may be exaggerated for clarity of the present disclosure. It will be understood that, although the terms “first,” “second,” etc., may be used herein to describe various components, these components should not be limited by these terms. These terms are only used to distinguish one component from another. For example, a first component could be termed a second component, and, similarly, a second component could be termed a first component, without departing from the scope of example embodiments of the present disclosure. As used herein, the singular forms, “a,” “an,” and “the” are intended to include the plural forms as well, unless the context clearly indicates otherwise.

In the present application, it will be understood that the terms “include,” “have” and/or the like specify the presence of features, numbers, steps, operations, components, parts, or combinations thereof disclosed in the specification, but do not exclude the possibility of presence or addition of one or more other features, numbers, steps, operations, components, parts, or combinations thereof.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary, when a layer, a film, a region, or a plate is referred to as being “below”, “in a lower portion of” another layer, film, region, or plate, it can be not only directly under the layer, film, region, or plate, but intervening layers, films, regions, or plates may also be present. In addition, it will be understood that when a part is referred to as being “on” another part, it can be disposed above the other part, or disposed under the other part as well.

In the specification, the term “substituted or unsubstituted” may refer to a functional group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the example substituents above may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle.

The hydrocarbon ring and the heterocycle may be monocyclic or polycyclic. In addition, the rings formed via the combination with an adjacent group may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, the two methyl groups in 1,2-dimethylbenzene may be interpreted as “adjacent groups” to each other and the two ethyl groups in 1,1-diethylcyclopentane may be interpreted as “adjacent groups” to each other. In addition, the two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the specification, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment of the present disclosure is not limited thereto.

In the specification, an alkenyl group refers to a hydrocarbon group including at least one carbon-carbon double bond in the middle and/or at the terminal end of an alkyl group having 2 or more carbon atoms. The alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the specification, an alkynyl group refers to a hydrocarbon group including at least one carbon-carbon triple bond in the middle and/or at the terminal end of an alkyl group having 2 or more carbon atoms. The alkynyl group may be linear or branched. Although the number of carbon atoms is not specifically limited, it may be 2 to 30, 2 to 20, or 2 to 10. Specific examples of the alkynyl group may include an ethynyl group, a propynyl group, etc., but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

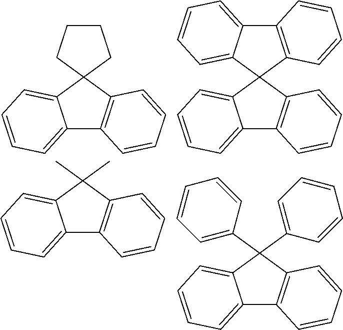

The term “heterocyclic group” as used herein refers to any functional group or substituent derived from a ring containing at least one of B, O, N, P, Si, or Se as a ring-forming heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a ring-forming heteroatom. When the heterocyclic group contains two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a ring-forming heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the present disclosure is not limited thereto.

In the specification, the heteroaryl group may contain at least one of B, O, N, P, Si, or S as a ring-forming heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiment of the present disclosure is not limited thereto.

In the specification, the number of carbon atoms in the carbonyl group is not specifically limited, but may be 1 to 40, 1 to 30, or 1 to 20. For example, the carbonyl group may have the following structures, but the embodiment of the present disclosure is not limited thereto.

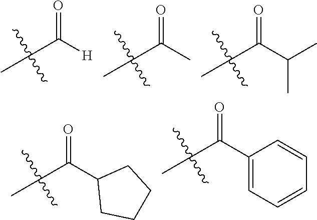

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined above. The oxy group may include an alkoxy group and an aryl oxy group. The alkoxy group may be a linear chain, a branched chain or a cyclic chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiment of the present disclosure is not limited thereto.

The term “boron group” as used herein may refer to that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but the embodiment of the present disclosure is not limited thereto.

In the specification, the alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiment of the present disclosure is not limited thereto.

In the specification, the alkyl group in the alkylthio group, the alkylsulfoxy group, the alkylaryl group, the alkylamino group, the alkyl boron group, the alkyl silyl group, and the alkyl amine group may be the same as the examples of the alkyl group described above.

In the specification, the aryl group in the aryloxy group, the arylthio group, the arylsulfoxy group, the arylamino group, the arylboron group, the arylsilyl group, the arylamine group may be the same as the examples of the aryl group described above.

In the specification, a direct linkage may refer to a single bond.

In some embodiments, in the specification,

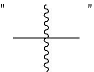

and “-*” each refer to a position to be connected.

Hereinafter, embodiments of the present disclosure will be described with reference to the accompanying drawings.

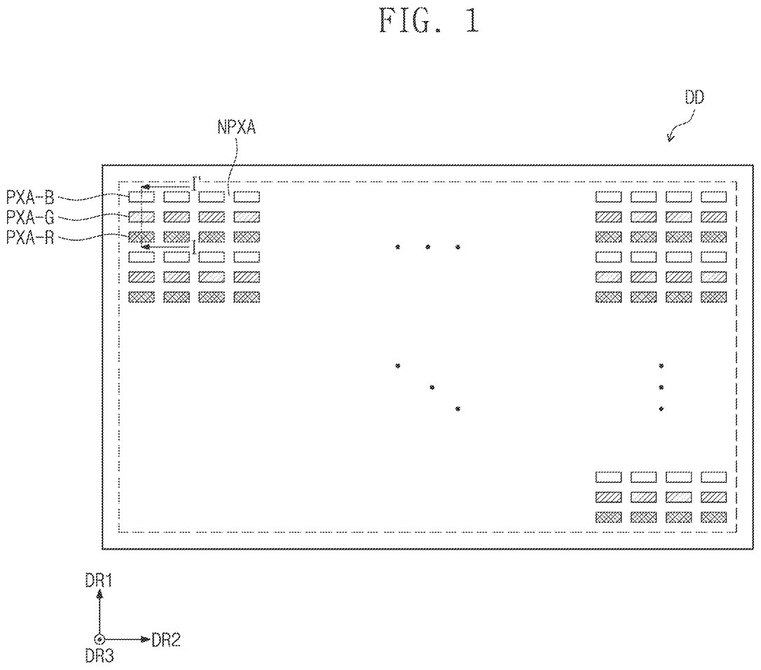

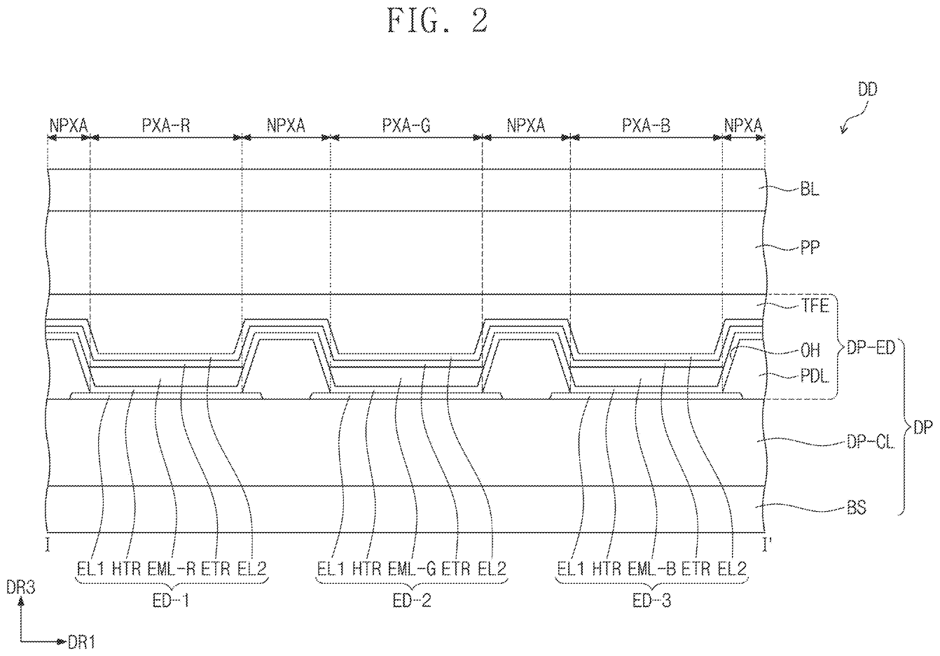

FIG. 1 is a plan view illustrating an embodiment of a display apparatus DD. FIG. 2 is a cross-sectional view of the display apparatus DD of the embodiment. FIG. 2 is a cross-sectional view illustrating a part taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include a plurality of light emitting devices ED-1, ED-2, and ED-3. The optical layer PP may be disposed on the display panel DP to control reflection of external light in the display panel DP. The optical layer PP may include, for example, a polarization layer and/or a color filter layer. In some embodiments, different from the configuration illustrated in the drawing, the optical layer PP may not be provided in the display apparatus DD of an embodiment.

A base substrate BL may be disposed on the optical layer PP. The base substrate BL may be a member which provides a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

The display apparatus DD according to an embodiment may further include a filling layer. The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

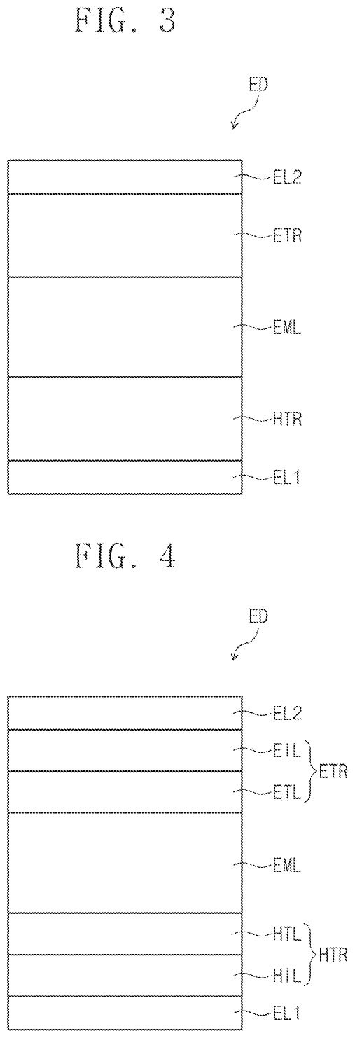

Each of the light emitting devices ED-1, ED-2, and ED-3 may have a structure of each light emitting device ED of embodiments according to FIGS. 3 to 6, which will be described in more detail later. Each of the light emitting devices ED-1, ED-2, and ED-3 may include a first electrode EL1, a hole transport region HTR, emission layers EML-R, EML-G, and EML-B (e.g., a corresponding one of the emission layer EML-R, the emission layer EML-G, or the emission layer EML-B), an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment of the present disclosure is not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in an embodiment may be provided by being patterned utilizing an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be one layer or a lamination of a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be disposed on the second electrode EL2 and may be disposed to fill the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced apart from each other on a plane (e.g., in a plan view).

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, and may correspond to the pixel defining film PDL. In some embodiments, in the specification, the light emitting regions PXA-R, PXA-G, and PXA-B may each correspond to a pixel. The pixel defining film PDL may divide the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and may be separated from each other.

The light emitting regions PXA-R, PXA-G, and PXA-B may be divided into a plurality of groups according to the color of light generated from the light emitting devices ED-1, ED-2, and ED-3. In the display apparatus DD of an embodiment illustrated in FIGS. 1 and 2, three light emitting regions PXA-R, PXA-G, and PXA-B, which emit red light, green light, and blue light, respectively, are illustrated. For example, the display device DD of an embodiment may include the red light emitting region PXA-R, the green light emitting region PXA-G, and the blue light emitting region PXA-B that are separated from each other.

In the display apparatus DD according to an embodiment, the plurality of light emitting devices ED-1, ED-2 and ED-3 may be to emit light (e.g., light beam) having wavelengths different from each other. For example, in an embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be to emit light (e.g., light beam) in substantially the same wavelength range or at least one light emitting device may be to emit a light (e.g., light beam) in a wavelength range different from the others. For example, the first to third light emitting devices ED-1, ED-2, and ED-3 may all emit blue light.

The light emitting regions PXA-R, PXA-G, and PXA-B in the display apparatus DD according to an embodiment may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged along the second directional axis DR2. In some embodiments, the red light emitting region PXA-R, the green light emitting region PXA-G, and the blue light emitting region PXA-B may be alternately arranged in this stated order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required or desired in the display apparatus DD. For example, the arrangement form of the light emitting regions PXA-R, PXA-G, and PXA-B may be a pentile (PENTILE@) arrangement form or a diamond (Diamond Pixel™) arrangement form. PENTILE@ and Diamond Pixel™ are trademarks of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

Hereinafter, FIGS. 3 to 6 are cross-sectional views schematically illustrating light emitting devices according to embodiments. The light emitting devices ED according to embodiments each may include a first electrode EL1, a second electrode EL2 facing the first electrode EL1, and at least one functional layer disposed between the first electrode EL1 and the second electrode EL2. The light emitting device ED of an embodiment may include a fused polycyclic compound of an embodiment, which will be described in more detail below, in at least one functional layer.

Each of the light emitting devices ED may include, as at least one functional layer, a hole transport region HTR, an emission layer EML, and an electron transport region ETR that are sequentially stacked. For example, each of the light emitting devices ED of embodiments may include the first electrode EL1, the hole transport region HTR, the emission layer EML, the electron transport region ETR, and the second electrode EL2 that are sequentially stacked in the stated order.

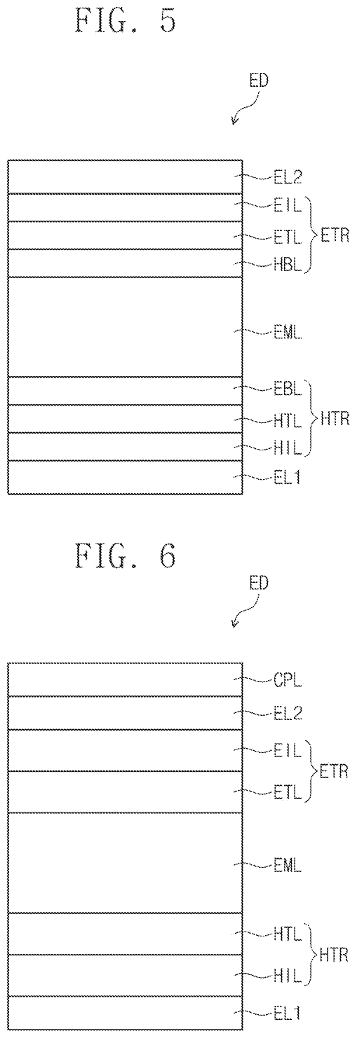

Compared with FIG. 3, FIG. 4 illustrates a cross-sectional view of a light emitting device ED of an embodiment, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting device ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of an embodiment including a capping layer CPL disposed on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the above-described metal materials, combinations of at least two metal materials of the above-described metal materials, oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in the respective stated order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

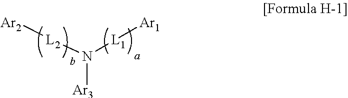

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 above may be a monoamine compound (e.g., a compound including a single amine group). In some embodiments, the compound represented by Formula H-1 above may be a diamine compound in which at least one among Ar₁ to Ar₃ includes the amine group as a substituent. In some embodiments, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among the compounds in Compound Group H. However, the compounds listed in Compound Group H are examples, and the compounds represented by Formula H-1 are not limited to those represented by Compound Group H:

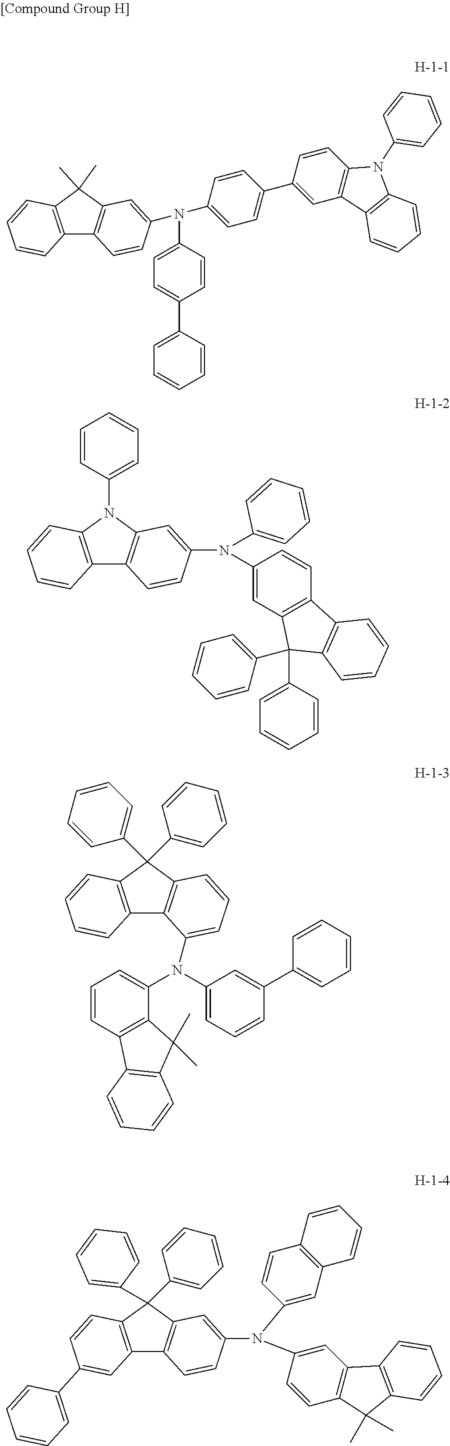 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

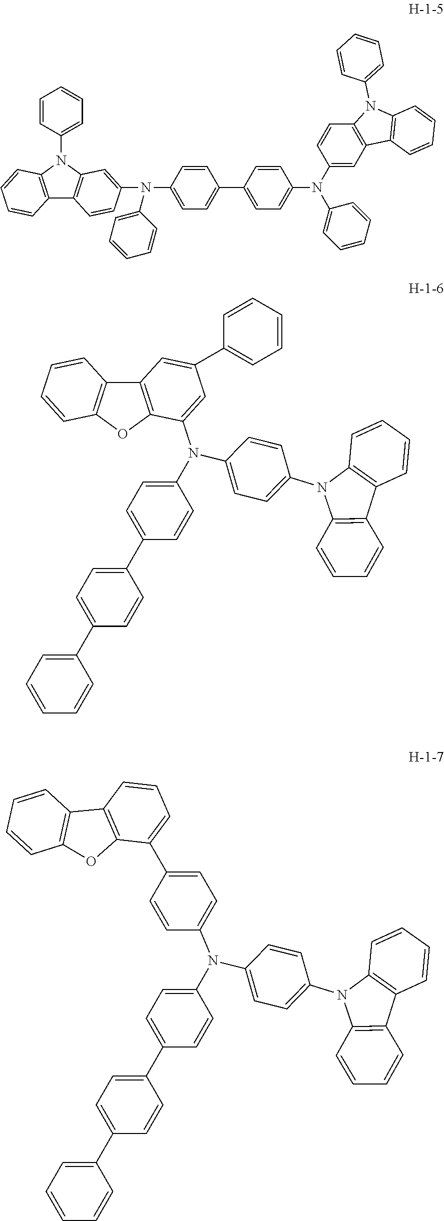 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

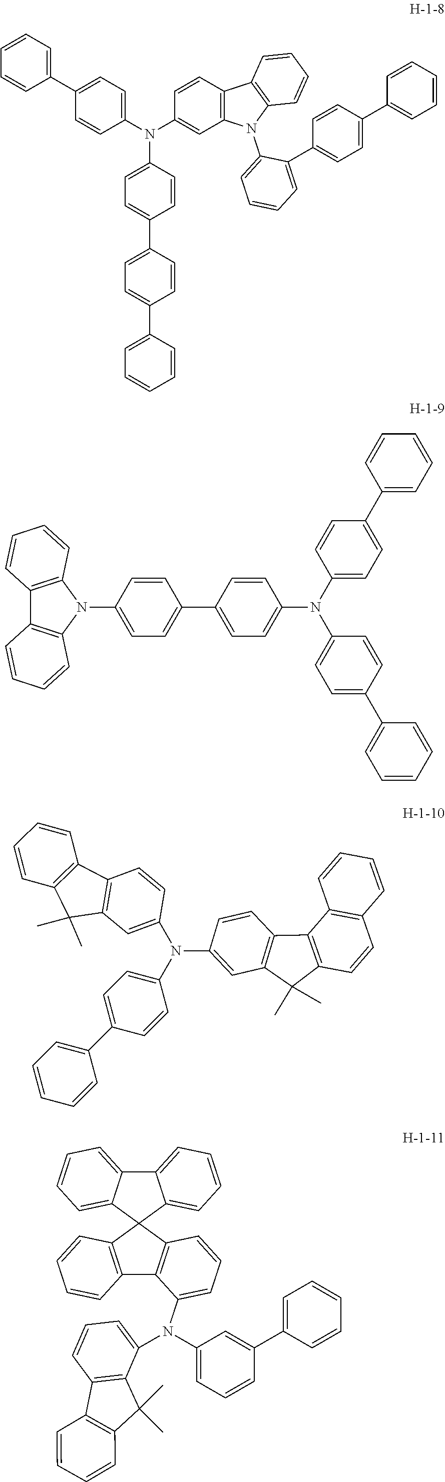 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

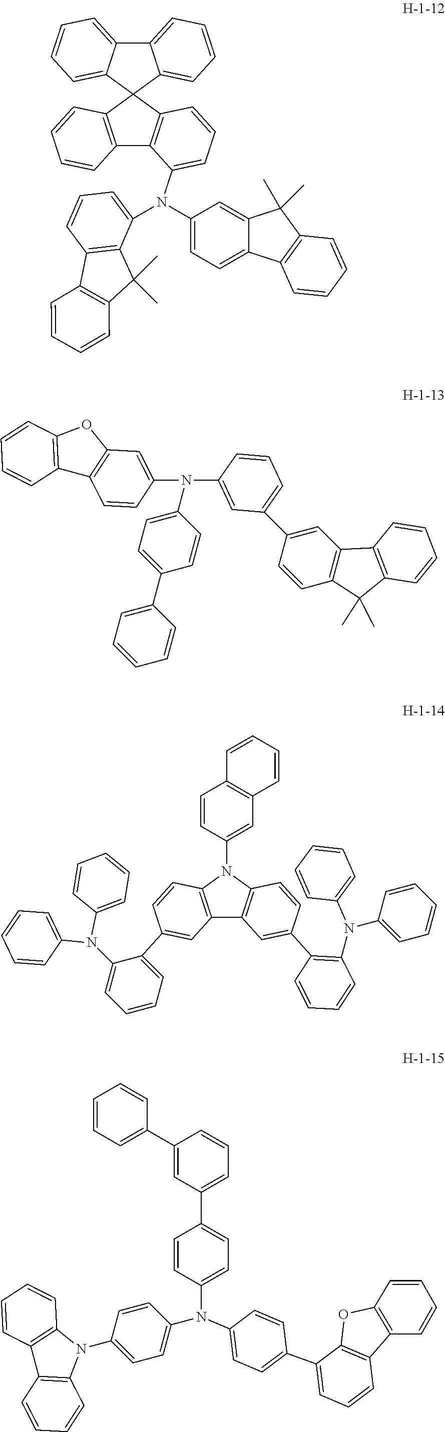 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

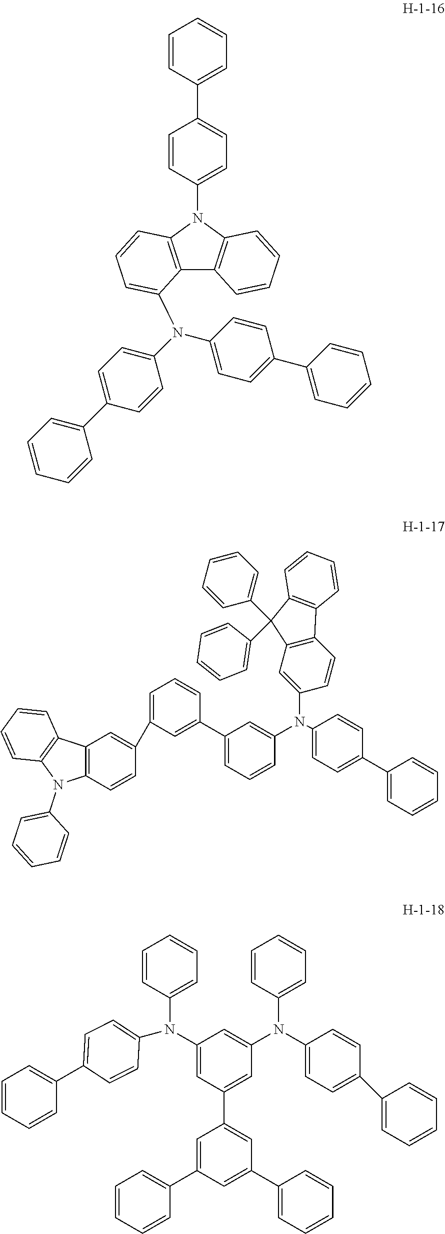 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

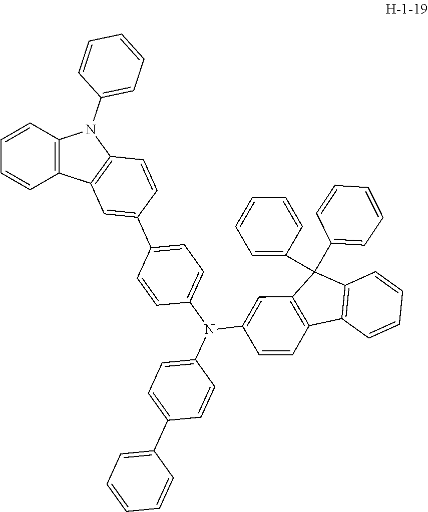 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N¹-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without a substantial increase in a driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as Cul and/or Rbl, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 or about 100 Å to about 300 Å. The emission layer EML may have a single layer formed of a single material, a single layer formed of a plurality of different materials, or a multilayer structure having a plurality of layers formed of a plurality of different materials.

The light emitting device ED of an embodiment may include a fused polycyclic compound represented by Formula 1 in at least one functional layer disposed between the first electrode EL1 and the second electrode EL2. The emission layer EML in the light emitting device ED according to an embodiment may include a fused polycyclic compound of an embodiment. In an embodiment, the emission layer EML may include the fused polycyclic compound of an embodiment as a dopant. The fused polycyclic compound of an embodiment may be a dopant material of the emission layer EML. In some embodiments, in the specification, the fused polycyclic compound of an embodiment, which will be described in more detail later, may be referred to as a first compound.

The fused polycyclic compound of an embodiment may include a structure in which a plurality of aromatic rings are fused via a boron atom and two heteroatoms. For example, the fused polycyclic compound of an embodiment may include a structure in which first to third aromatic rings are fused via one boron atom, a first heteroatom, and a second heteroatom. The first to third aromatic rings each may be linked to the boron atom, the first aromatic ring and the third aromatic ring may be linked to each other via the first heteroatom, and the second aromatic ring and the third aromatic ring may be linked to each other via the second heteroatom. In an embodiment, the first to third aromatic rings may all be 6-membered aromatic hydrocarbon rings. For example, the first to third aromatic rings may all be benzene rings. In an embodiment, the first heteroatom is a nitrogen atom (N). The second heteroatom may be an oxygen atom (O), a sulfur atom (S), or a nitrogen atom (N). In some embodiments, in the present specification, the boron atom, the first heteroatom, and the second heteroatom, and the first to third aromatic rings which are fused via the boron atom, the first heteroatom, and the second heteroatom together may be referred to as a “fused ring core.”

The fused polycyclic compound of an embodiment may include a first substituent linked to the fused ring core. The first substituent may be a structure in which two benzene moieties are bonded via a third heteroatom. The third heteroatom may be an oxygen atom (O) or a sulfur atom (S). The first substituent may include a dibenzofuran moiety or a dibenzothiophene moiety.

The fused polycyclic compound of an embodiment may include a plurality of first substituents linked to the fused ring core. The plurality of first substituents include a 1-1st substituent linked to the first aromatic ring. Carbon 1 of the 1-1st substituent may be linked to the first aromatic ring. Carbon 1 of the 1-1st substituent may be linked to the first aromatic ring at the meta-position based on (with respect to) the boron atom of the fused ring core. The plurality of first substituents may include a 1-2nd substituent linked to the second aromatic ring. Carbon 1 of the 1-2nd substituent may be linked to the second aromatic ring. Carbon 1 of the 1-2nd substituent may be linked to the second aromatic ring at the meta-position based on (with respect to) the boron atom of the fused ring core. Accordingly, when the fused polycyclic compound of an embodiment includes the 1-1st substituent and the 1-2nd substituent, a benzene moiety of the 1-1st substituent, which is not linked to the first aromatic ring, and a benzene moiety of the 1-2nd substituent, which is not linked to the second aromatic ring, may be positioned in a direction to be spaced apart from each other with respect to the boron atom.

In some embodiments, the numbering of carbon atoms constituting the first substituent may be represented by Formula S1:

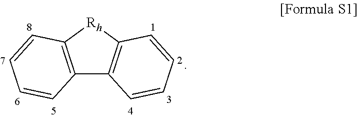

In Formula S1 above, Rh may refer to the third heteroatom as described above. With respect to the numbering of carbon atoms in the first substituent, as shown in Formula S1 above, the numbers are assigned in a clockwise direction from the carbon atom at a position closest to Rh atom.

The fused polycyclic compound of an embodiment may include a second substituent linked to the first heteroatom of the fused ring core. The second substituent may include a benzene moiety linked to the first heteroatom (nitrogen atom) of the fused ring core. The second substituent may have a structure in which substituted or unsubstituted phenyl groups are respectively introduced into both (e.g., simultaneously) ortho positions with respect to the first heteroatom (nitrogen atom). The second substituent may include a m-terphenyl moiety represented by Formula S2:

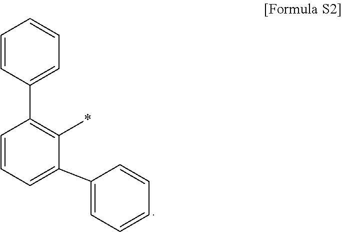 [SMILES: *c1c(-c2ccccc2)cccc1-c1ccccc1]

In Formula S2 above, -* may refer to a position linked to the first heteroatom of the fused ring core as described above.

The fused polycyclic compound of an embodiment may be represented by Formula 1:

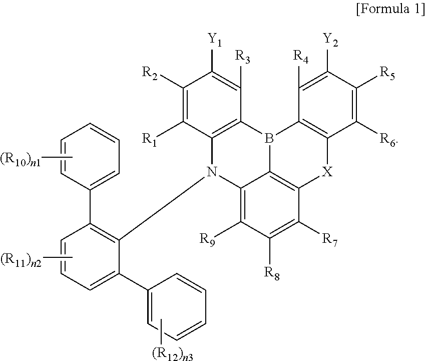

The fused polycyclic compound represented by Formula 1 of an embodiment may include a structure in which three aromatic rings are fused via one boron atom, the first heteroatom, and the second heteroatom. In Formula 1, X may be O, S, or NR₁₃. For example, X may be NR₁₃.

In Formula 1, R₁ to R₉ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted linear or branched alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₁ to R₉ may each independently be a substituted or unsubstituted linear or branched alkyl group having 1 to 20 carbon atoms, but the case where R₁ to R₉ are each a substituted or unsubstituted cycloalkyl group having 1 to 20 carbon atoms is excluded. For example, R₁ to R₉ may each independently be a hydrogen atom, a deuterium atom, a halogen atom, a cyano group, or a substituted or unsubstituted t-butyl group.

In Formula 1, R₁₀ to R₁₃ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₀ to R₁₂ may each independently be a hydrogen atom, a deuterium atom, a cyano group, a substituted or unsubstituted butyl group, or a substituted or unsubstituted phenyl group. For example, R₁₃ may be a substituted or unsubstituted aryl group having 6 to 30 ring-forming carbon atoms, or a substituted or unsubstituted heteroaryl group having 2 to 30 ring-forming carbon atoms.

In Formula 1, Y₁ and Y₂ may each independently be a hydrogen atom, a deuterium atom, a halogen atom, a cyano group, a hydroxy group, a substituted or unsubstituted oxy group, a substituted or unsubstituted thio group, a substituted or unsubstituted aryl group having 6 to 30 ring-forming carbon atoms, or a substituted or unsubstituted heteroaryl group having 2 to 30 ring-forming carbon atoms. In some embodiments, Y₁ and Y₂ may each independently be substituents represented by Formula 2. For example, Y₁ may be a substituent represented by Formula 2, and Y₂ may be a hydrogen atom, a substituted or unsubstituted phenyl group, a substituted or unsubstituted dibenzofuran group, dibenzothiophene group, or a substituent represented by Formula 2.

In Formula 1, n1 and n3 may each independently be an integer of 0 to 5. When each of n1 and n3 is 0, the fused polycyclic compound of an embodiment may not be substituted with each of R₁₀ and R₁₂. The case where each of n1 and n3 is 5 and R₁₀'s and R₁₂'s are each hydrogen atoms may be the same as the case where each of n1 and n3 is 0. When each of n1 and n3 is an integer of 2 or more, a plurality of R₁₀'s and R₁₂'s may each be the same or at least one among the plurality of R₁₀'s and R₁₂'s may be different from the others.

In Formula 1, n2 is an integer of 0 to 3. When n2 is 0, the fused polycyclic compound of an embodiment may not be substituted with R₁₁. The case where n2 is 3 and R₁₁'s are all hydrogen atoms may be the same as the case where n2 is 0. When n2 is an integer of 2 or more, a plurality of R₁₁'s may each be the same, or at least one among the plurality of R₁₁'s may be different from the others.

In some embodiments, in the present specification, in Formula 1, the benzene ring which is substituted with substituents represented by R₁ to R₃ and Y₁ may correspond to the aforementioned first aromatic ring, the benzene ring which is substituted with substituents represented by R₄ to R₆ and Y₂ may correspond to the aforementioned second aromatic ring, and the benzene ring which is substituted with substituents represented by R₇ to R₉ may correspond to the aforementioned third aromatic ring. In some embodiments, the nitrogen (N) atom in Formula 1 may correspond to the aforementioned first heteroatom, and X may correspond to the aforementioned second heteroatom. In Formula 1, the terphenyl group substituted with substituents represented by R₁₀ to R₁₂ in Formula 1 may correspond to the aforementioned second substituent.

In Formula 1, at least one among Y₁ and Y₂ may be represented by Formula 2:

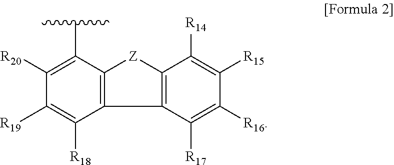

In Formula 2, Z may be O or S. For example, Z may be O.

In Formula 2, R₁₄ to R₂₀ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₄ to R₂₀ may each independently be a hydrogen atom, a deuterium atom, a cyano group, a substituted or unsubstituted alkyl group having 1 to 20 carbon atoms, or a substituted or unsubstituted aryl group having 6 to 30 ring-forming carbon atoms.

In Formula 2,

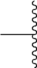

may be a position linked to Formula 1 above.

In some embodiments, in the present specification, Formula 2 may correspond to the above-described first substituent. Z in Formula 2 may correspond to the above-described third heteroatom.

In an embodiment, the fused polycyclic compound represented by Formula 1 may be represented by Formula 1-1 or Formula 1-2:

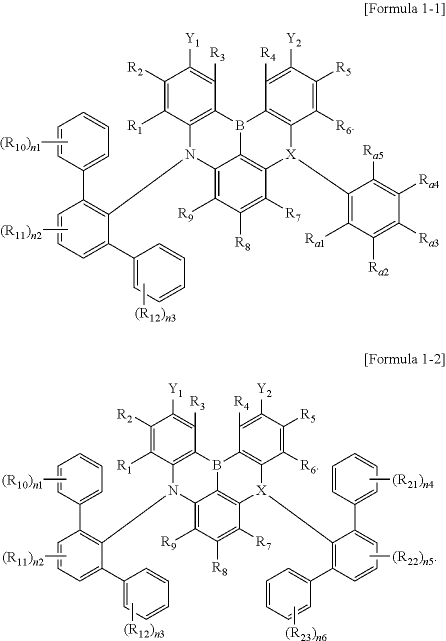

Formula 1-1 and Formula 1-2 represent the cases where X and R₁₃ are specified in Formula 1. Formula 1-1 and Formula 1-2 represent the cases where X in Formula 1 is N. Formula 1-1 represents the case where R₁₃ is a substituted or unsubstituted phenyl group, and Formula 1-2 represents the case where R₁₃ is a substituted or unsubstituted m-terphenyl group.

In Formula 1-1, Rₐ₁ to Rₐ₅ may each independently be a hydrogen atom, a deuterium atom, a halogen atom, a cyano group, or a substituted or unsubstituted aryl group having 6 to 30 ring-forming carbon atoms. For example, Rₐ₁ to Rₐ₅ may each independently be a hydrogen atom, or a substituted or unsubstituted phenyl group.

In Formula 1-2, R₂₁ to R₂₃ may each independently be a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ to R₂₃ may each independently be a hydrogen atom, a deuterium atom, a cyano group, a substituted or unsubstituted butyl group, or a substituted or unsubstituted phenyl group.

In Formula 1-2, n4 and n6 may each independently be an integer of 0 to 5. When each of n4 and n6 is 0, the fused polycyclic compound of an embodiment may not be substituted with each of R₂₁ and R₂₃. The case where each of n4 and n6 is 5 and R₂₁'s and R₂₃'s are each hydrogen atoms may be the same as the case where each of n4 and n6 is 0. When each of n4 and n6 is an integer of 2 or more, a plurality of R₂₁'s and R₂₃'s may each be the same or at least one among the plurality of R₂₁'s and R₂₃'s may be different from the others.

In Formula 1-2, n5 may be an integer of 0 to 3. When n5 is 0, the fused polycyclic compound of an embodiment may not be substituted with R₂₂. The case where n5 is 3 and R₂₂'s are all hydrogen atoms may be the same as the case where n5 is 0. When n5 is an integer of 2 or more, a plurality of R₂₂'s may each be the same, or at least one among the plurality of R₂₂'s may be different from the others.

In Formula 1-1 and Formula 1-2, the same as described in Formula 1 above may be applied to Y₁, Y₂, R₁ to R₁₂, and n1 to n3.

In an embodiment, the fused polycyclic compound represented by Formula 1 may be represented by Formula 1-3 or Formula 1-4:

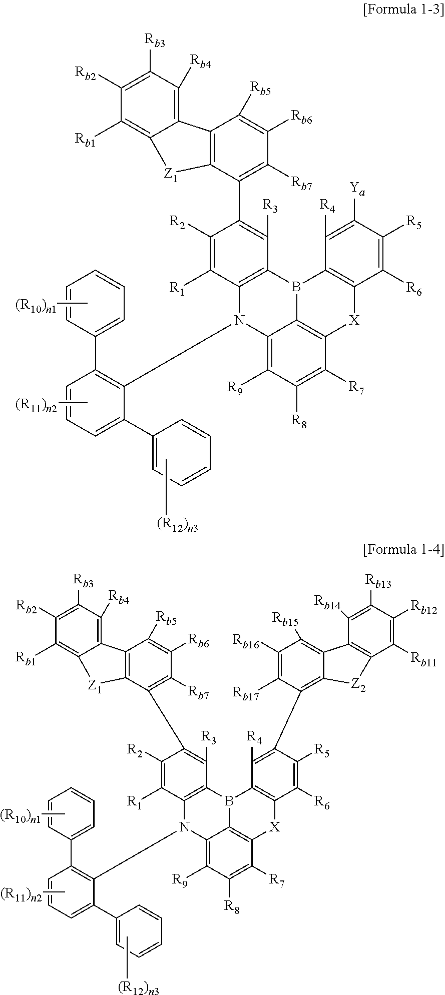

Formula 1-3 and Formula 1-4 represent the cases where the types (kinds) of Y₁ and Y₂ are specified in Formula 1. Formula 1-3 represents the case where Y₁ is a substituent represented by Formula 2 and Y₂ is Yₐ, and Formula 1-4 represents the case where Y₁ and Y₂ are both substituents represented by Formula 2.

In Formula 1-3, Yₐ may be a hydrogen atom, a substituted or unsubstituted aryl group having 6 to 30 ring-forming carbon atoms, or a substituted or unsubstituted heteroaryl group having 2 to 30 ring-forming carbon atoms. For example, Yₐ may be a hydrogen atom, a substituted or unsubstituted phenyl group, a substituted or unsubstituted biphenyl group, a substituted or unsubstituted dibenzofuran group, or a substituted or unsubstituted dibenzothiophene group.

In Formula 1-3 and Formula 1-4, Z₁ and Z₂ may each independently be O or S. For example, Z₁ and Z₂ may each be O. In some embodiments, Z₁ may be O and Z₂ may be S, or Z₁ may be S and Z₂ may be O.

In Formula 1-3 and Formula 1-4, R_{b1} to R_{b17} may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b1} to R_{b17} may each independently be a hydrogen atom, a deuterium atom, a cyano group, a substituted or unsubstituted alkyl group having 1 to 20 carbon atoms, or a substituted or unsubstituted aryl group having 6 to 30 ring-forming carbon atoms.

In Formula 1-3 and Formula 1-4, the same as described in Formula 1 above may be applied to X, R₁ to R₁₂, and n1 to n3.

In an embodiment, the fused polycyclic compound represented by Formula 1 may be represented by Formula 1-5:

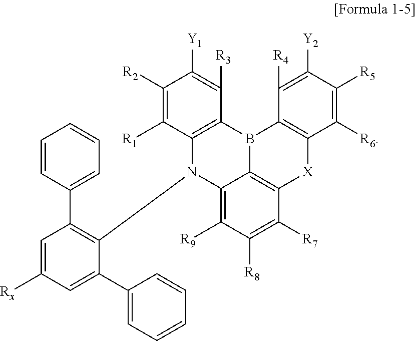

Formula 1-5 represents the case where in Formula 1, the types (kinds) of R₁₀, R₁₁, and R₁₂ are specified and n1, n2, and n3 are specified. Formula 1-5 represents the case where n1 and n3 are each 0, or the case where n1 and n3 are each 5, and a plurality of R₁₀'s and a plurality of R₁₂'s are all hydrogen atoms.

In Formula 1-5, Rx may be a hydrogen atom, a deuterium atom, a cyano group, a substituted or unsubstituted linear or branched alkyl group having 1 to 20 carbon atoms, or a substituted or unsubstituted aryl group having 6 to 30 ring-forming carbon atoms. For example, Rx may be a hydrogen atom, a substituted or unsubstituted butyl group, or a substituted or unsubstituted phenyl group.

In Formula 1-5, the same as described in Formula 1 above may be applied to X, R₁ to R₉, R₁₃, Y₁, and Y₂.

In an embodiment, the fused polycyclic compound represented by Formula 1 may be represented by Formula 1-6:

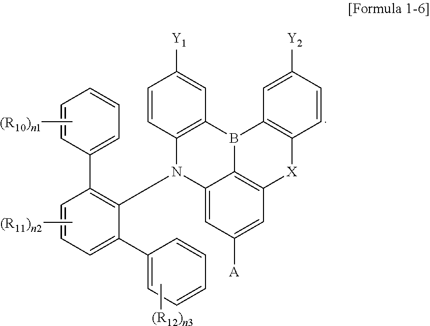

Formula 1-6 represents the case where the types (kinds) of R₁ to R₉ are specified in Formula 1. Formula 1-6 represents the case where R₁ to R₇ and R₉ are hydrogen atoms and R₈ is A.

In Formula 1-6, A may be a hydrogen atom, a deuterium atom, a cyano group, a halogen atom, or a substituted or unsubstituted linear or branched alkyl group having 1 to 20 carbon atoms. For example, A may be a hydrogen atom, a deuterium atom, a cyano group, a halogen atom, or a substituted or unsubstituted t-butyl group.

In Formula 1-6, the same as described in Formula 1 above may be applied to X, R₁₀ to R₁₃, n1 to n3, Y₁, and Y₂.

The fused polycyclic compound of an embodiment may be any one among the compounds represented by Compound Group 1. The light emitting device ED of an embodiment may include at least one fused polycyclic compound among the compounds represented by Compound Group 1 in the emission layer EML.

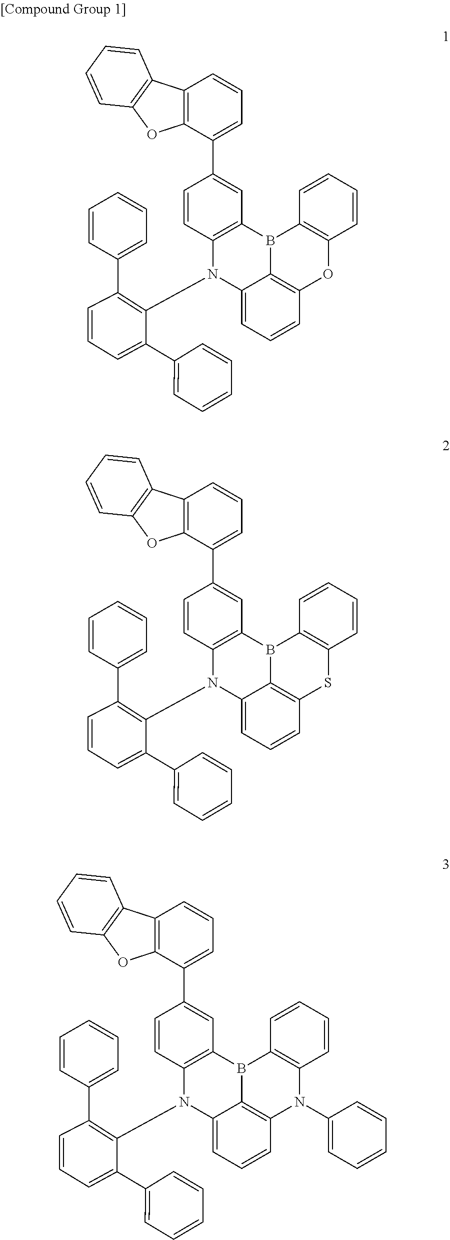 [SMILES: c1ccc(-c2cccc(-c3ccccc3)c2N2c3ccc(-c4cccc5c4oc4ccccc45)cc3B3c4ccccc4Oc4cccc2c43)cc1 ; c1ccc(-c2cccc(-c3ccccc3)c2N2c3ccc(-c4cccc5c4oc4ccccc45)cc3B3c4ccccc4Sc4cccc2c43)cc1 ; c1ccc(-c2cccc(-c3ccccc3)c2N2c3ccc(-c4cccc5c4oc4ccccc45)cc3B3c4ccccc4N(c4ccccc4)c4cccc2c43)cc1]

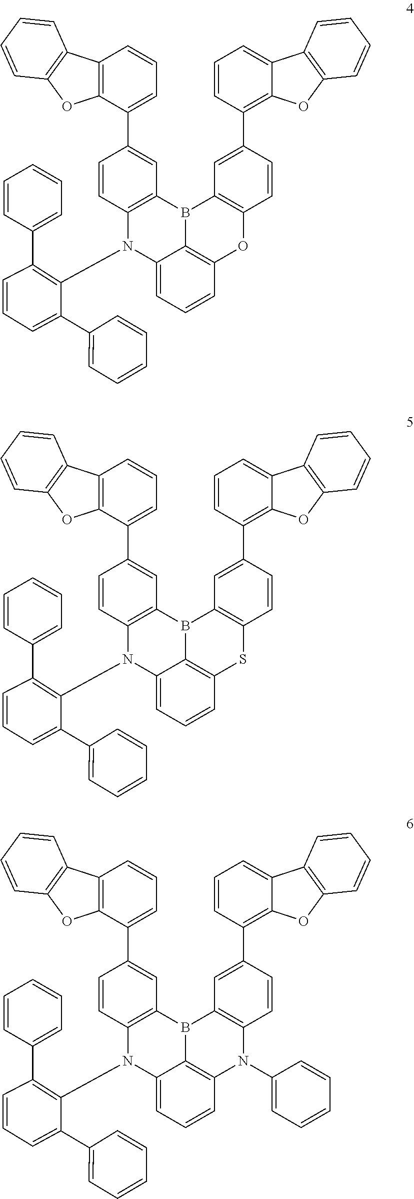 [SMILES: c1ccc(-c2cccc(-c3ccccc3)c2N2c3ccc(-c4cccc5c4oc4ccccc45)cc3B3c4cc(-c5cccc6c5oc5ccccc56)ccc4Oc4cccc2c43)cc1 ; c1ccc(-c2cccc(-c3ccccc3)c2N2c3ccc(-c4cccc5c4oc4ccccc45)cc3B3c4cc(-c5cccc6c5oc5ccccc56)ccc4Sc4cccc2c43)cc1 ; c1ccc(-c2cccc(-c3ccccc3)c2N2c3ccc(-c4cccc5c4oc4ccccc45)cc3B3c4cc(-c5cccc6c5oc5ccccc56)ccc4N(c4ccccc4)c4cccc2c43)cc1]

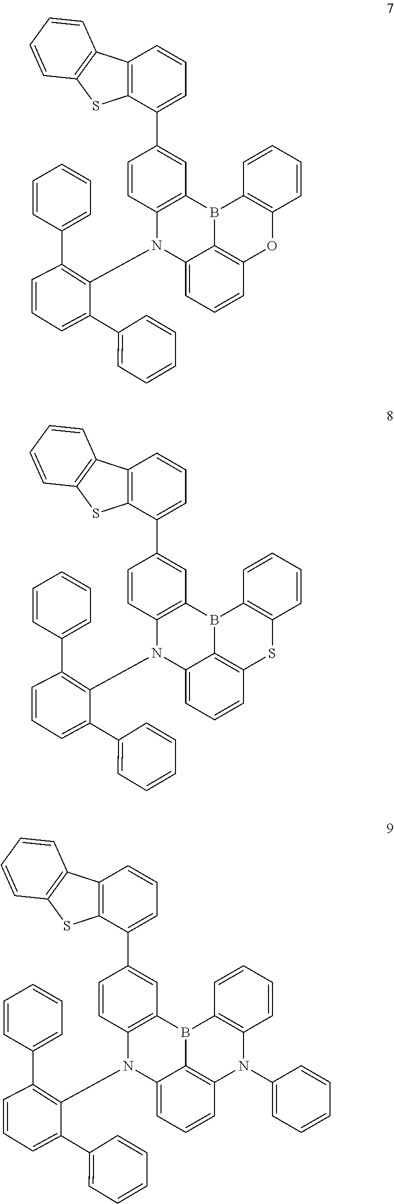 [SMILES: c1ccc(-c2cccc(-c3ccccc3)c2N2c3ccc(-c4cccc5c4sc4ccccc45)cc3B3c4ccccc4Oc4cccc2c43)cc1 ; c1ccc(-c2cccc(-c3ccccc3)c2N2c3ccc(-c4cccc5c4sc4ccccc45)cc3B3c4ccccc4Sc4cccc2c43)cc1 ; c1ccc(-c2cccc(-c3ccccc3)c2N2c3ccc(-c4cccc5c4sc4ccccc45)cc3B3c4ccccc4N(c4ccccc4)c4cccc2c43)cc1]

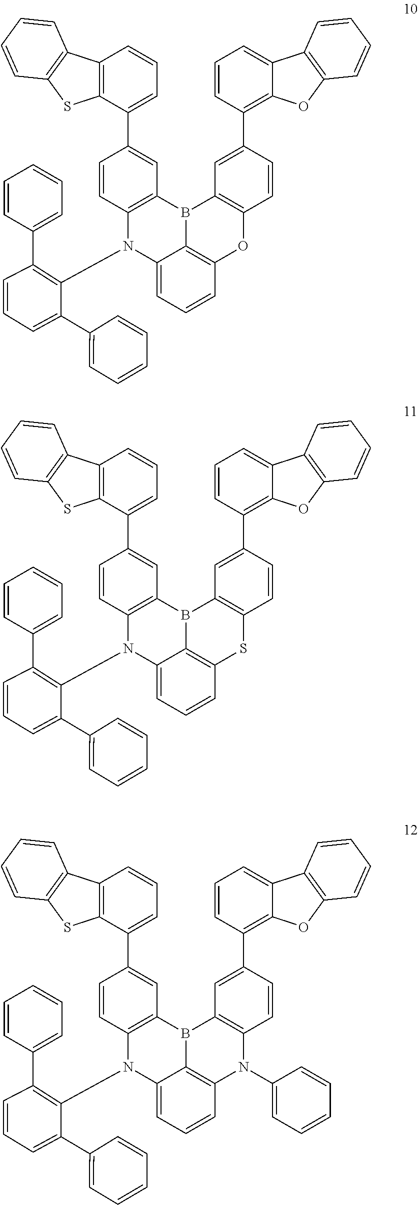 [SMILES: c1ccc(-c2cccc(-c3ccccc3)c2N2c3ccc(-c4cccc5c4sc4ccccc45)cc3B3c4cc(-c5cccc6c5oc5ccccc56)ccc4Oc4cccc2c43)cc1 ; c1ccc(-c2cccc(-c3ccccc3)c2N2c3ccc(-c4cccc5c4sc4ccccc45)cc3B3c4cc(-c5cccc6c5oc5ccccc56)ccc4Sc4cccc2c43)cc1 ; c1ccc(-c2cccc(-c3ccccc3)c2N2c3ccc(-c4cccc5c4sc4ccccc45)cc3B3c4cc(-c5cccc6c5oc5ccccc56)ccc4N(c4ccccc4)c4cccc2c43)cc1]

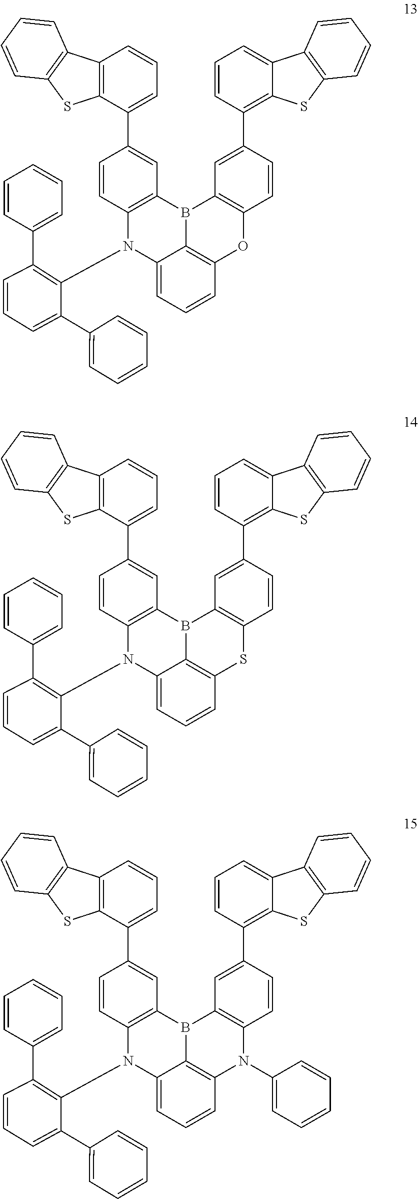 [SMILES: c1ccc(-c2cccc(-c3ccccc3)c2N2c3ccc(-c4cccc5c4sc4ccccc45)cc3B3c4cc(-c5cccc6c5sc5ccccc56)ccc4Oc4cccc2c43)cc1 ; c1ccc(-c2cccc(-c3ccccc3)c2N2c3ccc(-c4cccc5c4sc4ccccc45)cc3B3c4cc(-c5cccc6c5sc5ccccc56)ccc4Sc4cccc2c43)cc1 ; c1ccc(-c2cccc(-c3ccccc3)c2N2c3ccc(-c4cccc5c4sc4ccccc45)cc3B3c4cc(-c5cccc6c5sc5ccccc56)ccc4N(c4ccccc4)c4cccc2c43)cc1]

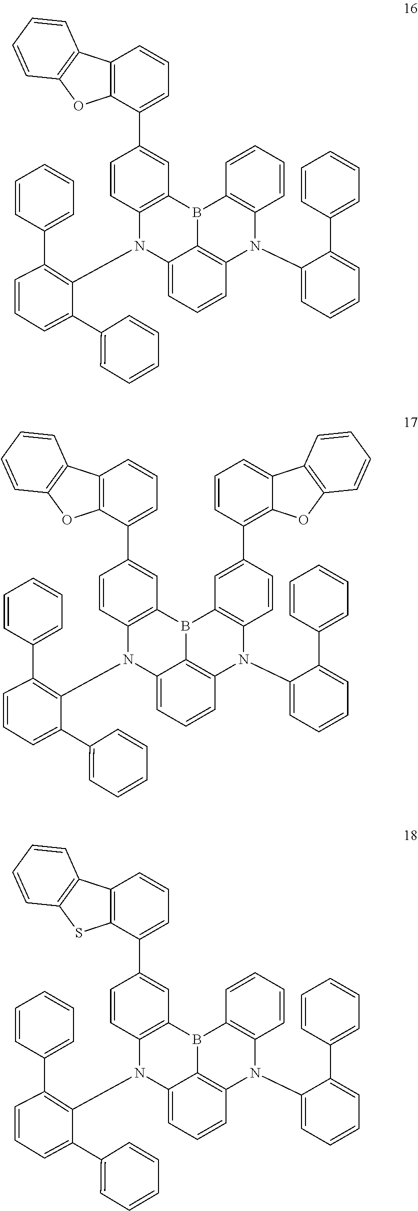 [SMILES: c1ccc(-c2ccccc2N2c3ccccc3B3c4cc(-c5cccc6c5oc5ccccc56)ccc4N(c4c(-c5ccccc5)cccc4-c4ccccc4)c4cccc2c43)cc1 ; c1ccc(-c2ccccc2N2c3ccc(-c4cccc5c4oc4ccccc45)cc3B3c4cc(-c5cccc6c5oc5ccccc56)ccc4N(c4c(-c5ccccc5)cccc4-c4ccccc4)c4cccc2c43)cc1 ; c1ccc(-c2ccccc2N2c3ccccc3B3c4cc(-c5cccc6c5sc5ccccc56)ccc4N(c4c(-c5ccccc5)cccc4-c4ccccc4)c4cccc2c43)cc1]

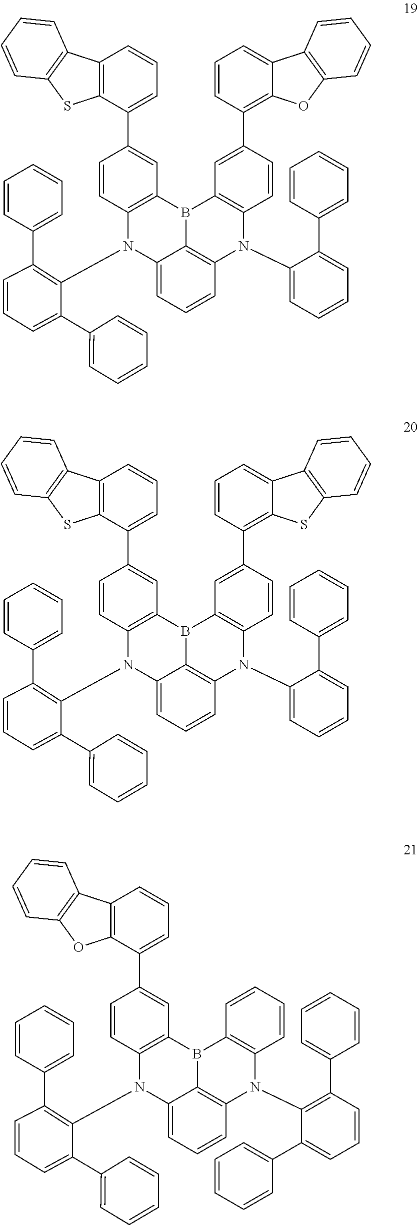 [SMILES: c1ccc(-c2ccccc2N2c3ccc(-c4cccc5c4oc4ccccc45)cc3B3c4cc(-c5cccc6c5sc5ccccc56)ccc4N(c4c(-c5ccccc5)cccc4-c4ccccc4)c4cccc2c43)cc1 ; c1ccc(-c2ccccc2N2c3ccc(-c4cccc5c4sc4ccccc45)cc3B3c4cc(-c5cccc6c5sc5ccccc56)ccc4N(c4c(-c5ccccc5)cccc4-c4ccccc4)c4cccc2c43)cc1 ; c1ccc(-c2cccc(-c3ccccc3)c2N2c3ccccc3B3c4cc(-c5cccc6c5oc5ccccc56)ccc4N(c4c(-c5ccccc5)cccc4-c4ccccc4)c4cccc2c43)cc1]

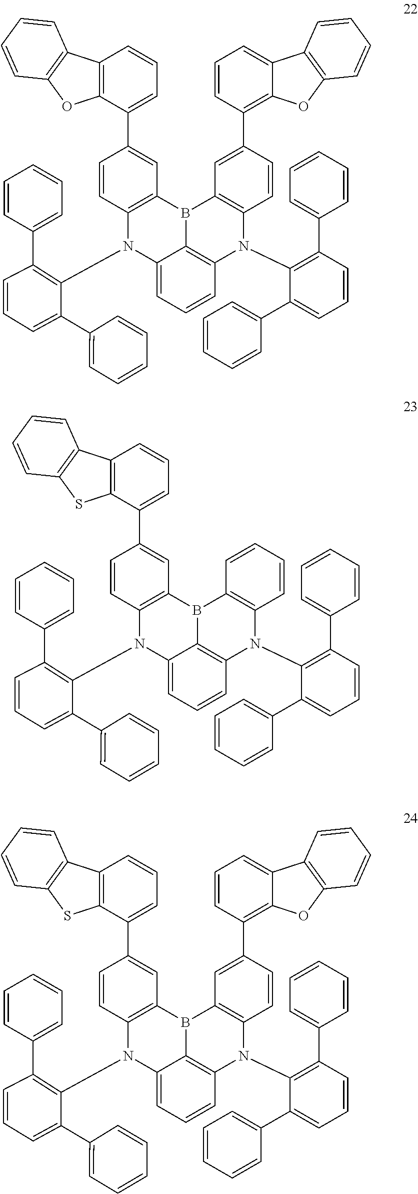 [SMILES: c1ccc(-c2cccc(-c3ccccc3)c2N2c3ccc(-c4cccc5c4oc4ccccc45)cc3B3c4cc(-c5cccc6c5oc5ccccc56)ccc4N(c4c(-c5ccccc5)cccc4-c4ccccc4)c4cccc2c43)cc1 ; c1ccc(-c2cccc(-c3ccccc3)c2N2c3ccccc3B3c4cc(-c5cccc6c5sc5ccccc56)ccc4N(c4c(-c5ccccc5)cccc4-c4ccccc4)c4cccc2c43)cc1 ; c1ccc(-c2cccc(-c3ccccc3)c2N2c3ccc(-c4cccc5c4oc4ccccc45)cc3B3c4cc(-c5cccc6c5sc5ccccc56)ccc4N(c4c(-c5ccccc5)cccc4-c4ccccc4)c4cccc2c43)cc1]

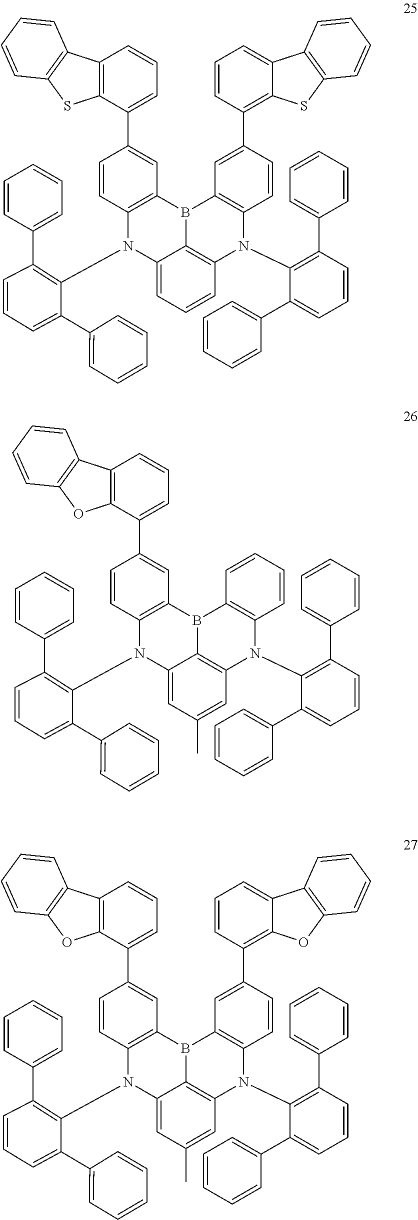 [SMILES: c1ccc(-c2cccc(-c3ccccc3)c2N2c3ccc(-c4cccc5c4sc4ccccc45)cc3B3c4cc(-c5cccc6c5sc5ccccc56)ccc4N(c4c(-c5ccccc5)cccc4-c4ccccc4)c4cccc2c43)cc1 ; Cc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; Cc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1]

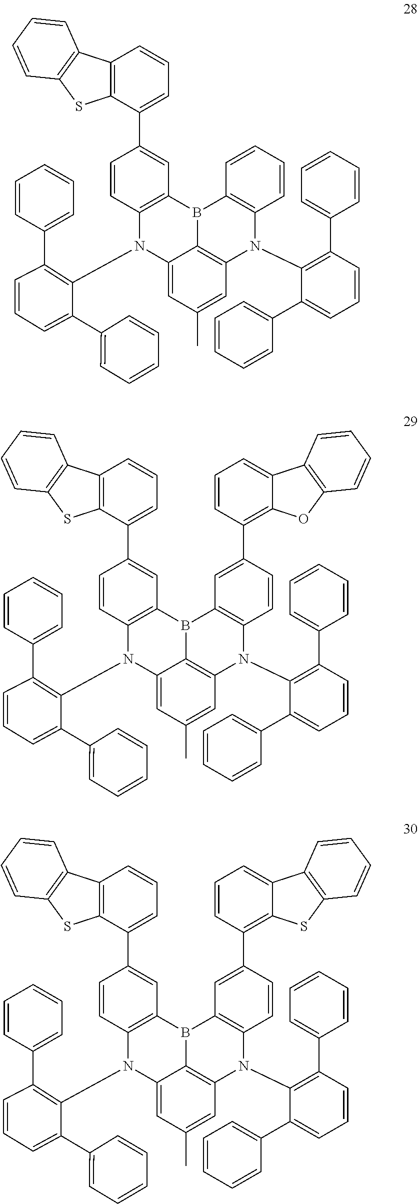 [SMILES: Cc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1 ; Cc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; Cc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1]

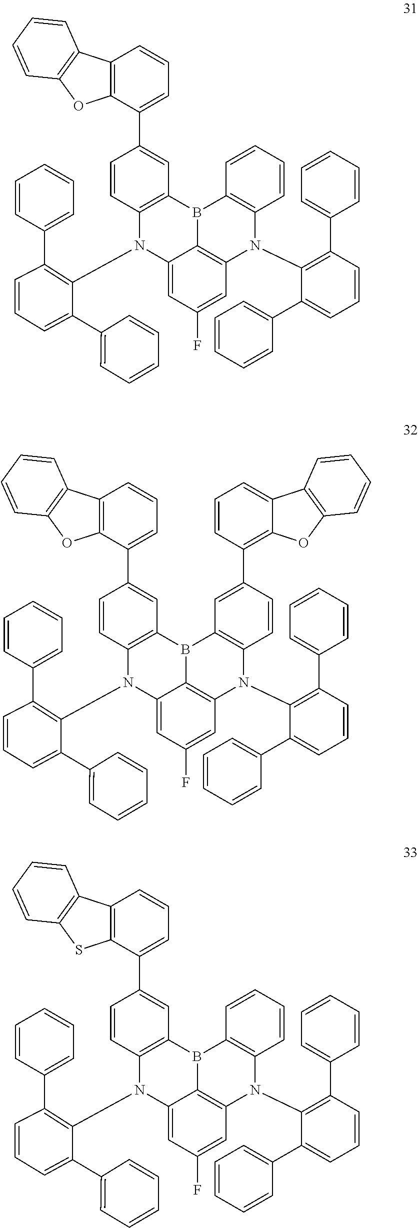 [SMILES: Fc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; Fc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; Fc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1]

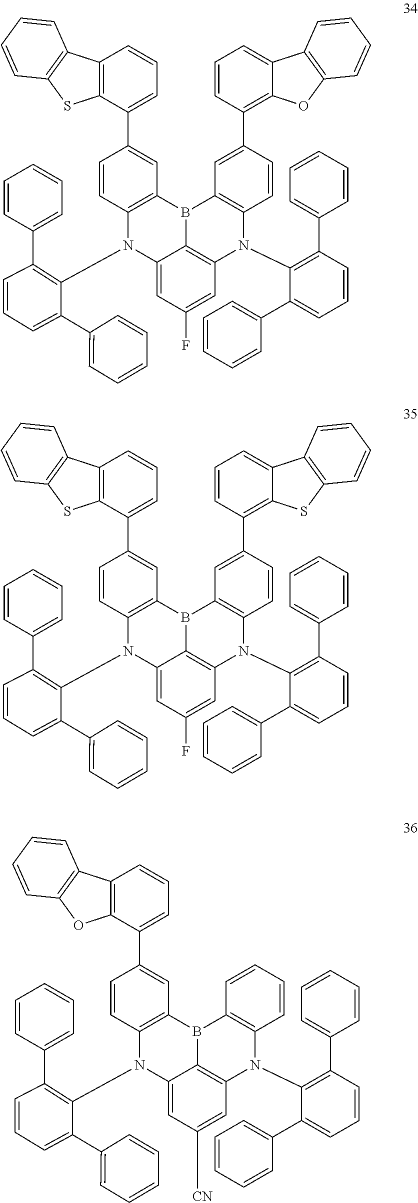 [SMILES: Fc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; Fc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; N#Cc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1]

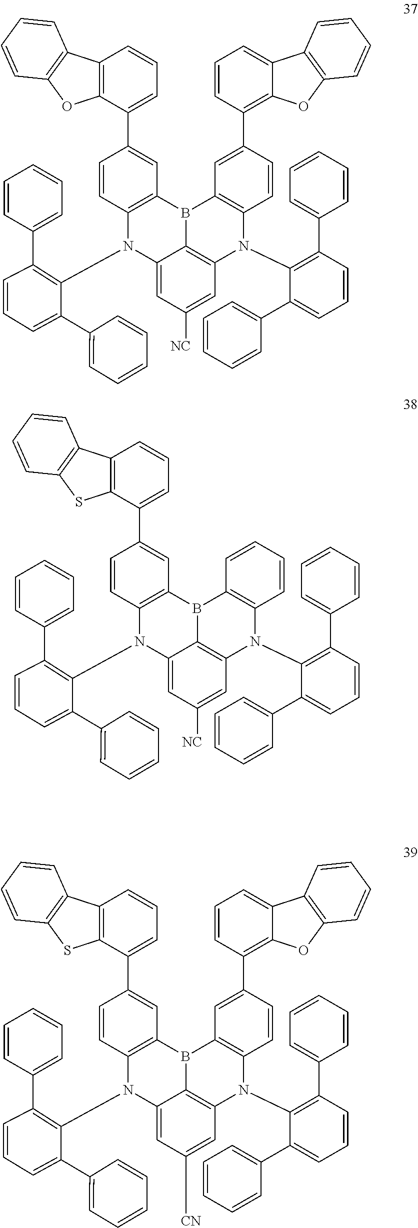 [SMILES: N#Cc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; N#Cc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1 ; N#Cc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1]

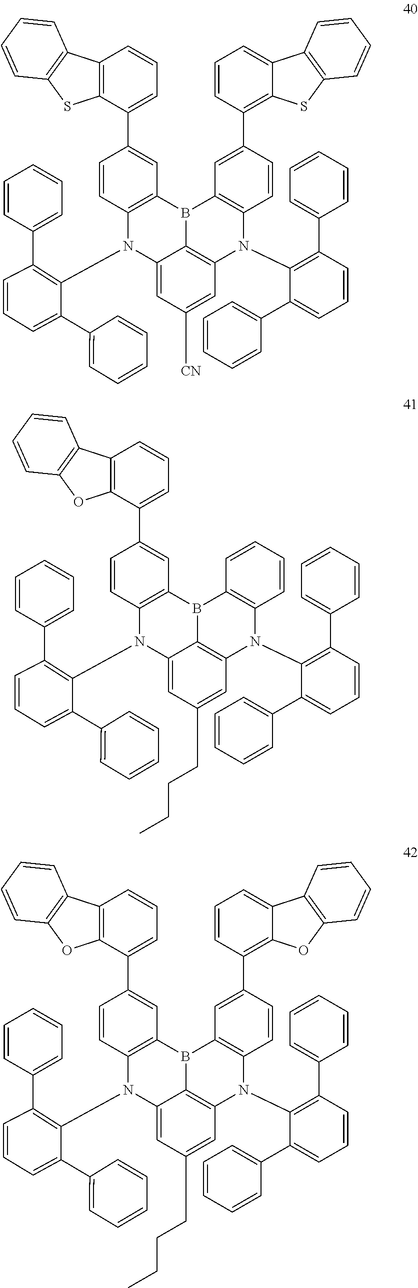 [SMILES: N#Cc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1]

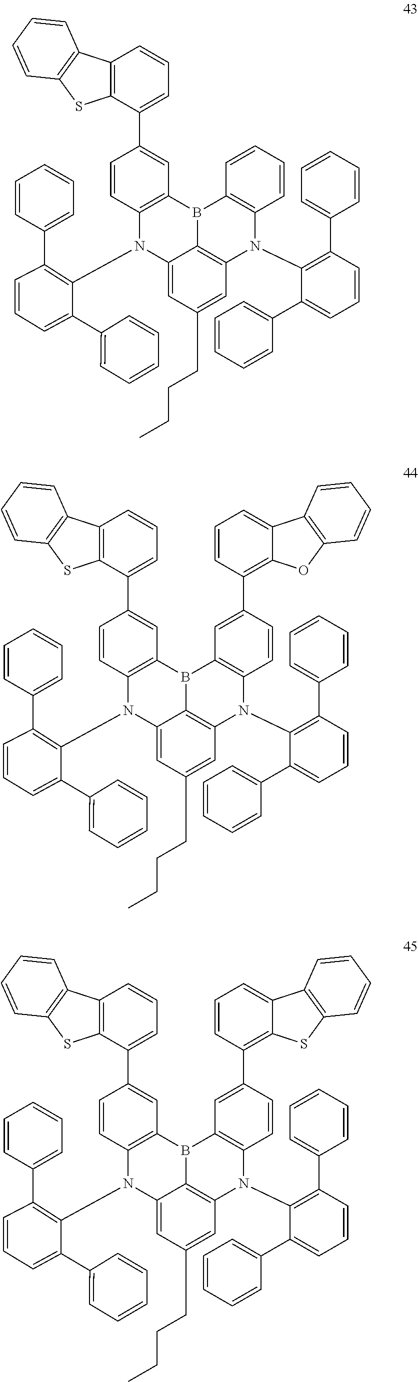 [SMILES: CCCCc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1]

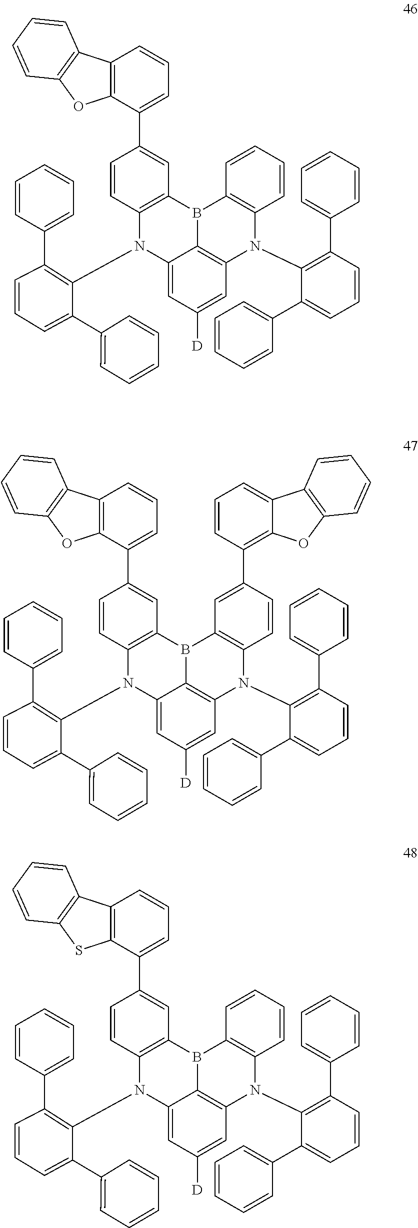 [SMILES: [2H]c1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; [2H]c1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; [2H]c1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1]

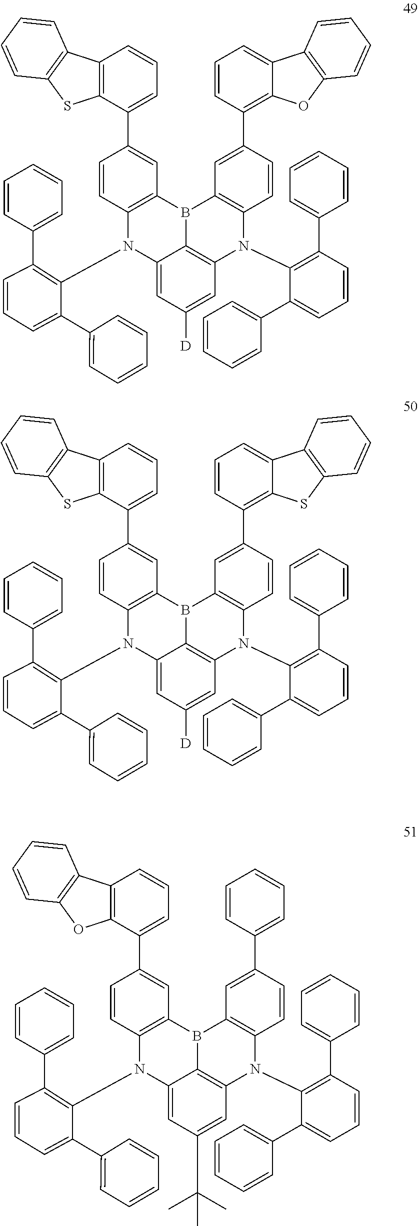 [SMILES: [2H]c1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; [2H]c1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4cccc5c4oc4ccccc45)cc1B3c1cc(-c3ccccc3)ccc1N2c1c(-c2ccccc2)cccc1-c1ccccc1]

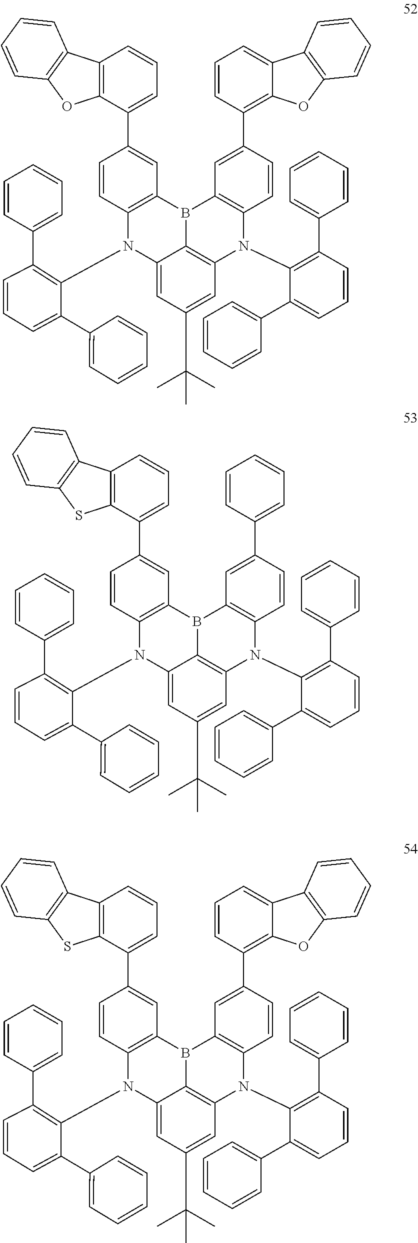 [SMILES: CC(C)(C)c1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4cccc5c4sc4ccccc45)cc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1]

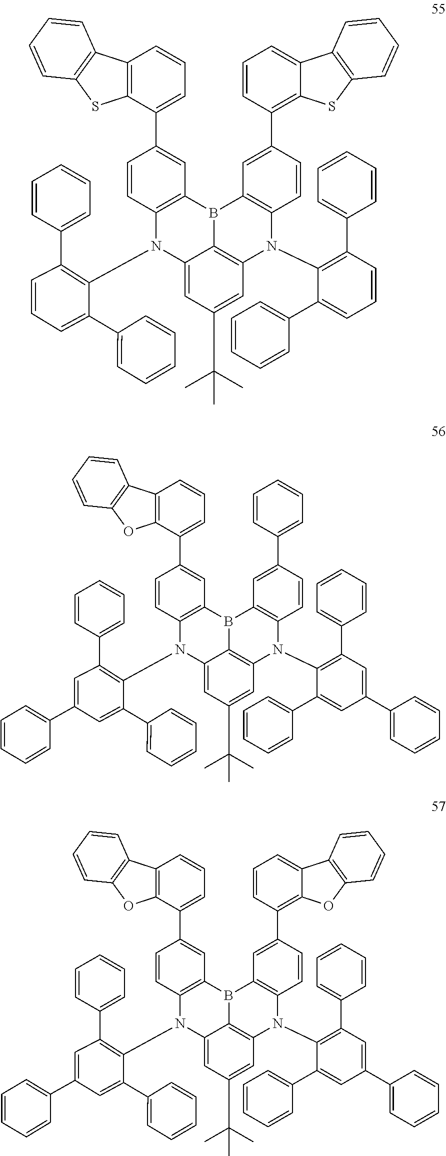 [SMILES: CC(C)(C)c1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccccc1)c1ccc(-c4cccc5c4oc4ccccc45)cc1B3c1cc(-c3ccccc3)ccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1ccc(-c4cccc5c4oc4ccccc45)cc1B3c1cc(-c3cccc4c3oc3ccccc34)ccc1N2c1c(-c2ccccc2)cc(-c2ccccc2)cc1-c1ccccc1]

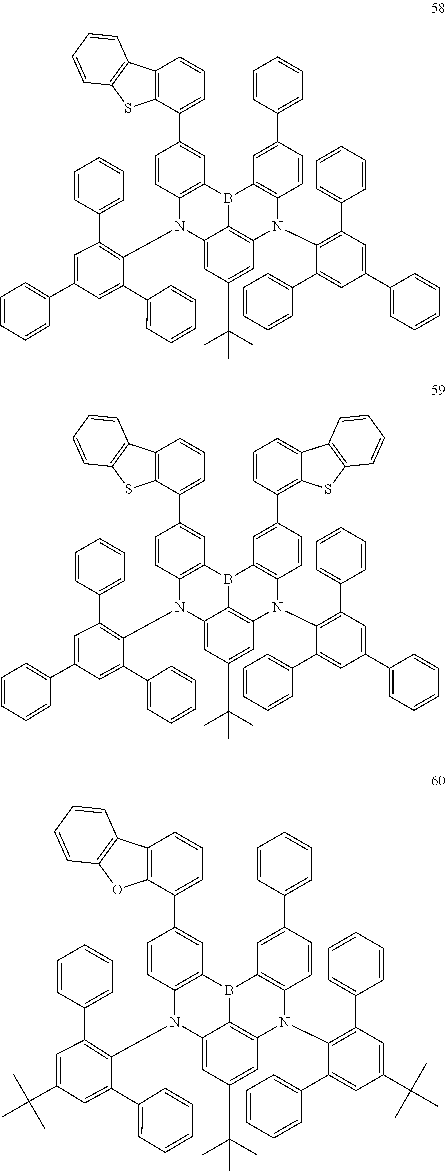 [SMILES: CC(C)(C)c1cc2c3c(c1)N(c1c(-c4ccccc4)cc(-c4ccccc4)cc1-c1ccccc1)c1ccc(-c4cccc5c4sc4ccccc45)cc1B3c1cc(-c3ccccc3)ccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1ccc(-c4cccc5c4sc4ccccc45)cc1B3c1cc(-c3cccc4c3sc3ccccc34)ccc1N2c1c(-c2ccccc2)cc(-c2ccccc2)cc1-c1ccccc1 ; CC(C)(C)c1cc(-c2ccccc2)c(N2c3ccc(-c4ccccc4)cc3B3c4cc(-c5cccc6c5oc5ccccc56)ccc4N(c4c(-c5ccccc5)cc(C(C)(C)C)cc4-c4ccccc4)c4cc(C(C)(C)C)cc2c43)c(-c2ccccc2)c1]

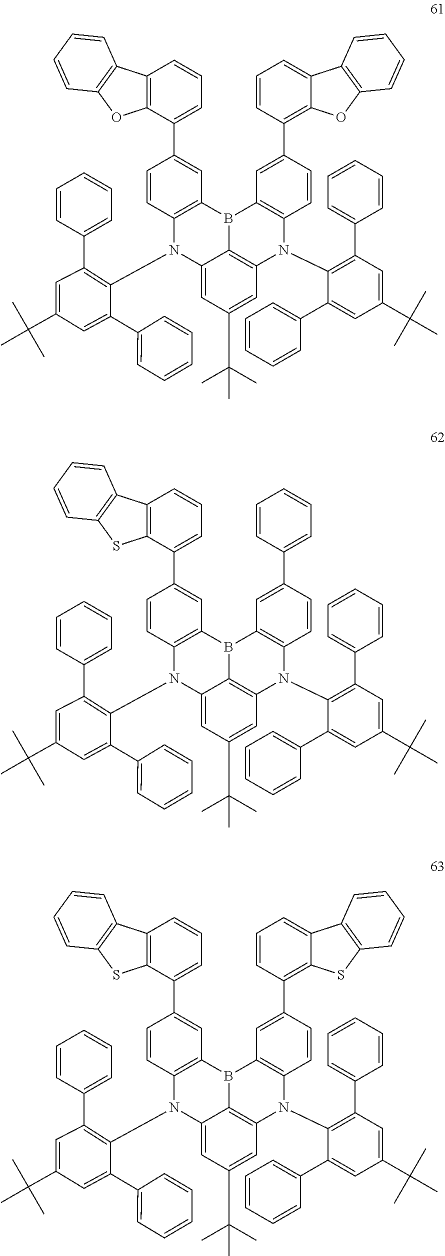

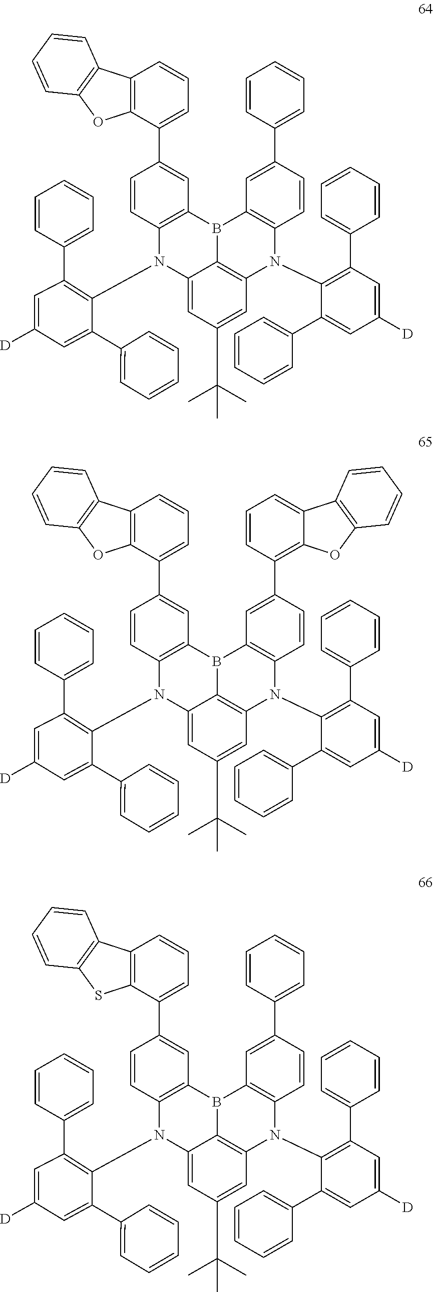 [SMILES: [2H]c1cc(-c2ccccc2)c(N2c3ccc(-c4ccccc4)cc3B3c4cc(-c5cccc6c5oc5ccccc56)ccc4N(c4c(-c5ccccc5)cc([2H])cc4-c4ccccc4)c4cc(C(C)(C)C)cc2c43)c(-c2ccccc2)c1 ; [2H]c1cc(-c2ccccc2)c(N2c3ccc(-c4cccc5c4oc4ccccc45)cc3B3c4cc(-c5cccc6c5oc5ccccc56)ccc4N(c4c(-c5ccccc5)cc([2H])cc4-c4ccccc4)c4cc(C(C)(C)C)cc2c43)c(-c2ccccc2)c1 ; [2H]c1cc(-c2ccccc2)c(N2c3ccc(-c4ccccc4)cc3B3c4cc(-c5cccc6c5sc5ccccc56)ccc4N(c4c(-c5ccccc5)cc([2H])cc4-c4ccccc4)c4cc(C(C)(C)C)cc2c43)c(-c2ccccc2)c1]

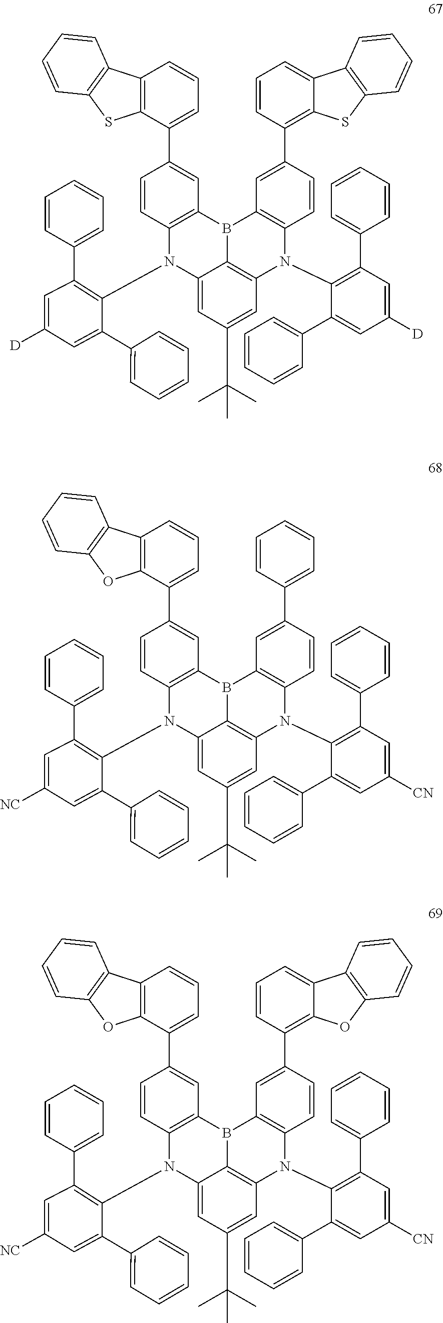 [SMILES: [2H]c1cc(-c2ccccc2)c(N2c3ccc(-c4cccc5c4sc4ccccc45)cc3B3c4cc(-c5cccc6c5sc5ccccc56)ccc4N(c4c(-c5ccccc5)cc([2H])cc4-c4ccccc4)c4cc(C(C)(C)C)cc2c43)c(-c2ccccc2)c1 ; CC(C)(C)c1cc2c3c(c1)N(c1c(-c4ccccc4)cc(C#N)cc1-c1ccccc1)c1ccc(-c4cccc5c4oc4ccccc45)cc1B3c1cc(-c3ccccc3)ccc1N2c1c(-c2ccccc2)cc(C#N)cc1-c1ccccc1 ; CC(C)(C)c1cc2c3c(c1)N(c1c(-c4ccccc4)cc(C#N)cc1-c1ccccc1)c1ccc(-c4cccc5c4oc4ccccc45)cc1B3c1cc(-c3cccc4c3oc3ccccc34)ccc1N2c1c(-c2ccccc2)cc(C#N)cc1-c1ccccc1]

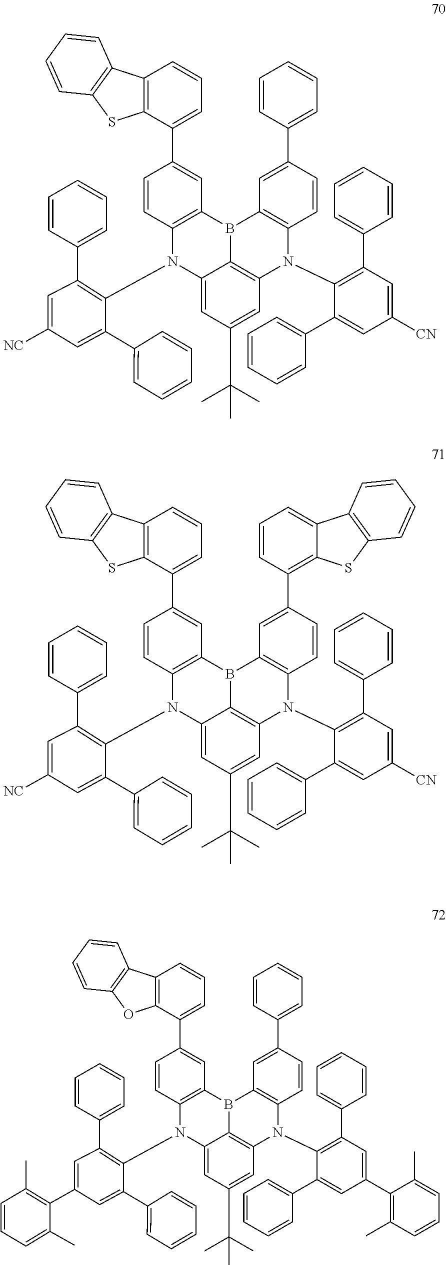 [SMILES: CC(C)(C)c1cc2c3c(c1)N(c1c(-c4ccccc4)cc(C#N)cc1-c1ccccc1)c1ccc(-c4cccc5c4sc4ccccc45)cc1B3c1cc(-c3ccccc3)ccc1N2c1c(-c2ccccc2)cc(C#N)cc1-c1ccccc1 ; CC(C)(C)c1cc2c3c(c1)N(c1c(-c4ccccc4)cc(C#N)cc1-c1ccccc1)c1ccc(-c4cccc5c4sc4ccccc45)cc1B3c1cc(-c3cccc4c3sc3ccccc34)ccc1N2c1c(-c2ccccc2)cc(C#N)cc1-c1ccccc1 ; Cc1cccc(C)c1-c1cc(-c2ccccc2)c(N2c3ccc(-c4ccccc4)cc3B3c4cc(-c5cccc6c5oc5ccccc56)ccc4N(c4c(-c5ccccc5)cc(-c5c(C)cccc5C)cc4-c4ccccc4)c4cc(C(C)(C)C)cc2c43)c(-c2ccccc2)c1]

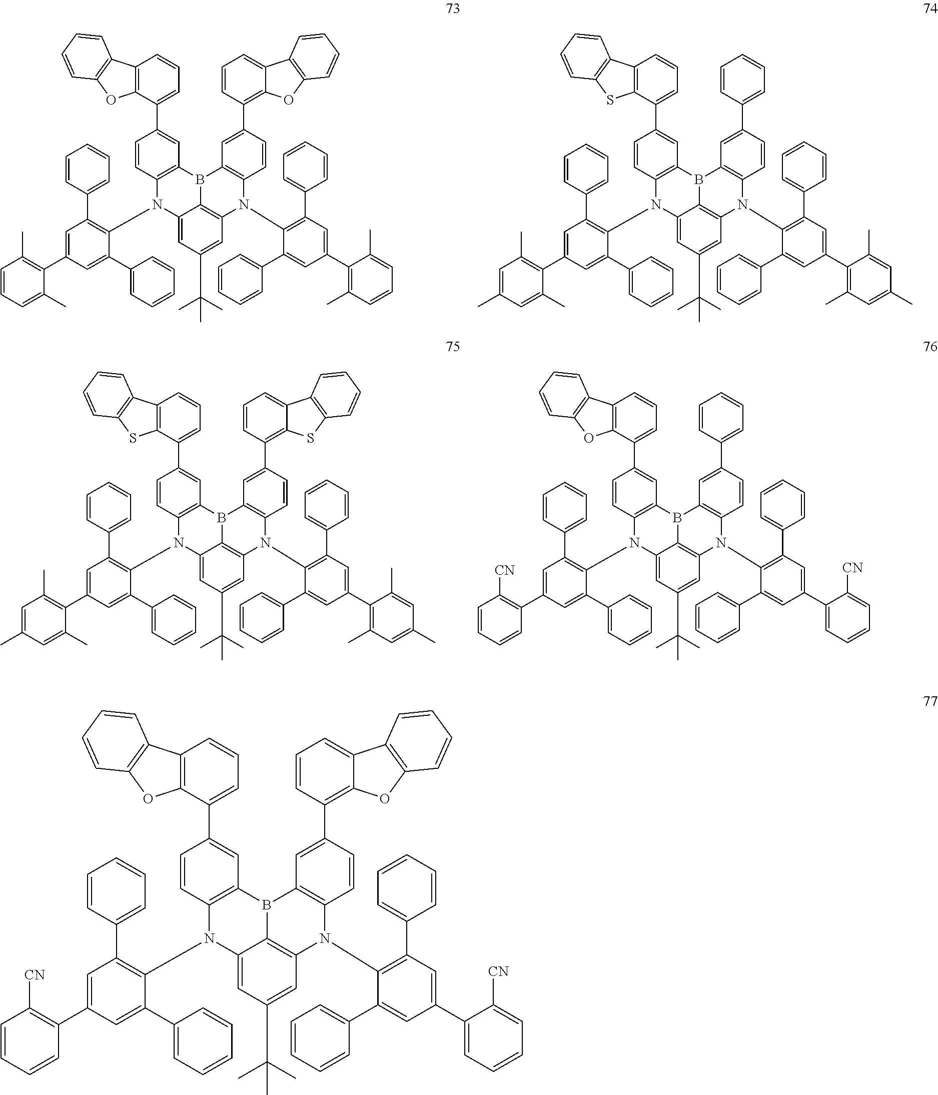

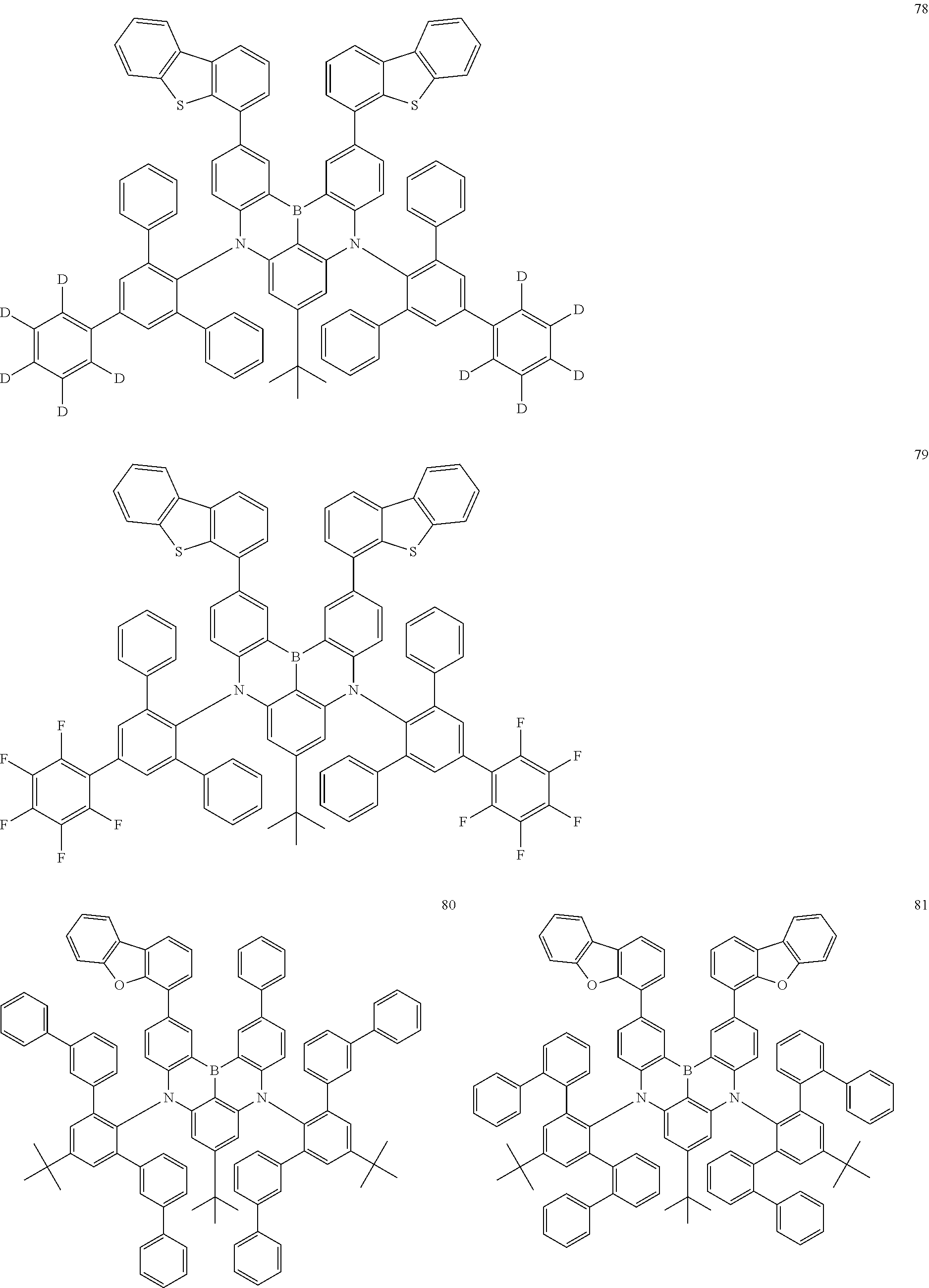

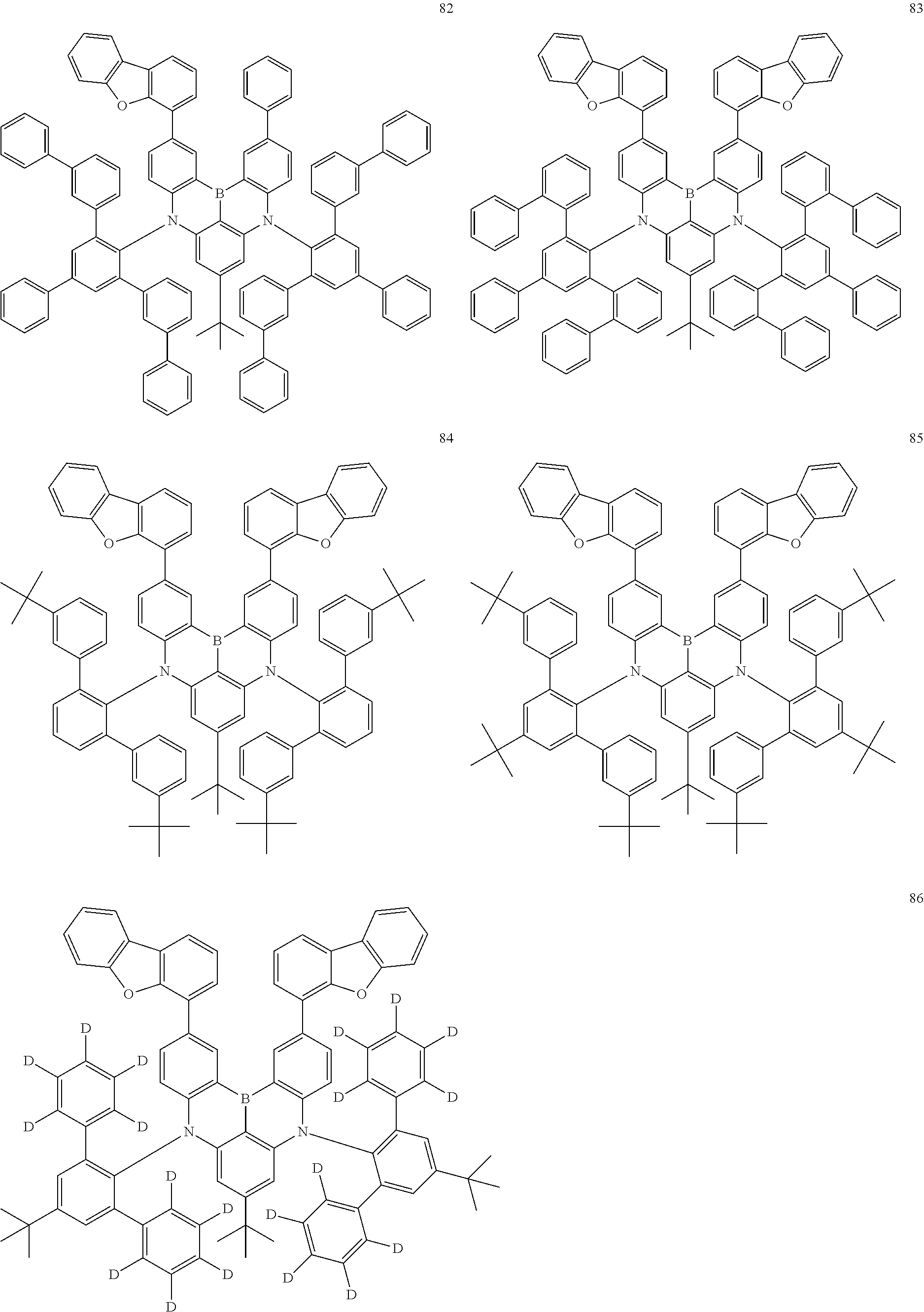

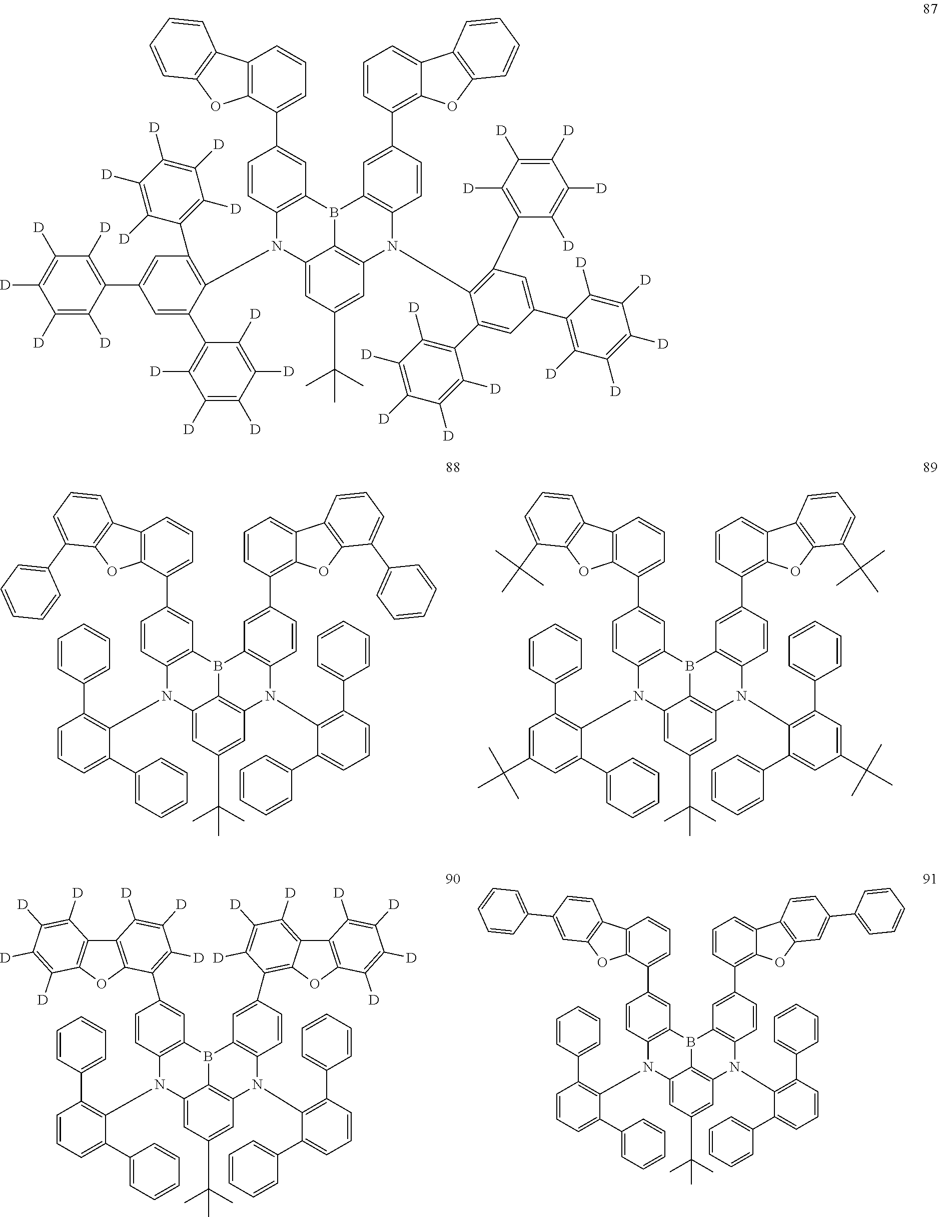

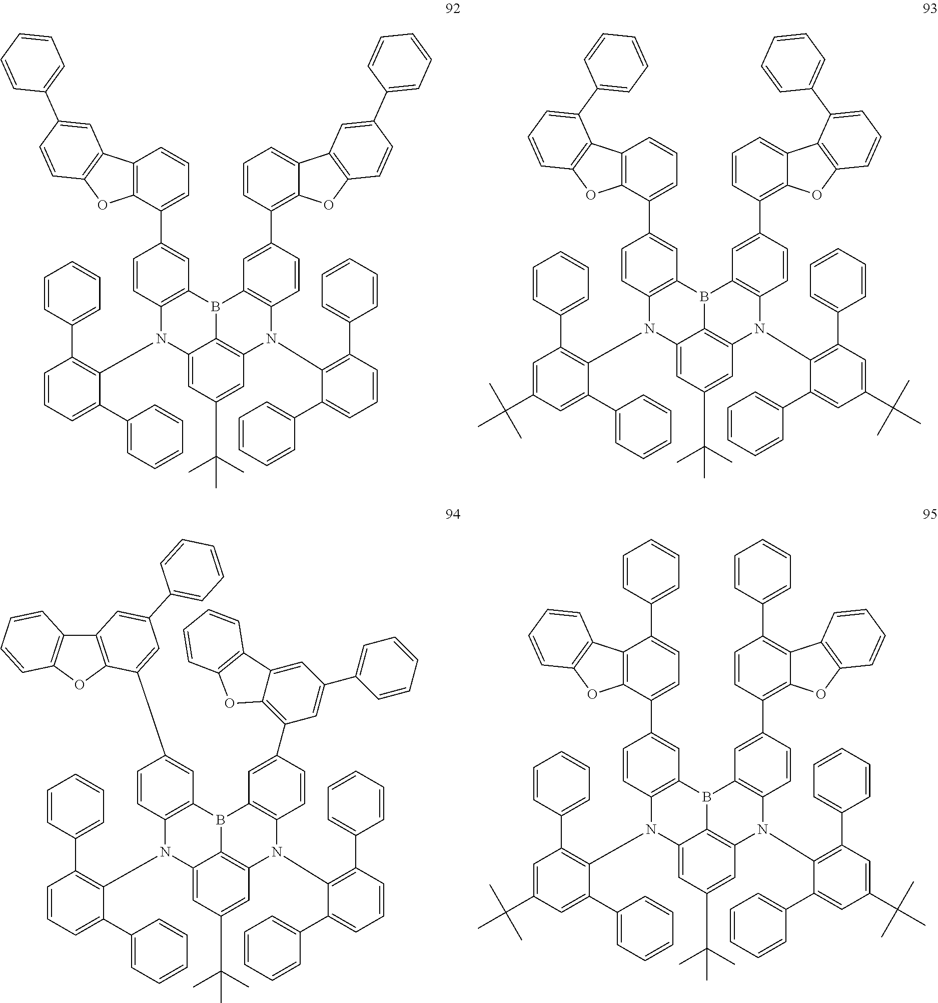

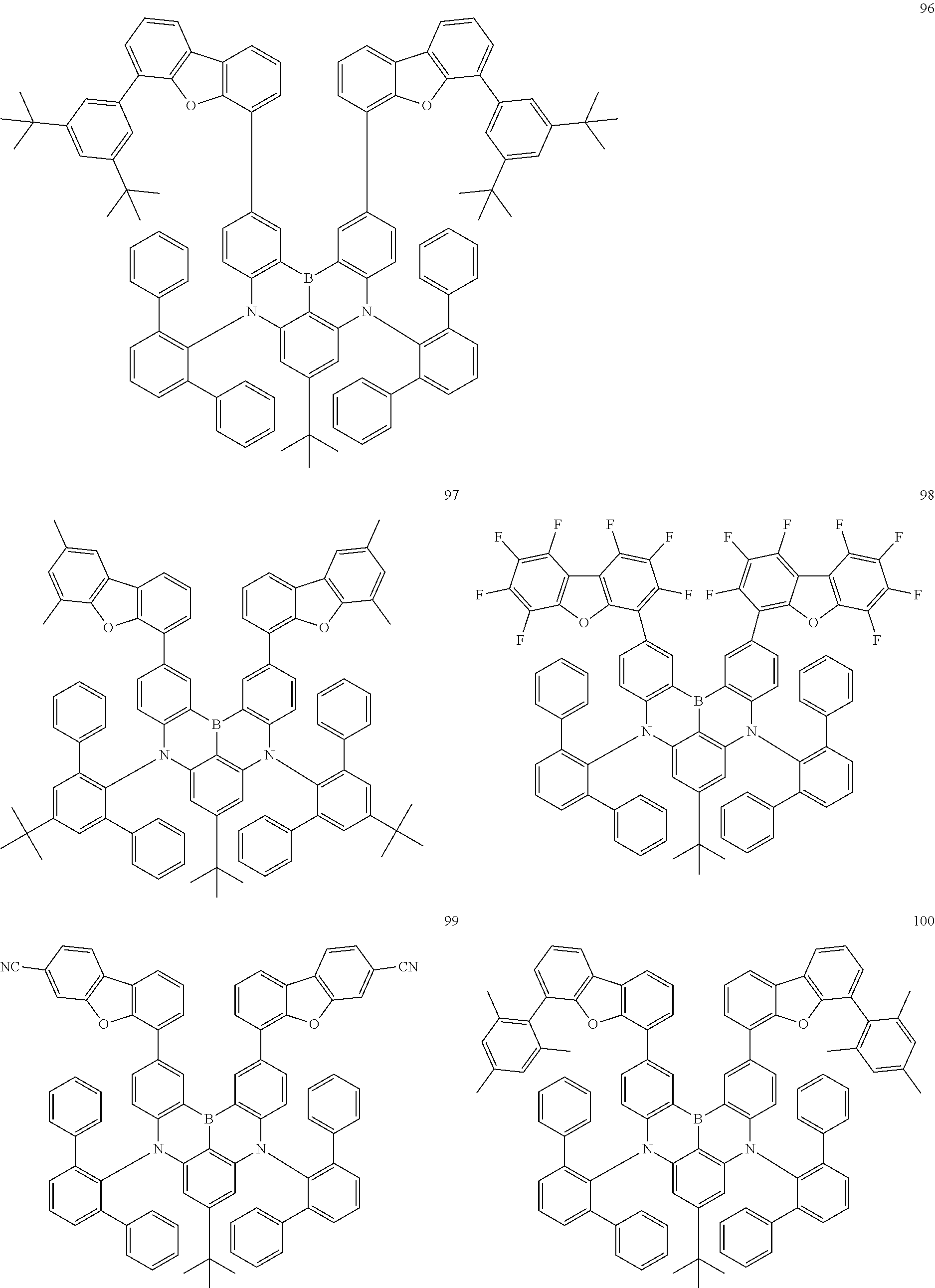

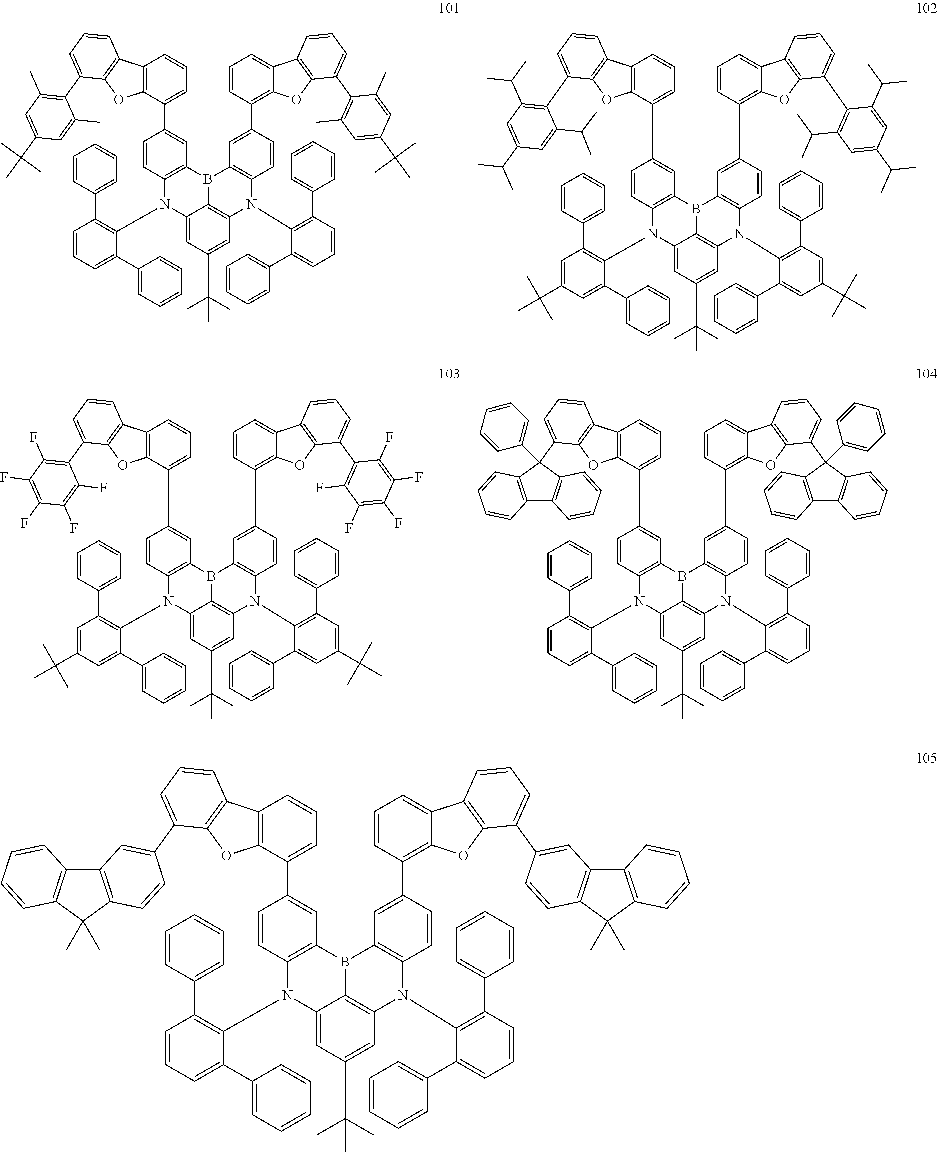

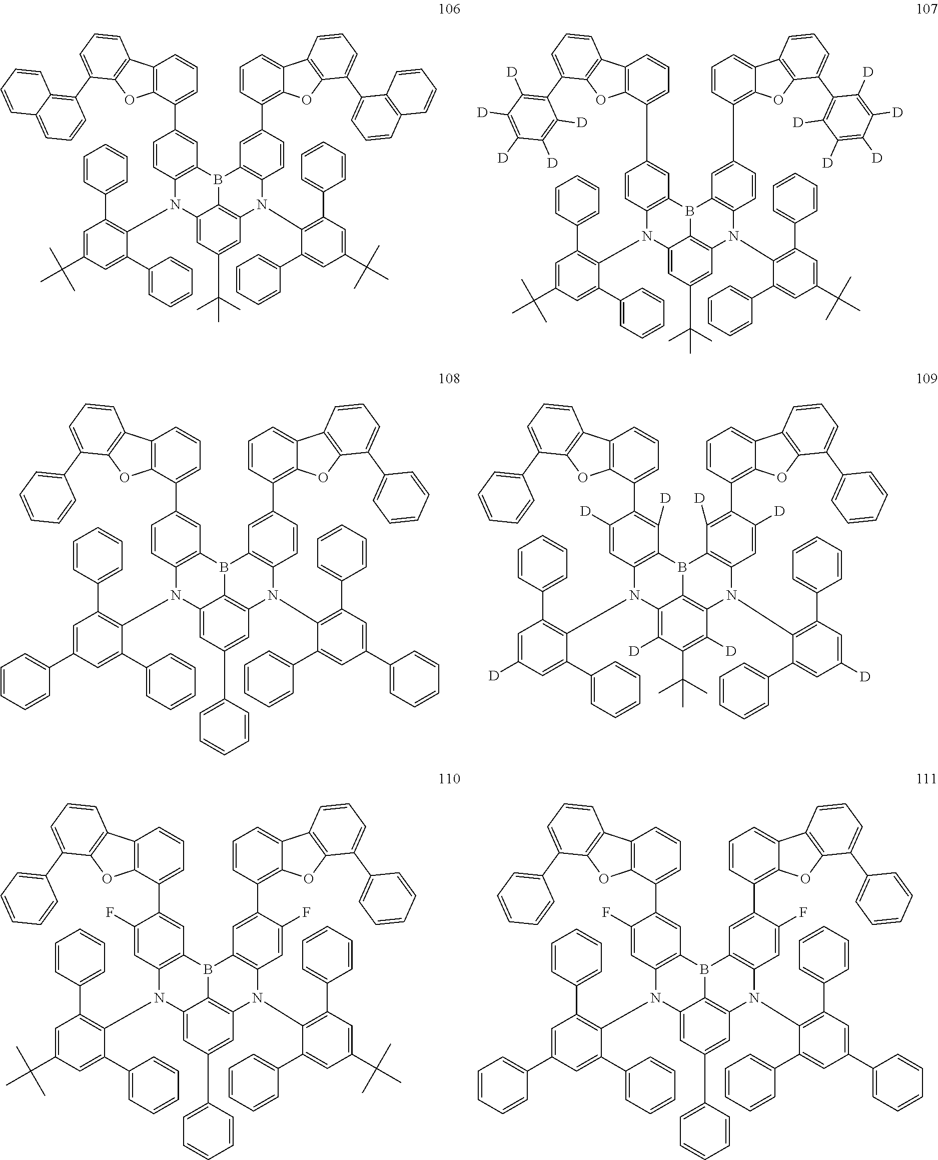

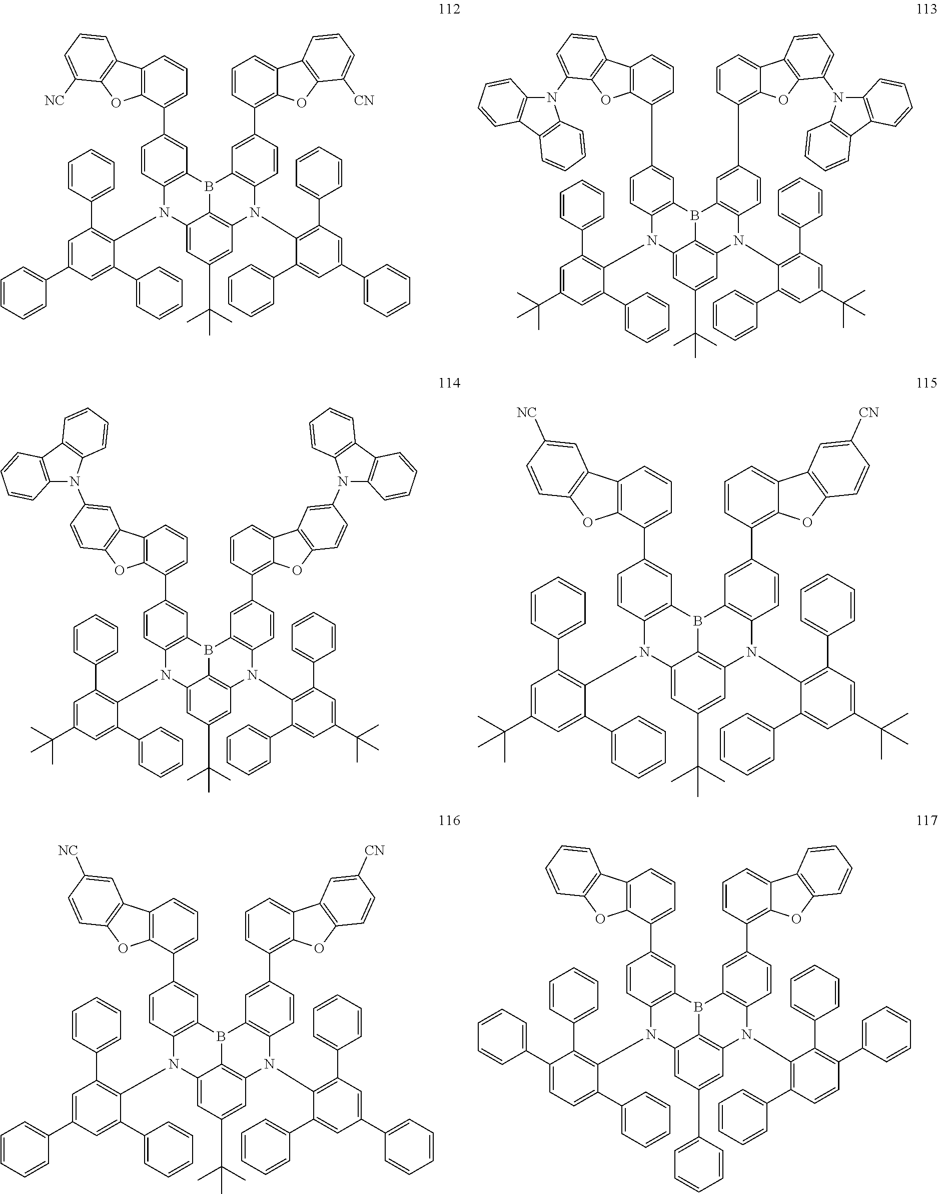

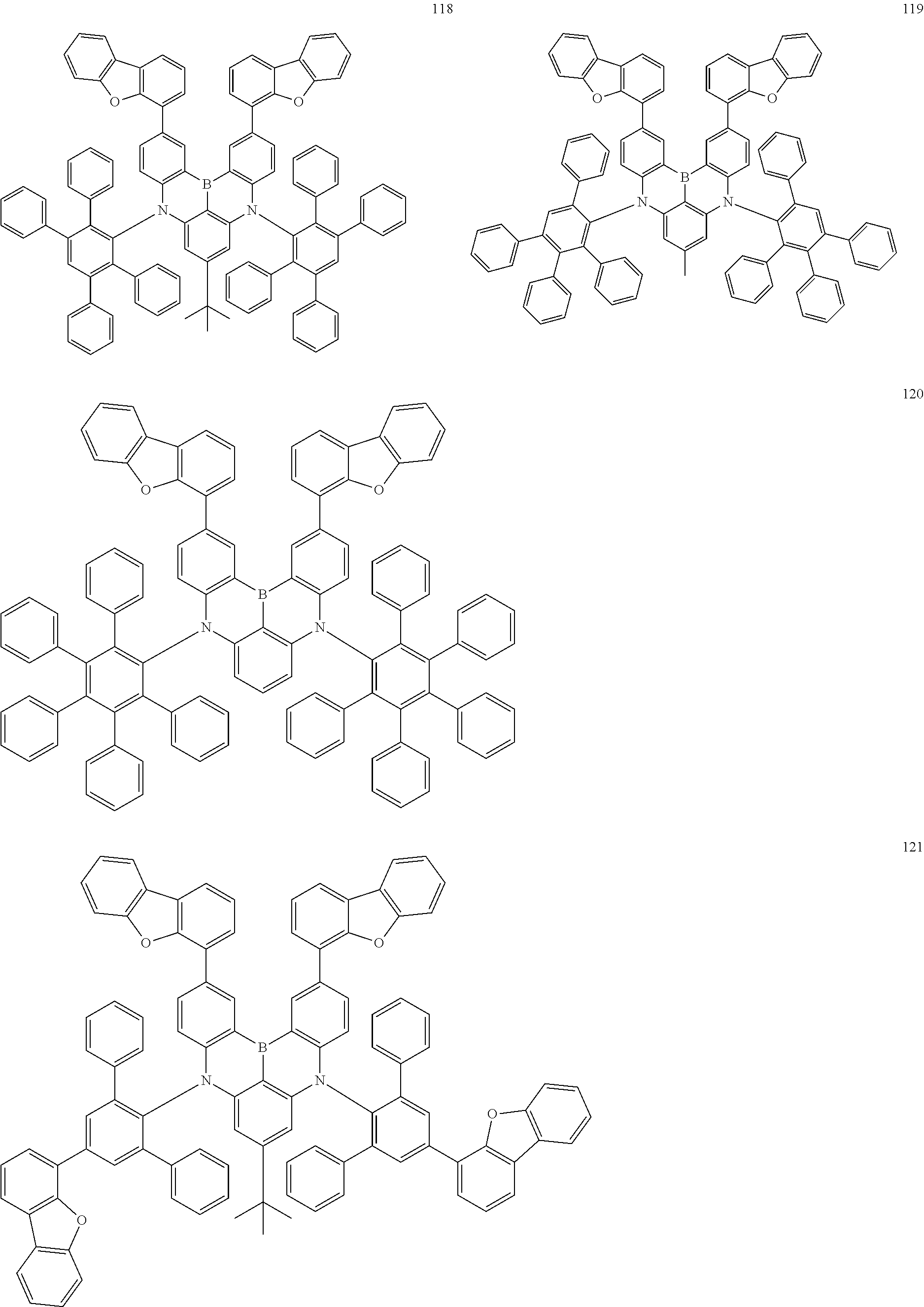

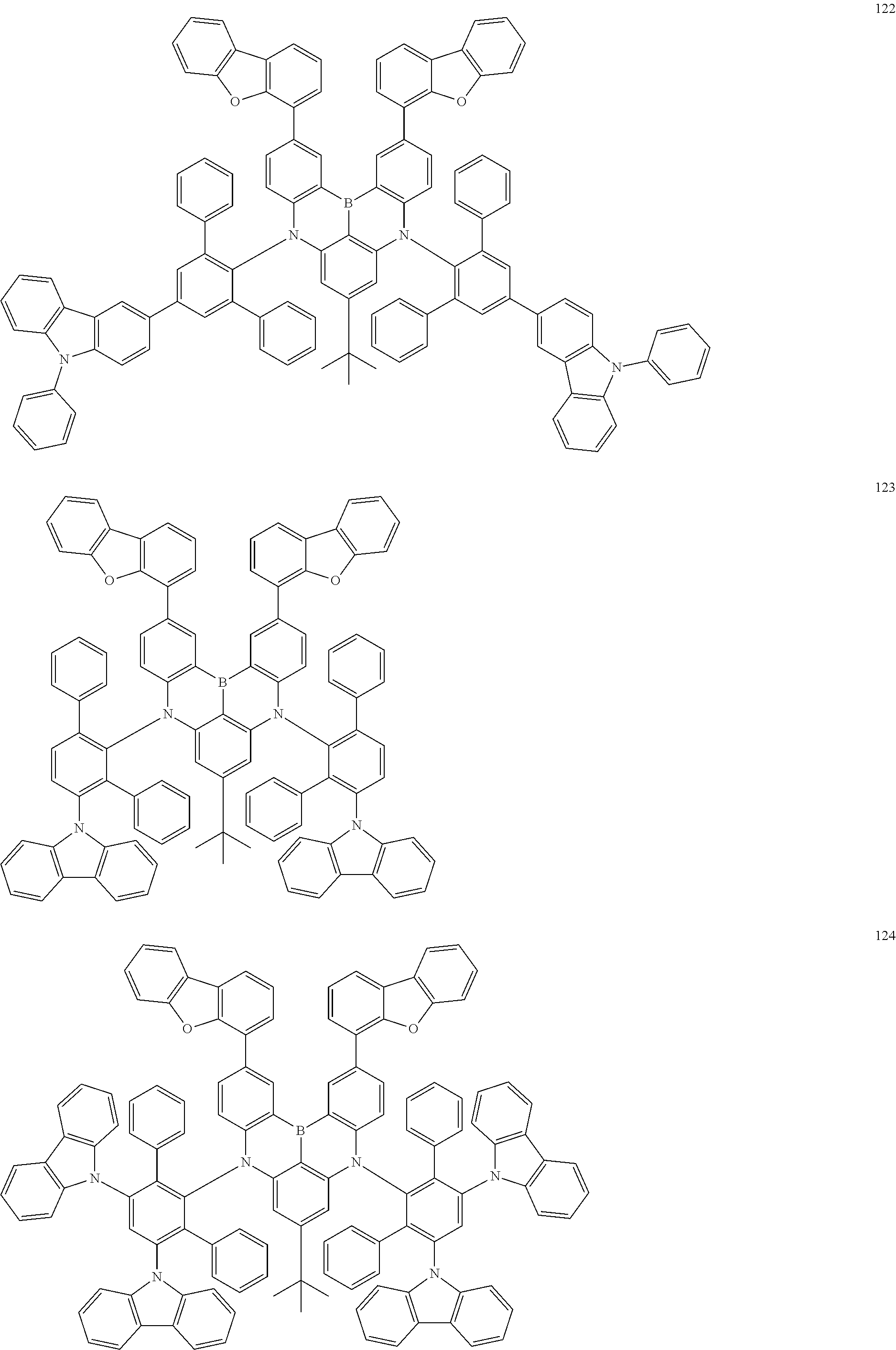

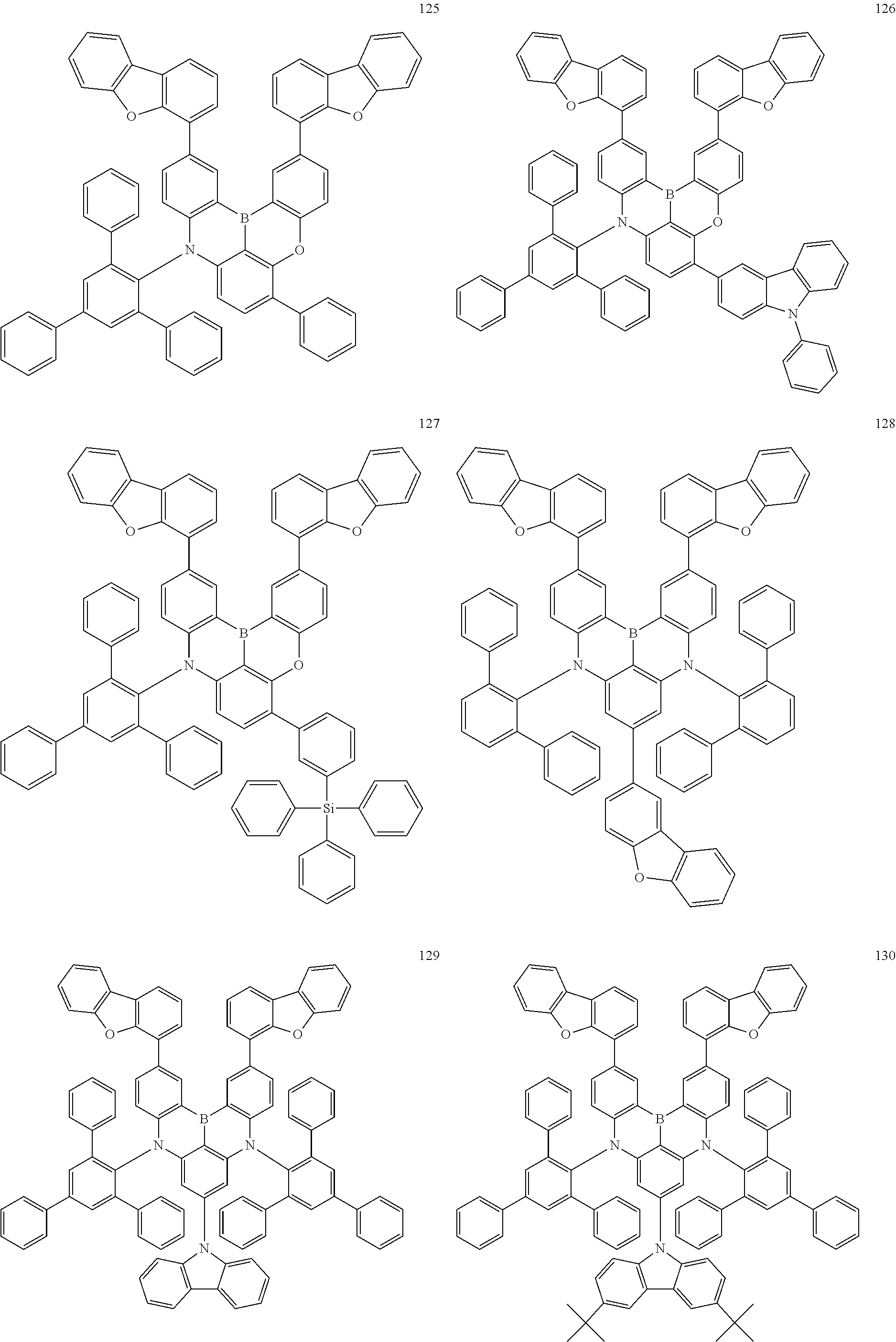

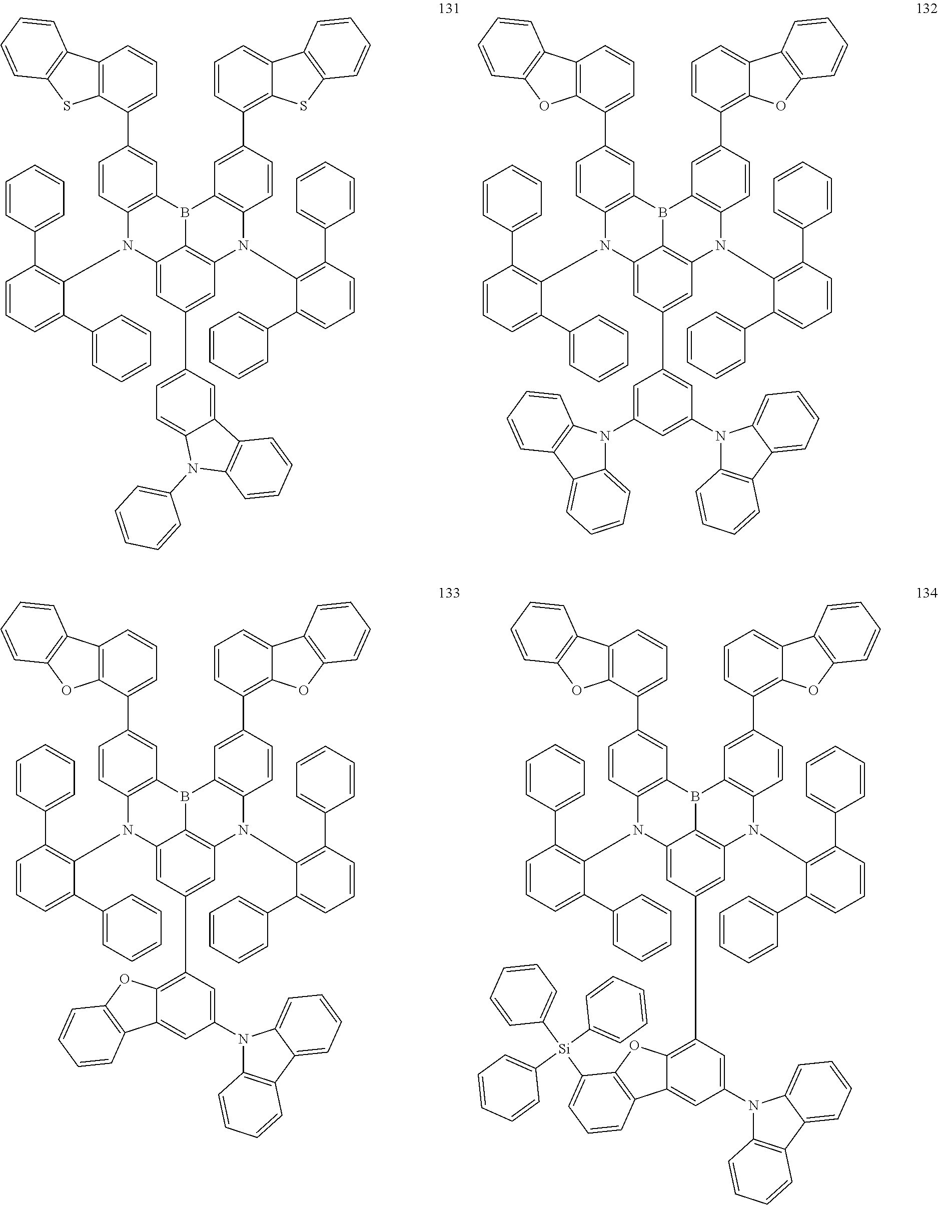

In the embodiment compounds presented in Compound Group 1, “D” refers to a deuterium atom.

The fused polycyclic compound represented by Formula 1 according to an embodiment has a structure in which the first substituent and the second substituent are introduced, and thus may achieve long service life.

The fused polycyclic compound represented by Formula 1 of an embodiment may have a structure which includes the fused ring core in which the first to third aromatic rings are fused via the boron atom, the first heteroatom, and the second heteroatom, and in which the first substituent is substituted at a specific position of the first aromatic ring or the second aromatic ring. The first substituent may include a dibenzofuran moiety or a dibenzothiophene moiety. For example, carbon 1 of the first substituent may be linked to the first aromatic ring or the second aromatic ring at the meta position based on (with respect to) the boron atom of the fused ring core. The fused polycyclic compound represented by Formula 1 of an embodiment has a structure in which the second substituent is substituted at the nitrogen atom that is the first heteroatom. The second substituent includes a benzene moiety linked to the nitrogen atom that is the first heteroatom, and the benzene moiety may be a structure in which substituted or unsubstituted phenyl groups are respectively bonded at both (e.g., simultaneously) ortho positions with respect to the nitrogen atom that is the first heteroatom.

The fused polycyclic compound of an embodiment has a structure in which the first substituent and the second substituent are introduced at the fused ring core, and thus may exhibit improved device service life characteristics. The fused polycyclic compound of an embodiment may effectively maintain a trigonal planar structure of the boron atom through the steric hindrance effect, by including the first substituent and the second substituent. In some embodiments, the fused polycyclic compound of an embodiment may control aggregation by the suppression of intermolecular interaction through the steric hindrance effect by the first substituent and the second substituent, and thus the luminous efficiency may be increased and film formation quality may be improved when organic layers of the light emitting device ED are formed. The fused polycyclic compound of an embodiment may control the rr-conjugation length of the whole molecule by introducing the first substituent and second substituent at a specific position, and thus the luminescence wavelength may be blue-shifted. In some embodiments, the fused polycyclic compound represented by Formula 1 of an embodiment is included in the light emitting device ED of an embodiment, and thus Forster energy transfer may be increased in auxiliary dopants and Dexter energy transfer may be decreased. According to the present disclosure, by including the first substituent and the second substituent having the large steric hindrance structure, the distance between adjacent molecules increases to thereby suppress or reduce the Dexter energy transfer, and thus the deterioration of service life due to the increase of triplet concentration may be suppressed or reduced. Therefore, when the fused polycyclic compound of an embodiment is applied to the emission layer EML of the light emitting device ED, the luminous efficiency may be increased and the device service life may be improved. The emission spectrum of the fused polycyclic compound represented by Formula 1 of an embodiment may have a full width of half maximum (FWHM) of about 10 nm to about 50 nm, or a FWHM of about 20 nm to about 40 nm. The emission spectrum of the fused polycyclic compound represented by Formula 1 of an embodiment has the above ranges of half-width, thereby improving luminous efficiency when applied to a device. In some embodiments, when the fused polycyclic compound of an embodiment is utilized as a blue light emitting device material for the luminescence device, the service life of the device may be improved.

The fused polycyclic compound represented by Formula 1 of an embodiment may be a thermally activated delayed fluorescence emitting material. Furthermore, the fused polycyclic compound represented by Formula 1 of an embodiment may be a thermally activated delayed fluorescence dopant having the difference (AEST) between the lowest triplet exciton energy level (T1 level) and the lowest singlet exciton energy level (S1 level) of about 0.6 eV or less. The fused polycyclic compound represented by Formula 1 of an embodiment may be a thermally activated delayed fluorescence dopant having the difference (AEST) between a lowest triplet exciton energy level (T1 level) and a lowest singlet exciton energy level (S1 level) of 0.2 eV or less.

The fused polycyclic compound represented by Formula 1 of an embodiment may be a luminescent material having a luminescence center wavelength (e.g., emission peak wavelength or emission center wavelength) in a wavelength region of about 430 nm to about 490 nm. For example, the fused polycyclic compound represented by Formula 1 of an embodiment may be a blue thermally activated delayed fluorescence (TADF) dopant. However, the embodiment of the present disclosure is not limited thereto, and when the fused polycyclic compound of an embodiment is utilized as a luminescent material, the first dopant may be utilized as a dopant material that emits light in one or more suitable wavelength regions, such as a red emitting dopant or a green emitting dopant.

The emission layer EML in the light emitting device ED of an embodiment may be to emit delayed fluorescence. For example, the emission layer EML may be to emit thermally activated delayed fluorescence (TADF).

In some embodiments, the emission layer EML of the light emitting device ED may be to emit blue light. For example, the emission layer EML of the organic electroluminescence device ED of an embodiment may be to emit blue light in the wavelength region of about 490 nm or less. However, the embodiment of the present disclosure is not limited thereto, and the emission layer EML may be to emit green light or red light.

In some embodiments, the fused polycyclic compound of an embodiment may be included in the emission layer EML. The fused polycyclic compound of an embodiment may be included as a dopant material in the emission layer EML. The fused polycyclic compound of an embodiment may be a thermally activated delayed fluorescence material. The fused polycyclic compound of an embodiment may be utilized as a thermally activated delayed fluorescence dopant. For example, in the light emitting device ED of an embodiment, the emission layer EML may include, as a thermally activated delayed fluorescence dopant, at least one of the fused polycyclic compounds from Compound Group 1 as described above. However, a usage of the fused polycyclic compound of an embodiment is not limited thereto.

In an embodiment, the emission layer EML may include a plurality of compounds. The emission layer EML of an embodiment may include the fused polycyclic compound represented by Formula 1, i.e., the first compound, and may further include at least one of the second compound represented by Formula HT-1, the third compound represented by Formula ET-1, the fourth compound represented by Formula D-1, or the fifth compound represented by Formula DA.

In an embodiment, the emission layer EML may include the first compound represented by Formula 1, and may further include at least one of the second compound represented by Formula HT-1, or the third compound represented by Formula ET-1.

In an embodiment, the emission layer EML may include the second compound represented by Formula HT-1. In an embodiment, the second compound may be utilized as a hole transporting host material of the emission layer EML.

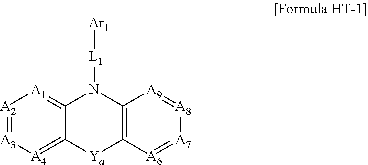

In Formula HT-1, A₁ to A₉ may each independently be N or CR₄₁. For example, all of A₁ to A₉ may each independently be CR₅₁. In some embodiments, any one among A₁ to A₉ may be N, and the rest (any remainder thereof) may each independently be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but the embodiment of the present disclosure is not limited thereto.

In Formula HT-1, Yₐ may be a direct linkage, CR₅₂R₅₃, or SiR₅₄R₅₅. For example, the two benzene rings linked to the nitrogen atom in Formula HT-1 may be further linked via a direct linkage,

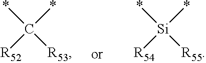

In Formula HT-1, when Yₐ is a direct linkage, the substituent represented by Formula HT-1 may include a carbazole moiety.

In Formula HT-1, Ar may be a substituted or unsubstituted aryl group having 6 to 30 ring-forming carbon atoms, or a substituted or unsubstituted heteroaryl group having 2 to 30 ring-forming carbon atoms. For example, Ar may be a substituted or unsubstituted carbazole group, a substituted or unsubstituted dibenzofuran group, a substituted or unsubstituted dibenzothiophene group, a substituted or unsubstituted biphenyl group, etc., but the embodiment of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₅ may be bonded to an adjacent group to form a ring. For example, R₅₁ to R₅₅ may each independently be a hydrogen atom or a deuterium atom, or R₅₁ to R₅₅ may each independently be an unsubstituted methyl group or an unsubstituted phenyl group.

In an embodiment, the second compound represented by Formula HT-1 may be represented by any one among the compounds represented by Compound Group 2. The emission layer EML may include at least one among the compounds represented by Compound Group 2 as a hole transporting host material.

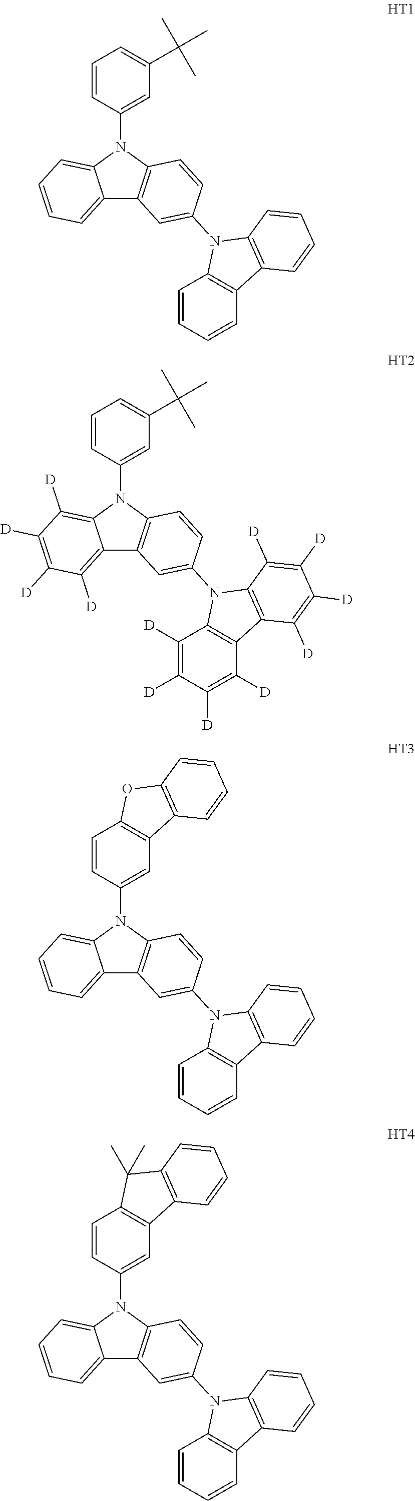

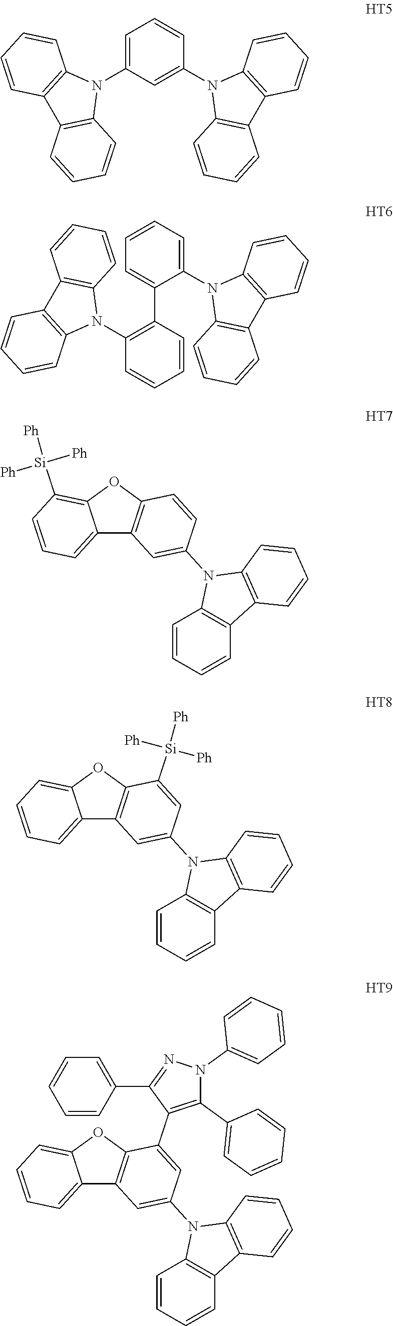

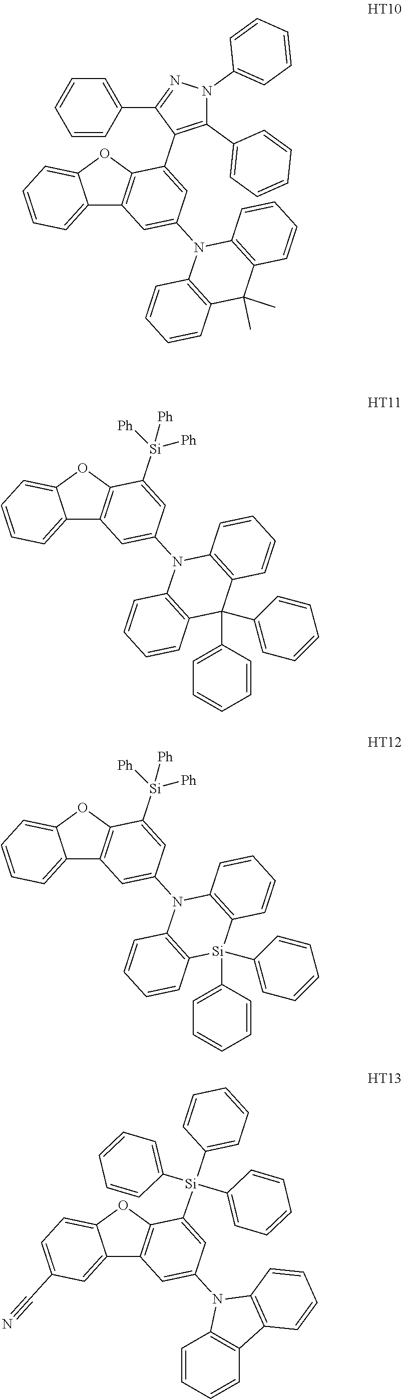

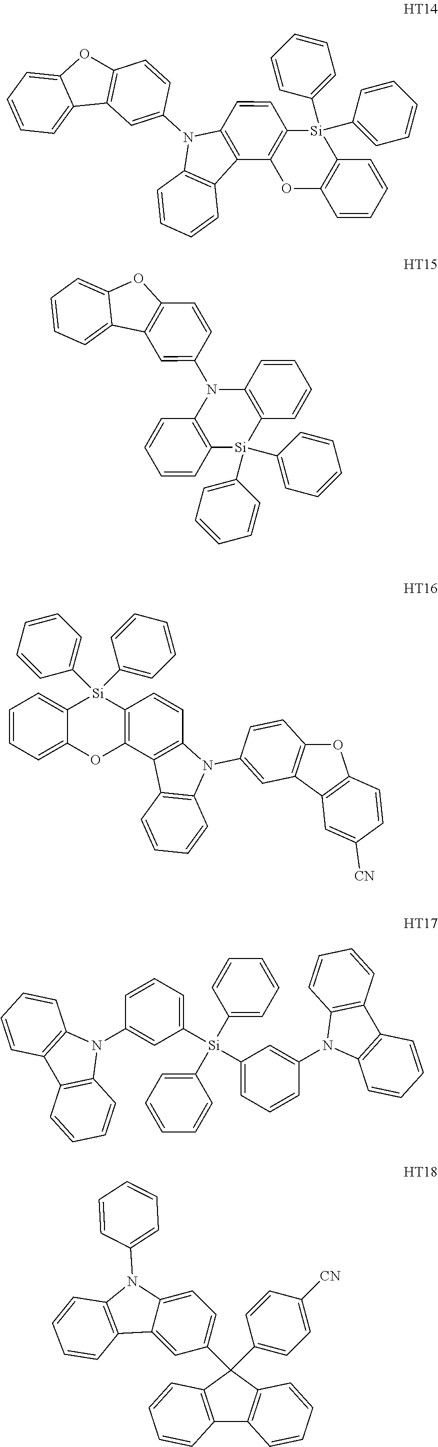 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

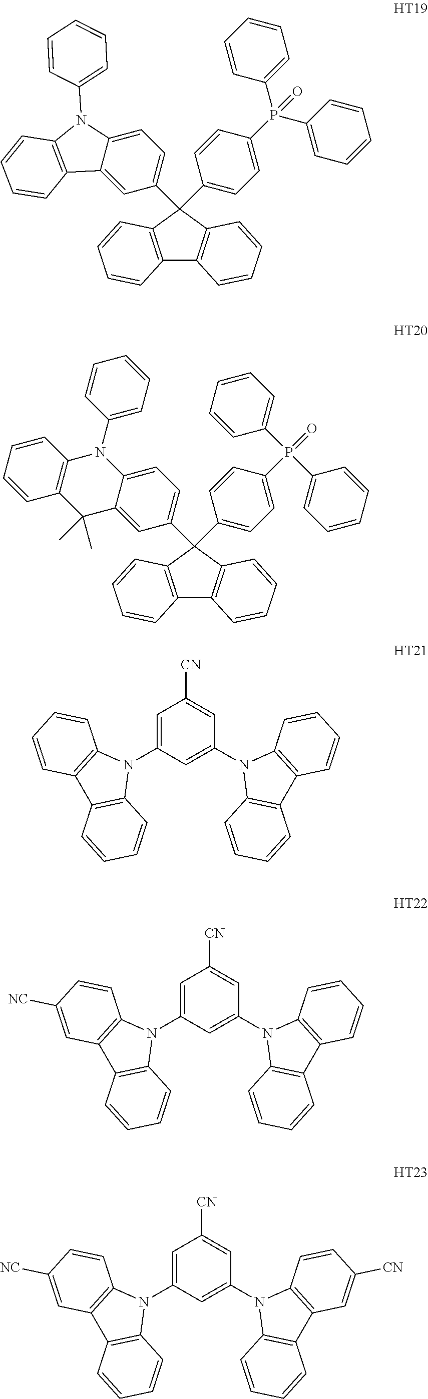 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1]

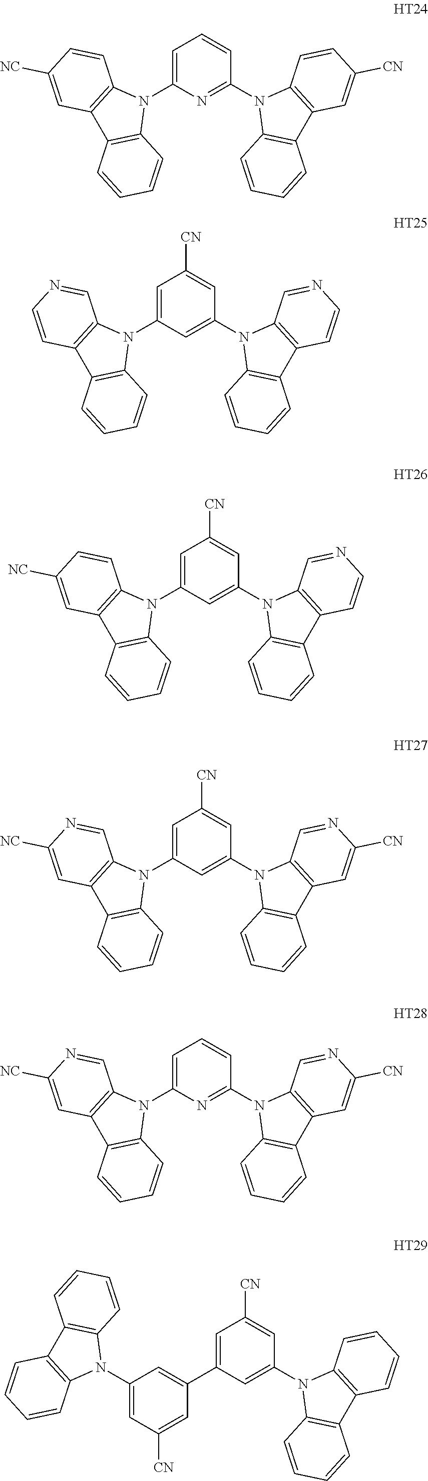 [SMILES: N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

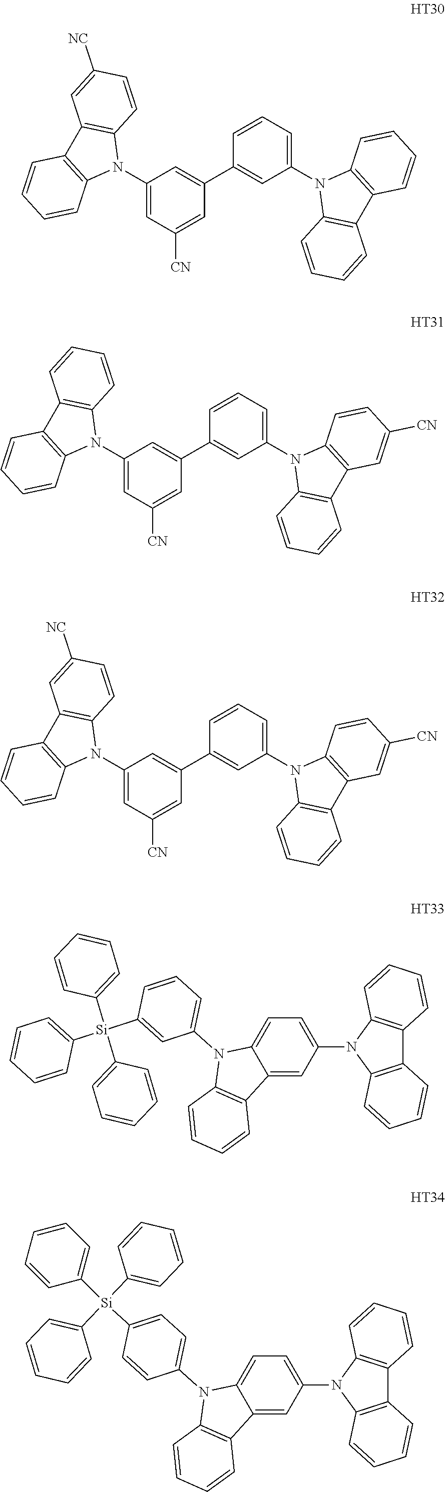 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

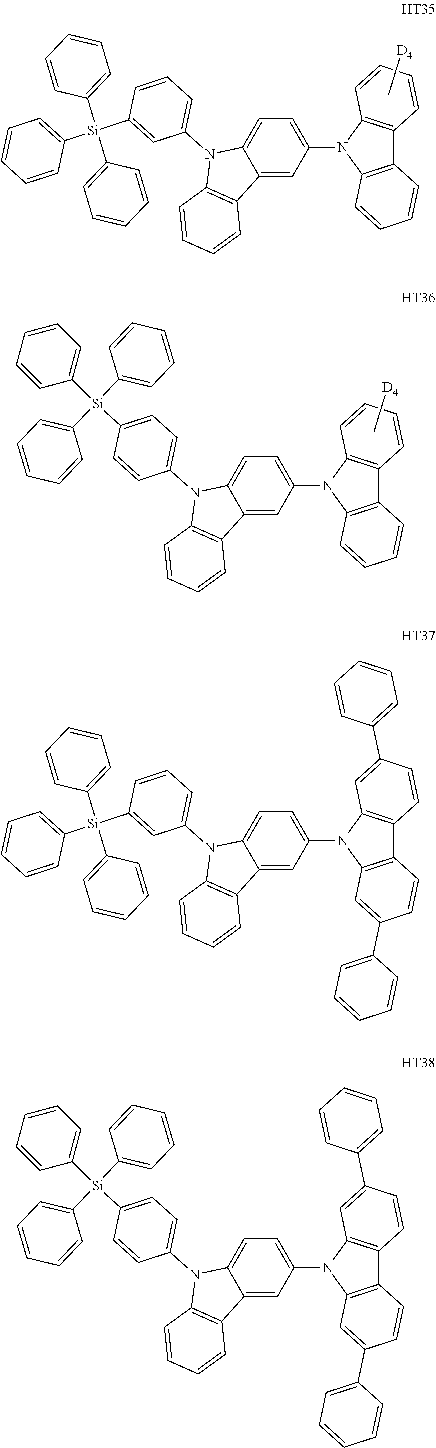

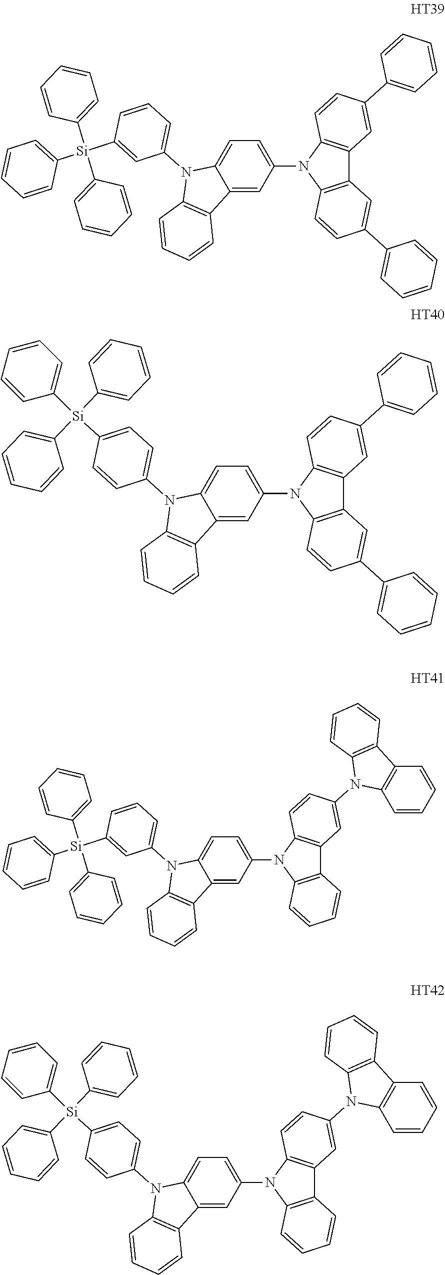 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

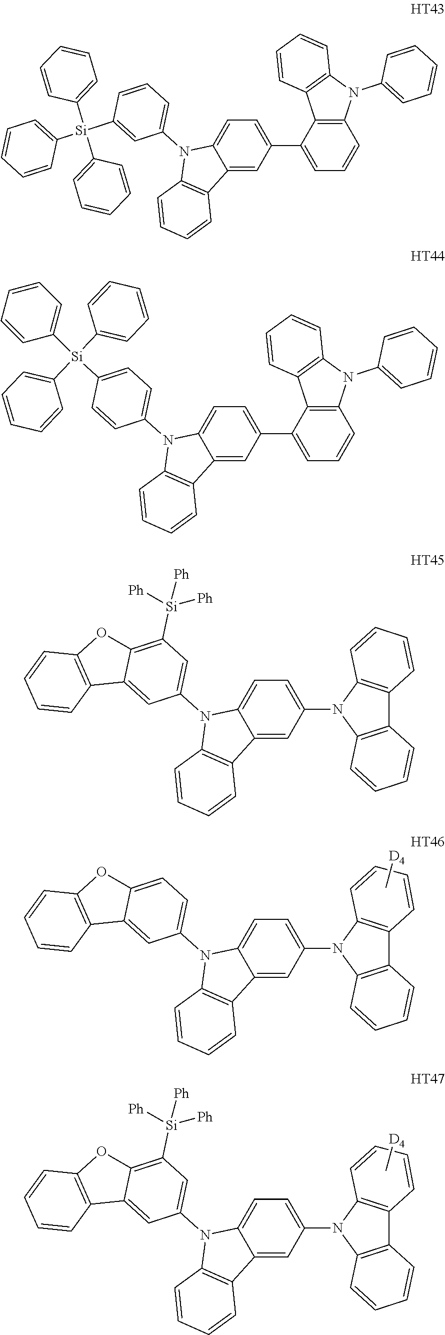

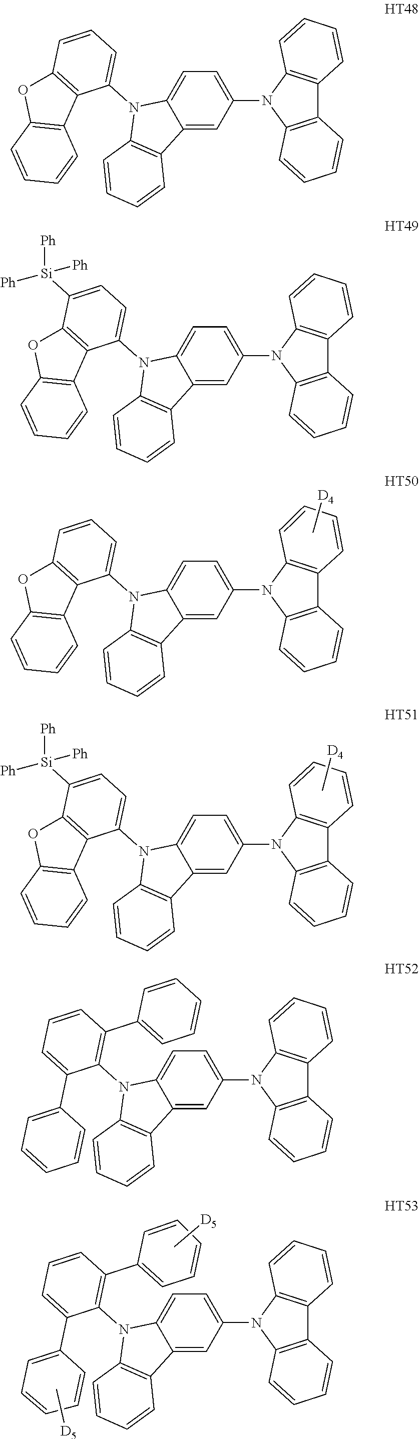

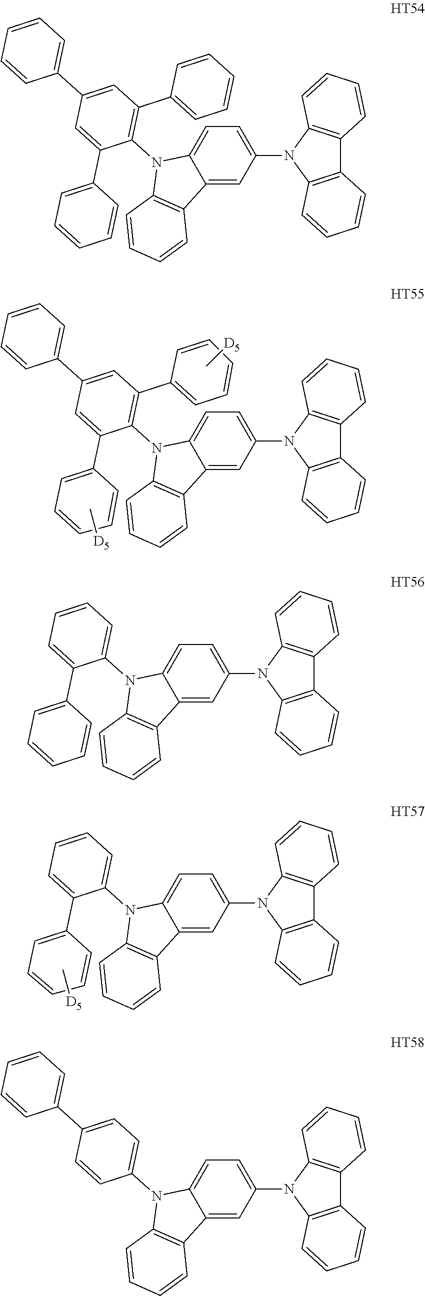

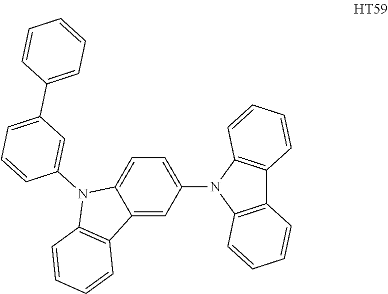 [SMILES: c1ccc(-c2cccc(-n3c4ccccc4c4cc(-n5c6ccccc6c6ccccc65)ccc43)c2)cc1]

In embodiment compounds presented in Compound Group 2, “D” may represent a deuterium atom, and “Ph” may represent a substituted or unsubstituted phenyl group. For example, in embodiment compounds presented in Compound Group 2, “Ph” may represent an unsubstituted phenyl group.

In an embodiment, the emission layer EML may include the third compound represented by Formula ET-1. For example, the third compound may be utilized as an electron transport host material for the emission layer EML.

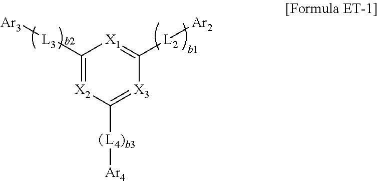

In Formula ET-1, at least one among X₁ to X₃ may be N, and the rest (any remainder thereof) may each independently be CR₅₆. For example, any one among X₁ to X₃ may be N, and the rest (any remainder thereof) may each independently be CR₅₆. In this case, the third compound represented by Formula ET-1 may include a pyridine moiety. In some embodiments, two among X₁ to X₃ may each be N, and the rest (the remainder thereof) may be CR₅₆. In this case, the third compound represented by Formula ET-1 may include a pyrimidine moiety. In some embodiments, X₁ to X₃ may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when one or more of b1 to b3 are integers of 2 or greater, the corresponding two or more L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In an embodiment, the third compound may be represented by any one among compounds in Compound Group 3. The light emitting device ED of an embodiment may include any one among the compounds in Compound Group 3.

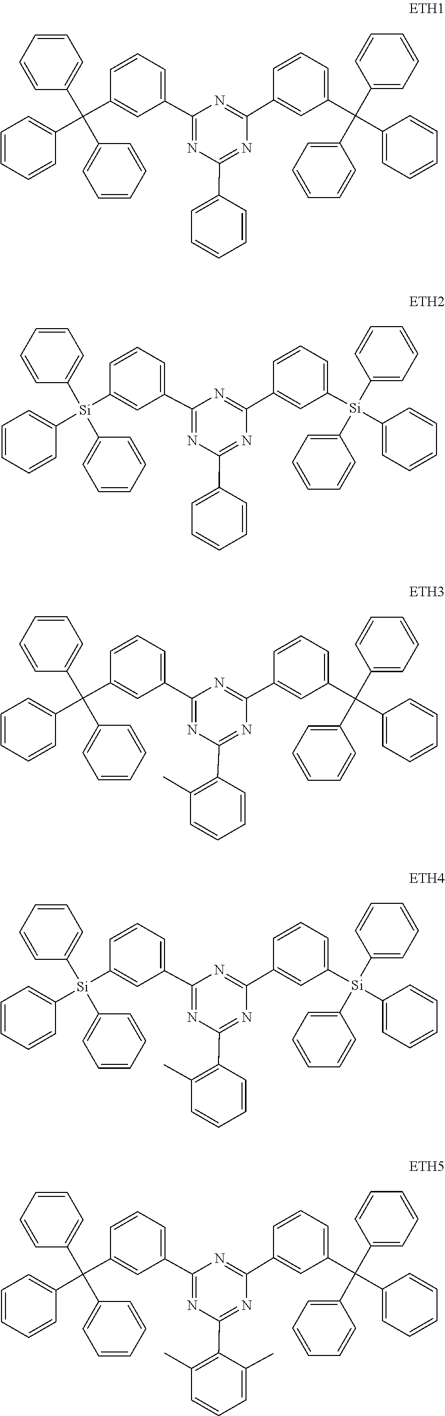

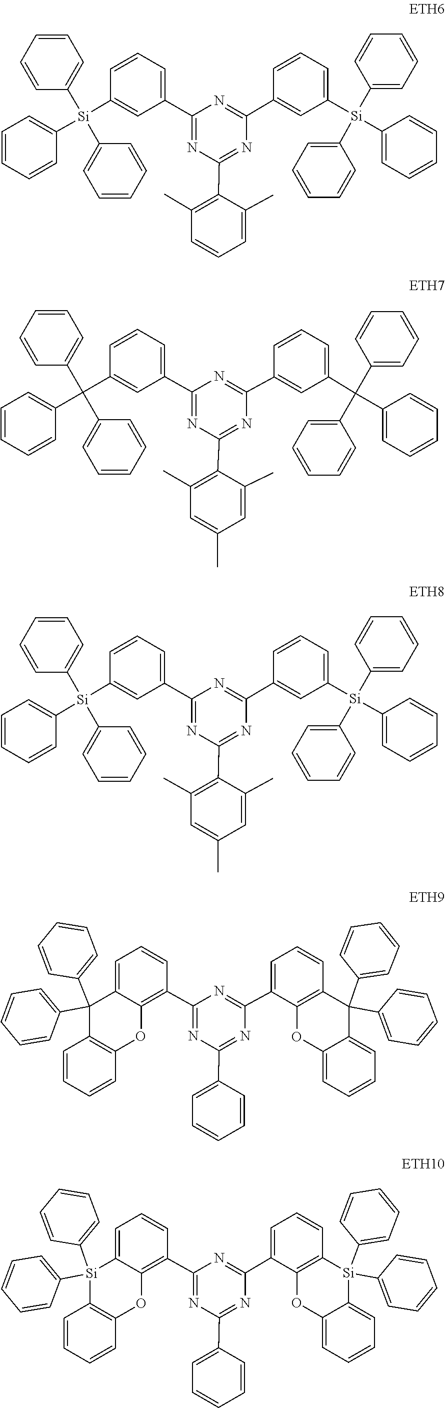

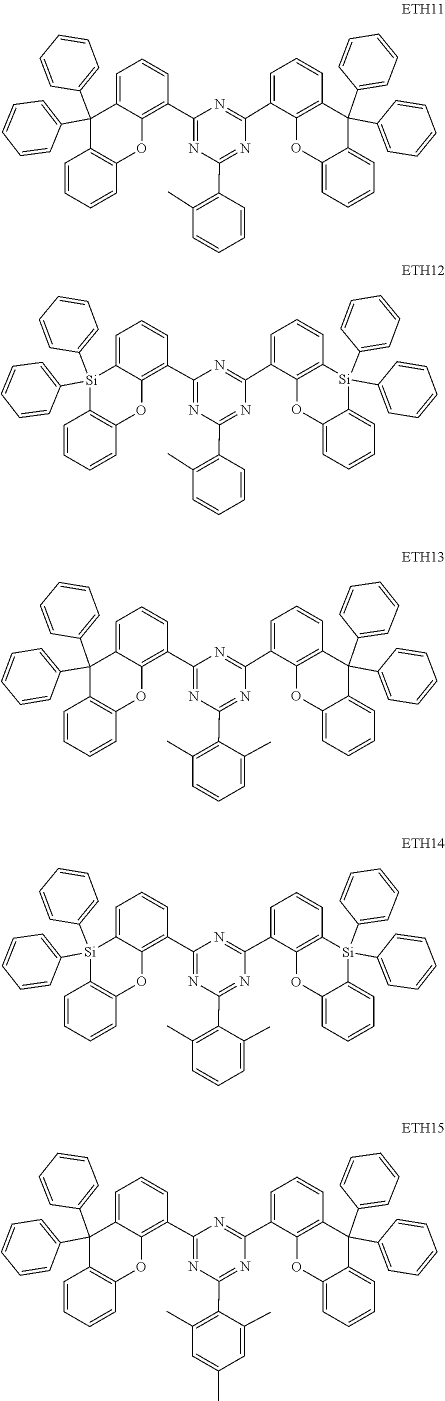

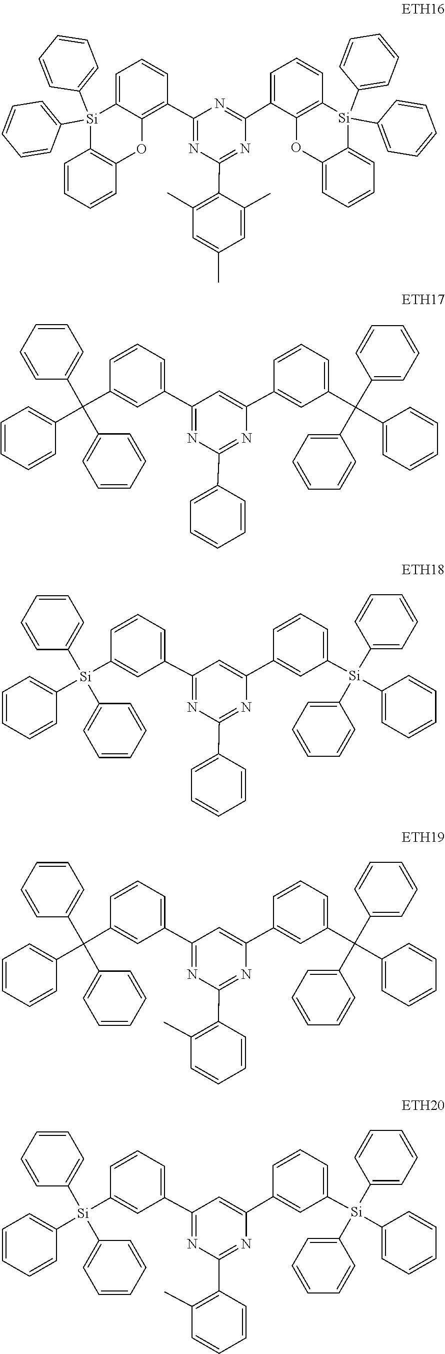

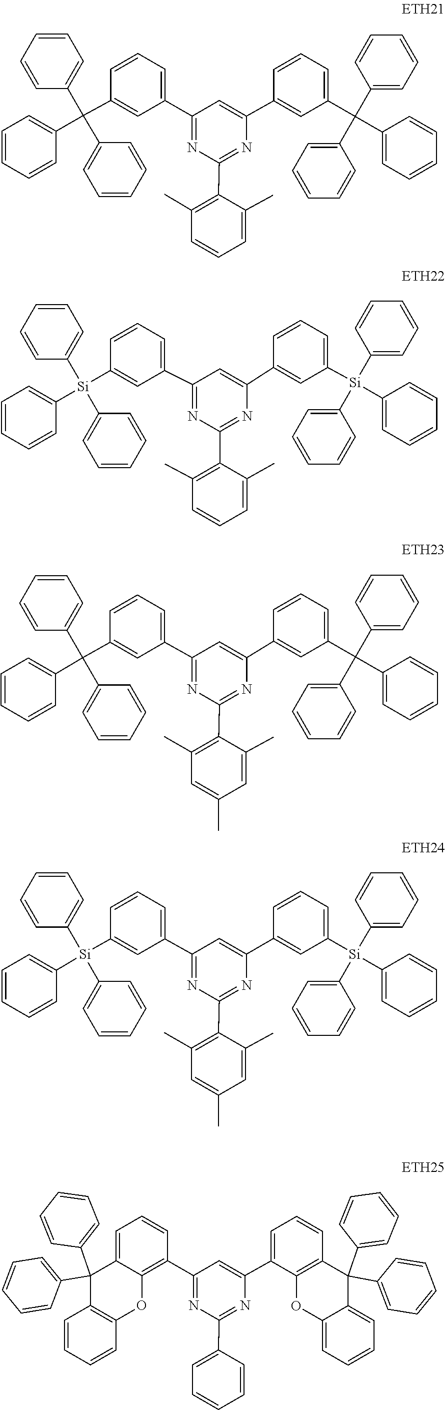

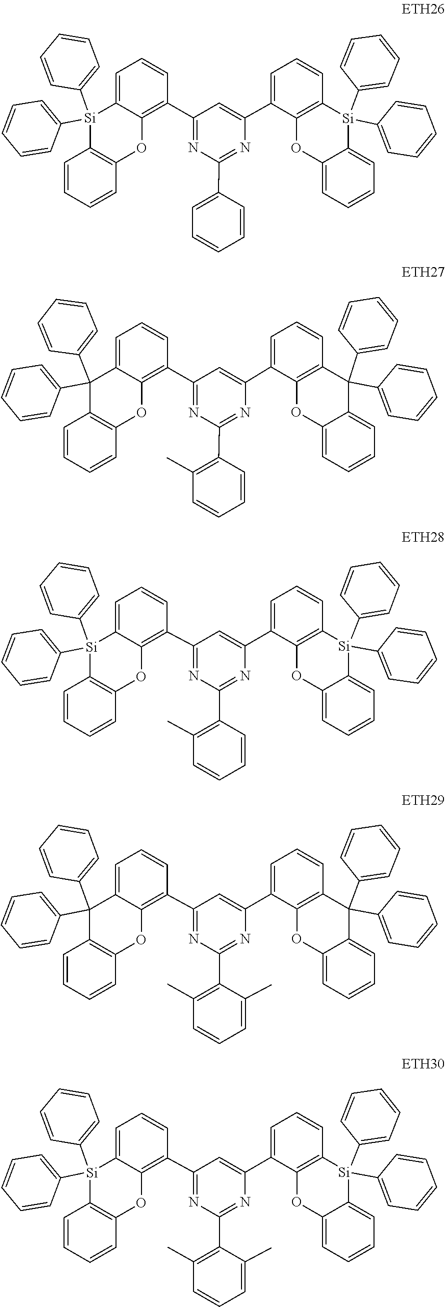

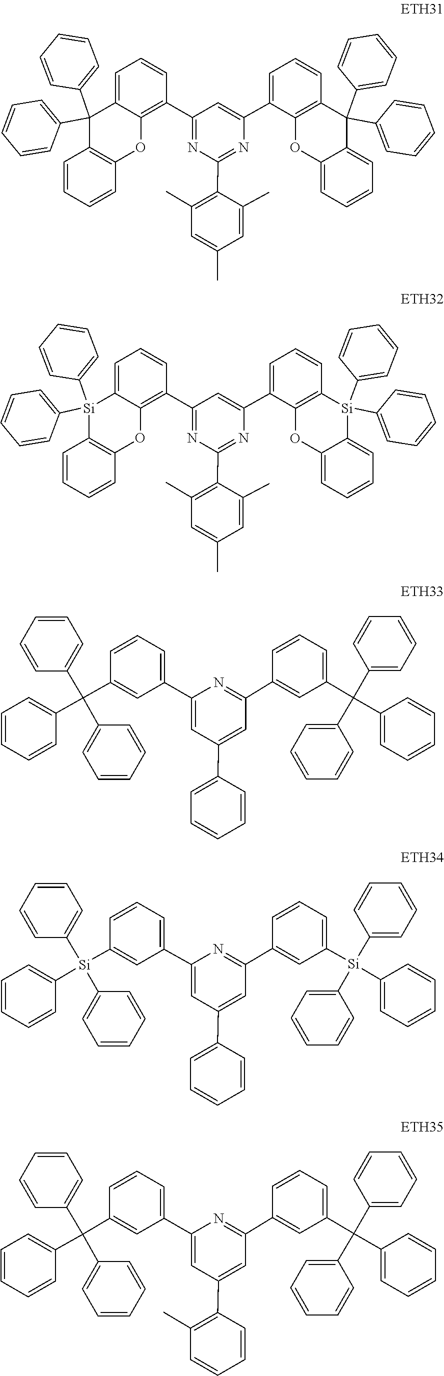

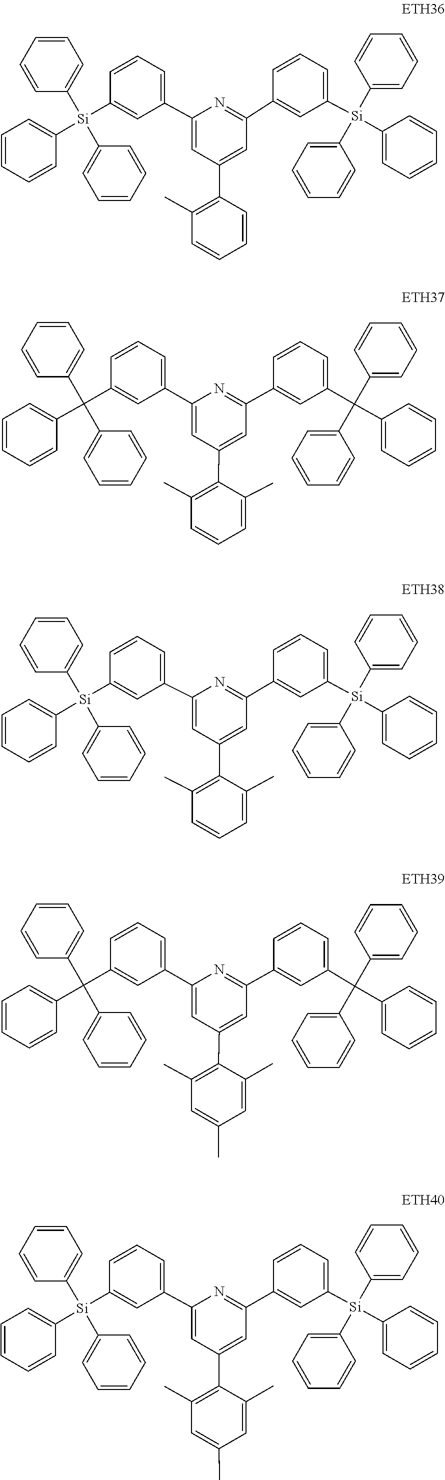

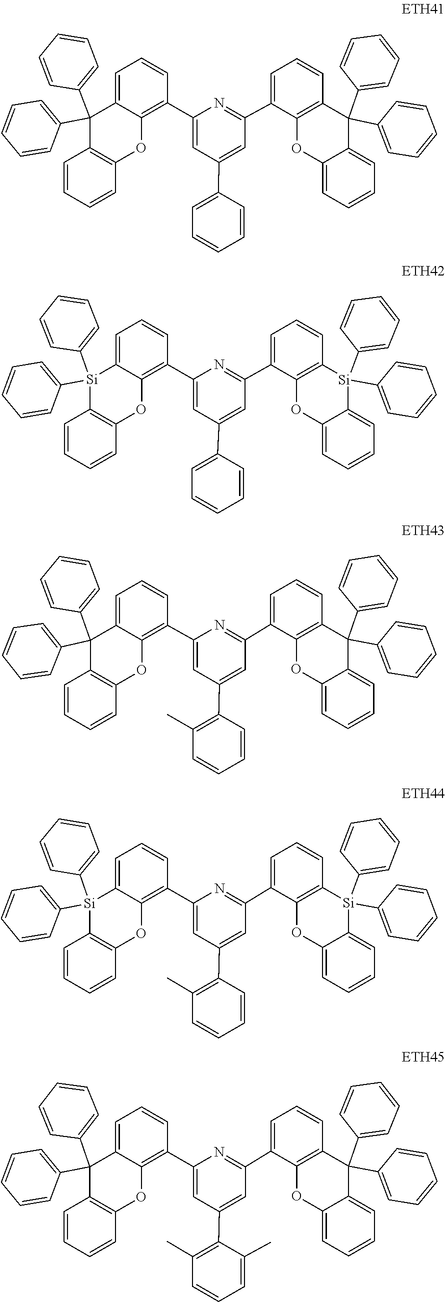

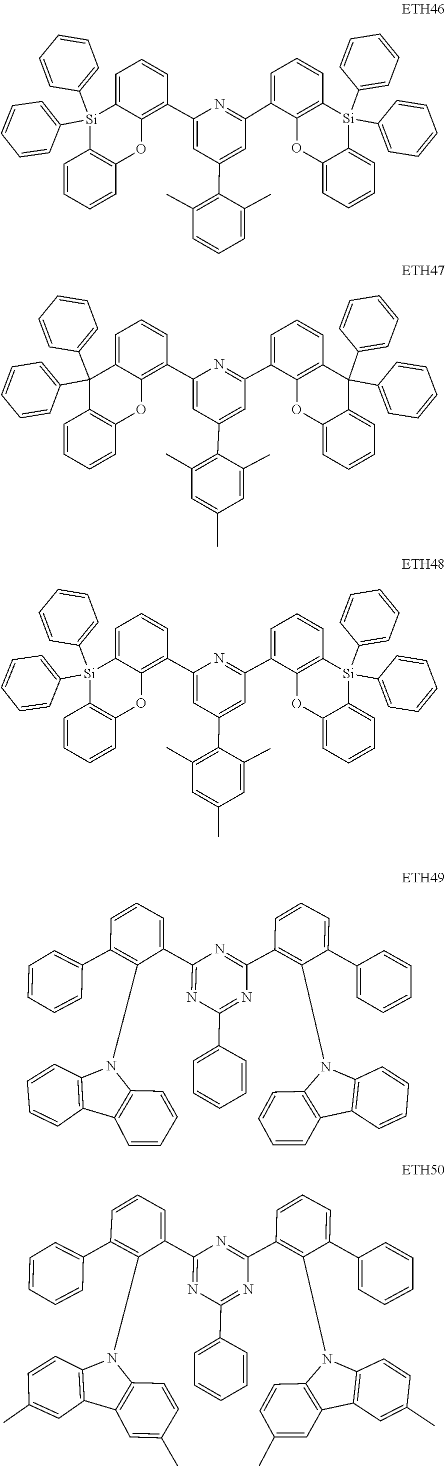

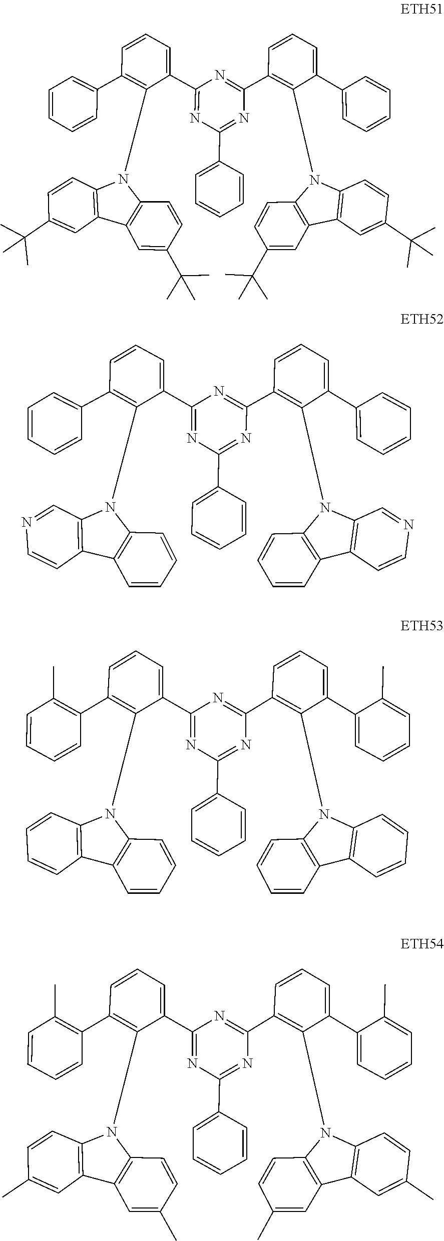

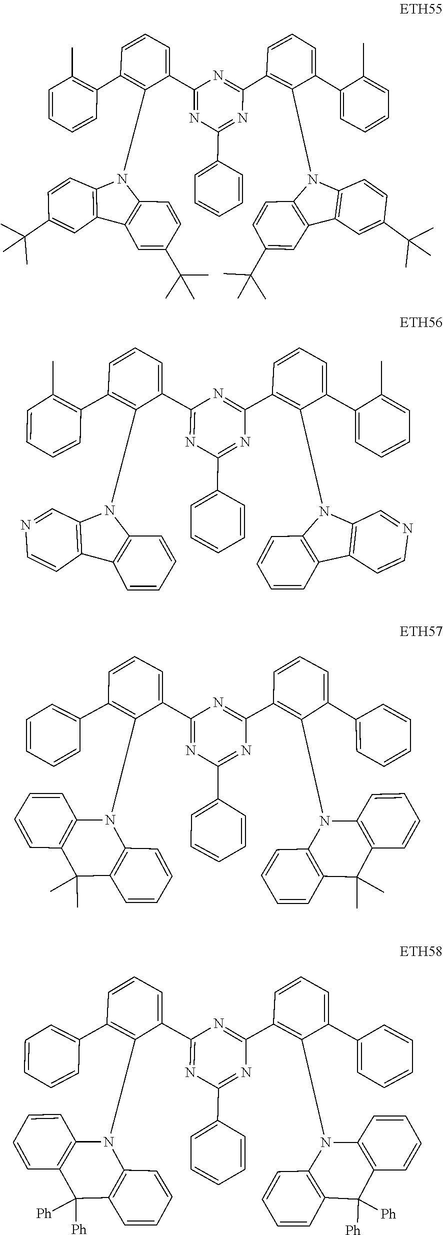

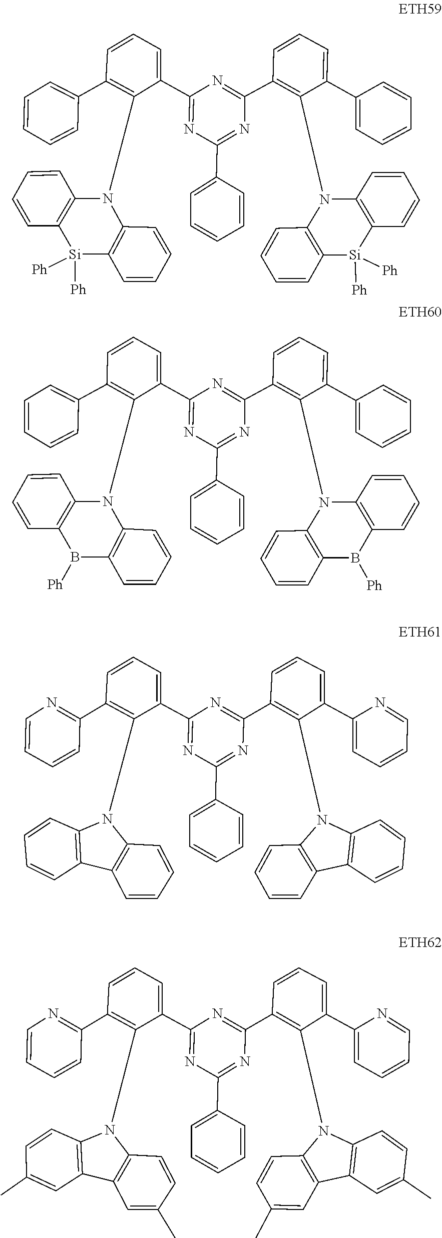

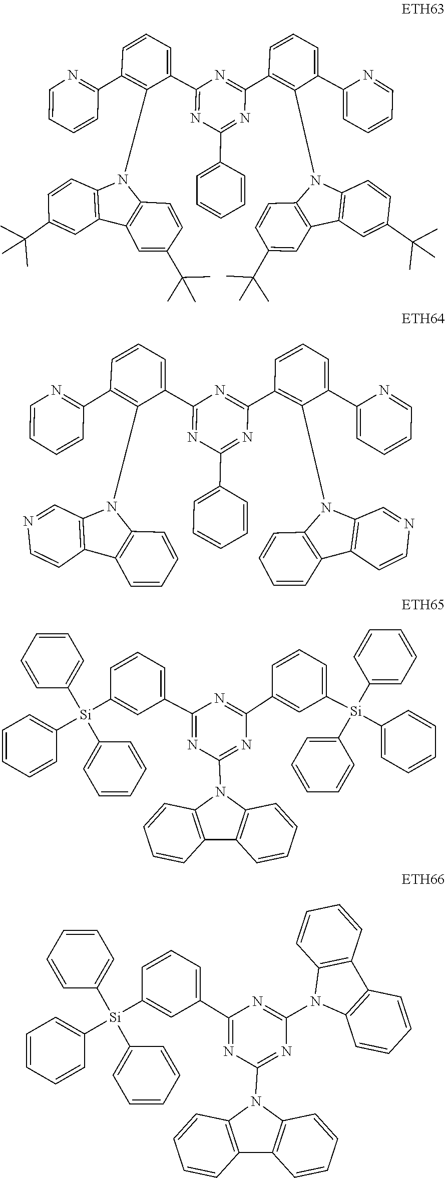 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

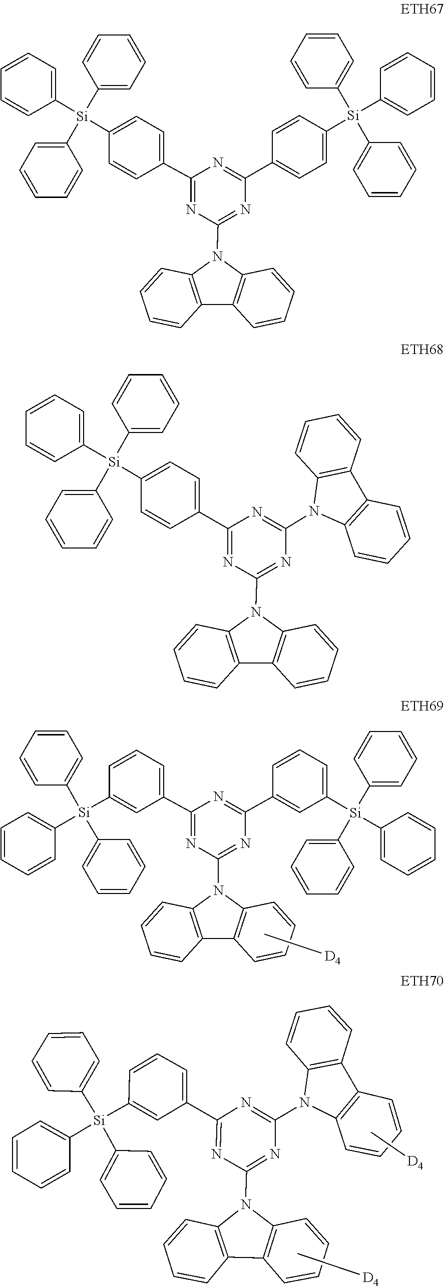

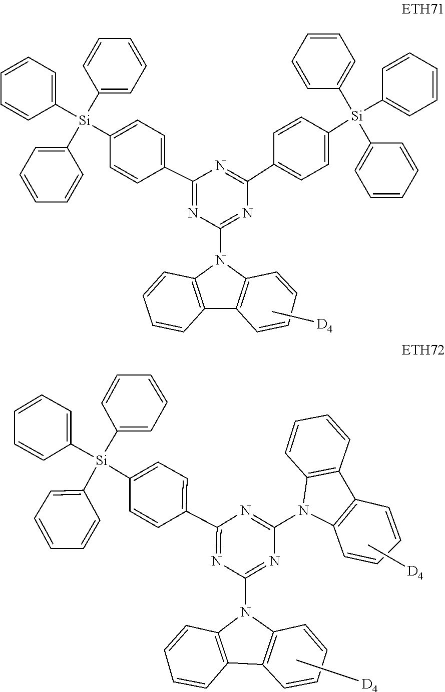

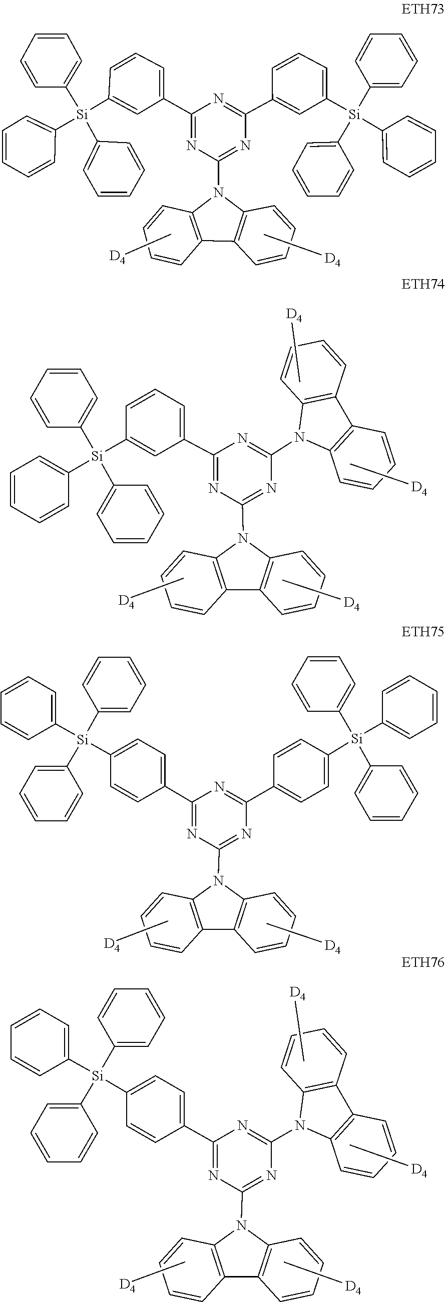

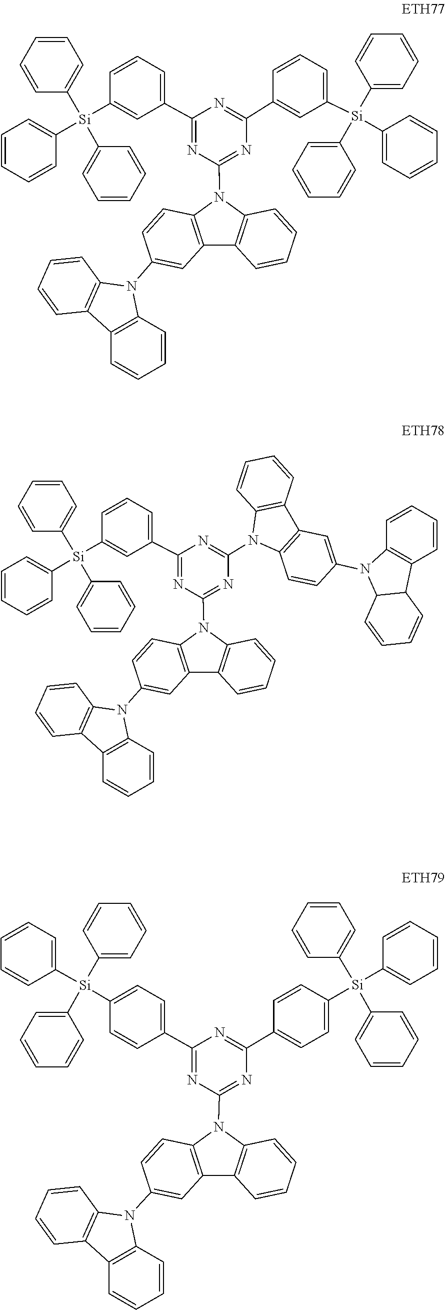 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; C1=CC2c3ccccc3N(c3ccc4c(c3)c3ccccc3n4-c3nc(-c4cccc([Si](c5ccccc5)(c5ccccc5)c5ccccc5)c4)nc(-n4c5ccccc5c5cc(-n6c7ccccc7c7ccccc76)ccc54)n3)C2C=C1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

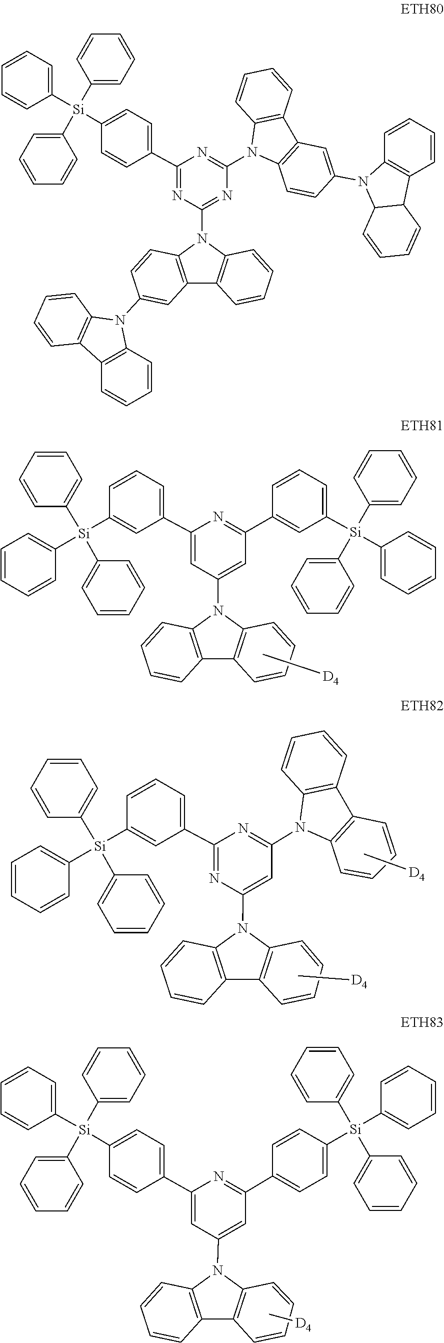

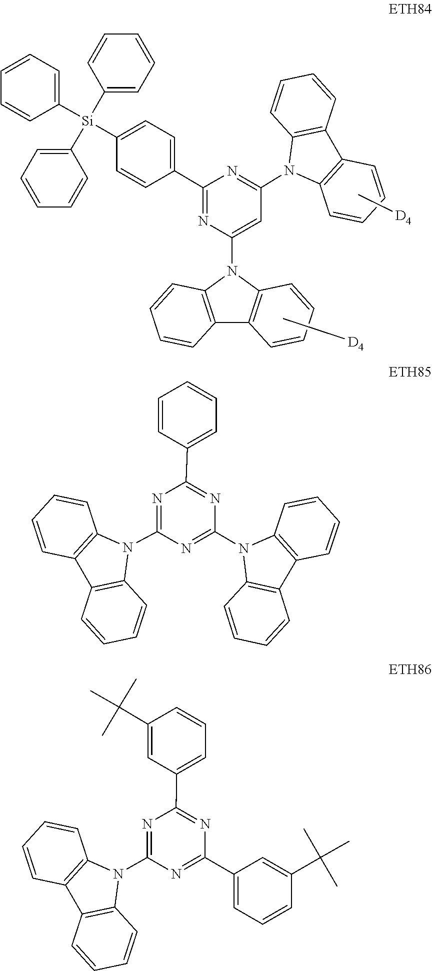

In the embodiment compounds presented in Compound Group 3, “D” refers to a deuterium atom and “Ph” refers to an unsubstituted phenyl group.

The emission layer EML may include the second compound and the third compound, and the second compound and the third compound may form an exciplex.

In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In an embodiment, the emission layer EML may include a fourth compound in addition to the first compound to the third compound as described above. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED of an embodiment may include, as the fourth compound, a compound represented by Formula D-1:

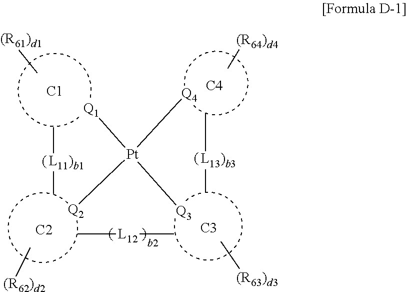

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage, *-O-*, *-S-*,

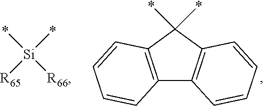

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “-*” represents a part linked to C1 to C4.

In Formula D-1, b1 to b3 may each independently be 0 or 1. When b1 is 0, C1 and C2 may not be linked to each other. When b2 is 0, C2 and C3 may not be linked to each other. When b3 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. In some embodiments, R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₆₁ to R₆₄. The case where each of d1 to d4 is 4 and R₆₁'s to R₆₄′ are each a hydrogen atom (i.e., they are all hydrogen atoms) may be the same as the case where each of d1 to d4 is 0. When each of d1 to d4 is an integer of 2 or more, a plurality of R₆₁'s to R₆₄'s may each be the same or at least one among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one among Formulae C-1 to C-4:

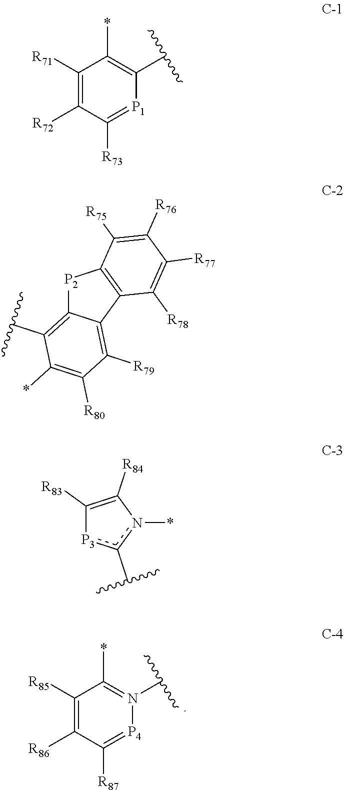

In Formulae C-1 to C-4, P₁ may be C-* or CR₇₄, P₂ may be N-* or NR₈₁, P₃ may be N-* or NR₈₂, and P₄ may be * or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formulae C-1 to C-4,

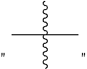

corresponds to a part linked to Pt that is the central metal atom, and “-*” corresponds to a part linked to a neighboring cyclic group (C1 to C4) or a linker (L₁₁ to L₁₃).

The emission layer EML of an embodiment may include the first compound, which is a fused polycyclic compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In an embodiment, the fourth compound may be a sensitizer. The fourth compound included in the emission layer EML in the light emitting device ED of an embodiment may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio (e.g., emission efficiency) of the first compound. Therefore, the emission layer EML of an embodiment may improve luminous efficiency. In some embodiments, when the energy delivery to the first compound is increased, an exciton formed in the emission layer EML is not accumulated inside the emission layer EML and light is emitted rapidly, and thus deterioration of the device may be reduced. Therefore, the service life of the light emitting device ED of an embodiment may increase.

The light emitting device ED of an embodiment may include all of the first compound, the second compound, the third compound, and the fourth compound, and the emission layer EML may include the combination of two host materials and two dopant materials. In the light emitting device ED of an embodiment, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In an embodiment, the fourth compound represented by Formula D-1 may represented at least one among the compounds represented by Compound Group 4.

The emission layer EML may include at least one among the compounds represented by Compound Group 4 as a sensitizer material.

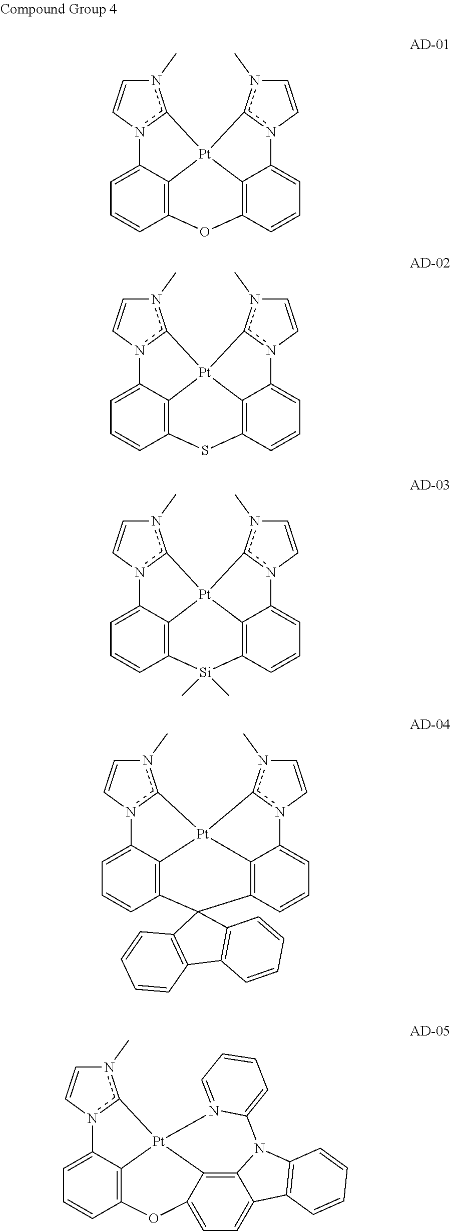

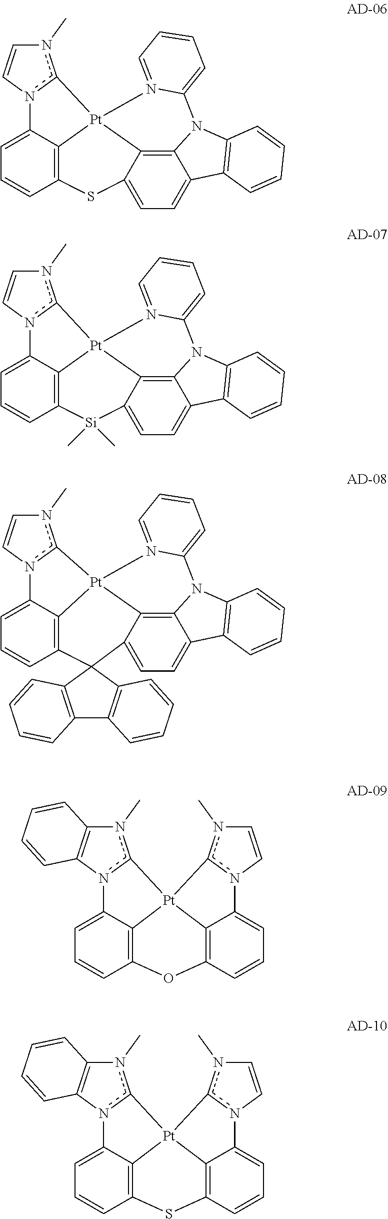

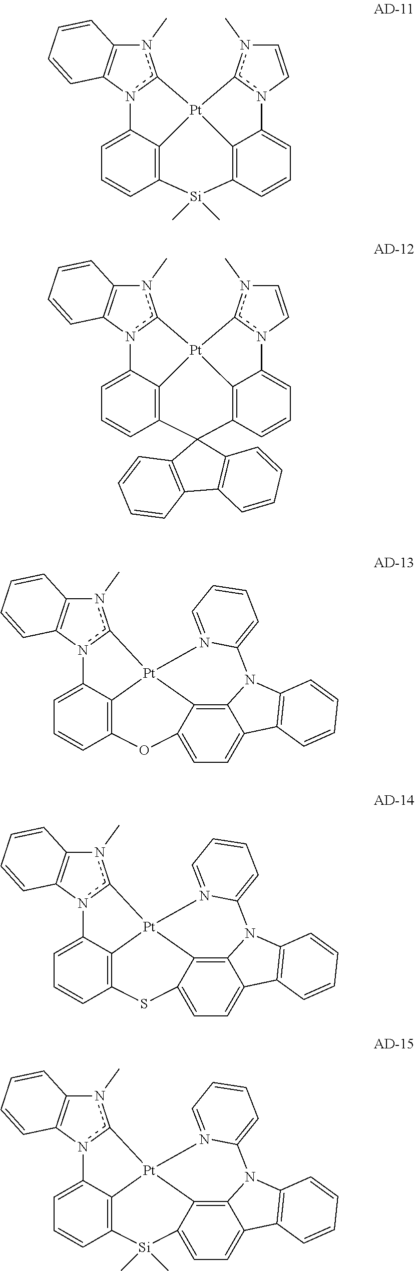

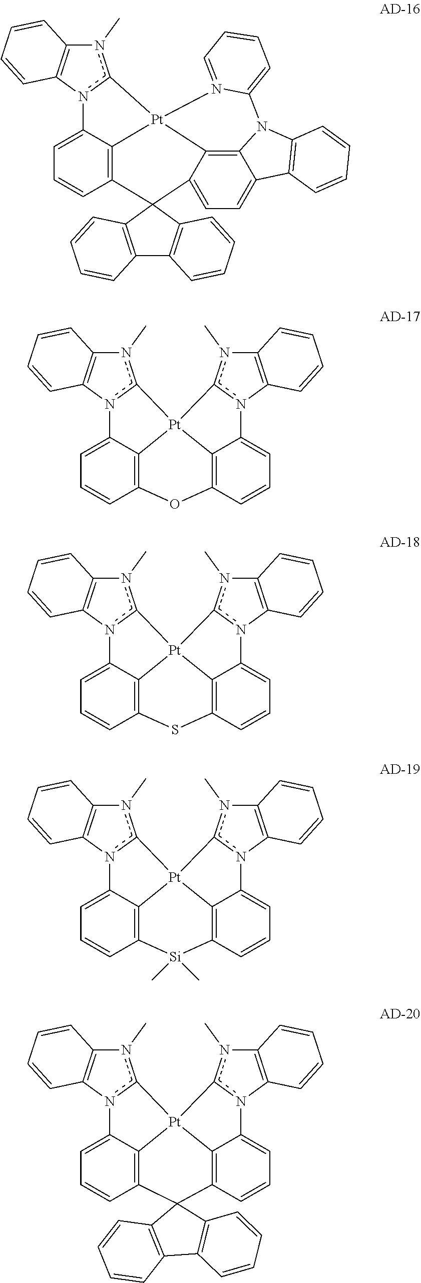

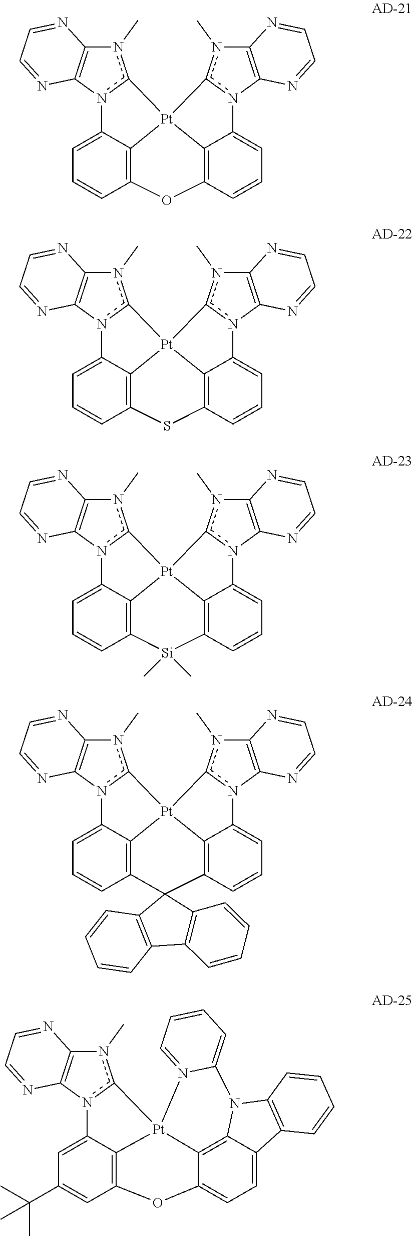

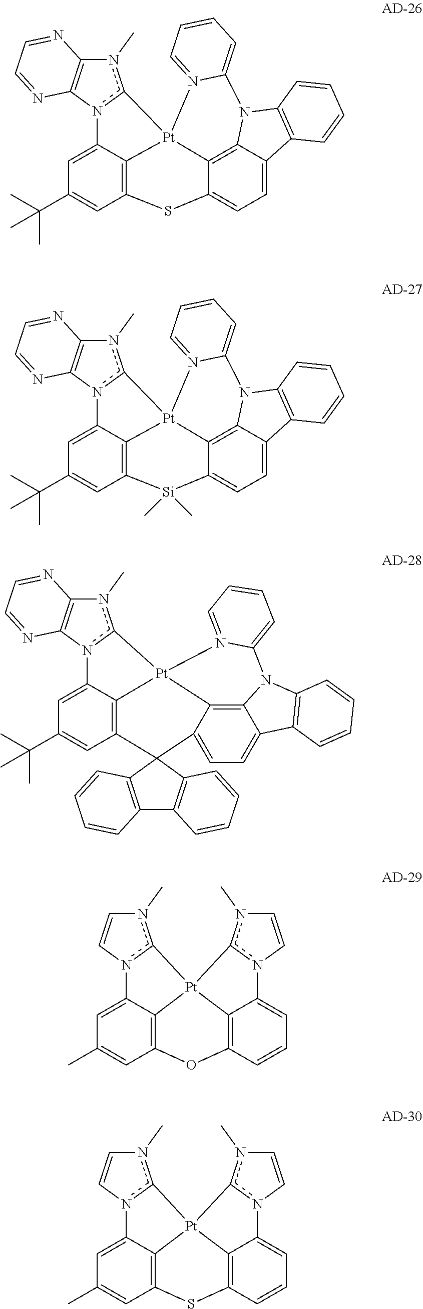

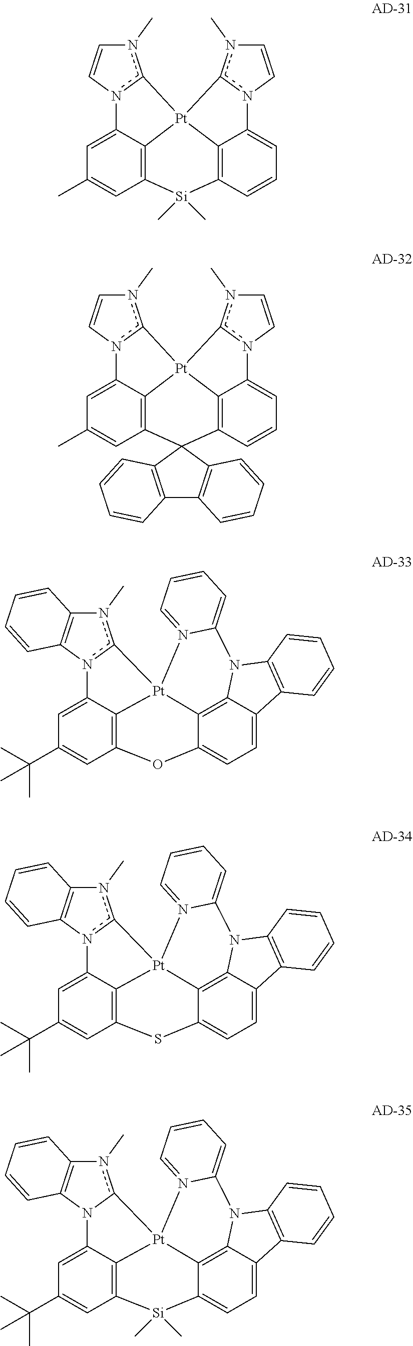

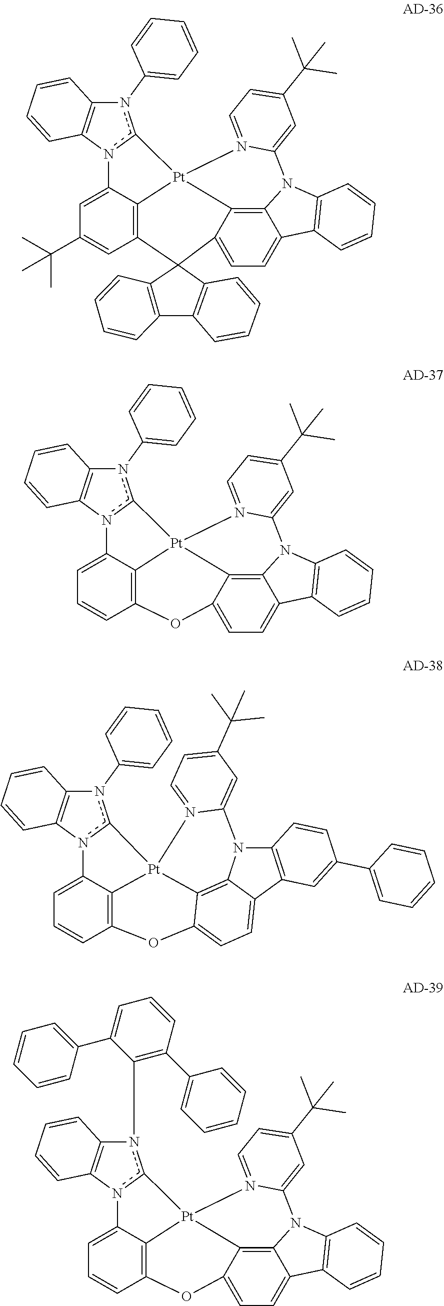

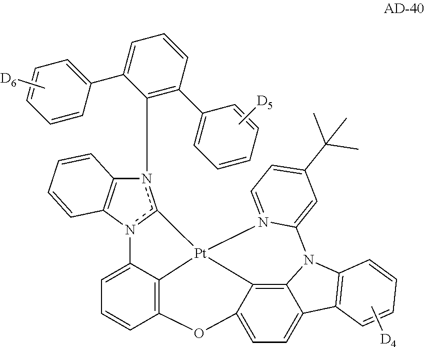

In the embodiment compounds presented in Compound Group 4, “D” refers to a deuterium atom.

In an embodiment, the emission layer EML may include a fifth compound represented by Formula DA. In an embodiment, the emission layer EML may include the first compound represented by Formula 1, and may further include the fifth compound represented by Formula DA. In an embodiment, the fifth compound may be utilized as an auxiliary dopant material for the emission layer EML.

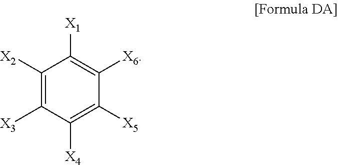

In Formula DA above, X₁ to X₆ may each independently be a hydrogen atom, a deuterium atom, an electron withdrawing group, or an electron donor group, with the proviso that at least one among X₁ to X₆ is an electron withdrawing group and at least another one is an electron donor group, wherein the electron withdrawing group may be a substituted or unsubstituted fluorine group, a fluorine group-substituted alkyl group having 1 to 20 carbon atoms, a fluorine group-substituted aryl group having 6 to 30 ring-forming carbon atoms, a cyano group, a cyano group-substituted aryl group having 6 to 30 ring-forming carbon atoms, a substituted or unsubstituted carbonyl group, or a substituted or unsubstituted triazine group, and the electron donor group may be a substituted or unsubstituted amine group, a substituted or unsubstituted heteroaryl group having 2 to 30 ring-forming carbon atoms containing a nitrogen atom, or a substituted or unsubstituted carbazole group.

In Formula DA above, at least one among X₁ to X₆ may be represented by Formula DA-1:

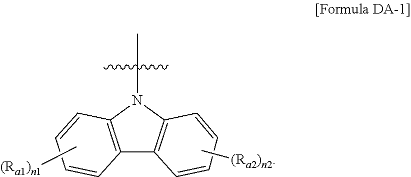

In Formula DA-1 above, Rₐ₁ and Rₐ₂ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, and n1 and n2 may each independently be an integer of 0 to 4.

In an embodiment, the fifth compound represented by Formula DA may be represented by any one among the compounds represented by Compound Group 5. The emission layer EML may include at least one among the compounds represented by Compound Group 5 as an auxiliary dopant material.

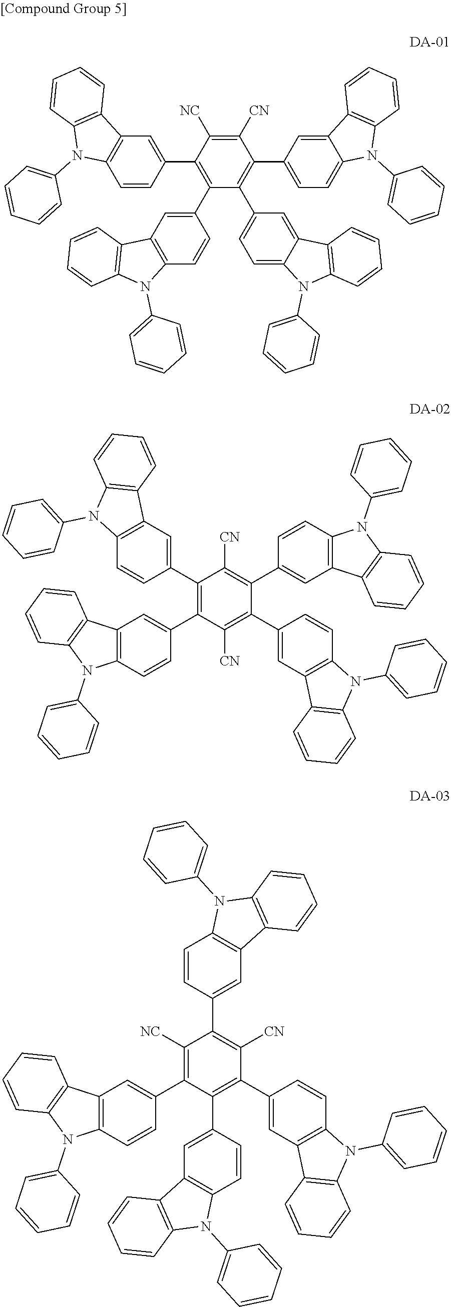 [SMILES: N#Cc1c(C#N)c(-c2ccc3c(c2)c2ccccc2n3-c2ccccc2)c(-c2ccc3c(c2)c2ccccc2n3-c2ccccc2)c(-c2ccc3c(c2)c2ccccc2n3-c2ccccc2)c1-c1ccc2c(c1)c1ccccc1n2-c1ccccc1 ; N#Cc1c(-c2ccc3c(c2)c2ccccc2n3-c2ccccc2)c(-c2ccc3c(c2)c2ccccc2n3-c2ccccc2)c(C#N)c(-c2ccc3c(c2)c2ccccc2n3-c2ccccc2)c1-c1ccc2c(c1)c1ccccc1n2-c1ccccc1 ; N#Cc1c(-c2ccc3c(c2)c2ccccc2n3-c2ccccc2)c(C#N)c(-c2ccc3c(c2)c2ccccc2n3-c2ccccc2)c(-c2ccc3c(c2)c2ccccc2n3-c2ccccc2)c1-c1ccc2c(c1)c1ccccc1n2-c1ccccc1]

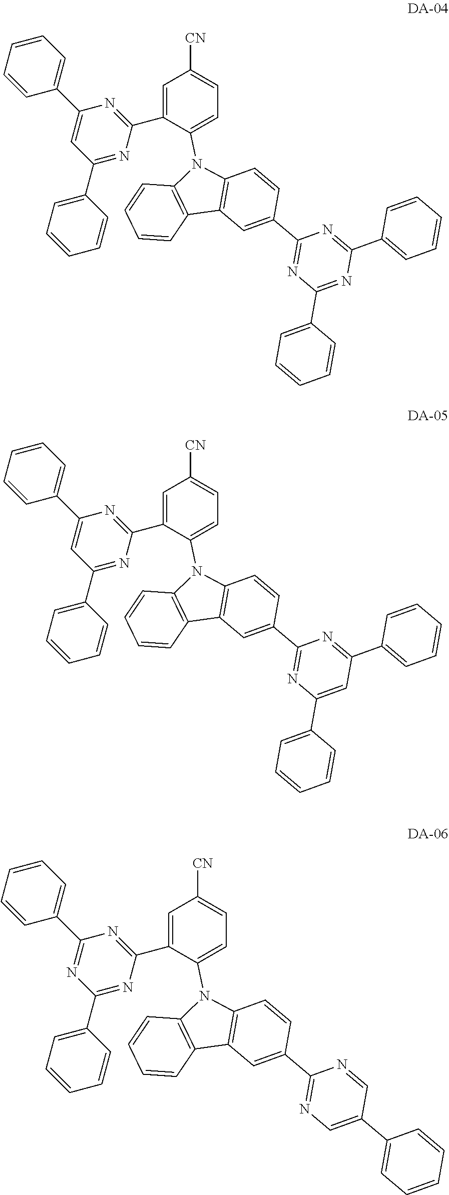 [SMILES: N#Cc1ccc(-n2c3ccccc3c3cc(-c4nc(-c5ccccc5)nc(-c5ccccc5)n4)ccc32)c(-c2nc(-c3ccccc3)cc(-c3ccccc3)n2)c1 ; N#Cc1ccc(-n2c3ccccc3c3cc(-c4nc(-c5ccccc5)cc(-c5ccccc5)n4)ccc32)c(-c2nc(-c3ccccc3)cc(-c3ccccc3)n2)c1 ; N#Cc1ccc(-n2c3ccccc3c3cc(-c4ncc(-c5ccccc5)cn4)ccc32)c(-c2nc(-c3ccccc3)nc(-c3ccccc3)n2)c1]

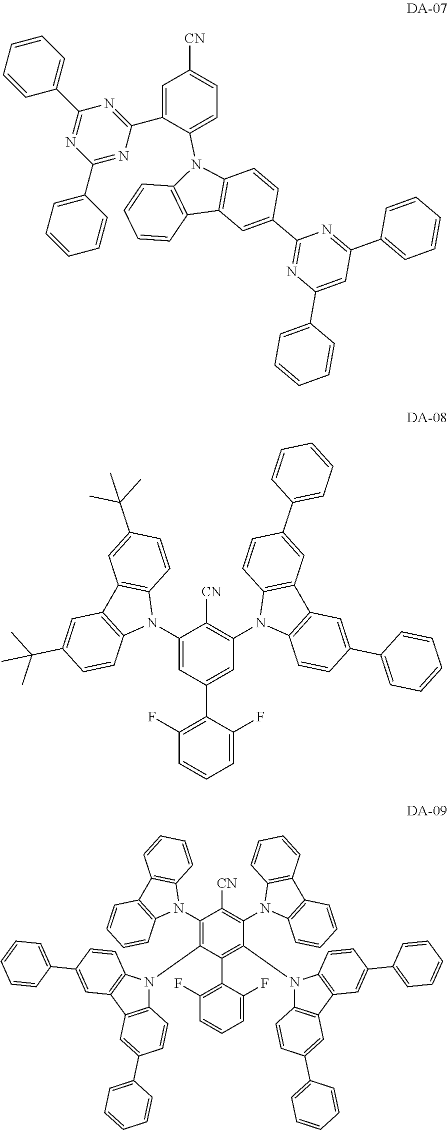 [SMILES: N#Cc1ccc(-n2c3ccccc3c3cc(-c4nc(-c5ccccc5)cc(-c5ccccc5)n4)ccc32)c(-c2nc(-c3ccccc3)nc(-c3ccccc3)n2)c1 ; CC(C)(C)c1ccc2c(c1)c1cc(C(C)(C)C)ccc1n2-c1cc(-c2c(F)cccc2F)cc(-n2c3ccc(-c4ccccc4)cc3c3cc(-c4ccccc4)ccc32)c1C#N ; N#Cc1c(-n2c3ccccc3c3ccccc32)c(-n2c3ccc(-c4ccccc4)cc3c3cc(-c4ccccc4)ccc32)c(-c2c(F)cccc2F)c(-n2c3ccc(-c4ccccc4)cc3c3cc(-c4ccccc4)ccc32)c1-n1c2ccccc2c2ccccc21]

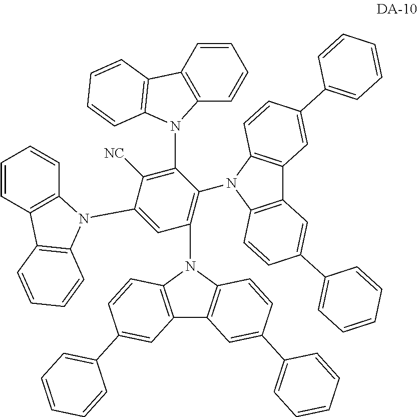 [SMILES: N#Cc1c(-n2c3ccccc3c3ccccc32)cc(-n2c3ccc(-c4ccccc4)cc3c3cc(-c4ccccc4)ccc32)c(-n2c3ccc(-c4ccccc4)cc3c3cc(-c4ccccc4)ccc32)c1-n1c2ccccc2c2ccccc21]

In some embodiments, the light emitting device ED of an embodiment may include a plurality of emission layers. The plurality of emission layers may be sequentially stacked and provided, and for example, the light emitting device ED including the plurality of emission layers may be to emit white light. The light emitting device including the plurality of emission layers may be a light emitting device having a tandem structure. When the light emitting device ED includes a plurality of emission layers, at least one emission layer EML may include the first compound represented by Formula 1 of an embodiment. In some embodiments, when the light emitting device ED includes the plurality of emission layers, at least one emission layer EML may include the first compound and the fifth compound as described above. In some embodiments, the emission layer EML of an embodiment may include all of the first compound, the second compound, the third compound, the fourth compound, and the fifth compound.

When the emission layer EML in the light emitting device ED of an embodiment includes all of the first compound, the second compound, and the third compound, with respect to the total weight of the first compound, the second compound, and the third compound, the content (e.g., amount) of the first compound may be about 0.1 wt % to about 5 wt %. However, the embodiment of the present disclosure is not limited thereto. When the content (e.g., amount) of the first compound satisfy the above-described range, the energy transfer from the second compound and the third compound to the first compound may increase, and thus the luminous efficiency and device service life may increase.

The contents (e.g., total amount) of the second compound and the third compound in the emission layer EML may be the rest (e.g., the balance) excluding the weight of the first compound. For example, the contents (e.g., total amount) of the second compound and the third compound in the emission layer EML may be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents of the second compound and the third compound satisfy the above-described ratio, a charge balance characteristic in the emission layer EML may be improved, and thus the luminous efficiency and device service life may increase. When the contents of the second compound and the third compound deviate from the above-described ratio range, a charge balance in the emission layer EML may be broken, and thus the luminous efficiency may be reduced and the device may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, the embodiment of the present disclosure is not limited thereto. When the content (e.g., amount) of the fourth compound satisfies the above-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency and long service life may be achieved.

In the light emitting device ED of an embodiment, the emission layer EML may include an anthracene derivative, a pyrene derivative, a fluoranthene derivative, a chrysene derivative, a dehydrobenzanthracene derivative, and/or a triphenylene derivative. For example, the emission layer EML may include the anthracene derivative and/or the pyrene derivative.

In each light emitting device ED of embodiments illustrated in FIGS. 3 to 6, the emission layer EML may further include a suitable host and dopant besides the above-described host and dopant, and for example the emission layer EML may include a compound represented by Formula E-1. The compound represented by Formula E-1 may be utilized as a fluorescent host material.

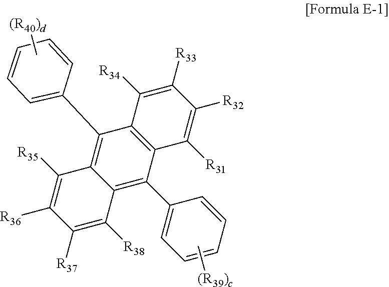

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one among Compound E1 to Compound E19:

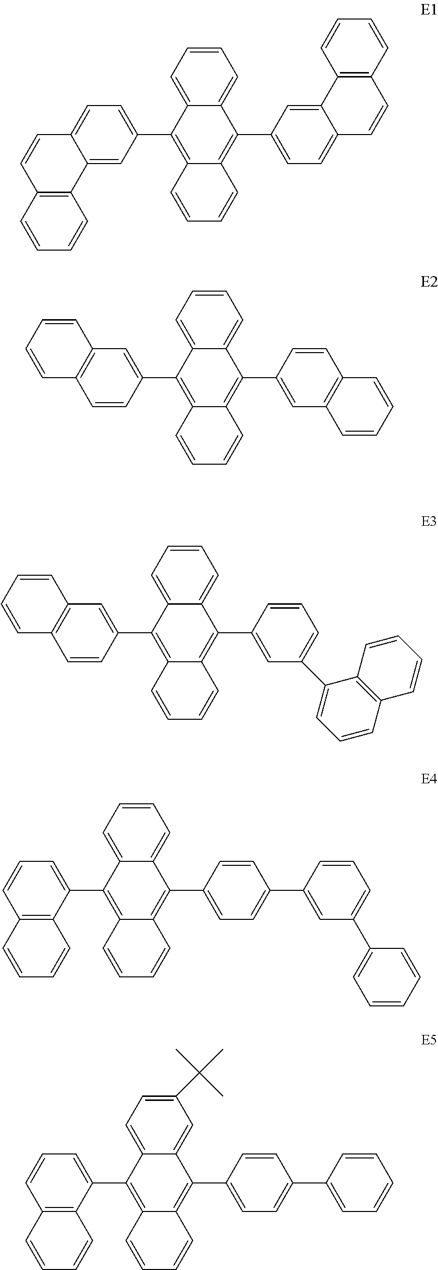

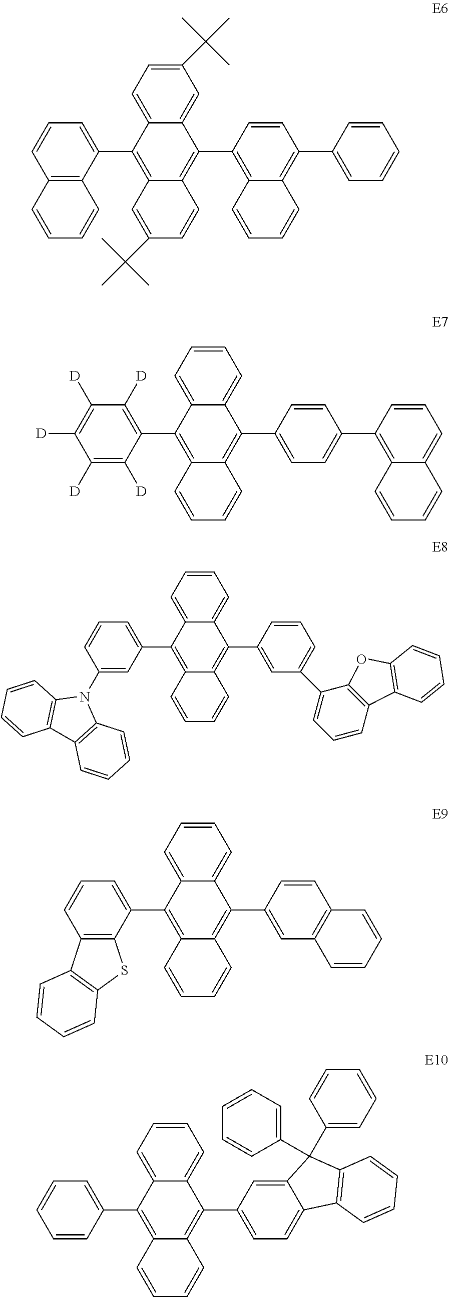

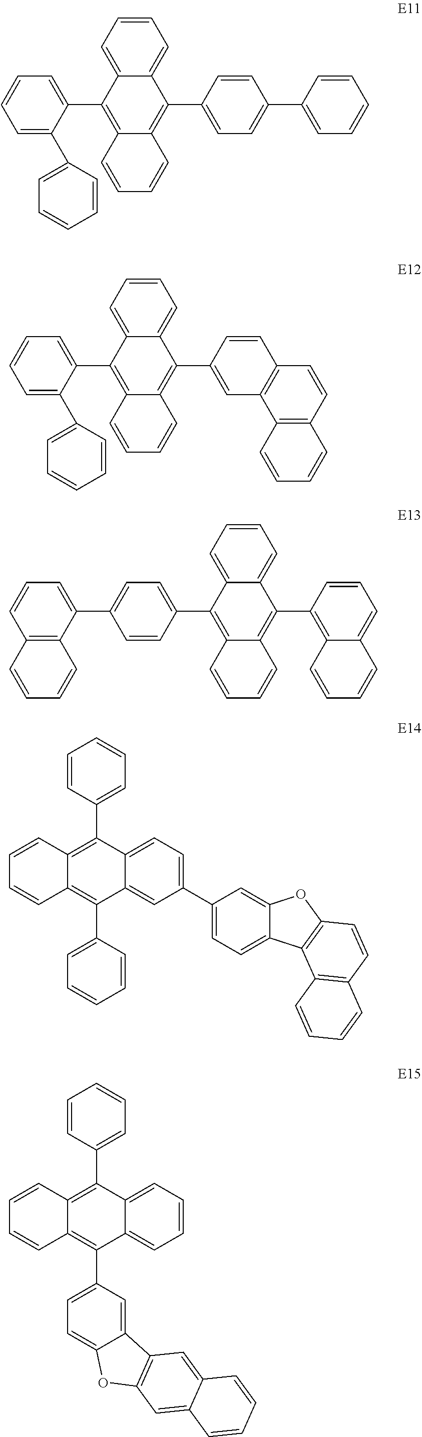

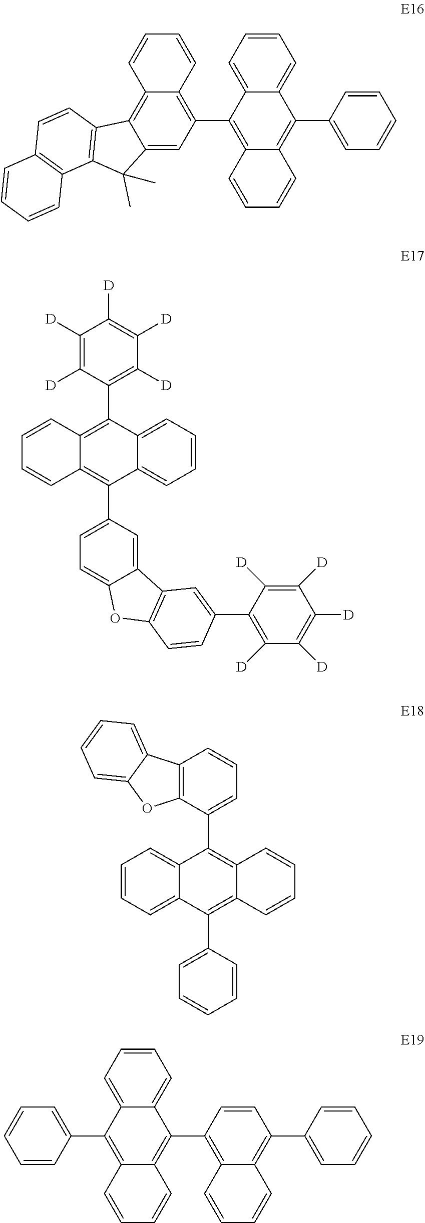

In an embodiment, the emission layer EML may include a compound represented by Formula E-2a or Formula E-2b. The compound represented by Formula E-2a or Formula E-2b may be utilized as a phosphorescent host material.

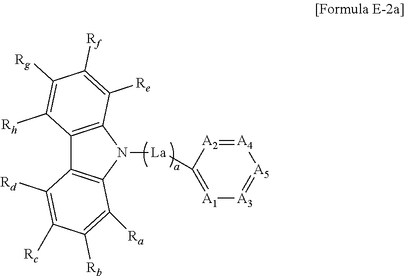

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc., as a ring-forming atom.

In some embodiments, in Formula E-2a, two or three selected from among A₁ to A₅ may be N, and the rest (any remainder thereof) may each independently be CRᵢ.

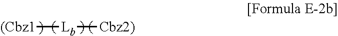

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2. However, the compounds listed in Compound Group E-2 are examples, and the compound represented by Formula E-2a or Formula E-2b is not limited to those represented in Compound Group E-2.

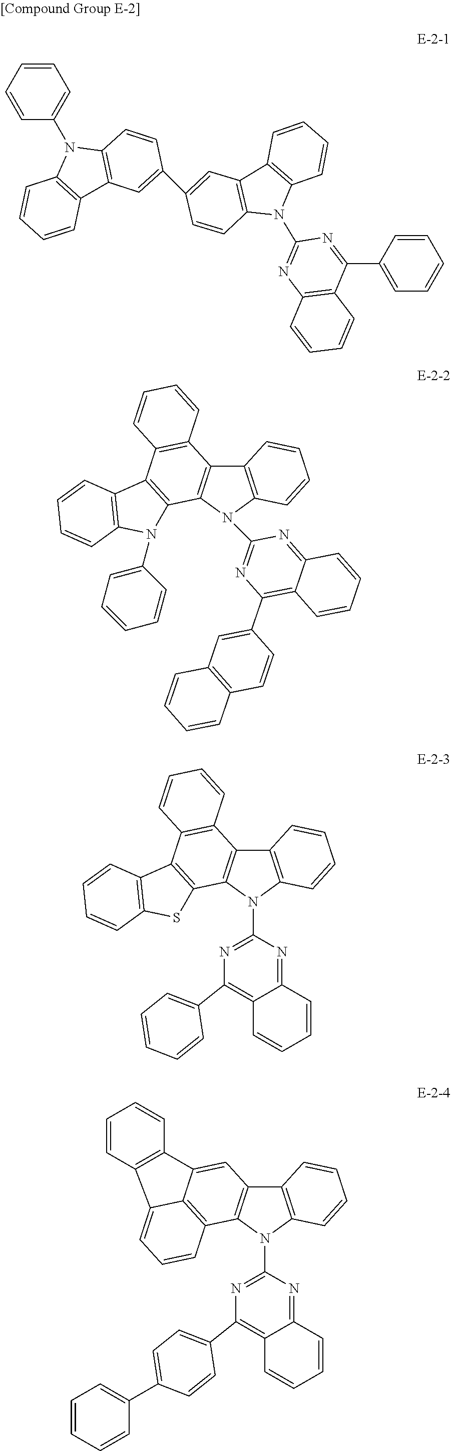

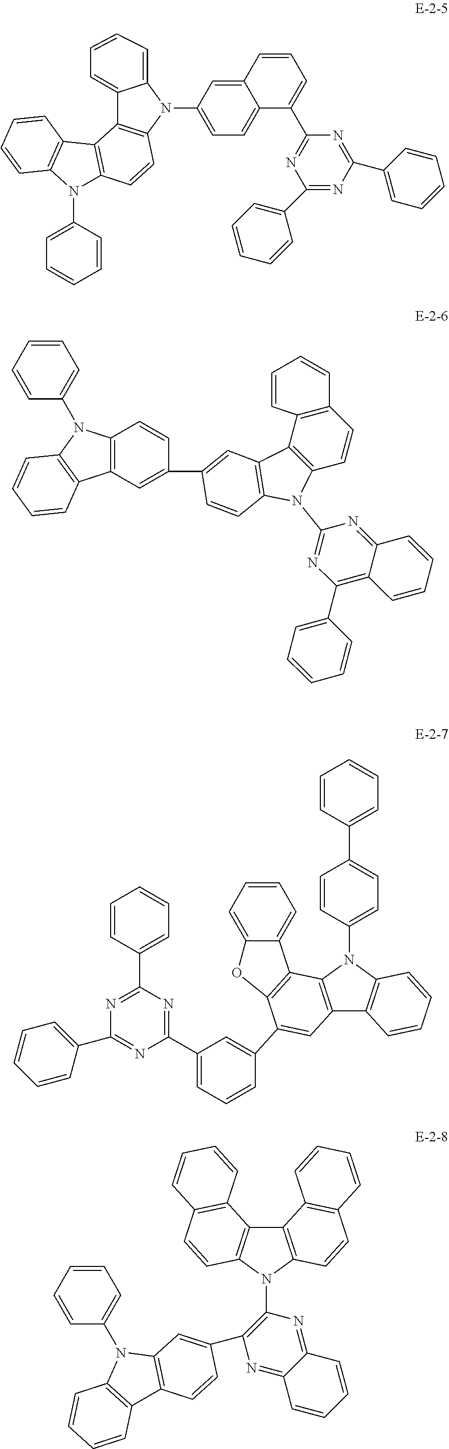

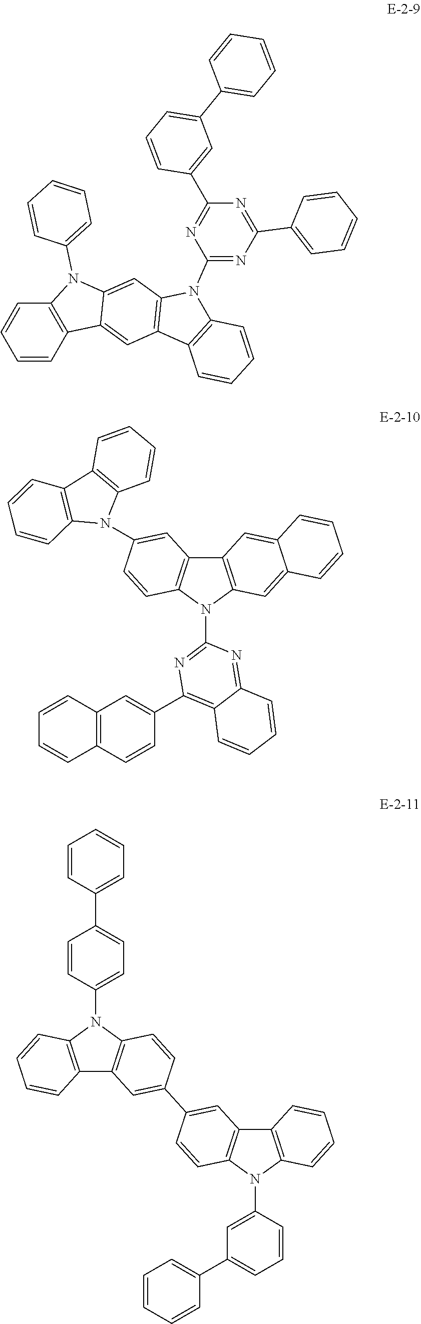 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

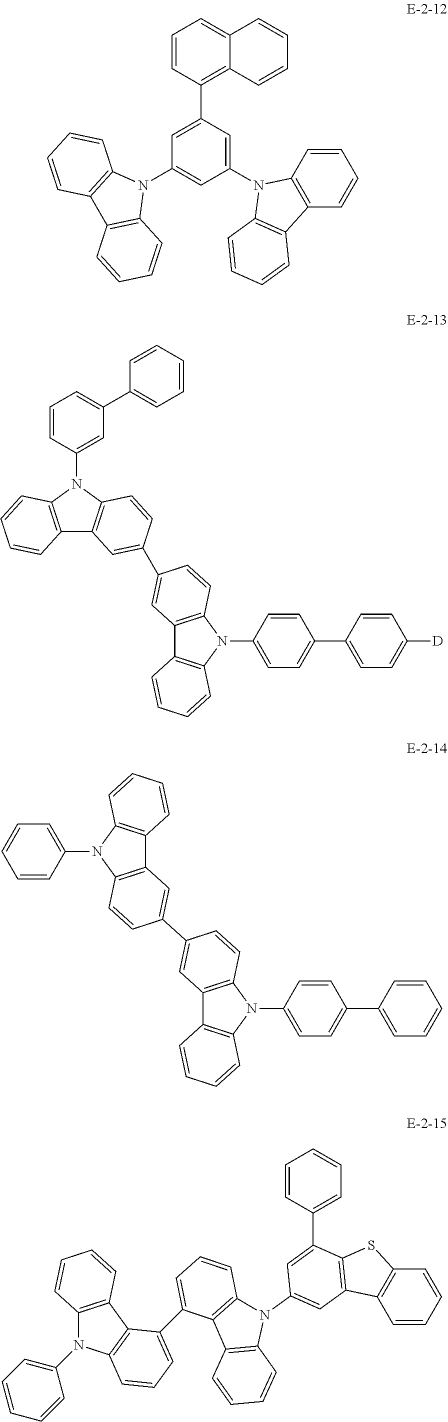 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

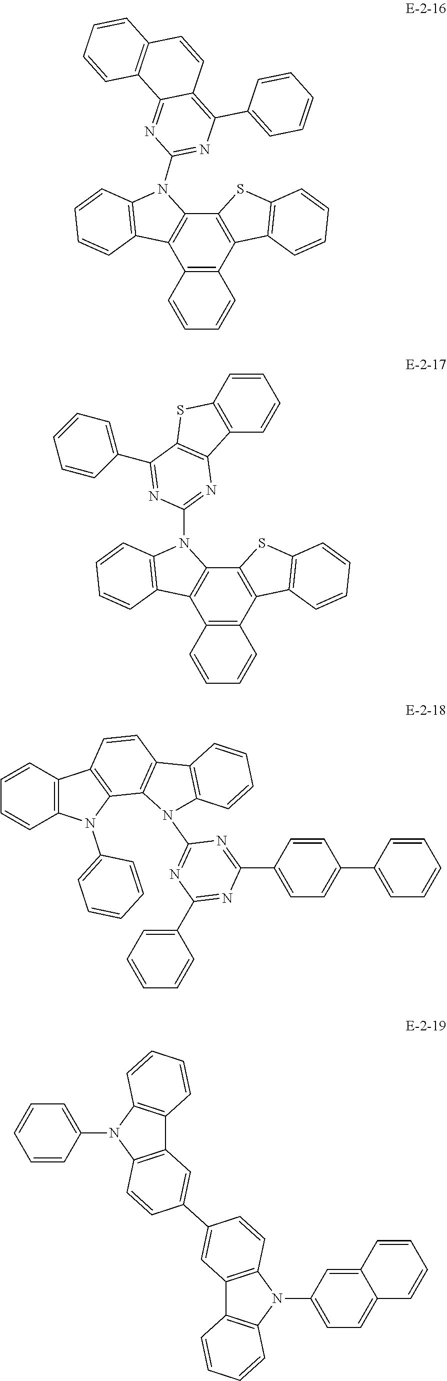

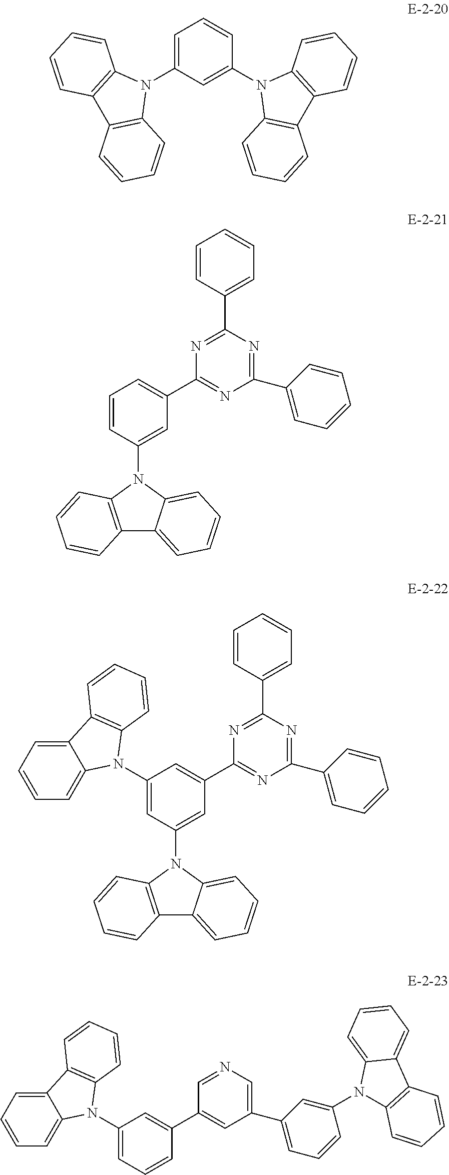 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

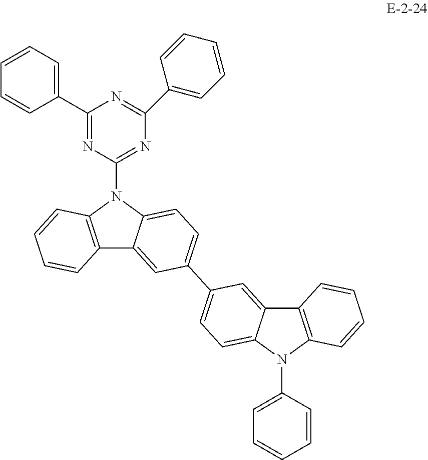 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetrasiloxane (DPSiO4), etc. may be utilized as a host material.

The emission layer EML may include the compound represented by Formula M-a. The compound represented by Formula M-a may be utilized as a phosphorescent dopant material.

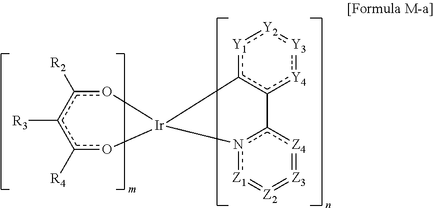

In Formula M-a above, Y₁ to Y₄ and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m may be 0 or 1, and n may be 2 or 3. In Formula M-a, when m is 0, n is 3, and when m is 1, n is 2.

The compound represented by Formula M-a may be utilized as a phosphorescent dopant.

The compound represented by Formula M-a may be represented by any one among Compound M-a1 to Compound M-a25. However, Compounds M-a1 to M-a25 are examples, and the compound represented by Formula M-a is not limited to those represented by Compounds M-a1 to M-a25.

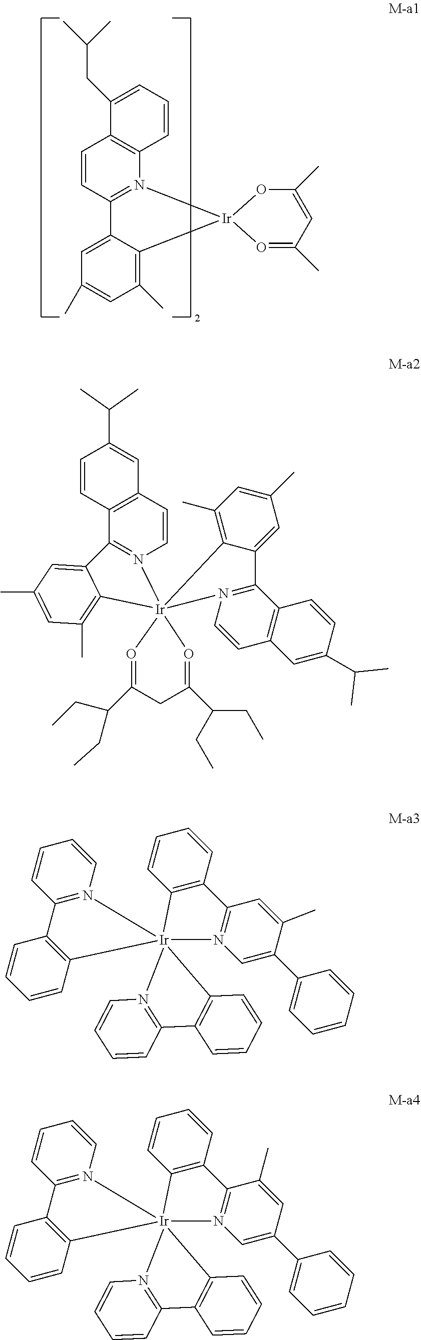

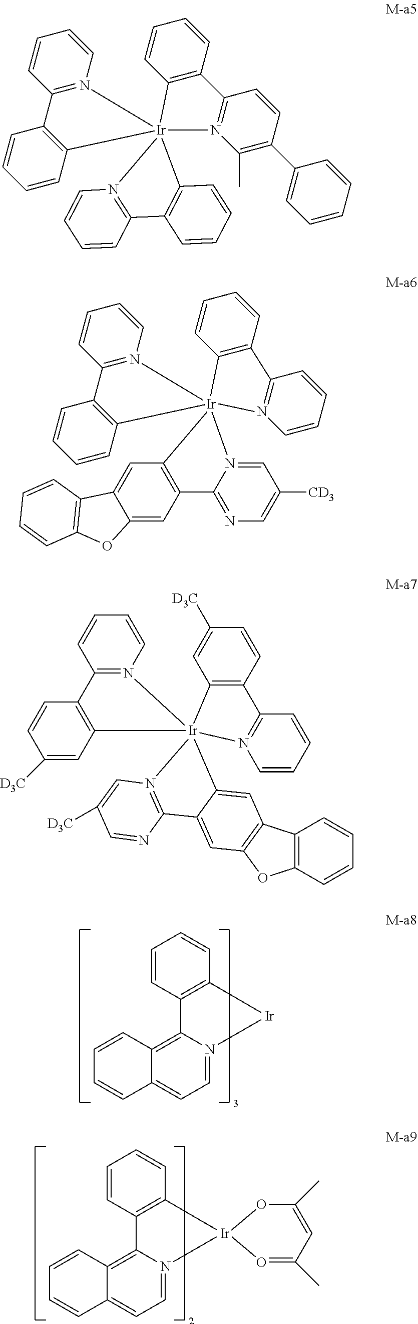

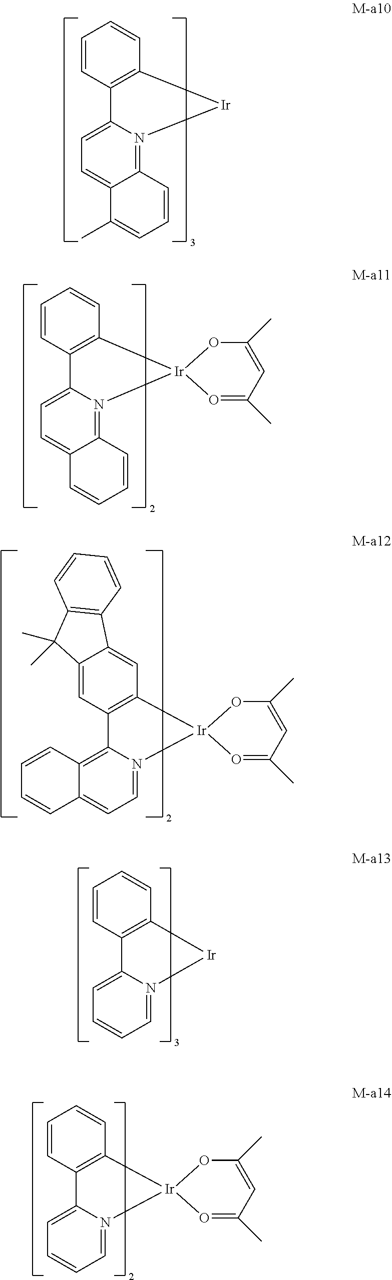

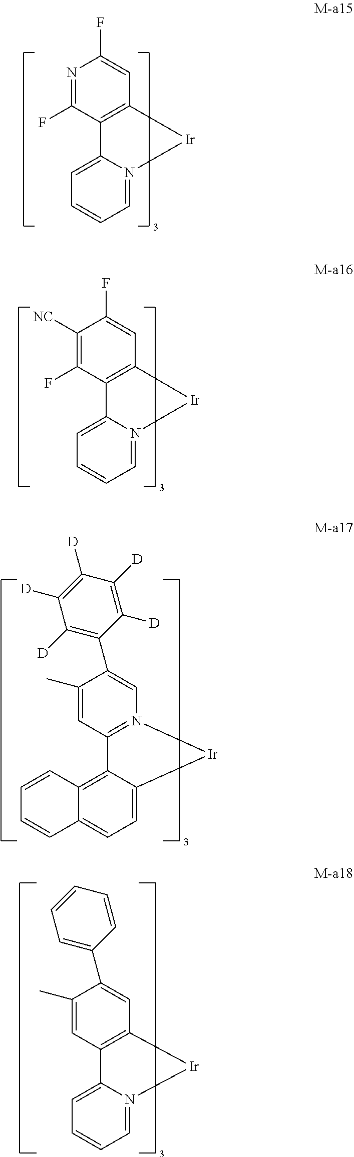

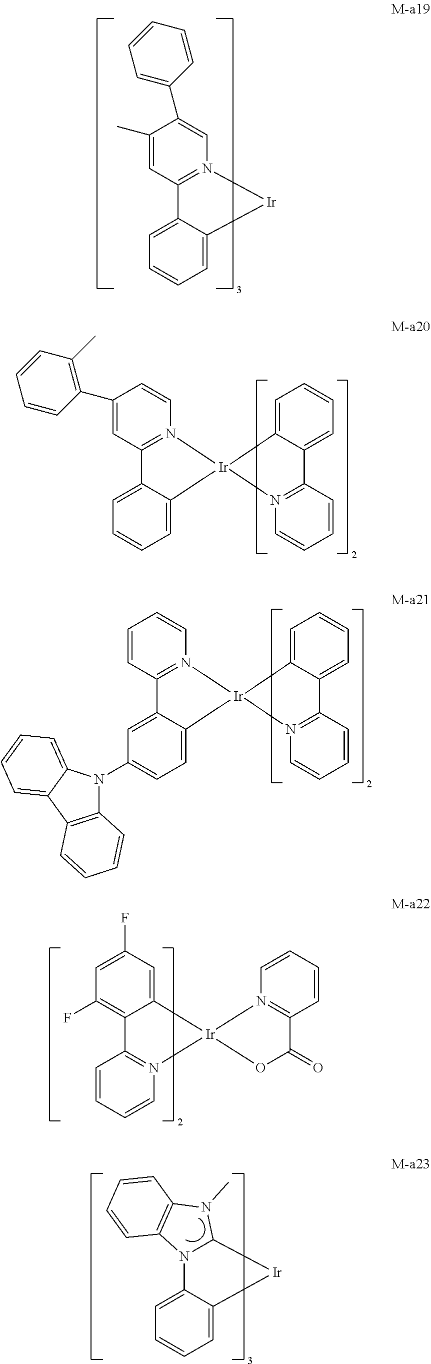

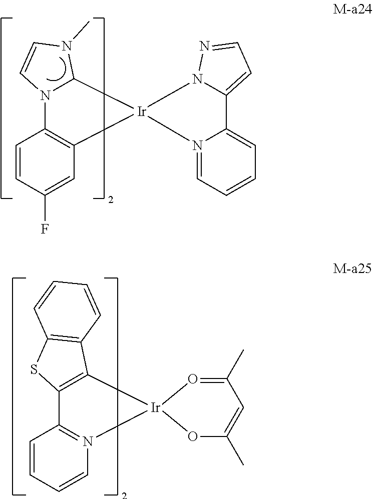

The emission layer EML may include a compound represented by any one among Formula F-a to Formula F-c. The compound represented by Formula F-a or Formula F-c may be utilized as a fluorescence dopant material.

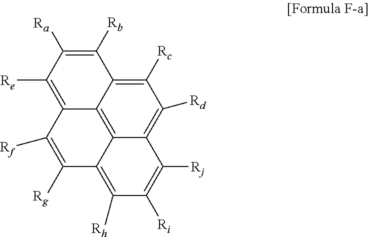

In Formula F-a above, two selected from among Rₐ to Rⱼ may each independently be substituted with *-NAr₁Ar₂. The others (e.g., any remainder thereof), which are not substituted with *-NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *-NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

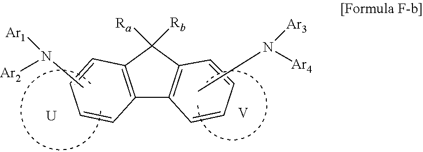

In Formula F-b above, Rₐ and Rb may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may each independently be 0 or 1. For example, in Formula F-b, when the number of U or V is 1, one ring at a part indicated by U or V forms a fused ring at the designated part, and when the number of U or V is 0, a ring does not exist at the part indicated by U or V. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

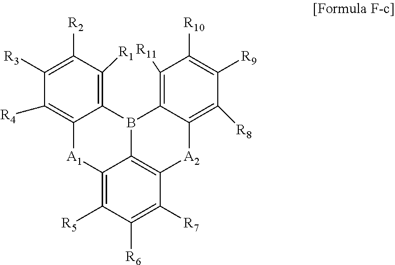

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

In an embodiment, the emission layer EML may further include, as a suitable dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, and/or 1,4-bis(N,N-diphenylamino)pyrene), etc.

The emission layer EML may further include a suitable phosphorescence dopant material. For example, a metal complex containing iridium (Ir), platinum (Pt), osmium (Os), gold (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2′)picolinate) (Firpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from a Group II-VI compound, a Group III-VI compound, a Group I-III-VI compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ or In₂Se₃, a ternary compound such as InGaS₃ and/or InGaSe₃, or any combination thereof.

The Group I-III-VI compound may be selected from a ternary compound selected from the group consisting of AgInS, AgInS₂, CulnS, CuInS₂, AgGaS₂, CuGaS₂ CuGaO₂, AgGaO₂, AgAlO₂, and a mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AINP, AlNAs, AINSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and a mixture thereof. In some embodiments, the Group III-V compound may further include a Group II metal. For example, InZnP, etc., may be selected as a Group III—II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, and/or the quaternary compound may be present in a particle with a substantially uniform or non-uniform concentration distribution. For example, the formulae representing the types (kinds) of elements included in the compounds, and the elemental ratio in the compound may be different. For example, AgInGaS₂ may refer to AgInxGa₁₋ₓS₂ (where x is a real number of 0 to 1).

In some embodiments, the quantum dot may have a single layer structure in which the concentration of each element included in the quantum dot is substantially uniform. Or the quantum dot may have a core-shell structure, in which the material included in the core may be different from the material included in the shell.

The shell of the quantum dot may serve as a protection layer to prevent or reduce the chemical deformation of the core to maintain semiconductor properties, and/or as a charging layer to impart electrophoresis properties to the quantum dot. The shell may be a single layer or multiple layers. An interface between the core and the shell may have a concentration gradient in which the concentration of an element present in the shell becomes lower towards the center of the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An example of the shell of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AlP, AISb, etc., but the embodiment of the present disclosure is not limited thereto.

The quantum dot may have a full width of half maximum (FWHM) of a light emitting wavelength spectrum of about 45 nm or less, about 40 nm or less, or about 30 nm or less, and color purity or color reproducibility may be improved in the above ranges. In some embodiments, light emitted through such a quantum dot is emitted in all directions so that a wide viewing angle may be improved.

In some embodiments, although the form of the quantum dot is not particularly limited as long as it is a form commonly utilized in the art, more specifically, the quantum dot in the form of spherical, pyramidal, multi-arm, or cubic nanoparticles, nanotubes, nanowires, nanofibers, nanoplate particles, etc., may be utilized.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, when the quantum dot described above (utilizing different sizes of quantum dots or different elemental ratios in the quantum dot compound) is utilized in the light emitting device, light emission in one or more suitable wavelengths may be implemented. For example, the adjustment of the size of the quantum dot or the elemental ratio in the quantum dot compound may be selected to emit red, green, and/or blue light. In some embodiments, the quantum dots may be configured to emit white light by combining one or more suitable colors of light.

In each of the light emitting devices ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, or may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in the respective stated order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

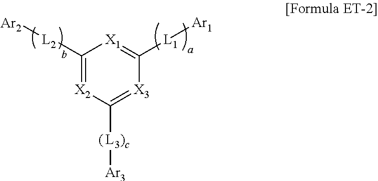

In Formula ET-2, at least one among X₁ to X₃ may be N, and the rest (any remainder thereof) may each independently be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each independently an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1, 10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include at least one among Compound ET1 to Compound ET36:

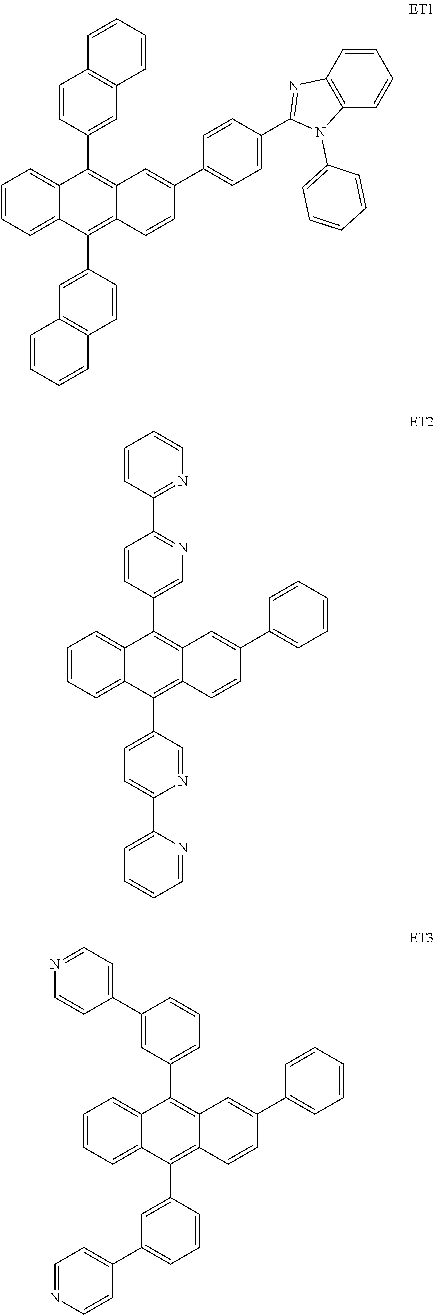 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

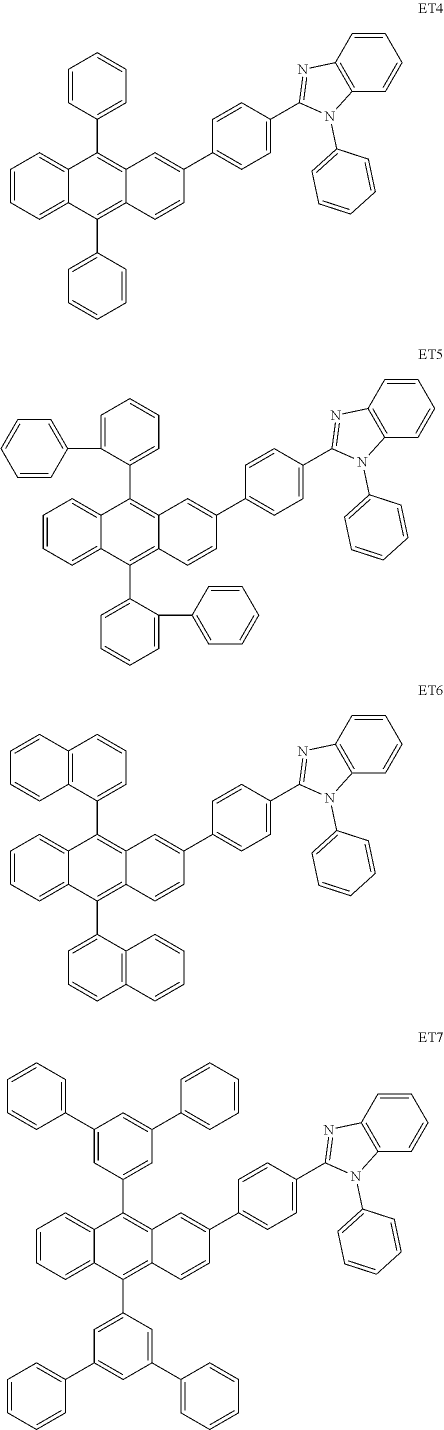 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

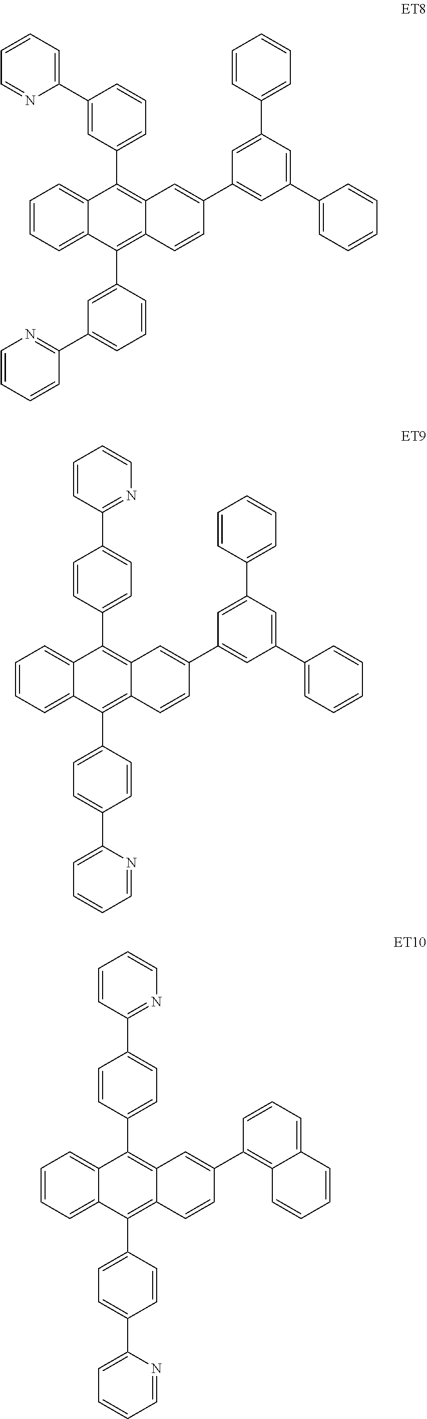

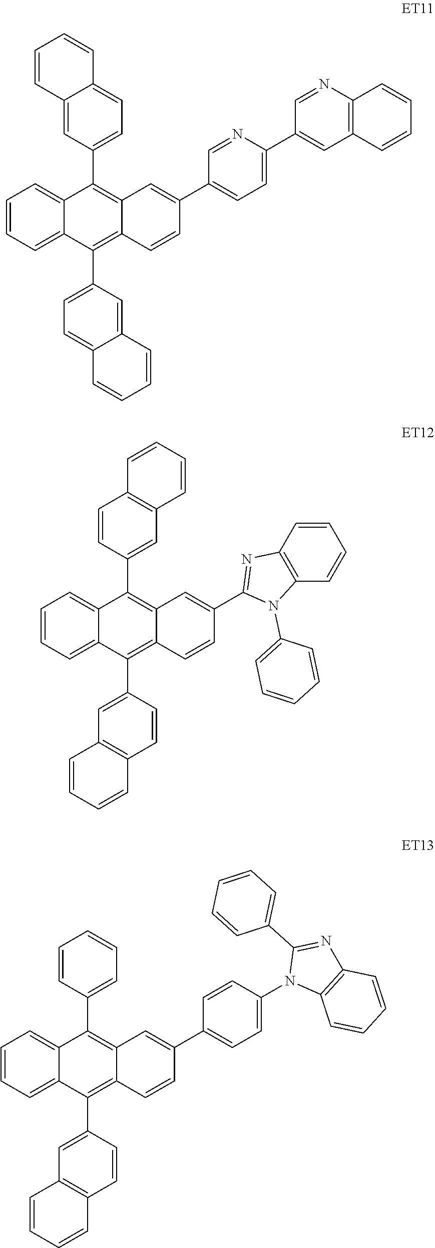 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

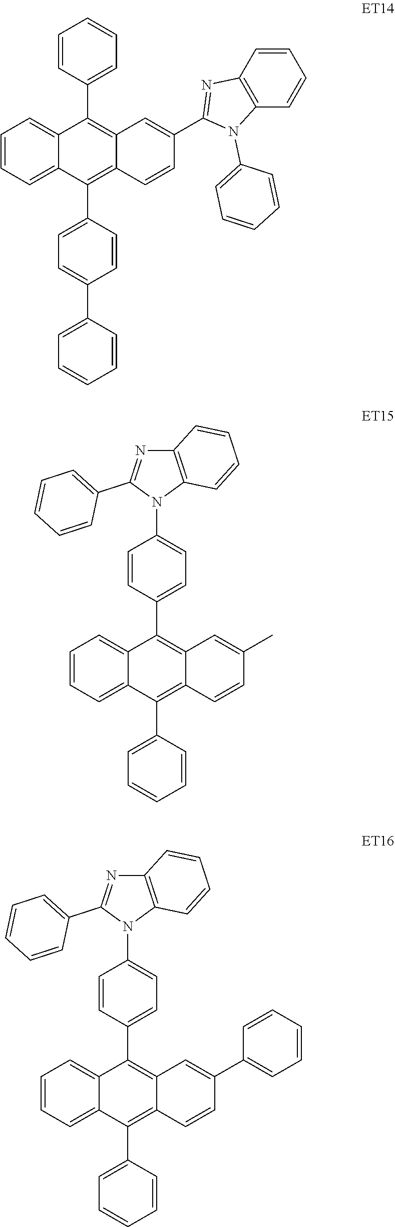 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

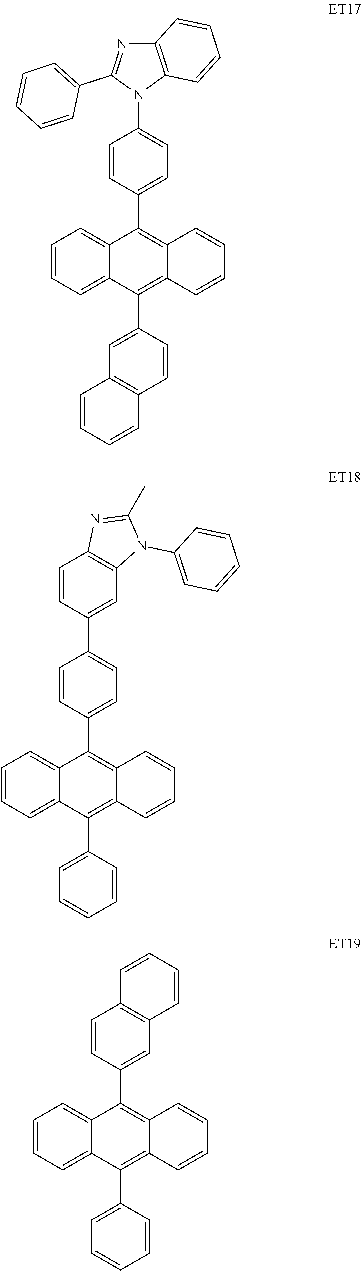

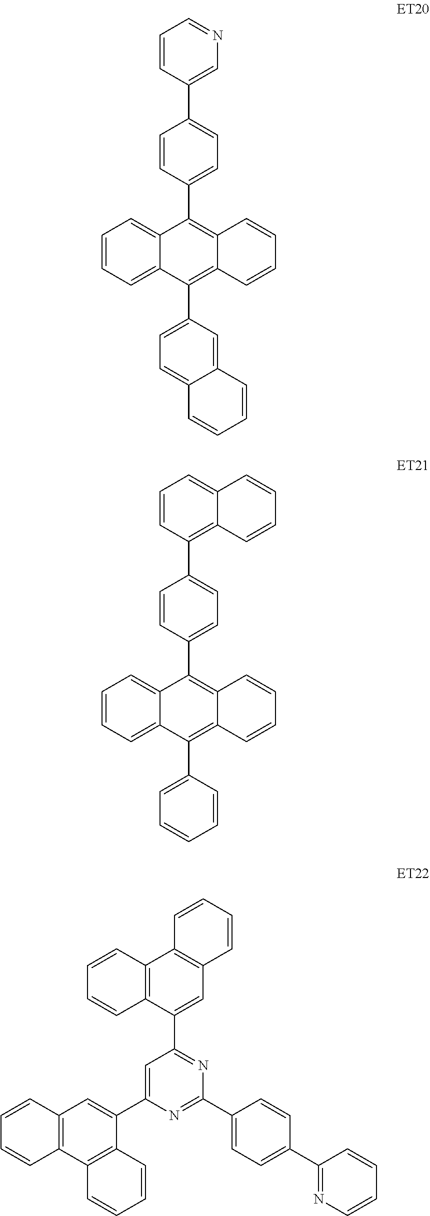

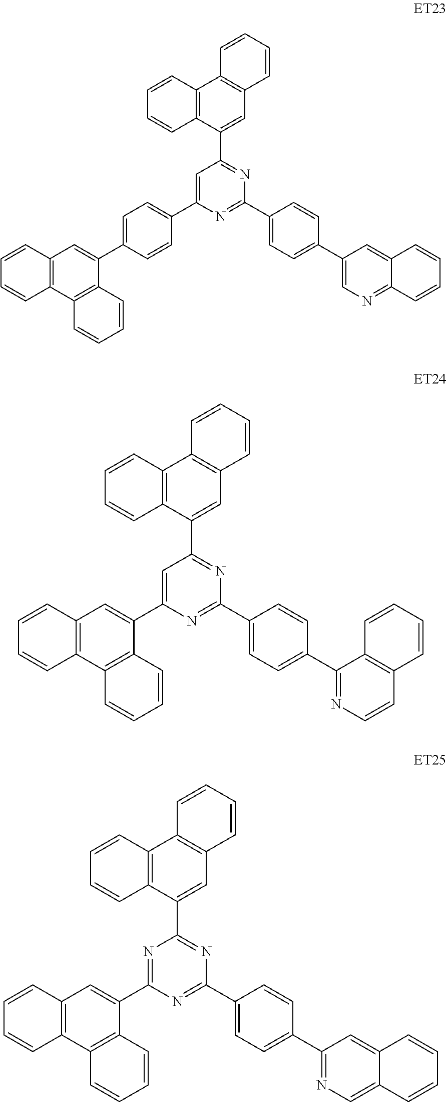 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)nc(-c5cc6ccccc6c6ccccc56)n4)cc3)ncc2c1]

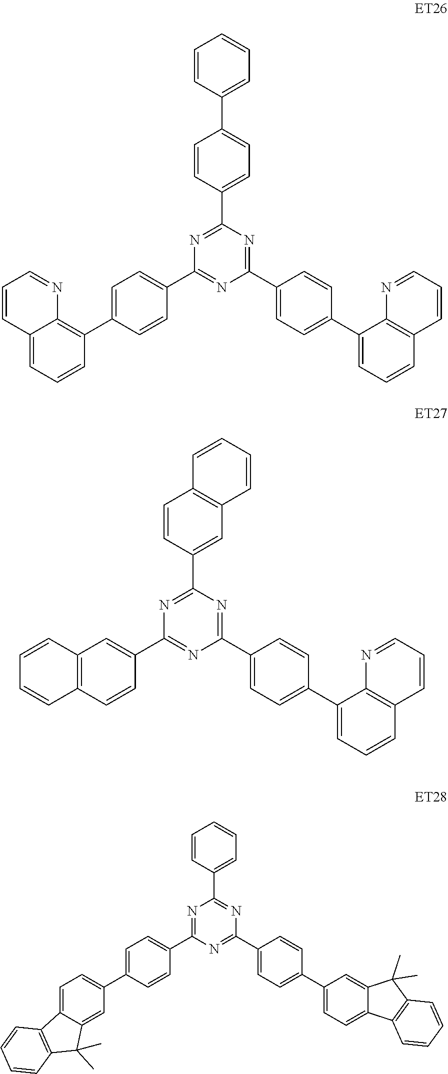 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

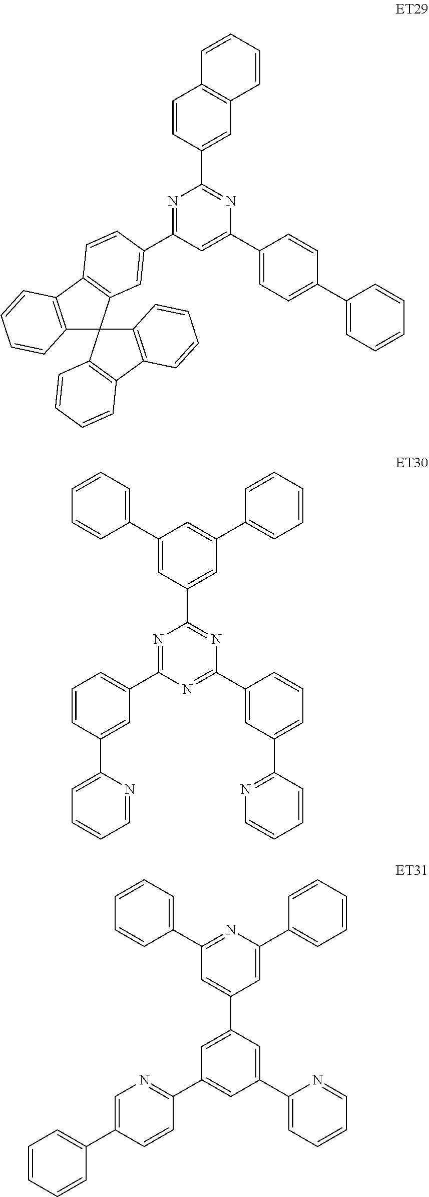 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

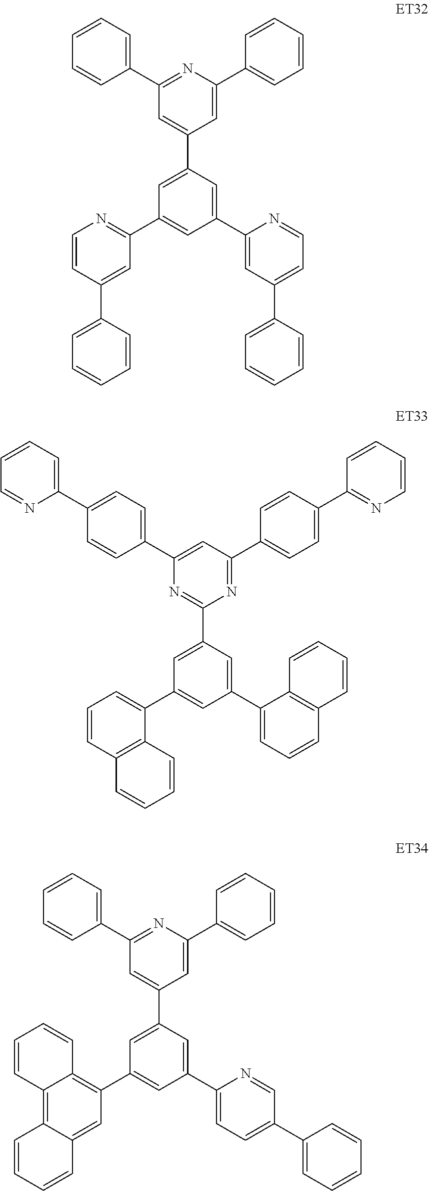 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

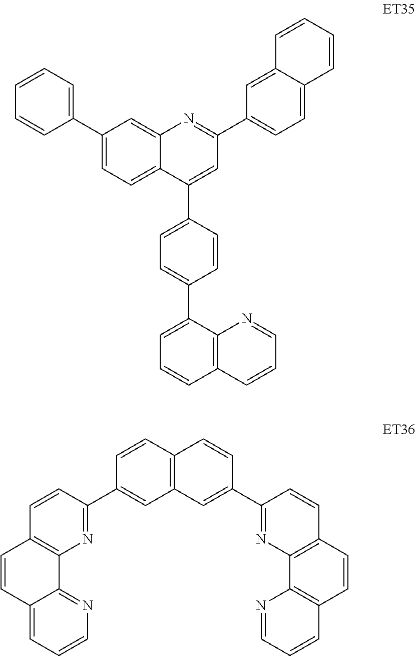 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCI, Rbl, Cul, and/or KI, a lanthanide metal such as Yb, or a co-deposited material of the metal halide and the lanthanide metal. For example, the electron transport region ETR may include KI:Yb, Rbl:Yb, LiF:Yb, etc., as a co-deposited material. In some embodiments, the electron transport region ETR may be formed utilizing a metal oxide such as Li₂O and/or BaO, and/or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1, 10-phenanthroline (Bphen) in addition to the above-described materials, but the embodiment of the present disclosure is not limited thereto.

The electron transport region ETR may include one or more selected from the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgAg). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include one or more of the above-described metal materials, combinations of at least two metal materials of the above-described metal materials, oxides of the above-described metal materials, and/or the like.

The second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting device ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., an epoxy resin, and/or acrylate such as methacrylate. However, the embodiment of the present disclosure is not limited thereto, and the capping layer CPL may include at least one among Compounds P1 to P5:

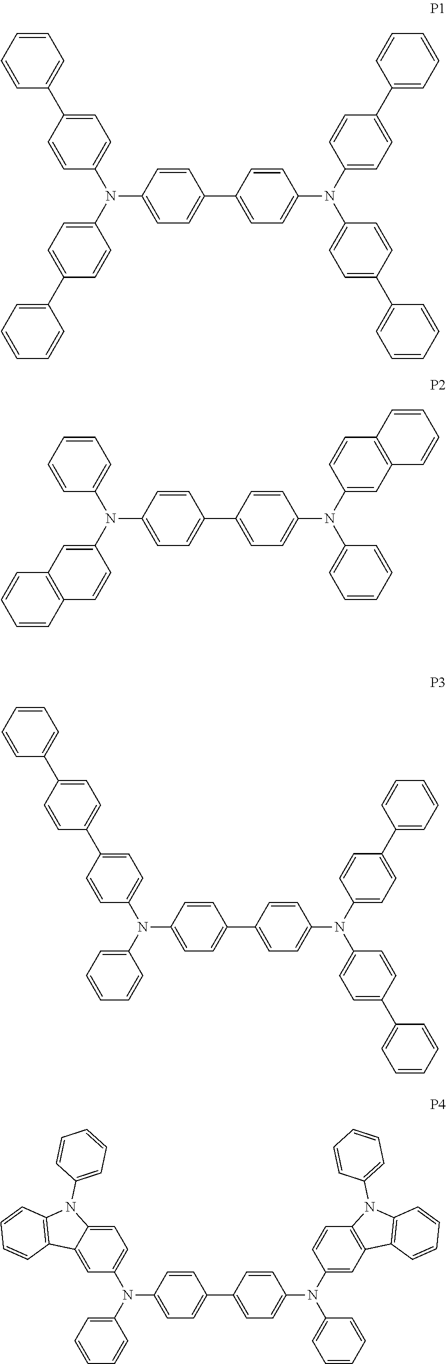 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

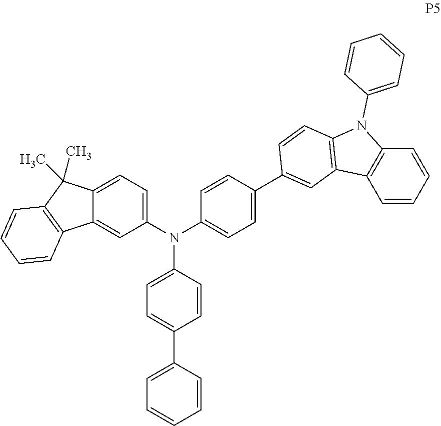 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

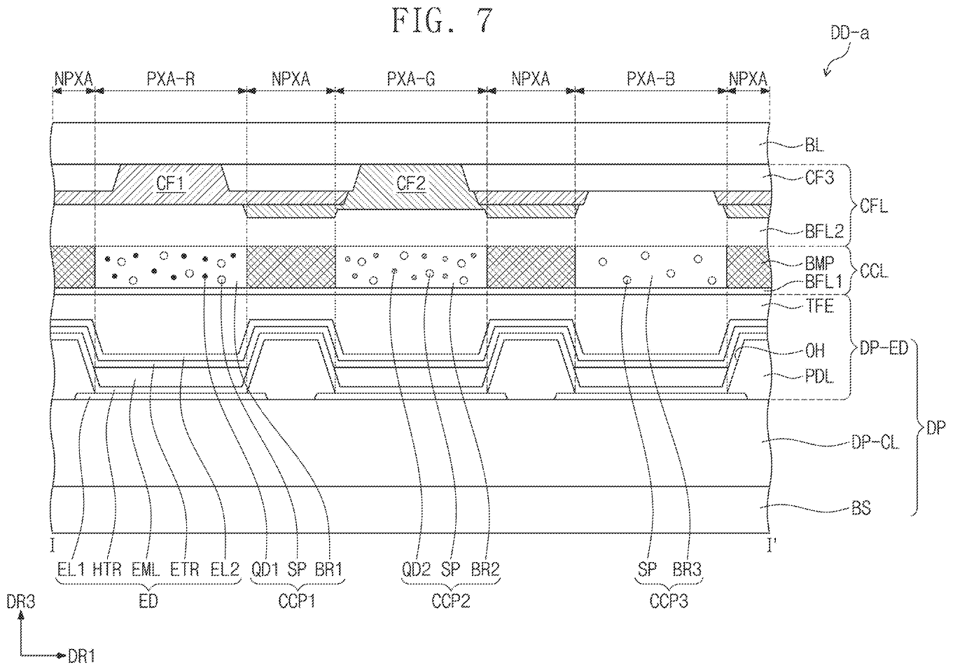

Each of FIGS. 7 to 10 is a cross-sectional view of a display apparatus according to an embodiment of the present disclosure. Hereinafter, in describing the display apparatuses of embodiments with reference to FIGS. 7 to 10, the duplicated features which have been described in FIGS. 1 to 6 are not described again, but their differences will be mainly described.

Referring to FIG. 7, the display apparatus DD-a according to an embodiment may include a display panel DP including a display device layer DP-ED, a light control layer CCL disposed on the display panel DP, and a color filter layer CFL. In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the structures of the light emitting devices of FIGS. 3 to 6 as described above may be equally applied to the structure of the light emitting device ED illustrated in FIG. 7.

The emission layer EML of the light emitting device ED included in the display apparatus DD-a according to an embodiment may include the above-described fused polycyclic compound of an embodiment.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display apparatus DD-a of an embodiment, the emission layer EML may be to emit blue light. In some embodiments, unlike the configuration illustrated, in an embodiment, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may transform the wavelength of light provided and then emit (e.g., emit light of a different color). For example, the light control layer CCL may be a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2 and CCP3 which are spaced apart from each other, but the embodiment of the present disclosure is not limited thereto. FIG. 7 illustrates that the divided patterns BMP do not overlap the light control parts CCP1, CCP2 and CCP3, but in some embodiments, at least a portion of the edges of the light control parts CCP1, CCP2 and CCP3 may overlap the divided patterns BMP.

The light control layer CCL may include a first light control part CCP1 containing a first quantum dot QD1 which converts the first color light provided from the light emitting device ED into a second color light, a second light control part CCP2 containing a second quantum dot QD2 which converts the first color light into a third color light, and a third light control part CCP3 which transmits the first color light. In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include(e.g., may exclude) any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be one or more acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the exposure of the light control parts CCP1, CCP2 and CCP3 to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display apparatus DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include color filters CF1, CF2, and CF3. The first to third filters CF1, CF2, and CF3 may be disposed corresponding to the red light emitting region PXA-R, the green light emitting region PXA-G, and the blue light emitting region PXA-B, respectively.

The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment or dye, and the third filter CF3 may include a blue pigment and/or dye.

In some embodiments, the embodiment of the present disclosure is not limited thereto, and the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but be provided as one filter.

In some embodiments, the color filter layer CFL may further include a light shielding part. The light shielding part may be a black matrix. The light shielding part may include an organic light shielding material or an inorganic light shielding material containing a black pigment and/or dye. The light shielding part may prevent or reduce light leakage, and may separate boundaries between the adjacent filters CF1, CF2, and CF3.

A base substrate BL may be disposed on the color filter layer CFL. The base substrate BL may be a member which provides a base surface on which the color filter layer CFL, the light control layer CCL, and/or the like are disposed. The base substrate BL may be a glass substrate, a metal substrate, a plastic substrate, etc.

However, the embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

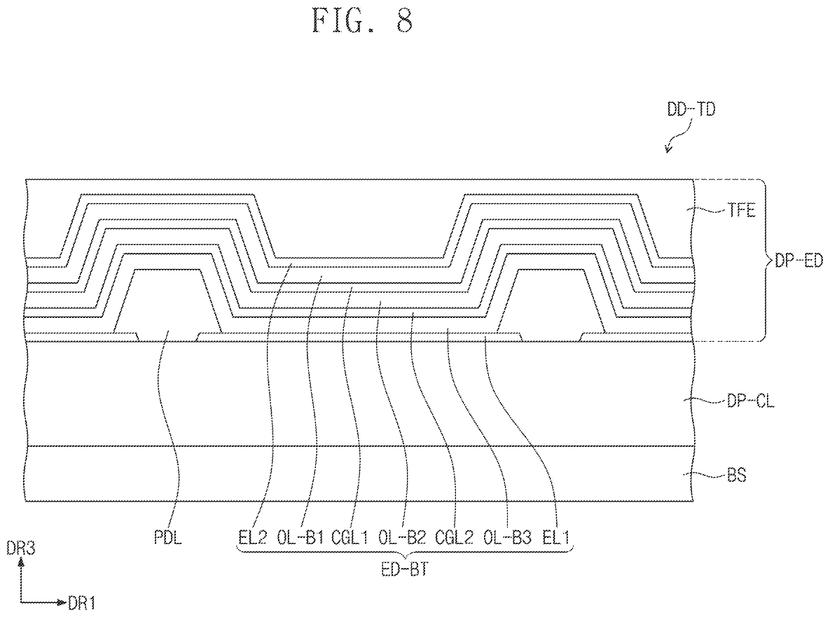

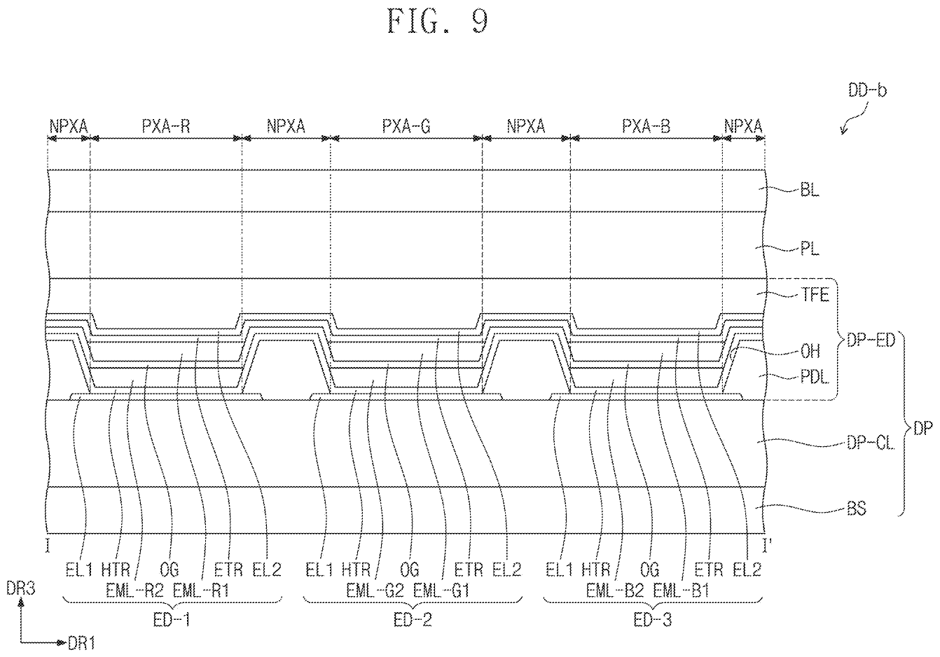

FIG. 8 is a cross-sectional view illustrating a portion of a display apparatus according to an embodiment. In the display apparatus DD-TD of an embodiment, the light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) located therebetween.

For example, the light emitting device ED-BT included in the display apparatus DD-TD of an embodiment may be a light emitting device having a tandem structure and including a plurality of emission layers.

In an embodiment illustrated in FIG. 8, all light (e.g., light beam) respectively emitted from the light emitting structures OL-B1, OL-B2, and OL-B3 may be blue light. However, the embodiment of the present disclosure is not limited thereto, and the light (e.g., light beam) respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light (e.g., light beam) having wavelength ranges different from each other may be to emit white light.

Charge generation layers CGL1 and CGL2 may be respectively disposed between two of the neighboring light emitting structures OL-B1, OL-B2, and OL-B3. The charge generation layers CGL1 and CGL2 may include a p-type or kind charge generation layer (e.g., a p-charge generation layer) and/or an n-type or kind charge generation layer (e.g., a n-charge generation layer).

At least one among the light emitting structures OL-B1, OL-B2, and OL-B3 included in the display apparatus DD-TD of an embodiment may contain the above-described fused polycyclic compound of an embodiment. For example, at least one among the plurality of emission layers included in the light emitting device ED-BT may include the fused polycyclic compound of an embodiment.

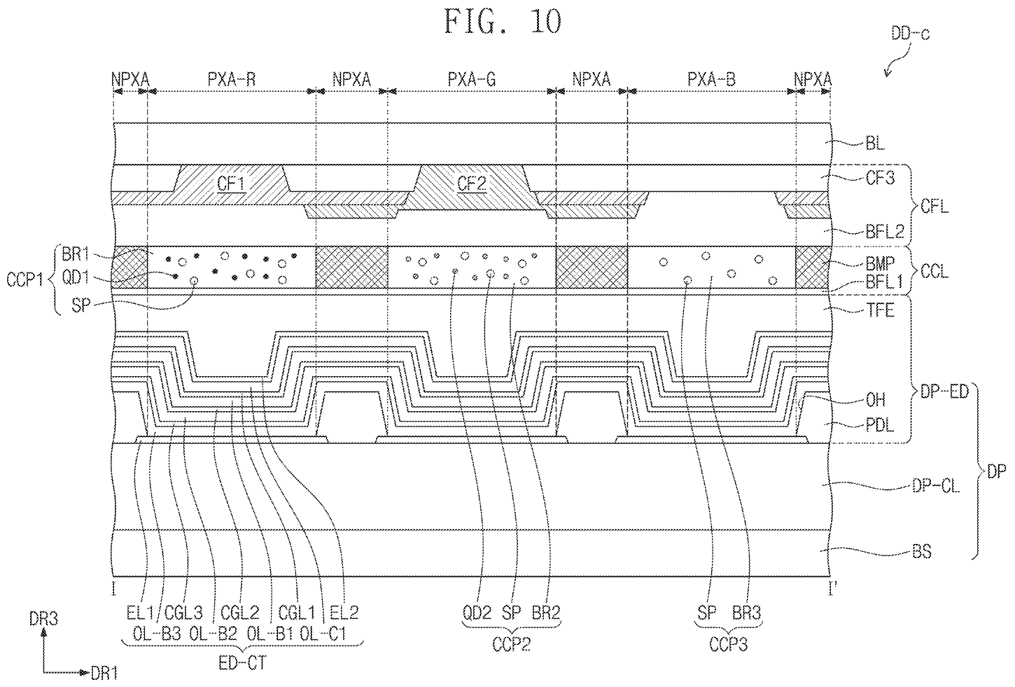

FIG. 9 is a cross-sectional view illustrating a display apparatus according to an embodiment of the present disclosure. FIG. 10 is a cross-sectional view illustrating a display apparatus according to an embodiment of the present disclosure.

Referring to FIG. 9, the display apparatus DD-b according to an embodiment may include light emitting devices ED-1, ED-2, and ED-3 in which two emission layers are stacked. Compared with the display apparatus DD of an embodiment illustrated in FIG. 2, an embodiment illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may be to emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be disposed on the display device layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display apparatus according to an embodiment may not be provided.

At least one emission layer included in the display apparatus DD-b of an embodiment illustrated in FIG. 9 may include the above-described fused polycyclic compound of an embodiment. For example, in an embodiment, at least one of the first blue emission layer EML-B1 or the second blue emission layer may include the fused polycyclic compound of an embodiment.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light (e.g., light beam) in different wavelength regions.

The charge generation layers CGL1, CGL2, and CGL3 disposed between adjacent light emitting structures OL-B1, OL-B2, OL-B3, and OL-C1 may include a p-type or kind charge generation layer and/or an n-type or kind charge generation layer.

At least one among the light emitting structures OL-B1, OL-B2, OL-B3, and OL-C1 included in the display apparatus DD-c of an embodiment may contain the above-described fused polycyclic compound of an embodiment. For example, in an embodiment, at least one among the first to third light emitting structures OL-B1, OL-B2, and OL-B3 may include the above described fused polycyclic compound of an embodiment.

The light emitting device ED according to an embodiment of the present disclosure may include the above-described polycyclic compound represented by Formula 1 of an embodiment in at least one functional layer disposed between the first electrode EL1 and the second electrode EL2, thereby exhibiting excellent or suitable luminous efficiency and improved service life characteristics. For example, the polycyclic compound according to an embodiment may be included in the emission layer EML of the light emitting device ED of an embodiment, and the light emitting device of an embodiment may exhibit a long service life characteristic.

In an embodiment, the electronic apparatus may include a display apparatus including a plurality of light emitting devices, and a control part which controls the display apparatus. The electronic apparatus of an embodiment may be a device that is activated according to an electrical signal. The electronic apparatus may include display apparatuses of one or more suitable embodiments. For example, the electronic apparatus may include not only large-sized electronic apparatuses such as a television set, a monitor, and/or an outdoor billboard but also include small- and medium-sized electronic apparatuses such as a personal computer, a laptop computer, a personal digital terminal, a display apparatus for a vehicle, a game console, a portable electronic device, and/or a camera.

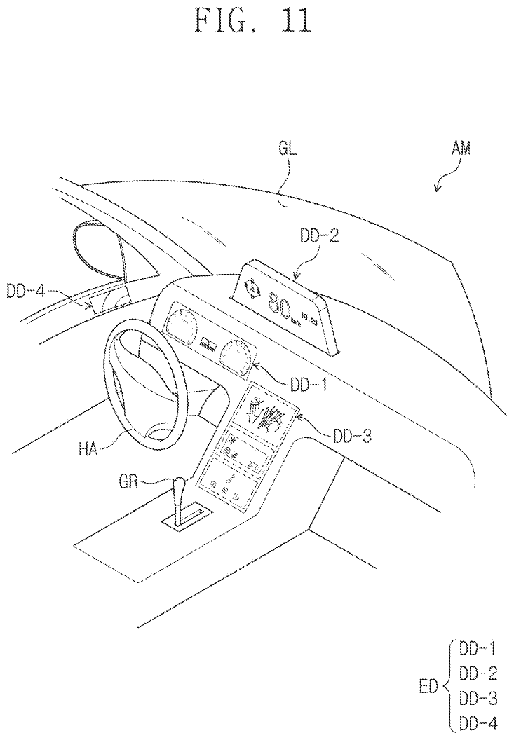

FIG. 11 is a view illustrating a vehicle AM in which first to fourth display apparatuses DD-1, DD-2, DD-3, and DD-4 are disposed. At least one among the first to fourth display apparatuses DD-1, DD-2, DD-3, and DD-4 may include the same configuration as the display apparatuses DD, DD-TD, DD-a, DD-b, and DD-c as described with reference to FIGS. 1, and 2, and 7 to 10.

FIG. 11 illustrates a vehicle AM, but this is an example, and the first to fourth display apparatuses DD-1, DD-2, DD-3, and DD-4 may be disposed in another transportation device such as bicycles, motorcycles, trains, ships, and/or airplanes. In some embodiments, at least one among the first to fourth display apparatuses DD-1, DD-2, DD-3, and DD-4 including the same configuration as the display apparatuses DD, DD-TD, DD-a, DD-b, and DD-c of an embodiment may be employed in a personal computer, a laptop computer, a personal digital terminal, a game console, a portable electronic device, a television, a monitor, an outdoor billboard, and/or the like. In addition, these are merely provided as embodiments, and thus may be employed in other electronic apparatuses unless departing from the present disclosure.

At least one among the first to fourth display apparatuses DD-1, DD-2, DD-3, and DD-4 may include the light emitting device ED of an embodiment as described with reference to FIGS. 3 to 6. The light emitting device ED of an embodiment may include a heterocyclic compound of an embodiment. At least one among the first to fourth display apparatuses DD-1, DD-2, DD-3, and DD-4 may include the light emitting device ED including a heterocyclic compound of an embodiment, thereby improving a display service life.

Referring to FIG. 11, the vehicle AM may include a steering wheel HA and a gear GR for driving the vehicle AM. In some embodiments, the vehicle AM may include a front window GL disposed to face the driver.

The first display apparatus DD-1 may be disposed in a first region overlapping the steering wheel HA. For example, the first display apparatus DD-1 may be a digital cluster which displays a first information of the vehicle AM. The first information may include a first scale which indicates a driving speed of the vehicle AM, a second scale which indicates an engine speed (that is, revolutions per minute (RPM)), an image which indicates a fuel state, etc. The first scale and the second scale may be indicated as a digital image.

The second display apparatus DD-2 may be disposed in a second region facing the driver's seat and overlapping the front window GL. The driver's seat may be a seat in which the steering wheel HA is disposed. For example, the second display apparatus DD-2 may be a head up display (HUD) which displays a second information of the vehicle AM. The second display apparatus DD-2 may be optically transparent. The second information may include digital numbers which indicate a driving speed, and may further include information such as the current time. In some embodiments, the second information of the second display apparatus DD-2 may be projected to the front window GL to be displayed.

The third display apparatus DD-3 may be disposed in a third region adjacent to the gear GR. For example, the third display apparatus DD-3 may be disposed between the driver's seat and the passenger seat and may be a center information display (CID) for a vehicle for displaying a third information. The passenger seat may be a seat spaced apart from the driver's seat with the gear GR disposed therebetween. The third information may include information about traffic (e.g., navigation information), playing music or radio or a video (or an image), temperatures inside the vehicle AM, etc.

The fourth display apparatus DD-4 may be spaced apart from the steering wheel HA and the gear GR, and may be disposed in a fourth region adjacent to the side of the vehicle AM. For example, the fourth display apparatus DD-4 may be a digital side-view mirror which displays a fourth information. The fourth display apparatus DD-4 may display an image outside the vehicle AM taken by a camera module CM disposed outside the vehicle AM. The fourth information may include an image outside the vehicle AM.

The above-described first to fourth information may be examples, and the first to fourth display apparatuses DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Hereinafter, with reference to Examples and Comparative Examples, a fused polycyclic according to an embodiment of the present disclosure and a luminescence device of an embodiment of the present disclosure will be described in more detail. In addition, Examples described below are only illustrations to assist the understanding of the present disclosure, and the scope of the present disclosure is not limited thereto.

### Examples

### 1. Synthesis of Fused Polycyclic Compound

First, a synthetic method of the fused polycyclic compound according to the current embodiment will be described in more detail by illustrating synthetic methods of Compounds 51, 55, 57, 61, 88, 89, 91, 96, 125, and 129. In addition, the synthetic methods of the fused polycyclic compounds as described below are only examples, and the synthetic method of the fused polycyclic compound according to an embodiment of the present disclosure is not limited to the following examples.

### (1) Synthesis of Compound 51

### Synthesis of Intermediate M1

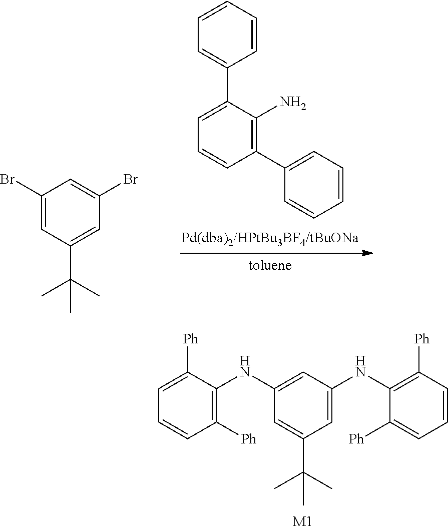

1,3-Dibromo-5-tert-butylbenzene (30 g), [1,1′:3′,1″-terphenyl]-2′-amine (53 g), Pd(dba)₂ (5.0 g), HPtBu₃BF₄ (5.0 g), and NaOtBu (24 g) were added to a 1 L three-necked flask, 500 mL of toluene was added thereto, the resulting mixture was stirred in an Ar atmosphere at about 80° C. for about 5 hours, and then solids were filtered out with silica gel pad to obtain a reaction solution. The obtained reaction solution was concentrated with an evaporator and washed by suspension by adding EtOH to obtain a white solid (53 g). In FAB-MS measurement of the obtained solid, it was confirmed that m/z=621, thereby identifying M1, a target product.

### Synthesis of Intermediate M2

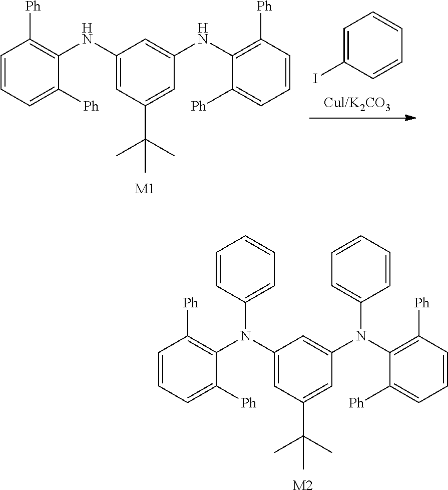

Intermediate M1 (30 g), iodobenzene (150 g), Cul (9.2 g), and K₂CO₃ (27 g) were added to a 500 mL three-necked flask, and stirred in an Ar atmosphere at about 180° C. for about 48 hours, and then solids were filtered out with silica gel pad to obtain a reaction solution. The obtained reaction solution was heated in a reduced-pressure atmosphere to distill off iodobenzene, and purified with column chromatography (eluent CH₂Cl₂/Hexane=¼), then concentrated, and washed by suspension by adding EtOH to obtain a white solid (11 g). In FAB-MS measurement of the obtained solid, it was confirmed that m/z=773, thereby identifying M2, a target product.

### Synthesis of Intermediate M3

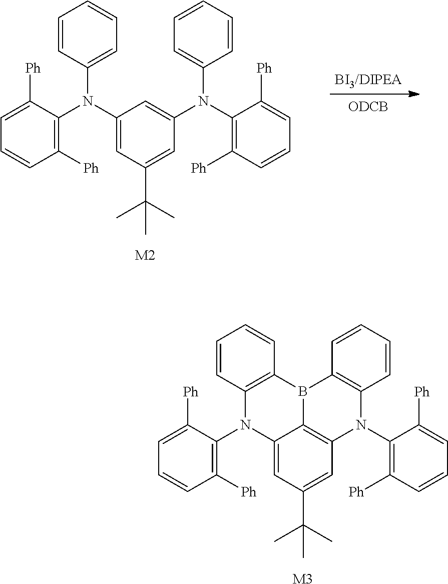

Intermediate M2 (11 g), B13 (22 g), and o-dichlorobenzene (140 mL) were added to a 500 mL three-necked flask, stirred in an Ar atmosphere at about 180° C. for about 48 hours, and cooled at room temperature, and 30 mL of diisopropylethylamine was added thereto under ice cooling. Water was added to the obtained reaction solution, and an organic layer was extracted with CH₂Cl₂, and dried over MgSO₄. Solids in the organic layer were filtered out and then CH₂Cl₂ in the organic layer was removed with an evaporator, then heated in a reduced-pressure atmosphere to distill off o-dichlorobenzene, and purified with column chromatography (eluent CH₂Cl₂/Hexane=¼), then concentrated, and washed by suspension by adding EtOH to obtain a yellow solid (0.56 g). In FAB-MS measurement of the obtained solid, it was confirmed that m/z=781, thereby identifying M3, a target product.

### Synthesis of Intermediate M4

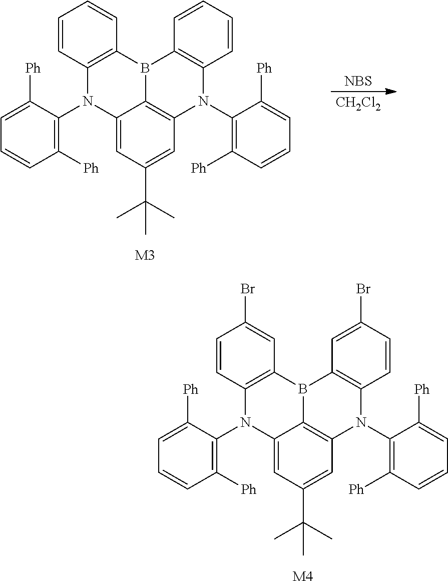

Intermediate M3 (0.56 g), N-bromosuccinimide (0.32 g), and CH₂Cl₂ (35 mL) were added to a 100 mL two-necked flask, and stirred at room temperature for about 8 hours, and water was added thereto. An organic layer was extracted with CH₂Cl₂, and dried over MgSO₄, and then solids were filtered out. The obtained organic layer was concentrated with an evaporator, and recrystallization was performed utilizing toluene and EtOH to obtain a yellow solid (0.64 g). In FAB-MS measurement of the obtained solid, it was confirmed that m/z=939, thereby identifying M4, a target product.

### Synthesis of Intermediate M5

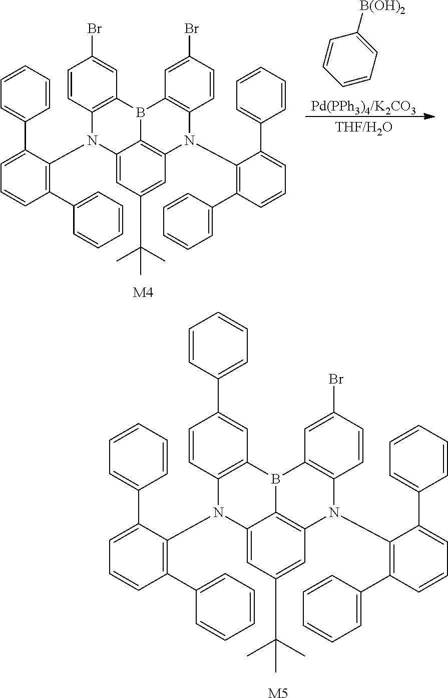

Intermediate M4 (0.20 g), phenylboronic acid (0.06 g), Pd(PPh₃)₄ (0.06 g), K₂CO₃ (0.12 g), THF (5 mL), and water (3 mL) were added to a 50 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (0.1 g). In FAB-MS measurement of the obtained solid, it was confirmed that m/z=936, thereby identifying M5, a target product.

### Synthesis of Compound 51

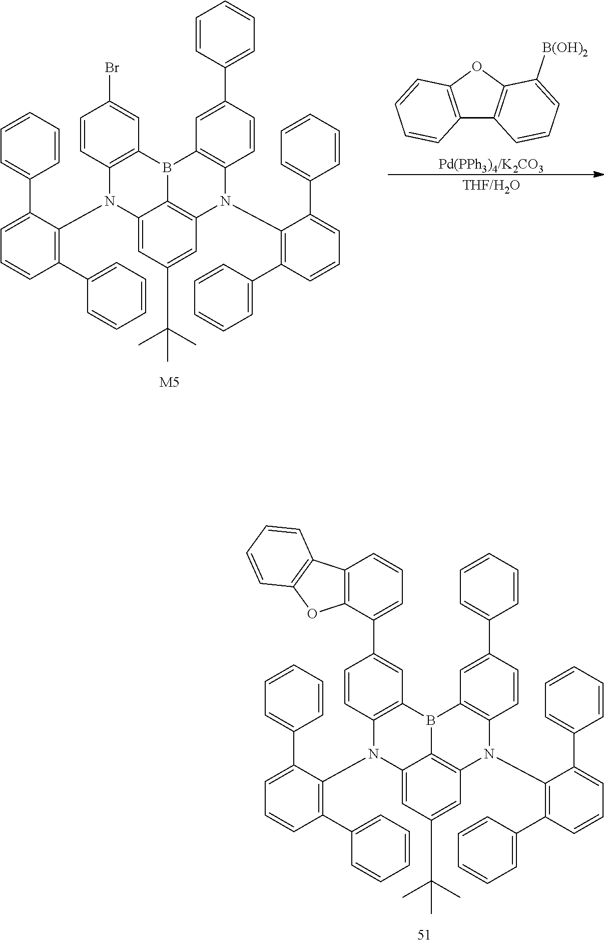

Intermediate M5 (0.10 g), 4-dibenzofuranboronic acid (0.05 g), Pd(PPh₃)₄ (0.03 g), K₂CO₃ (0.06 g), THF (3 mL), and water (1 mL) were added to a 30 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (0.087 g). In FAB-MS measurement of the obtained solid, it was confirmed that m/z=1023, thereby identifying Compound 51, a target product. The obtained Compound 51 was further purified by sublimation and utilized in the evaluation of luminescent properties and device.

### (2) Synthesis of Compound 55

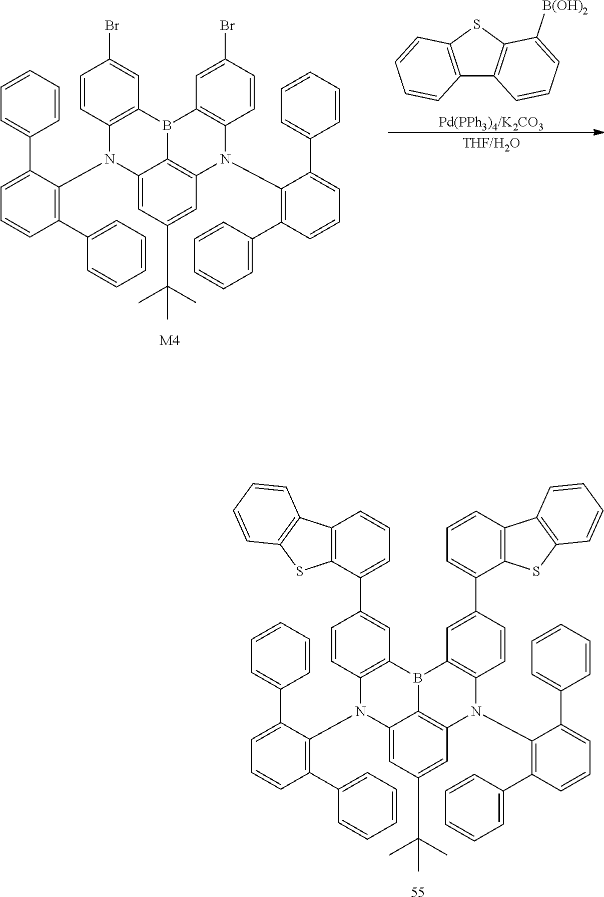

Intermediate M4 (0.20 g), 4-dibenzothiopheneboronic acid (0.12 g), Pd(PPh₃)₄ (0.06 g), K₂CO₃ (0.12 g), THF (5 mL), and water (3 mL) were added to a 50 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (0.195 g). In FAB-MS measurement of the obtained solid, it was confirmed that m/z=1145, thereby identifying Compound 55, a target product. The obtained Compound 55 was further purified by sublimation and utilized in the evaluation of luminescent properties and device.

### (3) Synthesis of Compound 57

### Synthesis of Intermediate M6

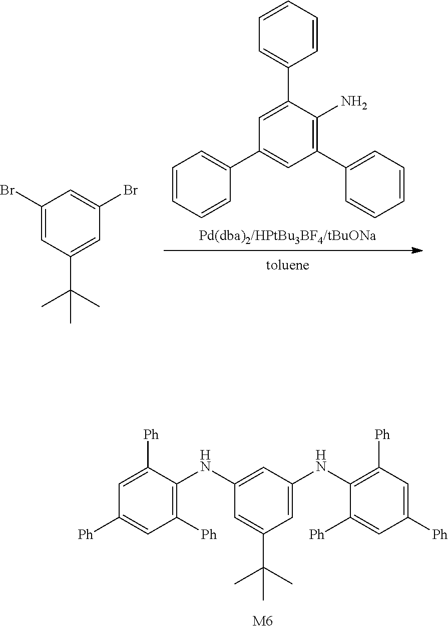

1,3-Dibromo-5-tert-butylbenzene (30 g), 5′-phenyl-[1, 1:3′,1″-terphenyl]-2′-amine (69 g), Pd(dba)₂ (5.0 g), HPtBu₃BF₄ (5.0 g), and NaOtBu (24 g) were added to a 1 L three-necked flask, 500 mL of toluene was added thereto, the resulting mixture was stirred in an Ar atmosphere at about 80° C. for about 5 hours, and then solids were filtered out with silica gel pad to obtain a reaction solution. The obtained reaction solution was concentrated with an evaporator and washed by suspension by adding EtOH to obtain a white solid (69 g). In FAB-MS measurement of the obtained solid, it was confirmed that m/z=773, thereby identifying M6, a target product.

### Synthesis of Intermediate M7

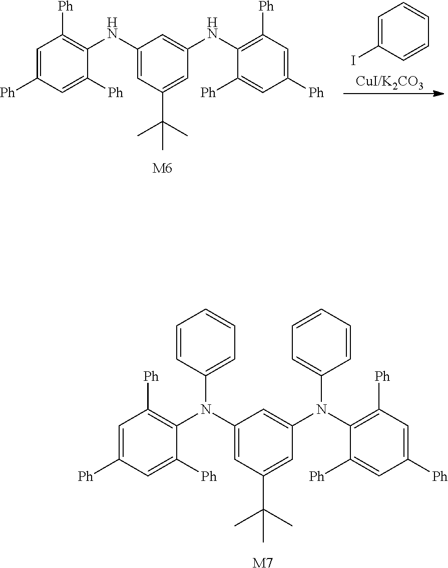

Intermediate M6 (69 g), iodobenzene (277 g), Cul (16 g), and K₂CO₃ (49 g) were added to a 500 mL three-necked flask, and stirred in an Ar atmosphere at about 180° C. for about 48 hours, and then solids were filtered out with silica gel pad to obtain a reaction solution. The obtained reaction solution was heated in a reduced-pressure atmosphere to distill off iodobenzene, and purified with column chromatography (eluent CH₂Cl₂/Hexane=¼), then concentrated, and washed by suspension by adding EtOH to obtain a white solid (28 g). In FAB-MS measurement of the obtained solid, it was confirmed that m/z=925, thereby identifying M7, a target product.

### Synthesis of Intermediate M8

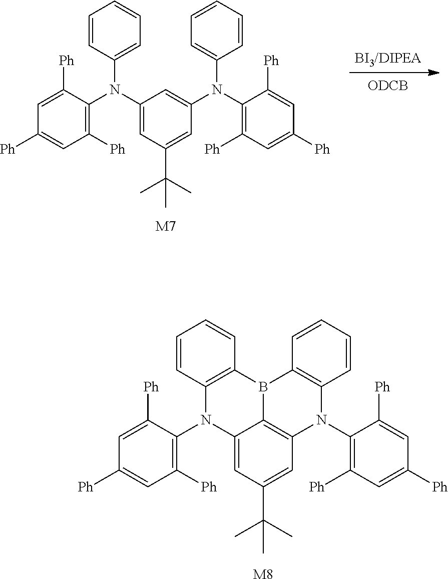

Intermediate M7 (28 g), Bl₃ (47 g), and o-dichlorobenzene (300 mL) were added to a 500 mL three-necked flask, stirred in an Ar atmosphere at about 180° C. for about 48 hours, and cooled at room temperature, and 63 mL of diisopropylethylamine was added thereto under ice cooling. Water was added to the obtained reaction solution, and an organic layer was extracted with CH₂Cl₂, and dried over MgSO₄. Solids in the organic layer were filtered out and then CH₂Cl₂ in the organic layer was removed with an evaporator, then heated in a reduced-pressure atmosphere to distill off o-dichlorobenzene, and purified with column chromatography (eluent CH₂Cl₂/Hexane=¼), then concentrated, and washed by suspension by adding EtOH to obtain a yellow solid (0.85 g). In FAB-MS measurement of the obtained solid, it was confirmed that m/z=933, thereby identifying M8, a target product.

### Synthesis of Intermediate M9

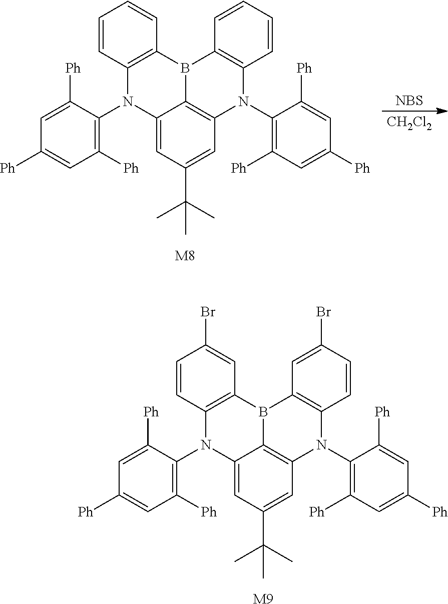

Intermediate M8 (0.85 g), N-bromosuccinimide (0.40 g), and CH₂Cl₂ (45 mL) were added to a 100 mL two-necked flask, and stirred at room temperature for about 8 hours, and water was added thereto. An organic layer was extracted with CH₂Cl₂, and dried over MgSO₄, and then solids were filtered out. The obtained organic layer was concentrated with an evaporator, and recrystallization was performed utilizing toluene and EtOH to obtain a yellow solid (0.94 g). In FAB-MS measurement of the obtained solid, it was confirmed that m/z=1091, thereby identifying M9, a target product.

### Synthesis of Compound 57

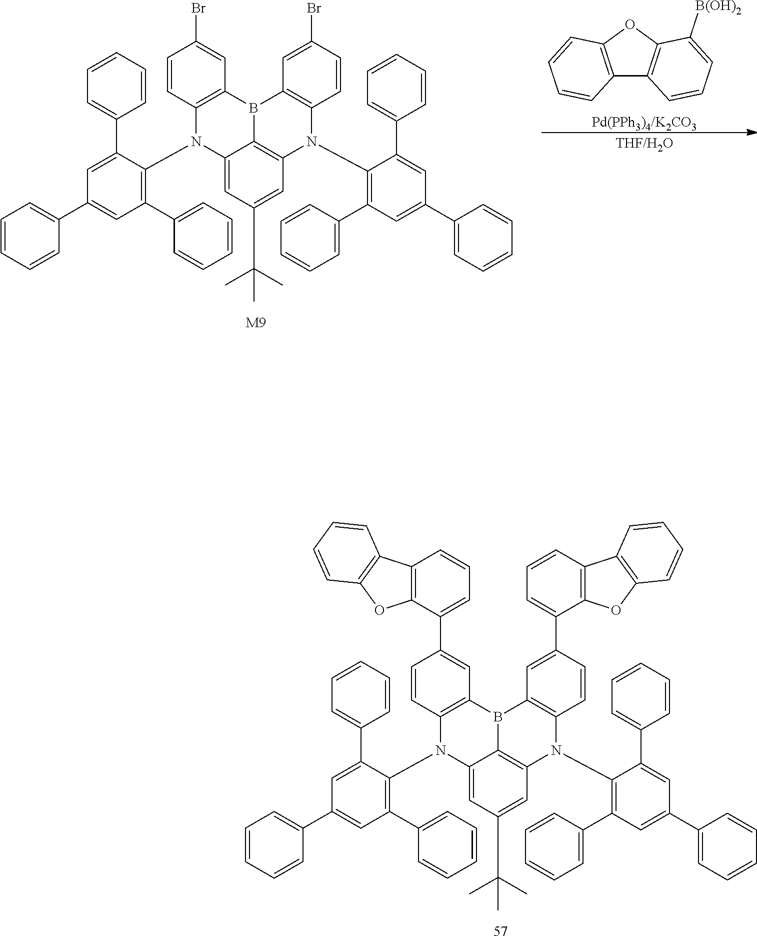

Intermediate M9 (0.94 g), 4-dibenzofuranboronic acid (0.44 g), Pd(PPh₃)₄ (0.24 g), K₂CO₃ (0.48 g), THF (22 mL), and water (11 mL) were added to a 50 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (0.872 g). In FAB-MS measurement of the obtained solid, it was confirmed that m/z=1265, thereby identifying Compound 57, a target product. The obtained Compound 57 was further purified by sublimation and utilized in the evaluation of luminescent properties and device.

### (4) Synthesis of Compound 61

### Synthesis of Intermediate M10

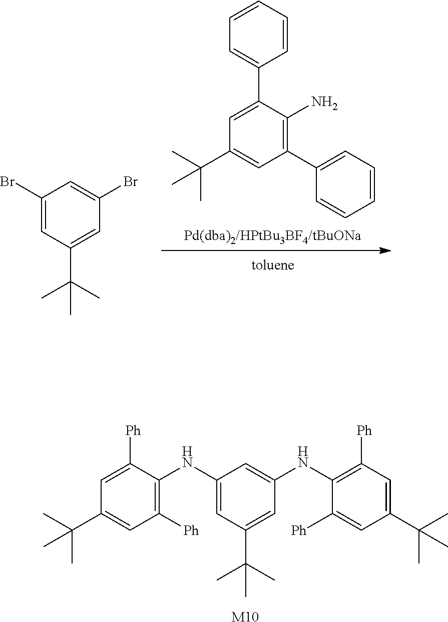

1,3-Dibromo-5-tert-butylbenzene (30 g), 5′-(tert-butyl)-[1, 1:3′,1″-terphenyl]-2′-amine (65 g), Pd(dba)₂ (5.0 g), HPtBu₃BF₄ (5.0 g), and NaOtBu (24 g) were added to a 1 L three-necked flask, 500 mL of toluene was added thereto, the resulting mixture was stirred in an Ar atmosphere at about 80° C. for about 5 hours, and then solids were filtered out with silica gel pad to obtain a reaction solution. The obtained reaction solution was concentrated with an evaporator and washed by suspension by adding EtOH to obtain a white solid (60 g). In FAB-MS measurement of the obtained solid, it was confirmed that m/z=733, thereby identifying M10, a target product.

### (Synthesis of Intermediate M11) PUP-102,C3

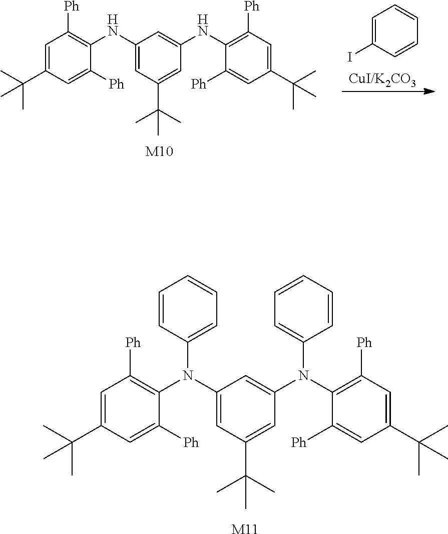

Intermediate M10 (60 g), iodobenzene (234 g), Cul (16 g), and K₂CO₃ (45 g) were added to a 500 mL three-necked flask, and stirred in an Ar atmosphere at about 180° C. for about 48 hours, and then solids were filtered out with silica gel pad to obtain a reaction solution. The obtained reaction solution was heated in a reduced-pressure atmosphere to distill off iodobenzene, and purified with column chromatography (eluent CH₂Cl₂/Hexane=¼), then concentrated, and washed by suspension by adding EtOH to obtain a white solid (25 g). In FAB-MS measurement of the obtained solid, it was confirmed that m/z=885, thereby identifying M11, a target product.

### Synthesis of Intermediate M12

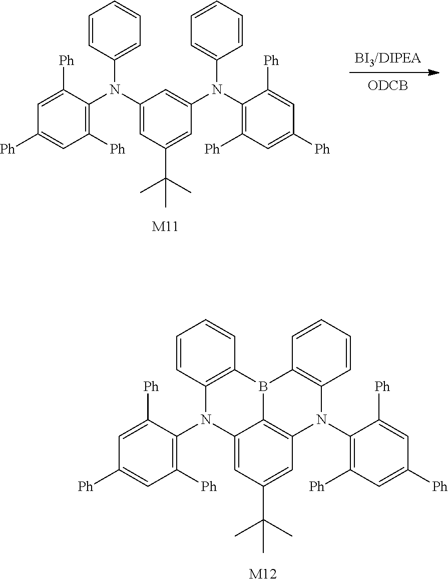

Intermediate M11 (35 g), B13 (60 g), and o-dichlorobenzene (380 mL) were added to a 1 L three-necked flask, stirred in an Ar atmosphere at about 180° C. for about 48 hours, and cooled at room temperature, and 79 mL of diisopropylethylamine was added thereto under ice cooling. Water was added to the obtained reaction solution, and an organic layer was extracted with CH₂Cl₂, and dried over MgSO₄. Solids in the organic layer were filtered out and then CH₂Cl₂ in the organic layer was removed with an evaporator, then heated in a reduced-pressure atmosphere to distill off o-dichlorobenzene, and purified with column chromatography (eluent CH₂Cl₂/Hexane=¼), then concentrated, and washed by suspension by adding EtOH to obtain a yellow solid (2.7 g). In FAB-MS measurement of the obtained solid, it was confirmed that m/z=893, thereby identifying M12, a target product.

### Synthesis of Intermediate M13

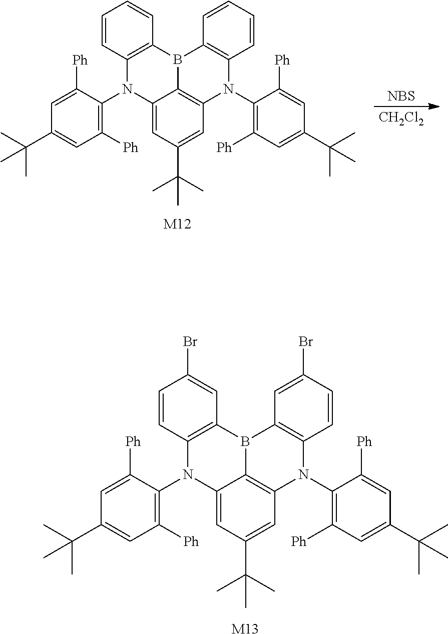

Intermediate M12 (2.7 g), N-bromosuccinimide (1.4 g), and CH₂Cl₂ (150 mL) were added to a 300 mL two-necked flask, and stirred at room temperature for about 8 hours, and water was added thereto. An organic layer was extracted with CH₂Cl₂, and dried over MgSO₄, and then solids were filtered out. The obtained organic layer was concentrated with an evaporator, and recrystallization was performed utilizing toluene and EtOH to obtain a yellow solid (3.0 g). In FAB-MS measurement of the obtained solid, it was confirmed that m/z=1051, thereby identifying M13, a target product.

### Synthesis of Compound 61

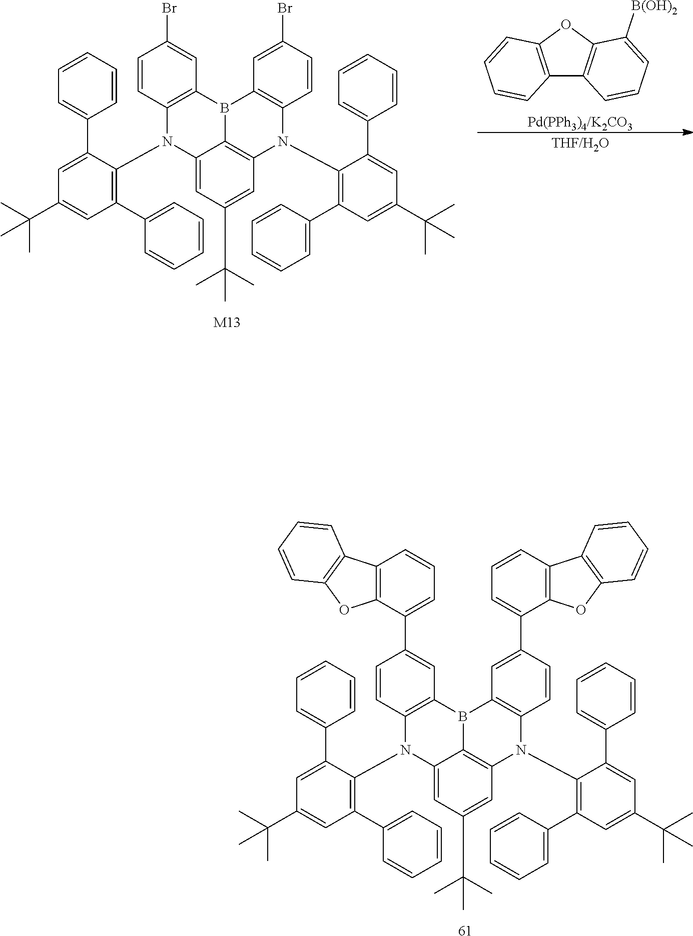

Intermediate M13 (1.5 g), 4-dibenzofuranboronic acid (0.73 g), Pd(PPh₃)₄ (0.40 g), K₂CO₃ (0.79 g), THF (36 mL), and water (18 mL) were added to a 100 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (1.5 g). In FAB-MS measurement of the obtained solid, it was confirmed that m/z=1225, thereby identifying Compound 61, a target product. The obtained Compound 61 was further purified by sublimation and utilized in the evaluation of luminescent properties and device.

### (5) Synthesis of Compound 88

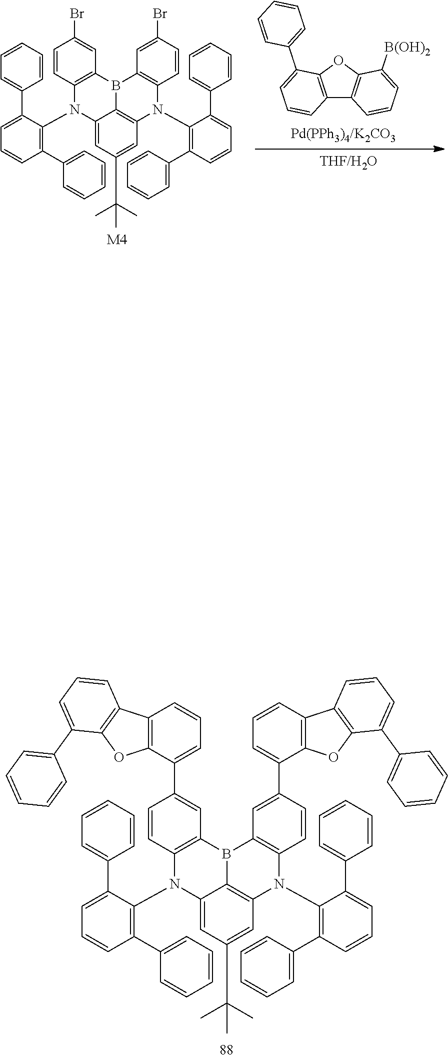

Intermediate M4 (0.2 g), 4-phenyl-6-dibenzofuranboronic acid (0.15 g), Pd(PPh₃)₄ (0.60 g), K₂CO₃ (0.12 g), THF (5 mL), and water (3 mL) were added to a 30 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (0.24 g). In FAB-MS measurement of the obtained solid, it was confirmed that m/z=1265, thereby identifying Compound 88, a target product. The obtained Compound 88 was further purified by sublimation and utilized in the evaluation of luminescent properties and device.

### (6) Synthesis of Compound 89

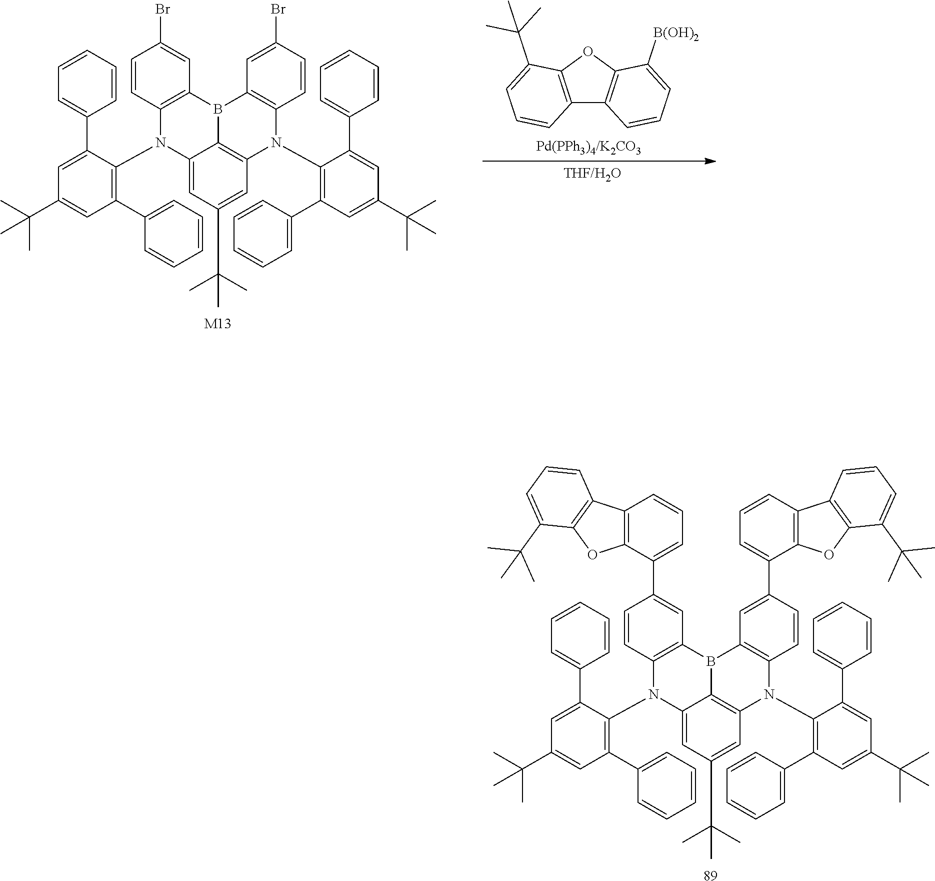

Intermediate M13 (1.5 g), 4-tert-butyl-6-dibenzofuranboronic acid (0.92 g), Pd(PPh₃)₄ (0.40 g), K₂CO₃ (0.79 g), THF (36 mL), and water (18 mL) were added to a 100 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (1.6 g). In FAB-MS measurement of the obtained solid, it was confirmed that m/z=1338, thereby identifying Compound 89, a target product. The obtained Compound 89 was further purified by sublimation and utilized in the evaluation of luminescent properties and device.

### (7) Synthesis of Compound 91

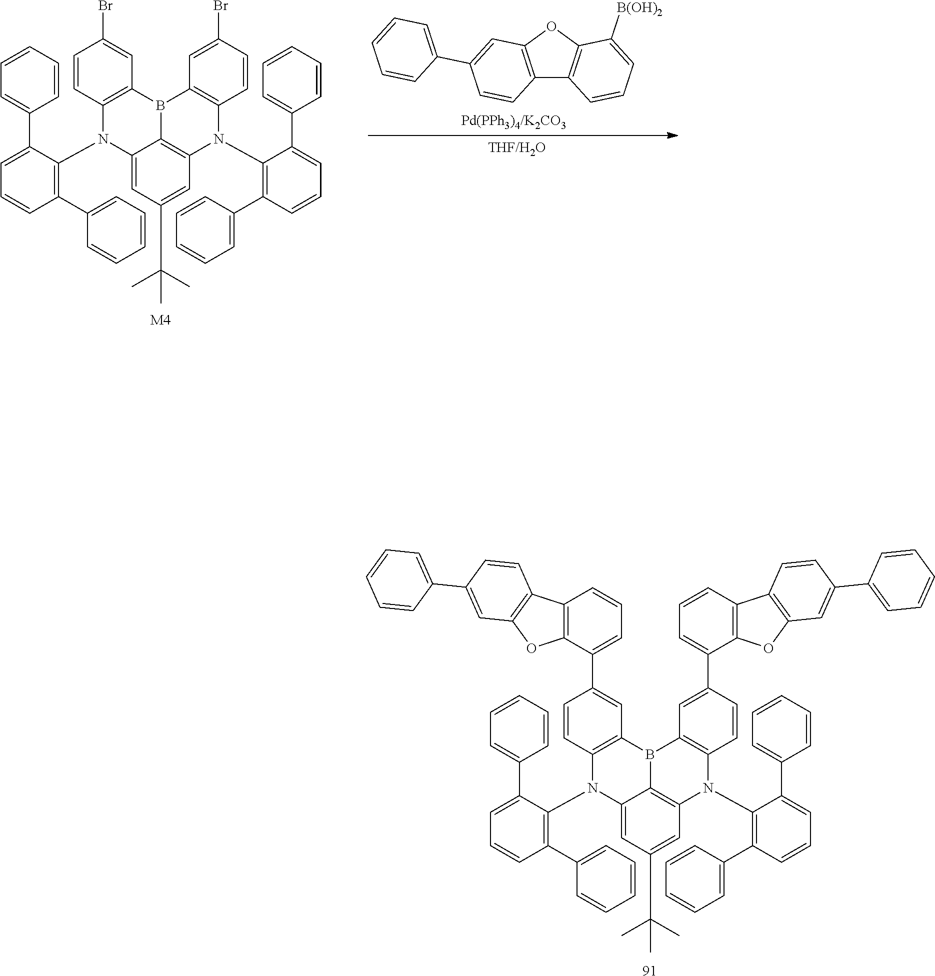

Intermediate M4 (0.2 g), 3-phenyl-6-dibenzofuranboronic acid (0.15 g), Pd(PPh₃)₄ (0.60 g), K₂CO₃ (0.12 g), THF (5 mL), and water (3 mL) were added to a 30 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (0.23 g). In FAB-MS measurement of the obtained solid, it was confirmed that m/z=1265, thereby identifying Compound 91, a target product. The obtained Compound 91 was further purified by sublimation and utilized in the evaluation of luminescent properties and device.

### (8) Synthesis of Compound 96

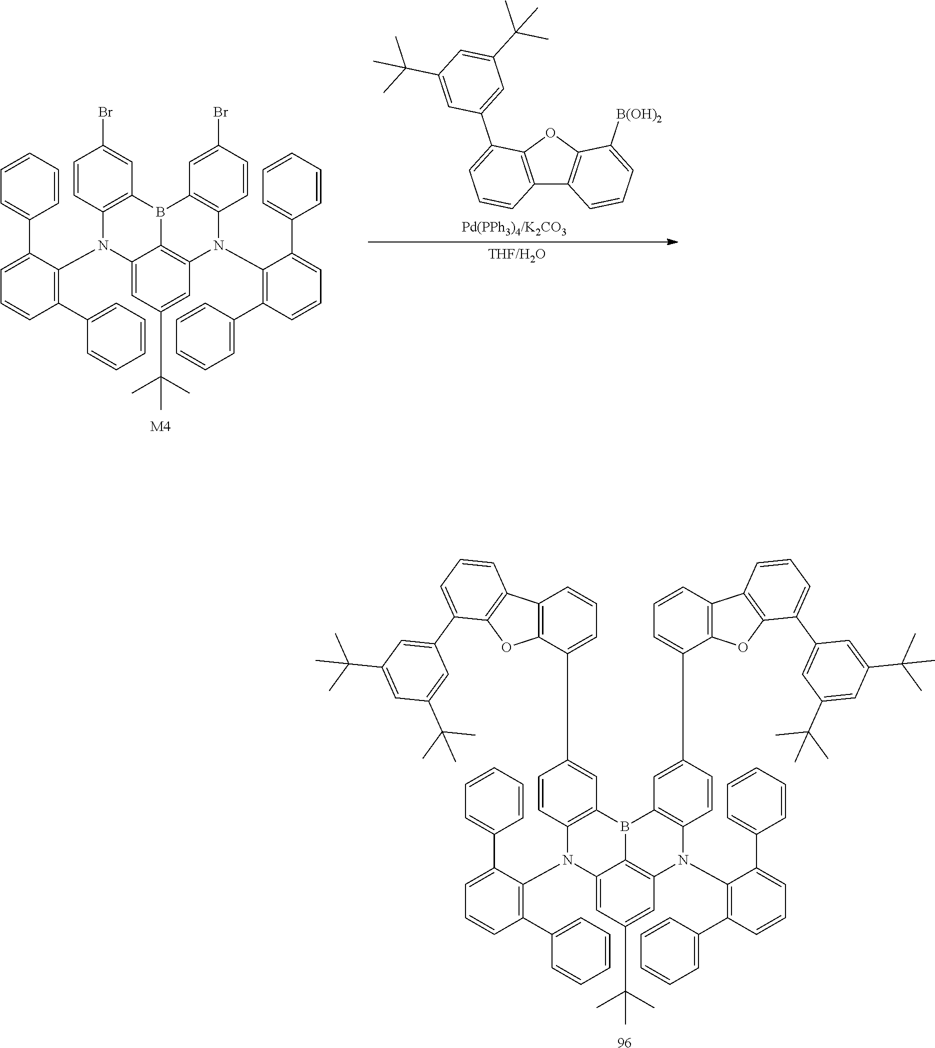

Intermediate M4 (0.2 g), (6-(3,5-di-tert-butylphenyl)dibenzo[b,d]furan-4-yl)boronic acid (0.20 g), Pd(PPh₃)₄ (0.60 g), K₂CO₃ (0.12 g), THF (5 mL), and water (3 mL) were added to a 30 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (0.29 g). In FAB-MS measurement of the obtained solid, it was confirmed that m/z=1490, thereby identifying Compound 96, a target product. The obtained Compound 96 was further purified by sublimation and utilized in the evaluation of luminescent properties and device.

### (9) Synthesis of Compound 125

### Synthesis of Intermediate M14

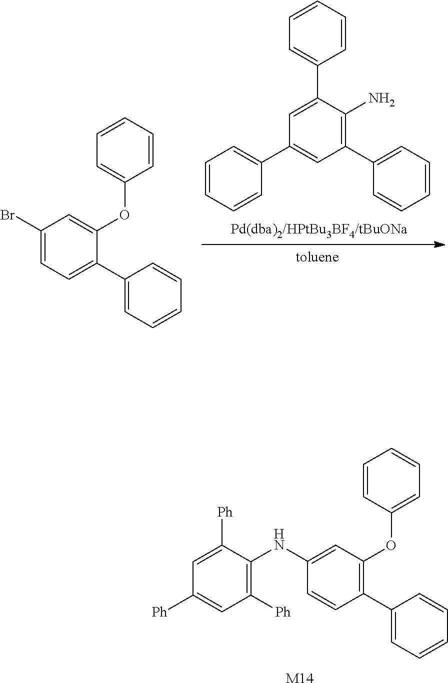 [SMILES: Brc1ccc(-c2ccccc2)c(Oc2ccccc2)c1 ; Nc1c(-c2ccccc2)cc(-c2ccccc2)cc1-c1ccccc1 ; c1ccc(Oc2cc(Nc3c(-c4ccccc4)cc(-c4ccccc4)cc3-c3ccccc3)ccc2-c2ccccc2)cc1 ; "M14"]

4-bromo-2-phenoxy-1,1′-biphenyl (30 g), 5′-phenyl-[1, 1:3′,1″-terphenyl]-2′-amine (31 g), Pd(dba)₂ (2.2 g), HPtBu₃BF₄ (2.2 g), and NaOtBu (11 g) were added to a 1 L three-necked flask, 500 mL of toluene was added thereto, the resulting mixture was stirred in an Ar atmosphere at about 80° C. for about 5 hours, and then solids were filtered out with silica gel pad to obtain a reaction solution. The obtained reaction solution was concentrated with an evaporator and washed by suspension by adding EtOH to obtain a white solid (48 g). In FAB-MS measurement of the obtained solid, it was confirmed that m/z=566, thereby identifying M14, a target product.

### Synthesis of Intermediate M15

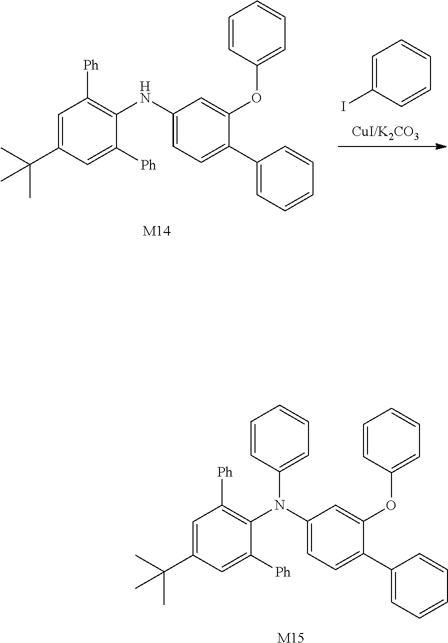 [SMILES: CC(C)(C)c1cc(-c2ccccc2)c(Nc2ccc(-c3ccccc3)c(Oc3ccccc3)c2)c(-c2ccccc2)c1 ; Ic1ccccc1 ; "M14" ; CC(C)(C)c1cc(-c2ccccc2)c(N(c2ccccc2)c2ccc(-c3ccccc3)c(Oc3ccccc3)c2)c(-c2ccccc2)c1 ; "M15"]

Intermediate M14 (48 g), iodobenzene (87 g), Cul (16 g), and K₂CO₃ (23 g) were added to a 300 mL three-necked flask, and stirred in an Ar atmosphere at about 180° C. for about 48 hours, and then solids were filtered out with silica gel pad to obtain a reaction solution. The obtained reaction solution was heated in a reduced-pressure atmosphere to distill off iodobenzene, and purified with column chromatography (eluent CH₂Cl₂/Hexane=⅙), then concentrated, and washed by suspension by adding EtOH to obtain a white solid (37 g). In FAB-MS measurement of the obtained solid, it was confirmed that m/z=642, thereby identifying M15, a target product.

### Synthesis of Intermediate M16

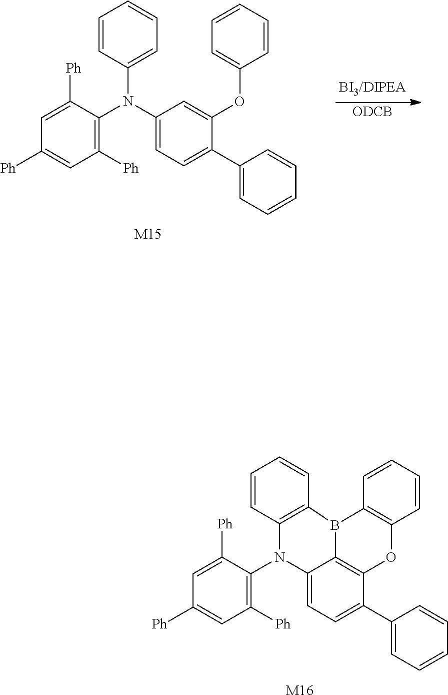 [SMILES: c1ccc(Oc2cc(N(c3ccccc3)c3c(-c4ccccc4)cc(-c4ccccc4)cc3-c3ccccc3)ccc2-c2ccccc2)cc1 ; "ODCB" ; "M15" ; c1ccc(-c2cc(-c3ccccc3)c(N3c4ccccc4B4c5ccccc5Oc5c(-c6ccccc6)ccc3c54)c(-c3ccccc3)c2)cc1 ; "M16"]

Intermediate M15 (37 g), B13 (45 g), and o-dichlorobenzene (560 mL) were added to a 1 L three-necked flask, stirred in an Ar atmosphere at about 180° C. for about 48 hours, and cooled at room temperature, and 60 mL of diisopropylethylamine was added thereto under ice cooling. Water was added to the obtained reaction solution, and an organic layer was extracted with CH₂Cl₂, and dried over MgSO₄. Solids in the organic layer were filtered out and then CH₂Cl₂ in the organic layer was removed with an evaporator, then heated in a reduced-pressure atmosphere to distill off o-dichlorobenzene, and purified with column chromatography (eluent CH₂Cl₂/Hexane=¼), then concentrated, and washed by suspension by adding EtOH to obtain a yellow solid (1.1 g). In FAB-MS measurement of the obtained solid, it was confirmed that m/z=650, thereby identifying M16, a target product.

### Synthesis of Intermediate M17

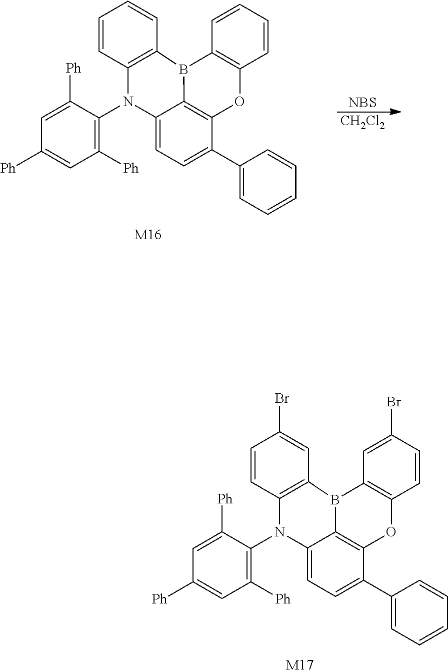 [SMILES: c1ccc(-c2cc(-c3ccccc3)c(N3c4ccccc4B4c5ccccc5Oc5c(-c6ccccc6)ccc3c54)c(-c3ccccc3)c2)cc1 ; "CH2Cl2" ; "NBS" ; "M16" ; Brc1ccc2c(c1)B1c3cc(Br)ccc3N(c3c(-c4ccccc4)cc(-c4ccccc4)cc3-c3ccccc3)c3ccc(-c4ccccc4)c(c31)O2 ; "M17"]

Intermediate M16 (1.1 g), N-bromosuccinimide (0.75 g), and CH₂Cl₂ (85 mL) were added to a 300 mL two-necked flask, and stirred at room temperature for about 8 hours, and water was added thereto. An organic layer was extracted with CH₂Cl₂, and dried over MgSO₄, and then solids were filtered out. The obtained organic layer was concentrated with an evaporator, and recrystallization was performed utilizing toluene and EtOH to obtain a yellow solid (1.3 g). In FAB-MS measurement of the obtained solid, it was confirmed that m/z=807, thereby identifying M17, a target product.

### Synthesis of Compound 125

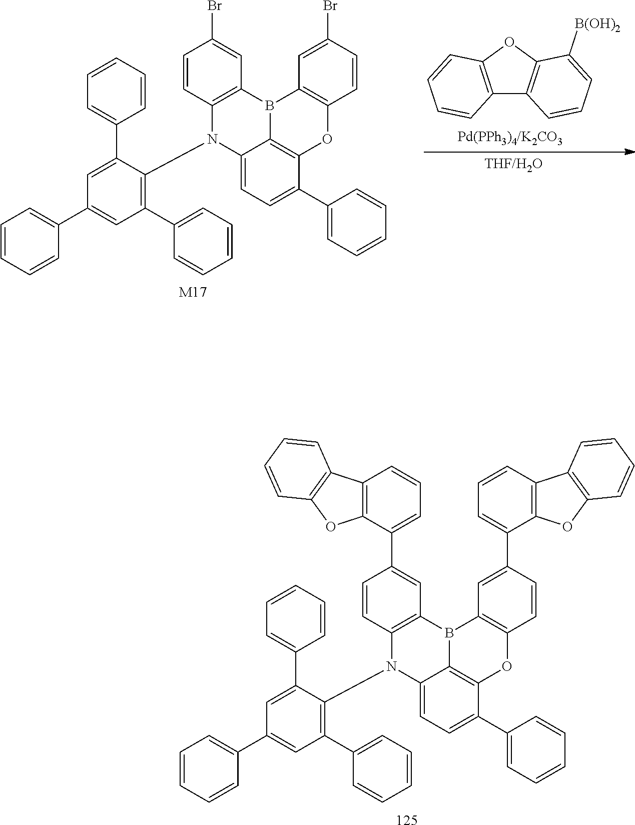

Intermediate M17 (1.3 g), 4-dibenzofuranboron ic acid (0.82 g), Pd(PPh₃)₄ (0.45 g), K₂CO₃ (0.89 g), THF (40 mL), and water (20 mL) were added to a 300 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (1.4 g). In FAB-MS measurement of the obtained solid, it was confirmed that m/z=982, thereby identifying Compound 125, a target product. The obtained Compound 125 was further purified by sublimation and utilized in the evaluation of luminescent properties and device.

### (10) Synthesis of Compound 129

### Synthesis of Intermediate M18

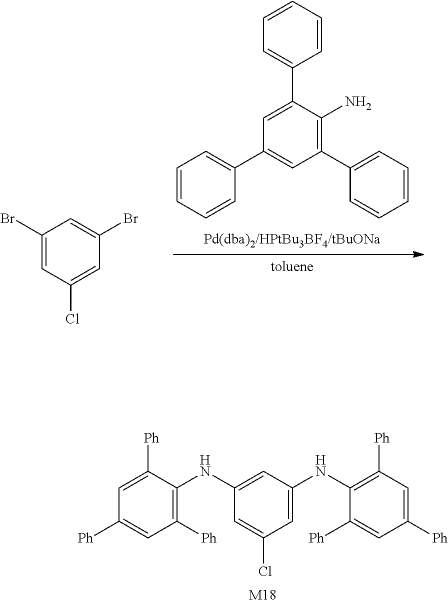

1,3-Dibromo-5-chlorobenzene (30 g), 5′-phenyl-[1,1′:3′,1″-terphenyl]-2′-amine (75 g), Pd(dba)₂ (5.3 g), HPtBu₃BF₄ (5.4 g), and NaOtBu (26 g) were added to a 1 L three-necked flask, 500 mL of toluene was added thereto, the resulting mixture was stirred in an Ar atmosphere at about 80° C. for about 5 hours, and then solids were filtered out with silica gel pad to obtain a reaction solution. The obtained reaction solution was concentrated with an evaporator and washed by suspension by adding EtOH to obtain a white solid (77 g). In FAB-MS measurement of the obtained solid, it was confirmed that m/z=751, thereby identifying M18, a target product.

### Synthesis of Intermediate M19

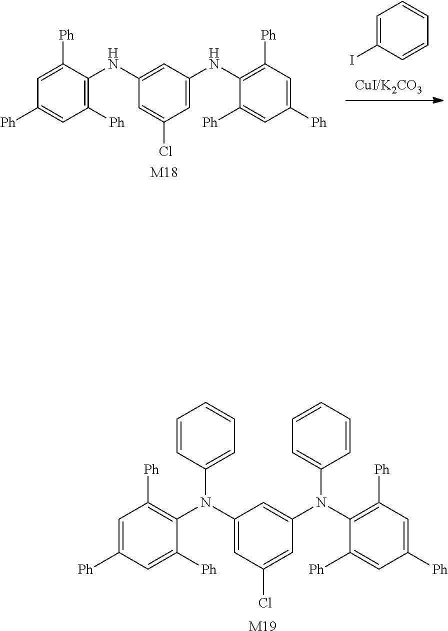

Intermediate M18 (48 g), iodobenzene (293 g), Cul (20 g), and K₂CO₃ (57 g) were added to a 500 mL three-necked flask, and stirred in an Ar atmosphere at about 180° C. for about 48 hours, and then solids were filtered out with silica gel pad to obtain a reaction solution. The obtained reaction solution was heated in a reduced-pressure atmosphere to distill off iodobenzene, and purified with column chromatography (eluent CH₂Cl₂/Hexane=¼), then concentrated, and washed by suspension by adding EtOH to obtain a white solid (23 g). In FAB-MS measurement of the obtained solid, it was confirmed that m/z=904, thereby identifying M19, a target product.

### Synthesis of Intermediate M20

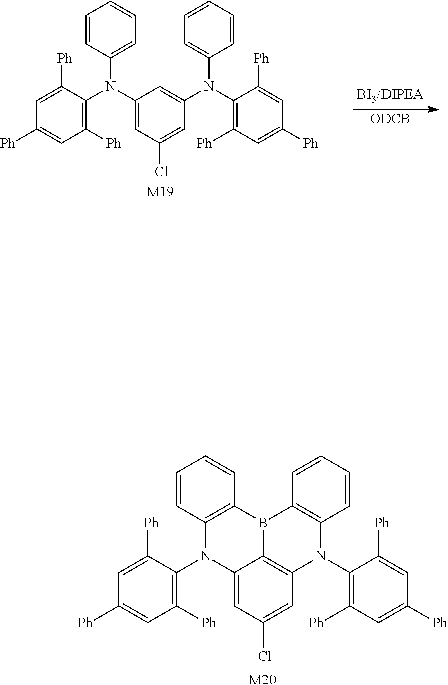

Intermediate M19 (23 g), B13 (40 g), and o-dichlorobenzene (255 mL) were added to a 1 L three-necked flask, stirred in an Ar atmosphere at about 180° C. for about 48 hours, and cooled at room temperature, and 53 mL of diisopropylethylamine was added thereto under ice cooling. Water was added to the obtained reaction solution, and an organic layer was extracted with CH₂Cl₂, and dried over MgSO₄. Solids in the organic layer were filtered out and then CH₂Cl₂ in the organic layer was removed with an evaporator, then heated in a reduced-pressure atmosphere to distill off o-dichlorobenzene, and purified with column chromatography (eluent CH₂Cl₂/Hexane=¼), then concentrated, and washed by suspension by adding EtOH to obtain a yellow solid (2.5 g). In FAB-MS measurement of the obtained solid, it was confirmed that m/z=911, thereby identifying M20, a target product.

### Synthesis of Intermediate M21

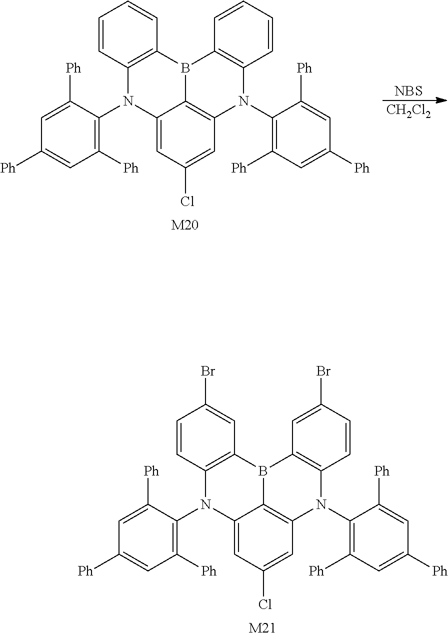

Intermediate M20 (2.5 g), N-bromosuccinimide (1.2 g), and CH₂Cl₂ (140 mL) were added to a 300 mL two-necked flask, and stirred at room temperature for about 8 hours, and water was added thereto. An organic layer was extracted with CH₂Cl₂, and dried over MgSO₄, and then solids were filtered out. The obtained organic layer was concentrated with an evaporator, and recrystallization was performed utilizing toluene and EtOH to obtain a yellow solid (2.6 g). In FAB-MS measurement of the obtained solid, it was confirmed that m/z=1069, thereby identifying M21, a target product.

### Synthesis of Intermediate M22

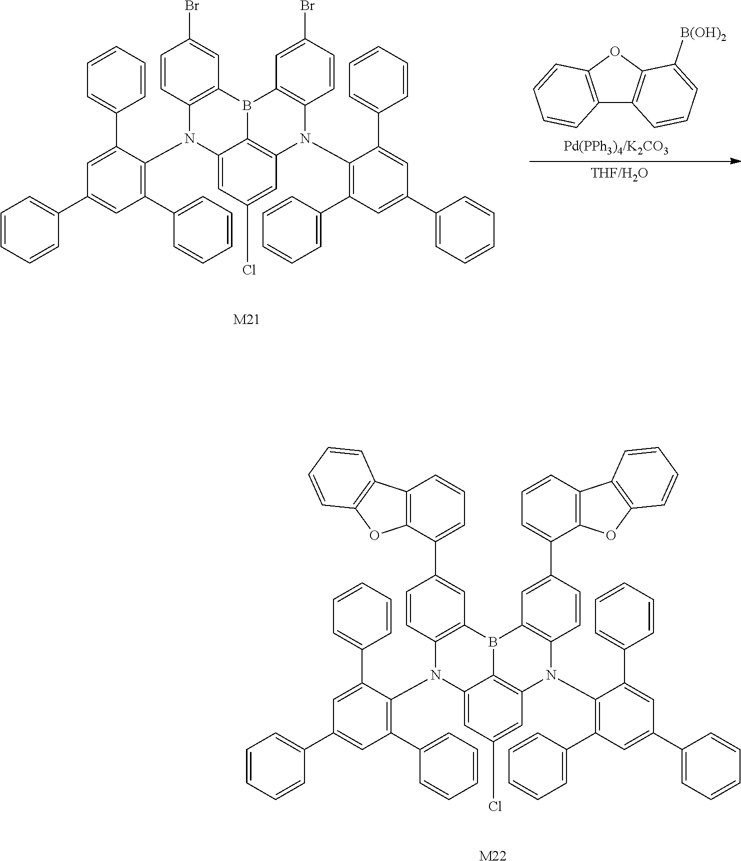 [SMILES: Clc1cc2c3c(c1)N(c1c(-c4ccccc4)cc(-c4ccccc4)cc1-c1ccccc1)c1ccc(Br)cc1B3c1cc(Br)ccc1N2c1c(-c2ccccc2)cc(-c2ccccc2)cc1-c1ccccc1 ; OB(O)c1cccc2c1oc1ccccc12 ; "M21" ; Clc1cc2c3c(c1)N(c1c(-c4ccccc4)cc(-c4ccccc4)cc1-c1ccccc1)c1ccc(-c4cccc5c4oc4ccccc45)cc1B3c1cc(-c3cccc4c3oc3ccccc34)ccc1N2c1c(-c2ccccc2)cc(-c2ccccc2)cc1-c1ccccc1 ; "M22"]

Intermediate M21 (2.6 g), 4-dibenzofuranboronic acid (1.2 g), Pd(PPh₃)₄ (0.67 g), K₂CO₃ (1.3 g), THF (60 mL), and water (30 mL) were added to a 300 mL three-necked flask, and reacted under reflux for about 12 hours. The reaction solution was extracted by adding toluene, dried over MgSO₄, and then solids were filtered out. The obtained organic layer was concentrated with an evaporator, and recrystallization was performed utilizing toluene and EtOH to obtain a yellow solid (2.9 g). In FAB-MS measurement of the obtained solid, it was confirmed that m/z=1244, thereby identifying Intermediate M22, a target product.

### Synthesis of Compound 129

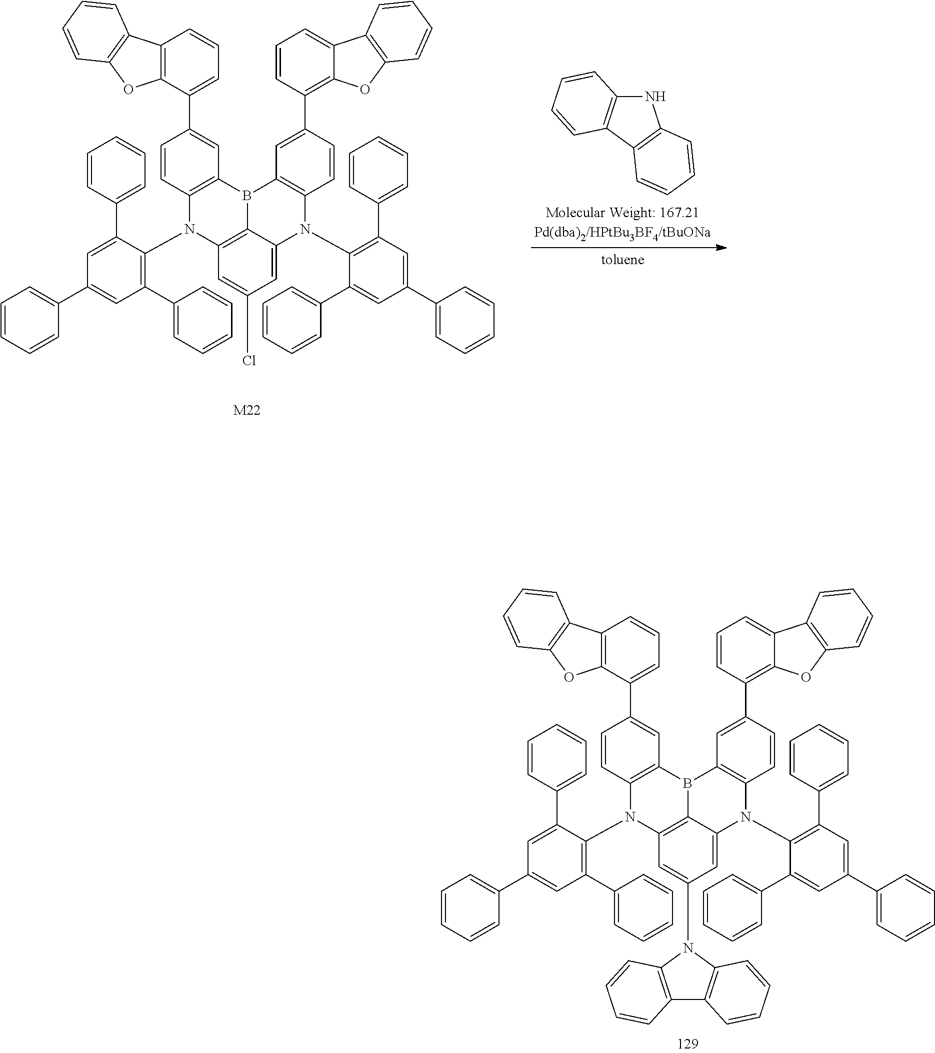 [SMILES: Clc1cc2c3c(c1)N(c1c(-c4ccccc4)cc(-c4ccccc4)cc1-c1ccccc1)c1ccc(-c4cccc5c4oc4ccccc45)cc1B3c1cc(-c3cccc4c3oc3ccccc34)ccc1N2c1c(-c2ccccc2)cc(-c2ccccc2)cc1-c1ccccc1 ; c1ccc2c(c1)[nH]c1ccccc12 ; "M22" ; c1ccc(-c2cc(-c3ccccc3)c(N3c4ccc(-c5cccc6c5oc5ccccc56)cc4B4c5cc(-c6cccc7c6oc6ccccc67)ccc5N(c5c(-c6ccccc6)cc(-c6ccccc6)cc5-c5ccccc5)c5cc(-n6c7ccccc7c7ccccc76)cc3c54)c(-c3ccccc3)c2)cc1]

Intermediate M22 (2.9 g), carbazole (0.6 g), Pd(dba)₂ (0.08 g), HPtBu₃BF₄ (0.08 g), and NaOtBu (0.27 g) were added to a 100 mL three-necked flask, 50 mL of toluene was added thereto, the resulting mixture was heated under reflux in an Ar atmosphere for about 5 hours, and then solids were filtered out with silica gel pad to obtain a reaction solution. The obtained reaction solution was concentrated with an evaporator and washed by suspension by adding EtOH to obtain a yellow solid (2.4 g). In FAB-MS measurement of the obtained solid, it was confirmed that m/z=1374, thereby identifying Compound 129, a target product. The obtained Compound 129 was further purified by sublimation and utilized in the evaluation of luminescent properties and device.

### 1. Manufacture and Evaluation of Light Emitting Devices

### (1) Manufacture of Light Emitting Devices

The light emitting devices of the examples each including the fused polycyclic compound of an example in an emission layer was manufactured as follows. Fused polycyclic compounds of Compounds 51, 55, 57, 61, 88, 89, 91, 96, 125, and 129, which are Example Compounds as described above, were utilized as dopant materials for the emission layers to manufacture the light emitting devices of Examples 1 to 10, respectively. Comparative Examples 1 to 6 correspond to the light emitting devices manufactured by utilizing Comparative Example Compounds X1 to X6 as emission layer dopant materials, respectively.

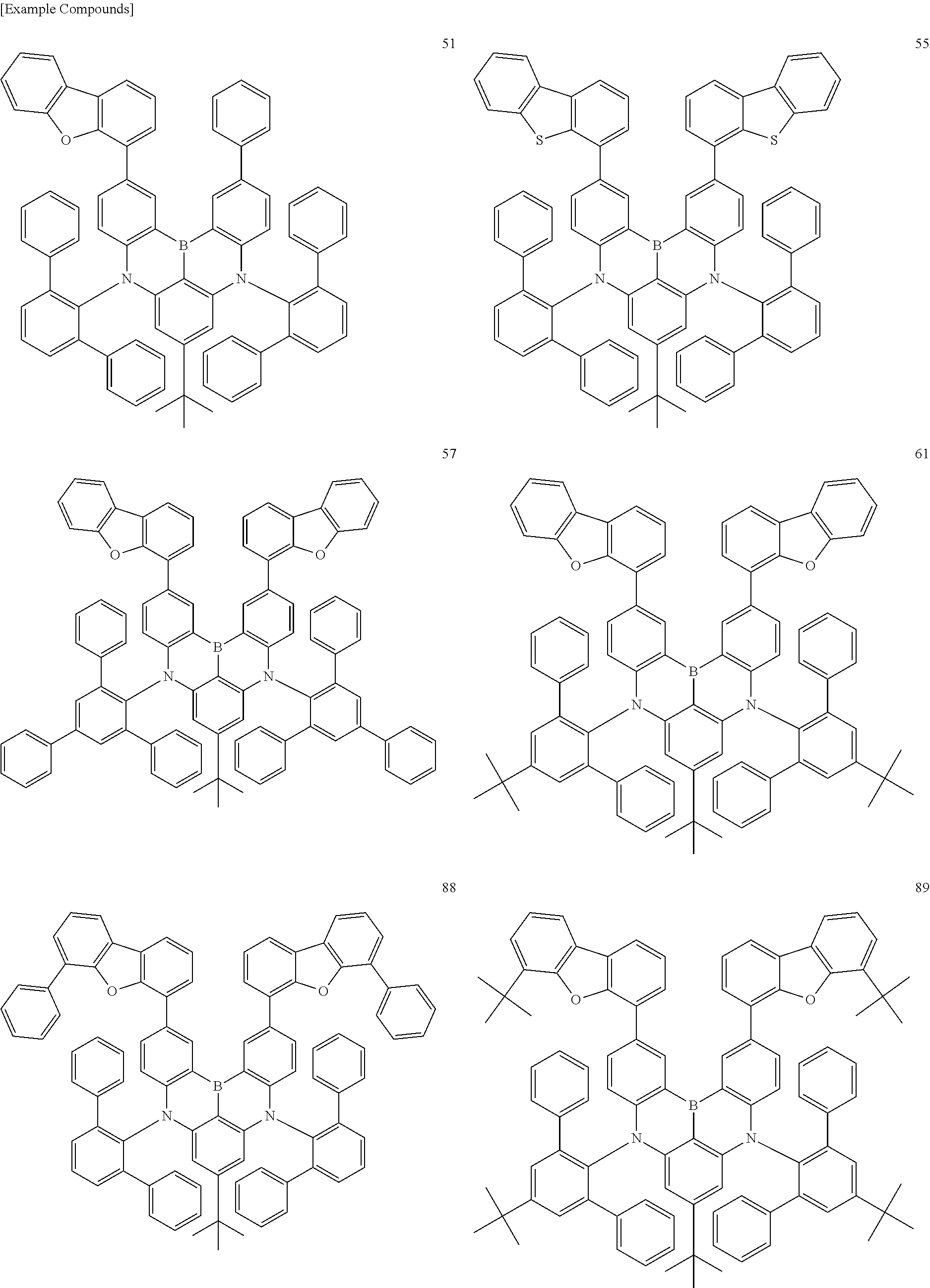

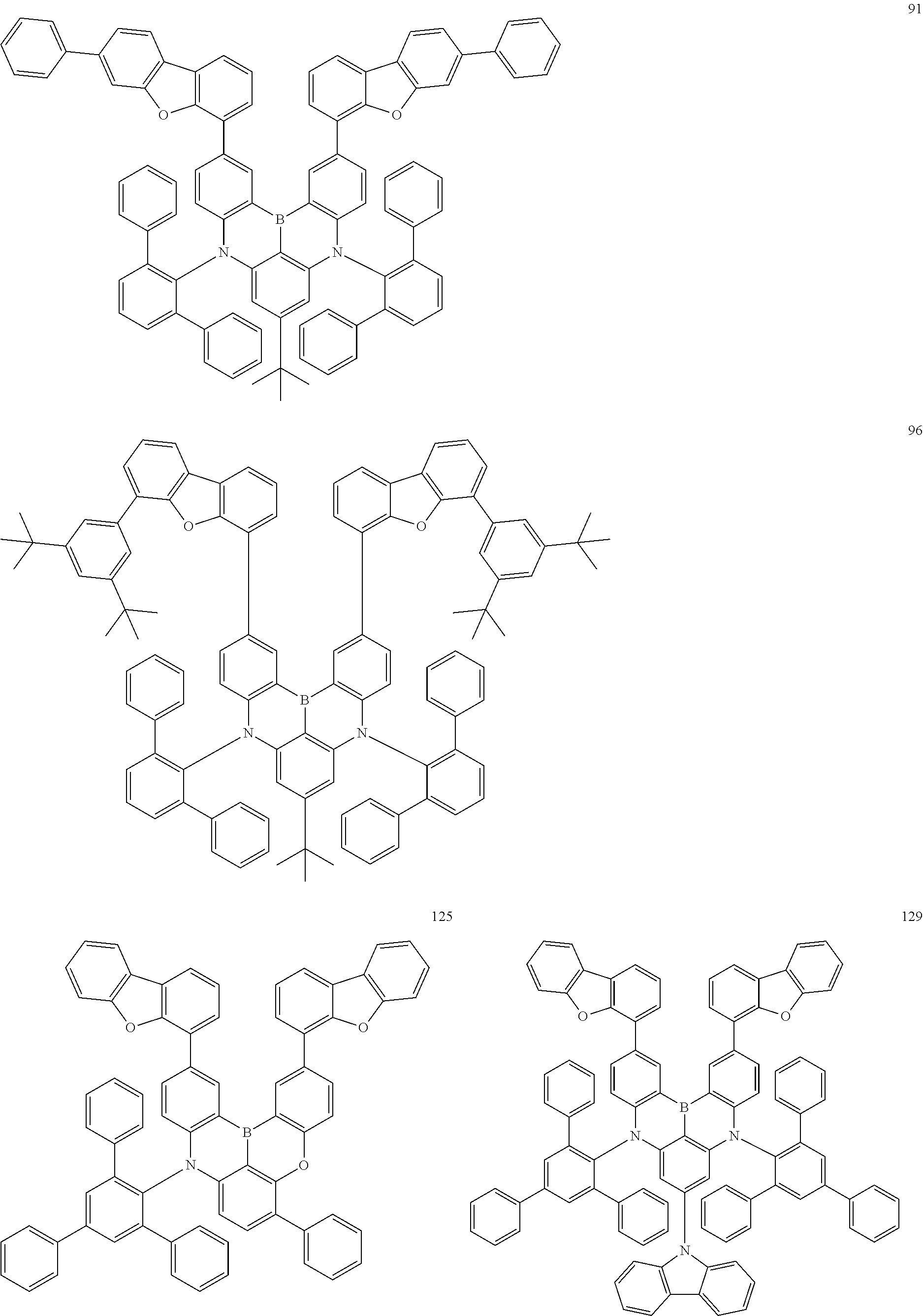

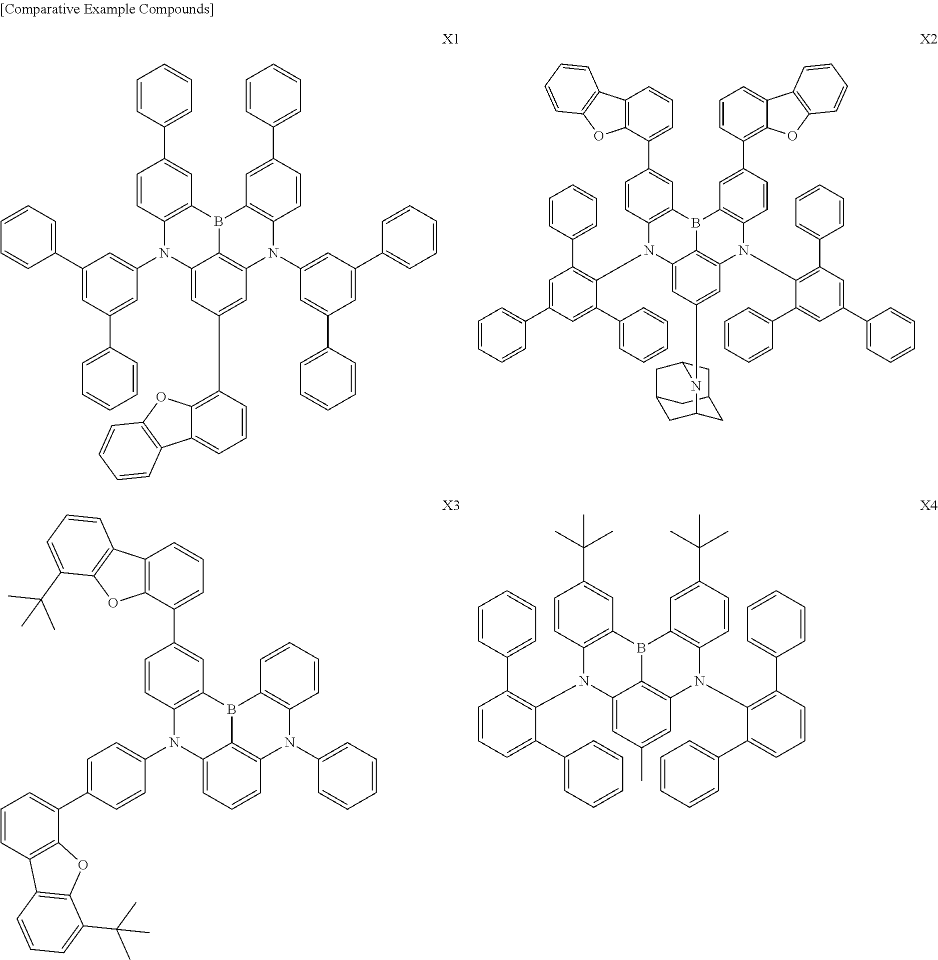

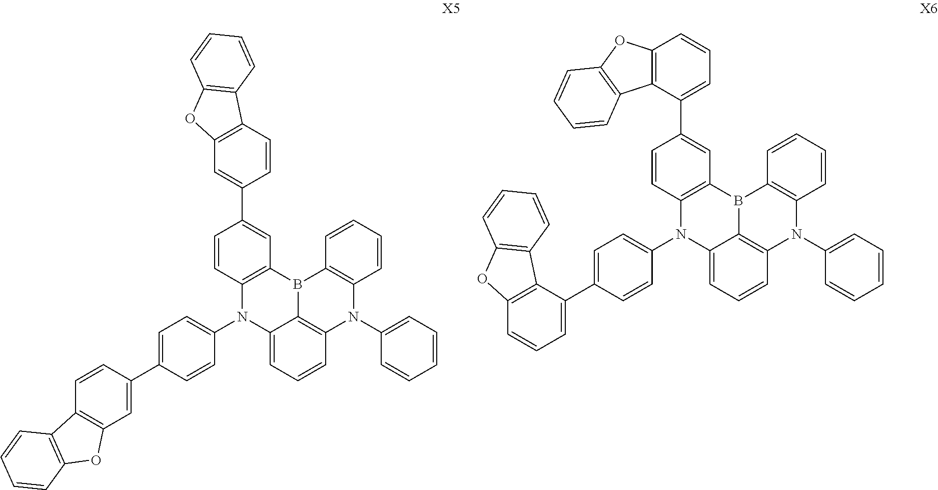 [SMILES: c1ccc(N2c3ccccc3B3c4cc(-c5ccc6c(c5)oc5ccccc56)ccc4N(c4ccc(-c5ccc6c(c5)oc5ccccc56)cc4)c4cccc2c43)cc1 ; c1ccc(N2c3ccccc3B3c4cc(-c5cccc6oc7ccccc7c56)ccc4N(c4ccc(-c5cccc6oc7ccccc7c56)cc4)c4cccc2c43)cc1]

### (Manufacture of Light Emitting Devices)

ITO was utilized to form a 150 nm-thick first electrode, dipyrazino[2,3-f: 2′,3′-h]quinoxaline-2,3,6,7,10,11-hexacarbonitrile (HATCN) was utilized to form a 10 nm-thick hole injection layer on the first electrode, 4,4′-cyclohexylidene bis[N,N-bis(4-methyl phenyl)benzenamine] (TAPC) was utilized to form a 20 nm-thick hole transport layer on the hole injection layer, 1,3-bis(N-carbazolyl)benzene (mCP) was utilized to form a 5 nm-thick emission auxiliary layer on the hole transport layer, 3,3′-di(9H-carbazol-9-yl)-1,1′-biphenyl (mCBP) was doped by 20% with auxiliary dopant DA-10 and doped by 0.5% with a dopant of Example Compound or Comparative Example Compound to form a 30 nm-thick emission layer on the emission auxiliary layer, 2-(9,9′-spirobi[fluoren]-3-yl)-4,6-diphenyl-1,3,5-triazine (SF3-TRZ) was utilized to form a 10 nm-thick electron blocking layer on the emission layer, 2-(9,9′-spirobi[fluoren]-3-yl)-4,6-diphenyl-1,3,5-triazine (SF3-TRZ) and 8-hydroxyl-lithium quinolate (Liq) at a weight ratio of 50:50 were utilized to from a 25 nm-thick electron transport layer on the hole blocking layer, 8-hydroxyl-lithium quinolate (Liq) was utilized to form a 2 nm-thick electron injection layer on the electron transport layer, and Al was utilized to form a 100 nm-thick second electrode on the electron injection layer. Each layer was formed by a deposition method in a vacuum atmosphere.

Compounds utilized for manufacturing the light emitting devices of Examples and Comparative Examples are disclosed below. The compounds below are suitable materials, and commercial products were subjected to sublimation purification and utilized to manufacture the devices.

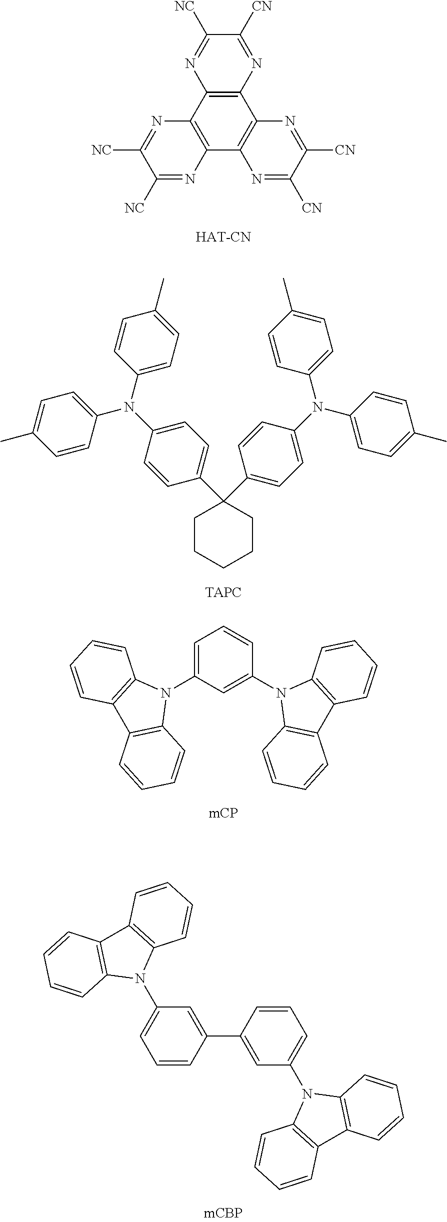

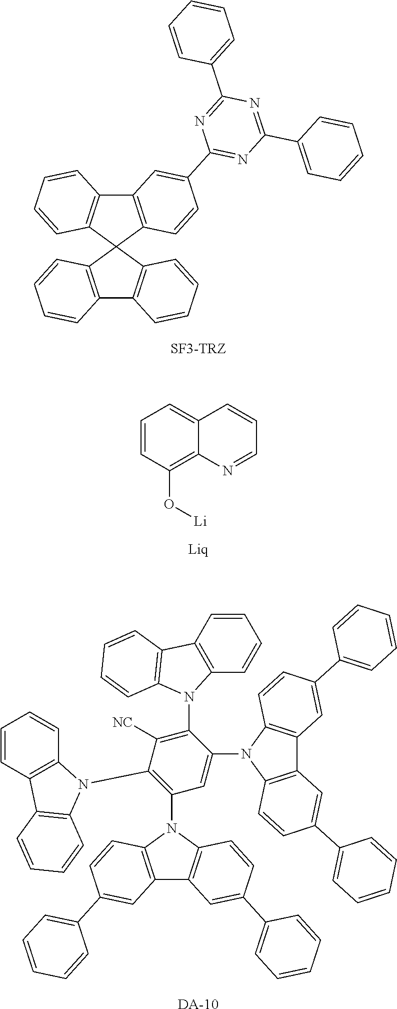

### (2) Evaluation of Compound and Light Emitting Device Characteristics

### (Evaluation of Compound Characteristics)

With respect to Example Compounds 57, 61, 88, 89, 91, and 96 and Comparative Example Compounds X1 to X6 as described above, emission spectra were measured in an inert gas atmosphere by adjusting a toluene solution utilizing U-3900-type or kind spectrophotometer made by Hitachi High-Tech, Co., and F-7000 fluorescence spectrophotometer made by Hitachi High-Tech, Co. The maximum absorption wavelength (Aabs), the maximum (e.g., peak) emission wavelength (Amax), and a full width of half maximum (FWHM) of the emission spectra were measured, and the results are shown in Table 1.

TABLE 1

| | Maximum | Maximum | Full width |
|---|---|---|---|
| | absorption | emission | of half |
| | wavelength | wavelength | maximum |
| Compound | (λabs, nm) | (λmax, nm) | (nm) |
| Compound 51 | 451 | 464 | 20 |
| Compound 55 | 452 | 464 | 21 |
| Compound 57 | 451 | 463 | 20 |
| Compound 61 | 451 | 463 | 20 |
| Compound 88 | 450 | 462 | 20 |
| Compound 89 | 449 | 461 | 19 |
| Compound 91 | 450 | 462 | 20 |
| Compound 96 | 449 | 461 | 19 |
| Compound 125 | 448 | 460 | 22 |
| Compound 129 | 448 | 459 | 19 |
| Comparative Example | 454 | 469 | 27 |
| Compound X1 | | | |
| Comparative Example | 439 | 456 | 24 |
| Compound X2 | | | |
| Comparative Example | 454 | 468 | 23 |
| Compound X3 | | | |
| Comparative Example | 442 | 456 | 26 |
| Compound X4 | | | |
| Comparative Example | 455 | 469 | 25 |
| Compound X5 | | | |
| Comparative Example | 453 | 467 | 24 |
| Compound X6 | | | |

### (Evaluation of Light Emitting Device Characteristics)

The maximum emission wavelengths and service lives of the light emitting devices manufactured with Example Compounds 51, 55, 57, 61, 88, 89, 91, 96, 125, and 129 and Comparative Example Compounds X1 to X6 as described above were evaluated. Evaluation results of the light emitting devices of Examples 1 to 10 and Comparative Examples 1 to 6 are listed in Table 2. In the evaluation of the device, the time taken to reduce the brightness to about 50% of an initial brightness of 1,000 cd/m² was measured and the numerical value of the obtained time was compared to Comparative Example 1, and the evaluation was carried out utilizing the value for Comparative Example 1 as 100%. The results are shown in Table 2.

TABLE 2

| | | Maximum | Relative |
|---|---|---|---|
| Examples of | | emission | device |
| manufacturing | | wavelength | service |
| devices | Dopant | (λmax, nm) | life (%) |
| Example 1 | Compound 51 | 465 | 120 |
| Example 2 | Compound 55 | 465 | 128 |
| Example 3 | Compound 57 | 464 | 124 |
| Example 4 | Compound 61 | 464 | 126 |
| Example 5 | Compound 88 | 463 | 135 |
| Example 6 | Compound 89 | 462 | 137 |
| Example 7 | Compound 91 | 463 | 139 |
| Example 8 | Compound 96 | 462 | 138 |
| Example 9 | Compound 125 | 461 | 105 |
| Example 10 | Compound 129 | 460 | 132 |
| Comparative | Comparative | 476 | 100 |
| Example 1 | Example | | |
| | Compound X1 | | |
| Comparative | Comparative | 472 | 90 |
| Example 2 | Example | | |
| | Compound X2 | | |
| Comparative | Comparative | 471 | 78 |
| Example 3 | Example | | |
| | Compound X3 | | |
| Comparative | Comparative | 472 | 150 |
| Example 4 | Example | | |
| | Compound X4 | | |
| Comparative | Comparative | 468 | 65 |
| Example 5 | Example | | |
| | Compound X5 | | |
| Comparative | Comparative | 466 | 54 |
| Example 6 | Example | | |
| | Compound X6 | | |

Referring to the results of Table 2, it may be confirmed that Examples of the light emitting devices, in which the fused polycyclic compounds according to examples of the present disclosure are utilized as a luminescent material, have improved service life characteristics and improved blue-shifted luminescence wavelength characteristics as compared with Comparative Examples. Example Compounds include the fused ring core in which the first to third aromatic rings are fused about the boron atom and the first and second heteroatoms, the first substituent is bonded to the fused ring core and the second substituent is bonded to the nitrogen atom of the fused ring core, and thus Forster energy transfer is increased in the auxiliary dopant and the multiple resonance effects are increased, thereby increasing delayed fluorescence characteristics to improve the luminous efficiency. In addition, Example Compounds have a structure in which the first substituent and the second substituent are introduced into the fused ring core, and thus the deterioration of service life due to the intermolecular interaction is reduced, thereby achieving long service life.

The light emitting device of an example includes the fused polycyclic compound of an example as a light emitting dopant of a thermally activated delayed fluorescence (TADF) light emitting device, and thus may achieve an increase in luminous efficiency in a short wavelength region, and long service life.

Referring to Comparative Examples 1, 3, 5, and 6, it may be confirmed that Comparative Example Compounds X1, X3, X5 and X6 each include a planar skeleton structure having one boron atom, and two nitrogen atoms at the center thereof, but do not include, in the planar skeleton structure, the first substituent and the second substituent proposed by the present disclosure, and thus when Comparative Example Compounds are applied to the devices, the devices have red-shifted luminescence wavelengths, and deteriorated device service lives as compared to Examples. Without being bound by any specific theory, it is thought that Comparative Example Compounds X1, X3, X5 and X6 have high planarity in the molecular structure and thus the stability of the compound is increased and at the same time the absorption wavelength and luminescence wavelength are red-shifted. Also, it is thought that Comparative Example Compounds X1, X3, X5 and X6 do not include the first substituent and the second substituent as a steric hindrance substituent and thus the deterioration is generated due to electron exchange reaction with other materials in the light emitting device, thereby deteriorating the service life.

Referring to Comparative Examples 2 and 4, it may be confirmed that Comparative Example Compounds X2 and X4 include a planar skeleton structure having one boron atom and two nitrogen atoms at the center thereof, but do not include, in the planar skeleton structure, the first substituent proposed by the present disclosure, and thus when Comparative Example Compounds X2 and X4 are applied to the devices, the devices have red-shifted luminescence wavelengths, and deteriorated device service lives as compared to Examples. Without being bound by any specific theory, itis thought that Comparative Example Compounds X2 and X4 do not increase Forster energy transfer in the auxiliary dopant, and thus the luminescence wavelength is red-shifted and the device service life deteriorates.

The light emitting device of an embodiment may exhibit improved device characteristics with high efficiency and a long service life.

The fused polycyclic compound of an embodiment may be included in the emission layer of the light emitting device to contribute to high efficiency and a long service life of the light emitting device.

The use of “may” when describing embodiments of the present disclosure refers to “one or more embodiments of the present disclosure”. As used herein, the term “and/or” includes any and all combinations of one or more of the associated listed items. Throughout the disclosure, the expression, such as “at least one of a, b or c”, “at least one selected from a, b, and c”, “at least one selected from the group consisting of a, b, and c”, “at least one from among a, b, and c”, etc., indicates only a, only b, only c, both (e.g., simultaneously) a and b, both (e.g., simultaneously) a and c, both (e.g., simultaneously) b and c, all of a, b, and c, or variation(s) thereof.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus, the display device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to embodiments of the present disclosure, it will be understood that the present disclosure should not be limited to these embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting device comprising:
a first electrode;
a second electrode on the first electrode; and
at least one functional layer between the first electrode and the second electrode and comprises a fused polycyclic compound represented by Formula 1: 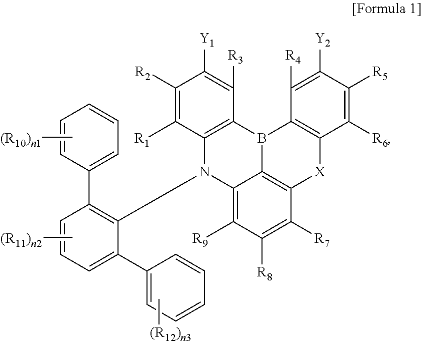
wherein, in Formula 1,
X is O, S, or NR₁₃,
R₁ to R₉ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted linear or branched alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₀ to R₁₃ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
Y₁ and Y₂ are each independently a hydrogen atom, a deuterium atom, a halogen atom, a cyano group, a hydroxy group, a substituted or unsubstituted oxy group, a substituted or unsubstituted thio group, a substituted or unsubstituted aryl group having 6 to 30 ring-forming carbon atoms, or a substituted or unsubstituted heteroaryl group having 2 to 30 ring-forming carbon atoms,
n1 and n3 are each independently an integer of 0 to 5,
n2 is an integer of 0 to 3, and
at least one of Y₁ or Y₂ is represented by Formula 2: 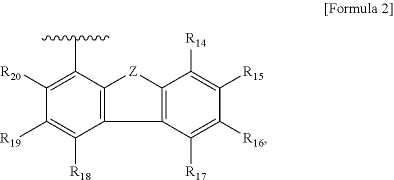
wherein, in Formula 2,
Z is O or S,
R₁₄ to R₂₀ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and 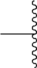
is a position linked to Formula 1.

2. The light emitting device of claim 1, wherein the at least one functional layer comprises an emission layer, a hole transport region between the first electrode and the emission layer, and an electron transport region between the emission layer and the second electrode, and
the emission layer comprises the fused polycyclic compound.

3. The light emitting device of claim 2, wherein the emission layer is to emit delayed fluorescence.

4. The light emitting device of claim 2, wherein the emission layer is to emit light having a luminescence center wavelength of about 430 nm to about 490 nm.

5. The light emitting device of claim 1, wherein, in Formula 1,
Y₁ is a substituent represented by Formula 2, and
Y₂ is a hydrogen atom, a substituted or unsubstituted aryl group having 6 to 30 ring-forming carbon atoms, a substituted or unsubstituted heteroaryl group having 2 to 30 ring-forming carbon atoms, or a substituent represented by Formula 2.

6. The light emitting device of claim 1, wherein, in Formula 1,
R₁ to R₉ are each independently a hydrogen atom, a deuterium atom, a halogen atom, a cyano group, a hydroxy group, a substituted or unsubstituted oxy group, or a substituted or unsubstituted linear or branched alkyl group having 1 to 20 carbon atoms.

7. The light emitting device of claim 1, wherein, in Formula 2,
R₁₄ to R₂₀ are each independently a hydrogen atom, a deuterium atom, a cyano group, a substituted or unsubstituted alkyl group having 1 to 20 carbon atoms, or a substituted or unsubstituted aryl group having 6 to 30 ring-forming carbon atoms.

8. The light emitting device of claim 1, wherein the fused polycyclic compound represented by Formula 1 is represented by Formula 1-1 or Formula 1-2: 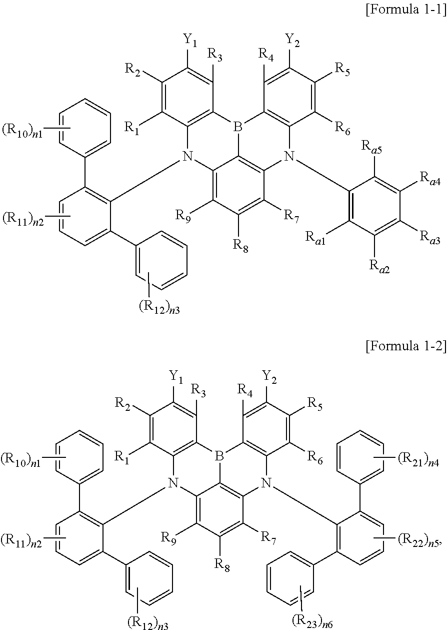
wherein, in Formula 1-1 and Formula 1-2,
Rₐ₁ to Rₐ₅ are each independently a hydrogen atom, a deuterium atom, a halogen atom, a cyano group, or a substituted or unsubstituted aryl group having 6 to 30 ring-forming carbon atoms,
R₂₁ to R₂₃ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
n4 and n6 are each independently an integer of 0 to 5,
n5 is an integer of 0 to 3, and
Y₁, Y₂, R₁ to R₁₂, and n1 to n3 are each independently the same as defined in Formula 1.

9. The light emitting device of claim 1, wherein the fused polycyclic compound represented by Formula 1 is represented by Formula 1-3 or Formula 1-4: 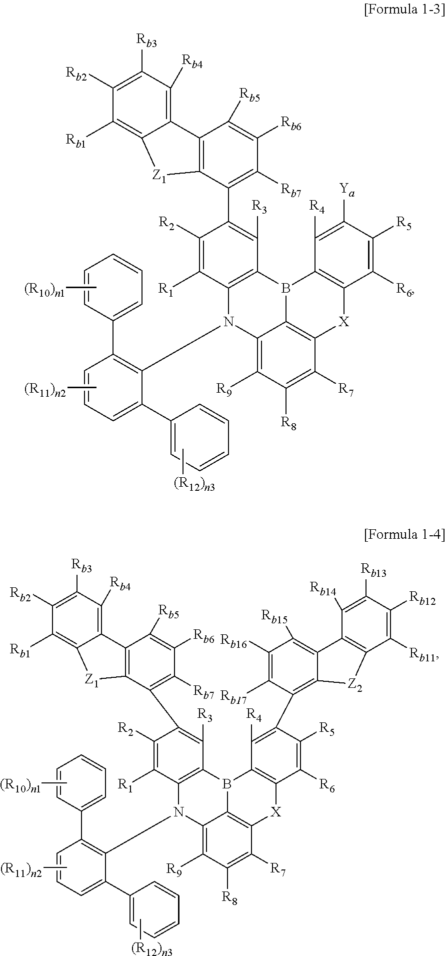
wherein, in Formula 1-3 and Formula 1-4,
Yₐ is a hydrogen atom, a substituted or unsubstituted aryl group having 6 to 30 ring-forming carbon atoms, or a substituted or unsubstituted heteroaryl group having 2 to 30 ring-forming carbon atoms,
Z₁ and Z₂ are each independently O or S,
R_{b1} to R_{b7} and R_{b11} to R_{b17} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
X, R₁ to R₁₂, and n1 to n3 are each independently the same as defined in Formula 1.

10. The light emitting device of claim 1, wherein the fused polycyclic compound represented by Formula 1 is represented by Formula 1-5: 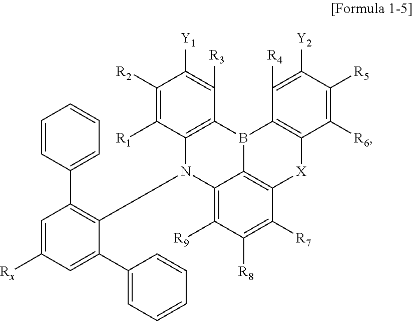
wherein, in Formula 1-5,
Rₓ is a hydrogen atom, a deuterium atom, a cyano group, a substituted or unsubstituted linear or branched alkyl group having 1 to 20 carbon atoms, or a substituted or unsubstituted aryl group having 6 to 30 ring-forming carbon atoms, and
X, R₁ to R₉, R₁₃, Y₁ and Y₂ are each independently the same as defined in Formula 1.

11. The light emitting device of claim 1, wherein the fused polycyclic compound represented by Formula 1 is represented by Formula 1-6: 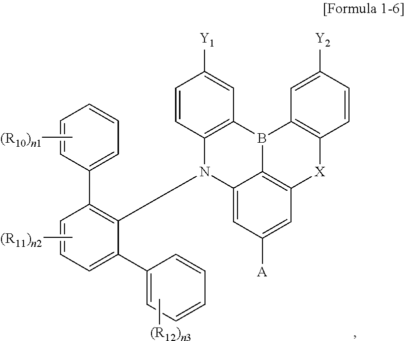
wherein, in Formula 1-6,
A is a hydrogen atom, a deuterium atom, a cyano group, a halogen atom, or a substituted or unsubstituted linear or branched alkyl group having 1 to 20 carbon atoms, and
X, R₁₀ to R₁₃, n1 to n3, Y₁ and Y₂ are each independently the same as defined in Formula 1.

12. The light emitting device of claim 11, wherein in Formula 1-6, A is a substituted or unsubstituted t-butyl group.

13. The light emitting device of claim 1, wherein the fused polycyclic compound represented by Formula 1 comprises at least one from among compounds in Compound Group 1:

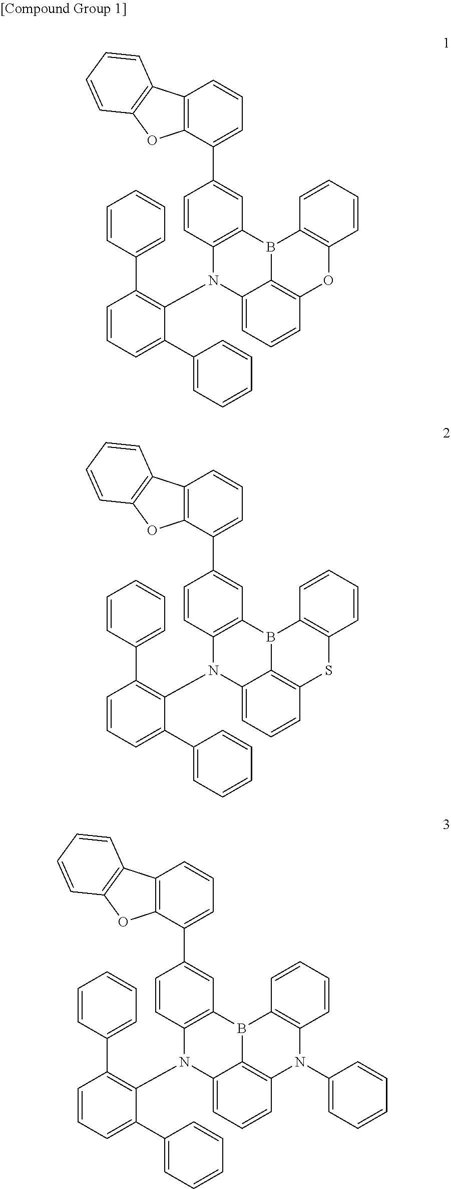 [SMILES: c1ccc(-c2cccc(-c3ccccc3)c2N2c3ccc(-c4cccc5c4oc4ccccc45)cc3B3c4ccccc4Oc4cccc2c43)cc1 ; c1ccc(-c2cccc(-c3ccccc3)c2N2c3ccc(-c4cccc5c4oc4ccccc45)cc3B3c4ccccc4Sc4cccc2c43)cc1 ; c1ccc(-c2cccc(-c3ccccc3)c2N2c3ccc(-c4cccc5c4oc4ccccc45)cc3B3c4ccccc4N(c4ccccc4)c4cccc2c43)cc1]

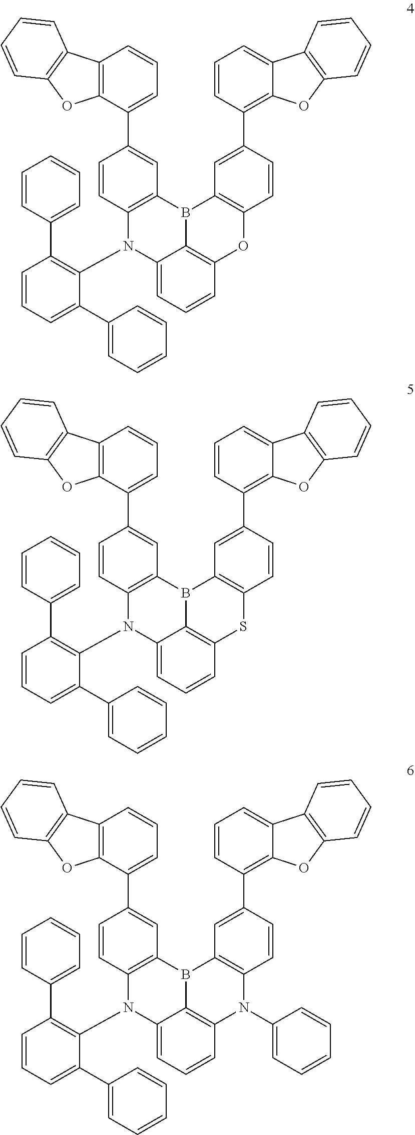 [SMILES: c1ccc(-c2cccc(-c3ccccc3)c2N2c3ccc(-c4cccc5c4oc4ccccc45)cc3B3c4cc(-c5cccc6c5oc5ccccc56)ccc4Oc4cccc2c43)cc1 ; c1ccc(-c2cccc(-c3ccccc3)c2N2c3ccc(-c4cccc5c4oc4ccccc45)cc3B3c4cc(-c5cccc6c5oc5ccccc56)ccc4Sc4cccc2c43)cc1 ; c1ccc(-c2cccc(-c3ccccc3)c2N2c3ccc(-c4cccc5c4oc4ccccc45)cc3B3c4cc(-c5cccc6c5oc5ccccc56)ccc4N(c4ccccc4)c4cccc2c43)cc1]

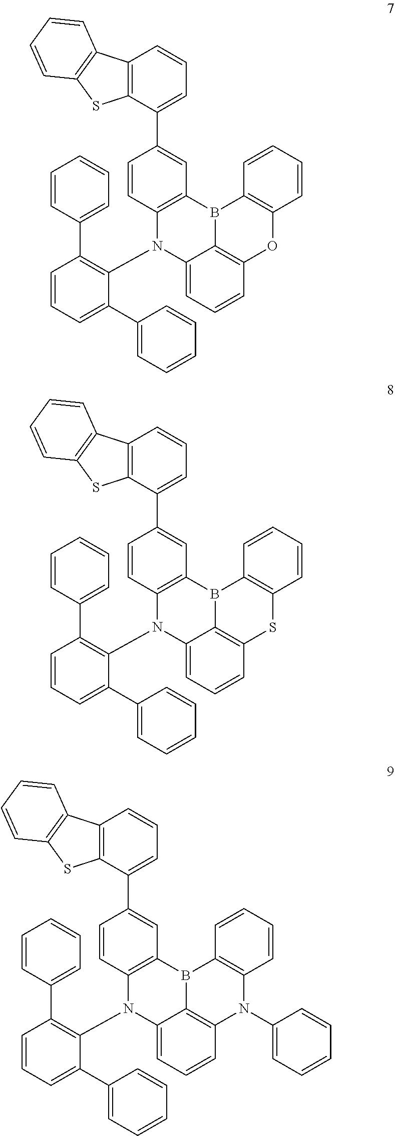 [SMILES: c1ccc(-c2cccc(-c3ccccc3)c2N2c3ccc(-c4cccc5c4sc4ccccc45)cc3B3c4ccccc4Oc4cccc2c43)cc1 ; c1ccc(-c2cccc(-c3ccccc3)c2N2c3ccc(-c4cccc5c4sc4ccccc45)cc3B3c4ccccc4Sc4cccc2c43)cc1 ; c1ccc(-c2cccc(-c3ccccc3)c2N2c3ccc(-c4cccc5c4sc4ccccc45)cc3B3c4ccccc4N(c4ccccc4)c4cccc2c43)cc1]

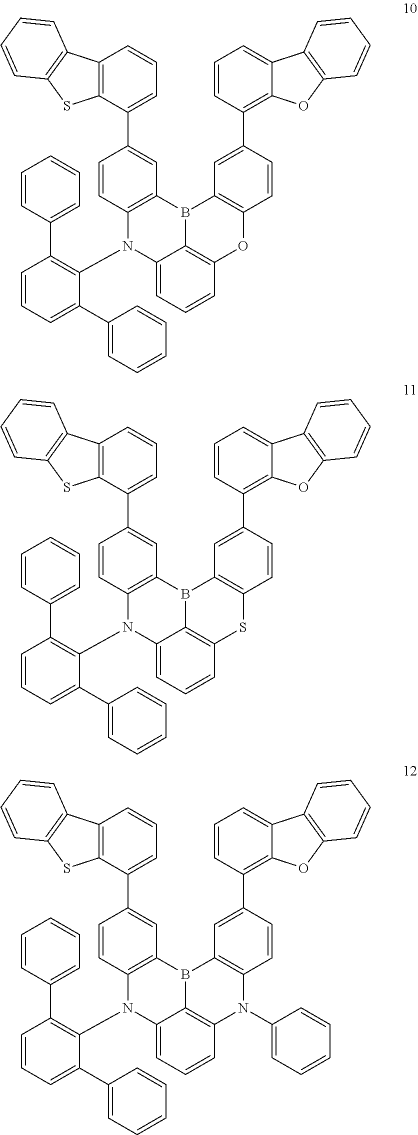 [SMILES: c1ccc(-c2cccc(-c3ccccc3)c2N2c3ccc(-c4cccc5c4sc4ccccc45)cc3B3c4cc(-c5cccc6c5oc5ccccc56)ccc4Oc4cccc2c43)cc1 ; c1ccc(-c2cccc(-c3ccccc3)c2N2c3ccc(-c4cccc5c4sc4ccccc45)cc3B3c4cc(-c5cccc6c5oc5ccccc56)ccc4Sc4cccc2c43)cc1 ; c1ccc(-c2cccc(-c3ccccc3)c2N2c3ccc(-c4cccc5c4sc4ccccc45)cc3B3c4cc(-c5cccc6c5oc5ccccc56)ccc4N(c4ccccc4)c4cccc2c43)cc1]

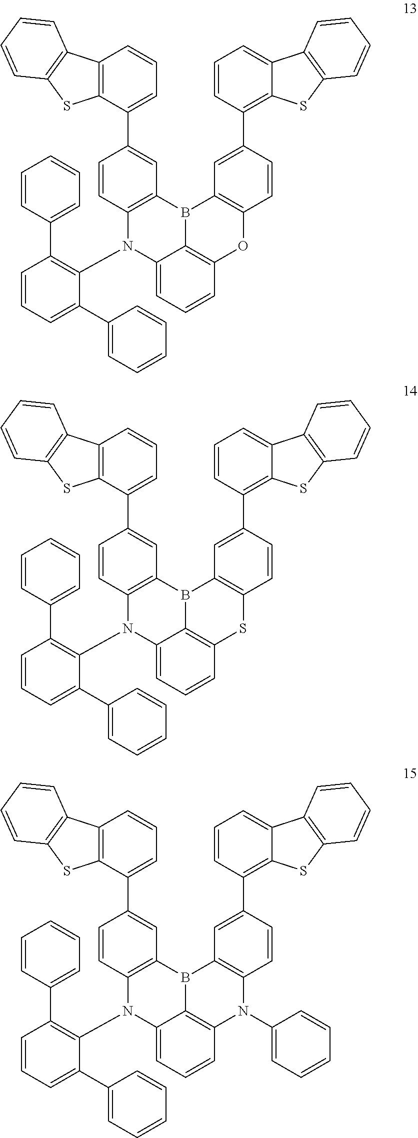 [SMILES: c1ccc(-c2cccc(-c3ccccc3)c2N2c3ccc(-c4cccc5c4sc4ccccc45)cc3B3c4cc(-c5cccc6c5sc5ccccc56)ccc4Oc4cccc2c43)cc1 ; c1ccc(-c2cccc(-c3ccccc3)c2N2c3ccc(-c4cccc5c4sc4ccccc45)cc3B3c4cc(-c5cccc6c5sc5ccccc56)ccc4Sc4cccc2c43)cc1 ; c1ccc(-c2cccc(-c3ccccc3)c2N2c3ccc(-c4cccc5c4sc4ccccc45)cc3B3c4cc(-c5cccc6c5sc5ccccc56)ccc4N(c4ccccc4)c4cccc2c43)cc1]

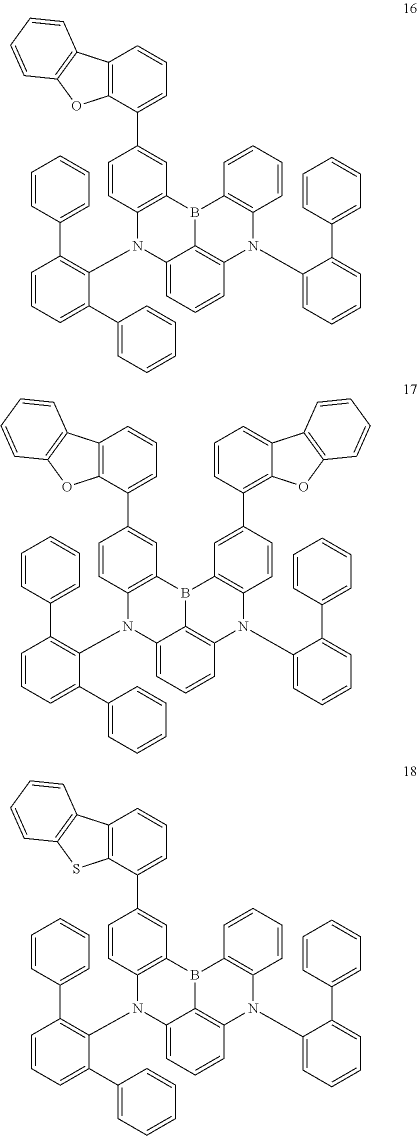 [SMILES: c1ccc(-c2ccccc2N2c3ccccc3B3c4cc(-c5cccc6c5oc5ccccc56)ccc4N(c4c(-c5ccccc5)cccc4-c4ccccc4)c4cccc2c43)cc1 ; c1ccc(-c2ccccc2N2c3ccc(-c4cccc5c4oc4ccccc45)cc3B3c4cc(-c5cccc6c5oc5ccccc56)ccc4N(c4c(-c5ccccc5)cccc4-c4ccccc4)c4cccc2c43)cc1 ; c1ccc(-c2ccccc2N2c3ccccc3B3c4cc(-c5cccc6c5sc5ccccc56)ccc4N(c4c(-c5ccccc5)cccc4-c4ccccc4)c4cccc2c43)cc1]

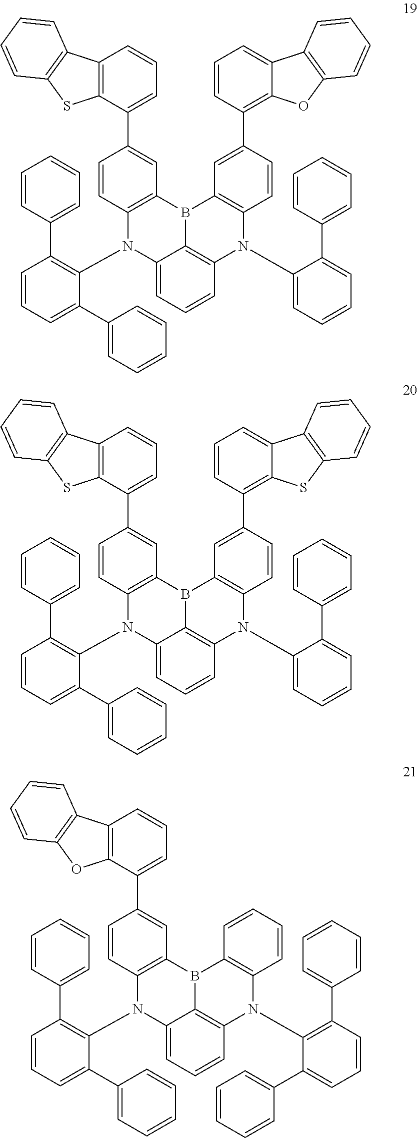 [SMILES: c1ccc(-c2ccccc2N2c3ccc(-c4cccc5c4oc4ccccc45)cc3B3c4cc(-c5cccc6c5sc5ccccc56)ccc4N(c4c(-c5ccccc5)cccc4-c4ccccc4)c4cccc2c43)cc1 ; c1ccc(-c2ccccc2N2c3ccc(-c4cccc5c4sc4ccccc45)cc3B3c4cc(-c5cccc6c5sc5ccccc56)ccc4N(c4c(-c5ccccc5)cccc4-c4ccccc4)c4cccc2c43)cc1 ; c1ccc(-c2cccc(-c3ccccc3)c2N2c3ccccc3B3c4cc(-c5cccc6c5oc5ccccc56)ccc4N(c4c(-c5ccccc5)cccc4-c4ccccc4)c4cccc2c43)cc1]

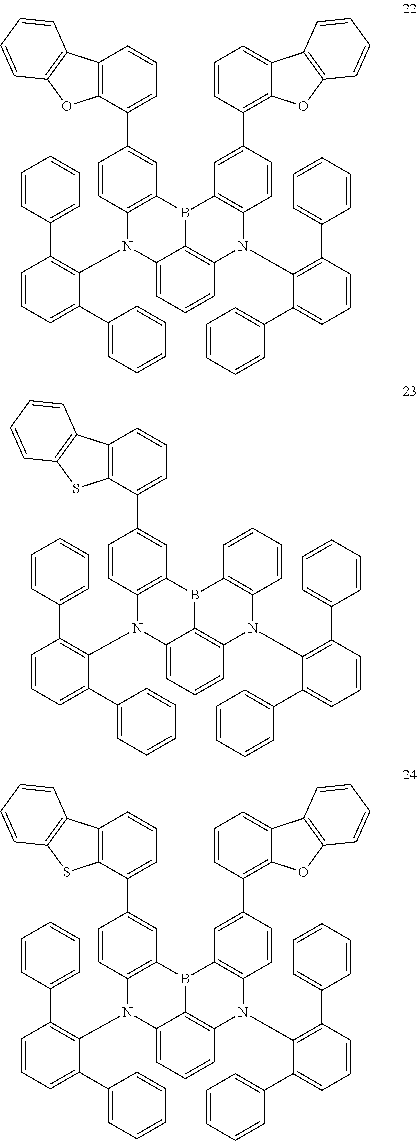 [SMILES: c1ccc(-c2cccc(-c3ccccc3)c2N2c3ccc(-c4cccc5c4oc4ccccc45)cc3B3c4cc(-c5cccc6c5oc5ccccc56)ccc4N(c4c(-c5ccccc5)cccc4-c4ccccc4)c4cccc2c43)cc1 ; c1ccc(-c2cccc(-c3ccccc3)c2N2c3ccccc3B3c4cc(-c5cccc6c5sc5ccccc56)ccc4N(c4c(-c5ccccc5)cccc4-c4ccccc4)c4cccc2c43)cc1 ; c1ccc(-c2cccc(-c3ccccc3)c2N2c3ccc(-c4cccc5c4oc4ccccc45)cc3B3c4cc(-c5cccc6c5sc5ccccc56)ccc4N(c4c(-c5ccccc5)cccc4-c4ccccc4)c4cccc2c43)cc1]

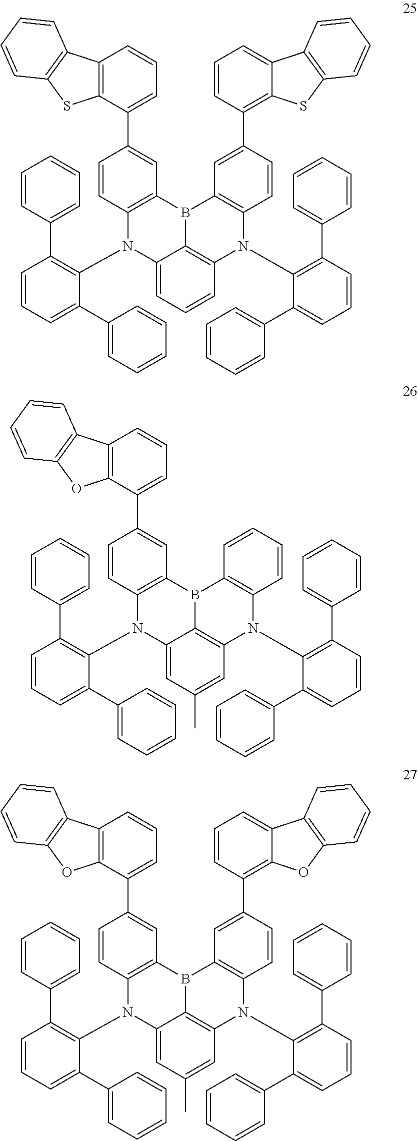 [SMILES: c1ccc(-c2cccc(-c3ccccc3)c2N2c3ccc(-c4cccc5c4sc4ccccc45)cc3B3c4cc(-c5cccc6c5sc5ccccc56)ccc4N(c4c(-c5ccccc5)cccc4-c4ccccc4)c4cccc2c43)cc1 ; Cc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; Cc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1]

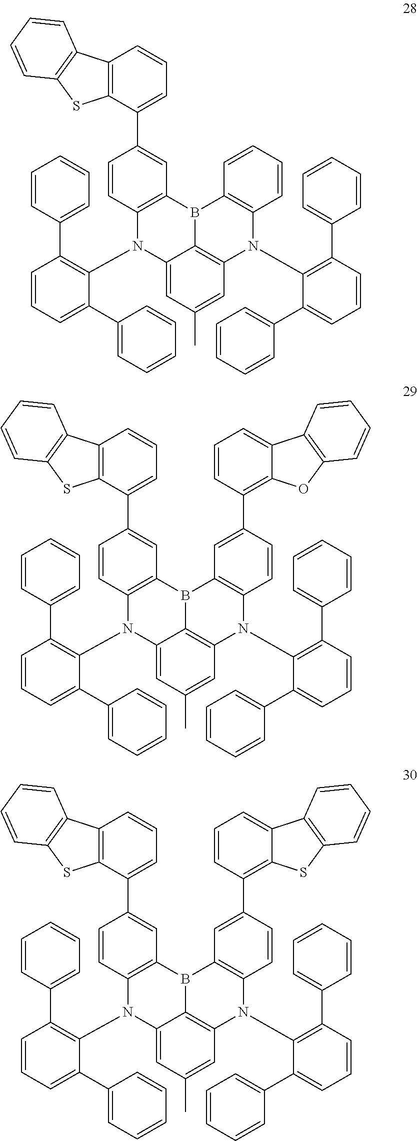 [SMILES: Cc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1 ; Cc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; Cc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1]

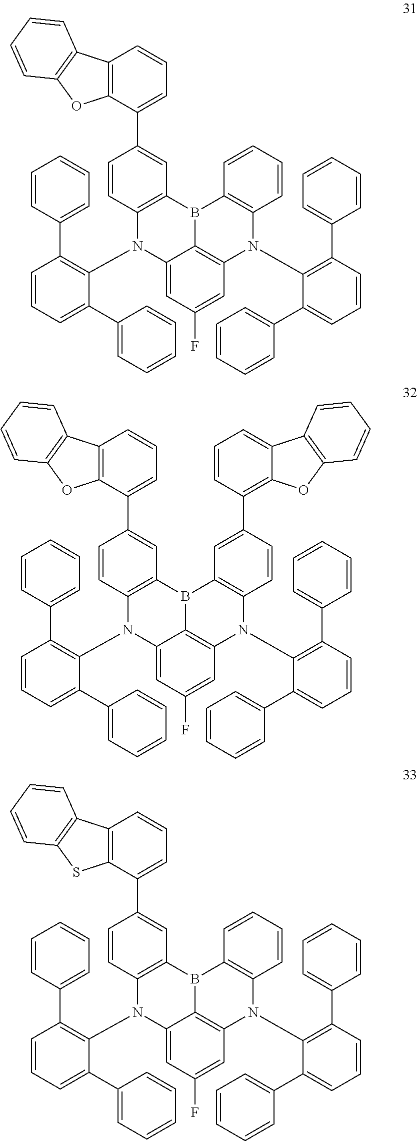 [SMILES: Fc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; Fc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; Fc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1]

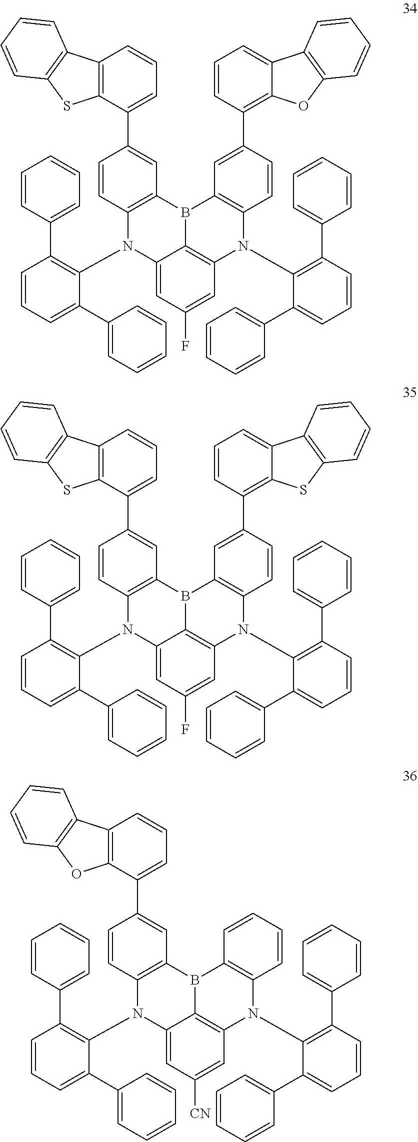 [SMILES: Fc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; Fc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; N#Cc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1]

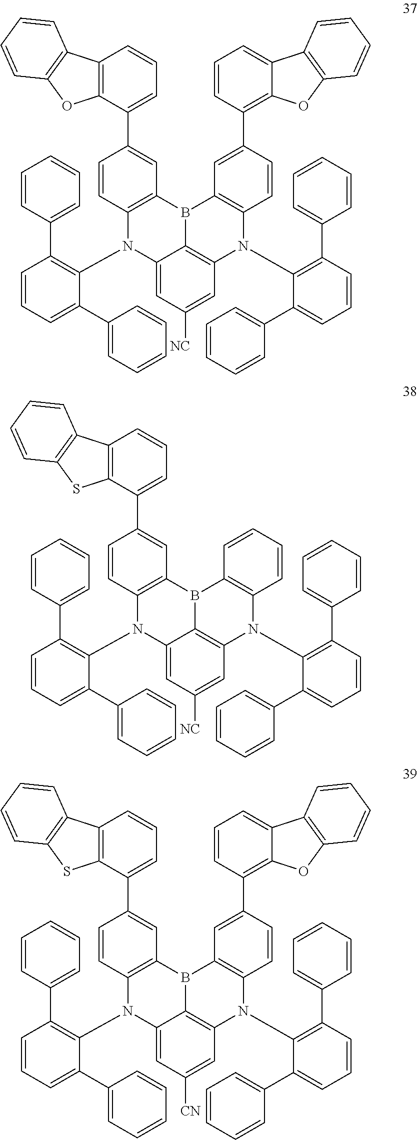 [SMILES: N#Cc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; N#Cc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1 ; N#Cc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1]

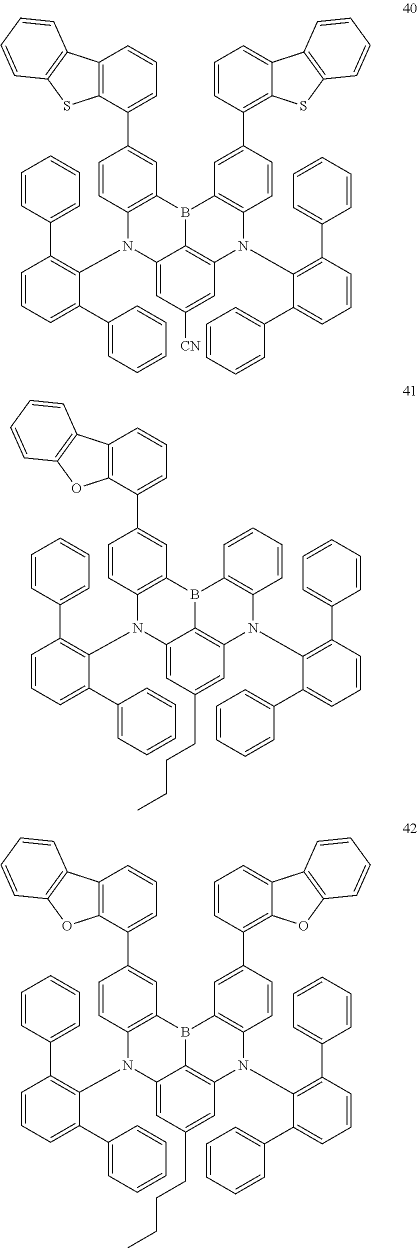 [SMILES: N#Cc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1]

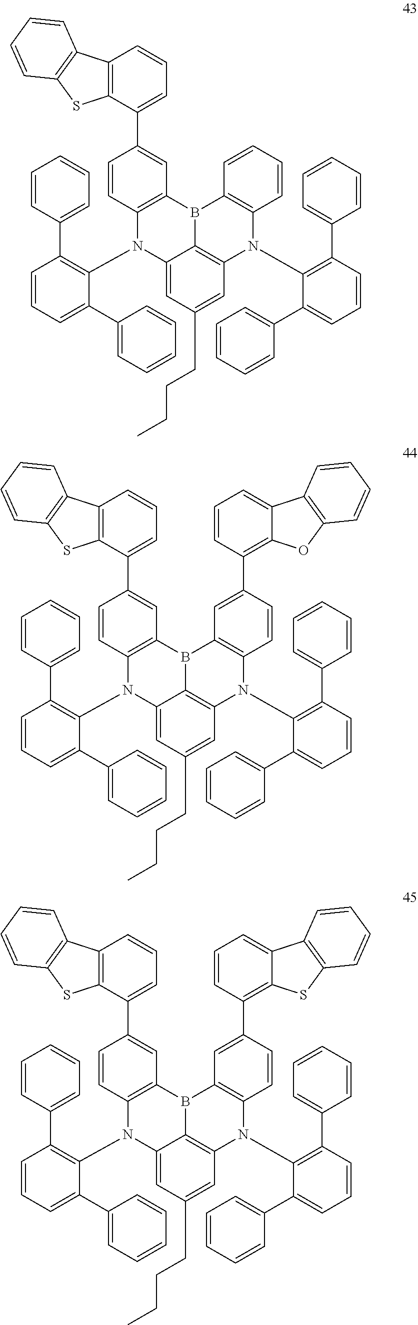 [SMILES: CCCCc1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; CCCCc1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1]

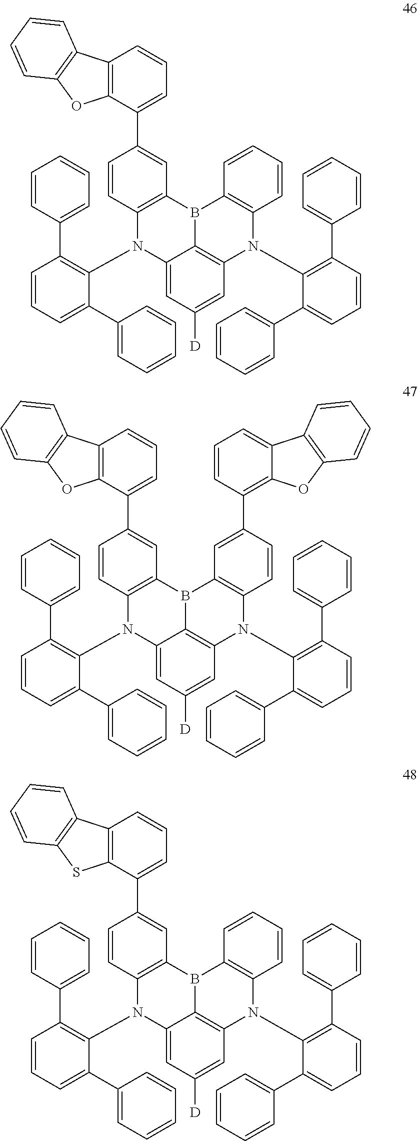 [SMILES: [2H]c1cc2c3c(c1)N(c1c(-c4ccccc4)cccc1-c1ccccc1)c1ccc(-c4cccc5c4oc4ccccc45)cc1B3c1ccccc1N2c1c(-c2ccccc2)cccc1-c1ccccc1 ; [2H]c1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; [2H]c1cc2c3c(c1)N(c1c(-c4ccccc4)cccc1-c1ccccc1)c1ccc(-c4cccc5c4sc4ccccc45)cc1B3c1ccccc1N2c1c(-c2ccccc2)cccc1-c1ccccc1]

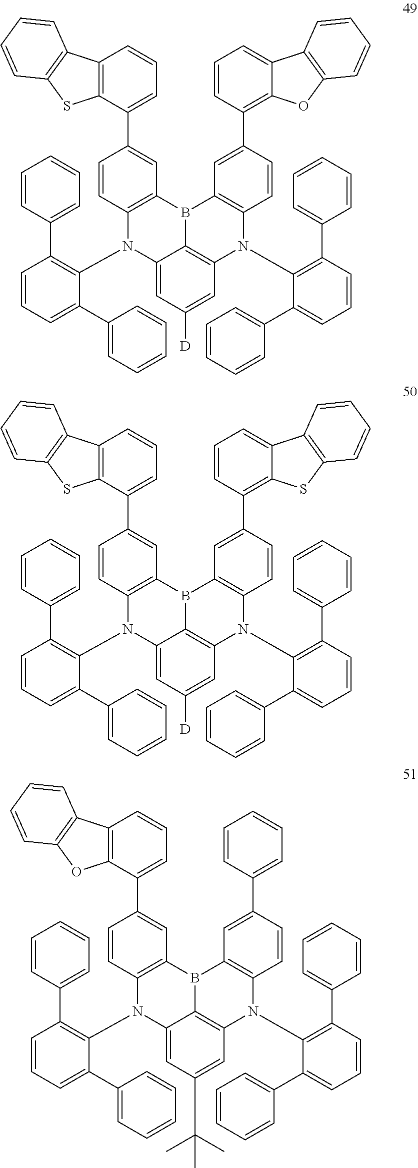 [SMILES: [2H]c1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1 ; [2H]c1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4cccc5c4oc4ccccc45)cc1B3c1cc(-c3ccccc3)ccc1N2c1c(-c2ccccc2)cccc1-c1ccccc1]

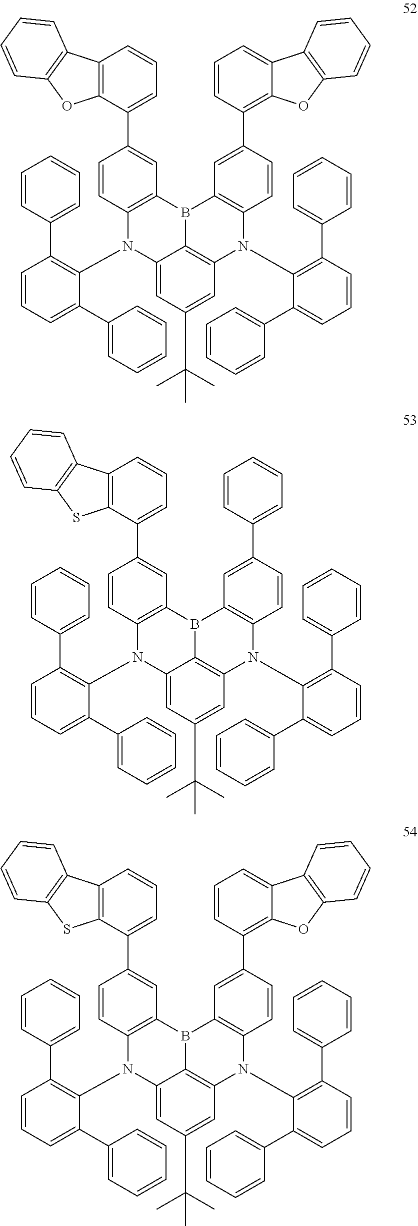 [SMILES: CC(C)(C)c1cc2c3c(c1)N(c1c(-c4ccccc4)cccc1-c1ccccc1)c1ccc(-c4cccc5c4oc4ccccc45)cc1B3c1cc(-c3cccc4c3oc3ccccc34)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4cccc5c4sc4ccccc45)cc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4cccc5c4sc4ccccc45)cc1B3c1cc(-c3cccc4c3oc3ccccc34)ccc1N2c1c(-c2ccccc2)cccc1-c1ccccc1]

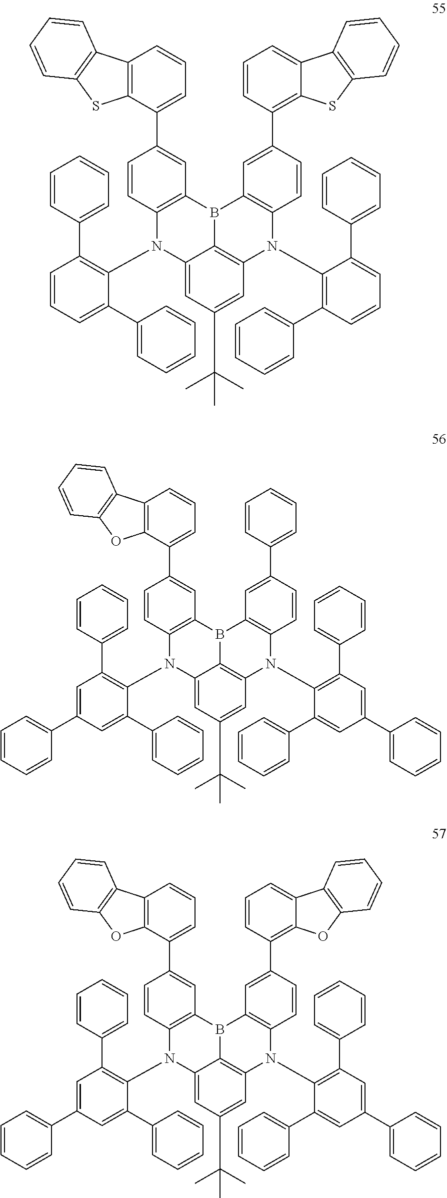 [SMILES: CC(C)(C)c1cc2c3c(c1)N(c1c(-c4ccccc4)cccc1-c1ccccc1)c1ccc(-c4cccc5c4sc4ccccc45)cc1B3c1cc(-c3cccc4c3sc3ccccc34)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccccc1)c1ccc(-c4cccc5c4oc4ccccc45)cc1B3c1cc(-c3ccccc3)ccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1ccc(-c4cccc5c4oc4ccccc45)cc1B3c1cc(-c3cccc4c3oc3ccccc34)ccc1N2c1c(-c2ccccc2)cc(-c2ccccc2)cc1-c1ccccc1]

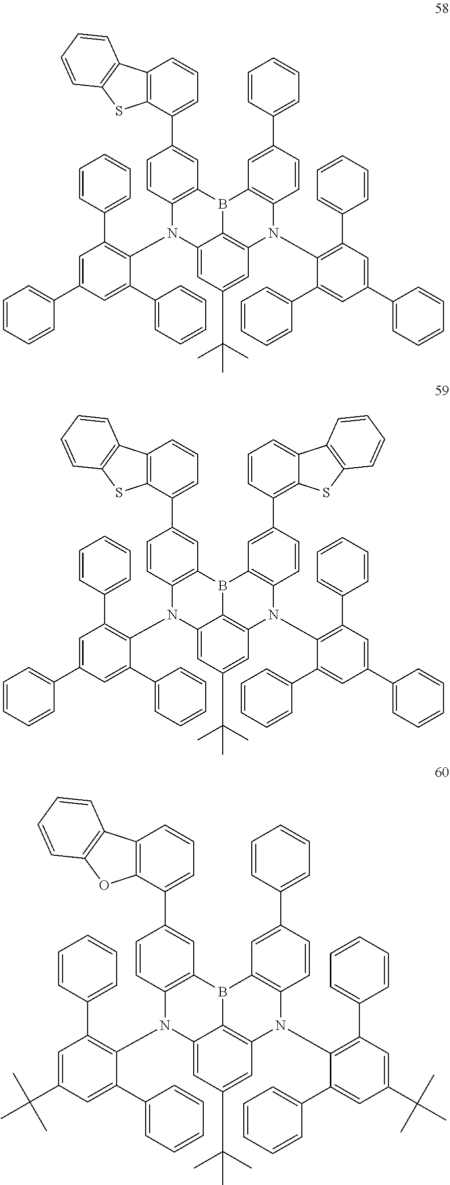 [SMILES: CC(C)(C)c1cc2c3c(c1)N(c1c(-c4ccccc4)cc(-c4ccccc4)cc1-c1ccccc1)c1ccc(-c4cccc5c4sc4ccccc45)cc1B3c1cc(-c3ccccc3)ccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1ccc(-c4cccc5c4sc4ccccc45)cc1B3c1cc(-c3cccc4c3sc3ccccc34)ccc1N2c1c(-c2ccccc2)cc(-c2ccccc2)cc1-c1ccccc1 ; CC(C)(C)c1cc(-c2ccccc2)c(N2c3ccc(-c4ccccc4)cc3B3c4cc(-c5cccc6c5oc5ccccc56)ccc4N(c4c(-c5ccccc5)cc(C(C)(C)C)cc4-c4ccccc4)c4cc(C(C)(C)C)cc2c43)c(-c2ccccc2)c1]

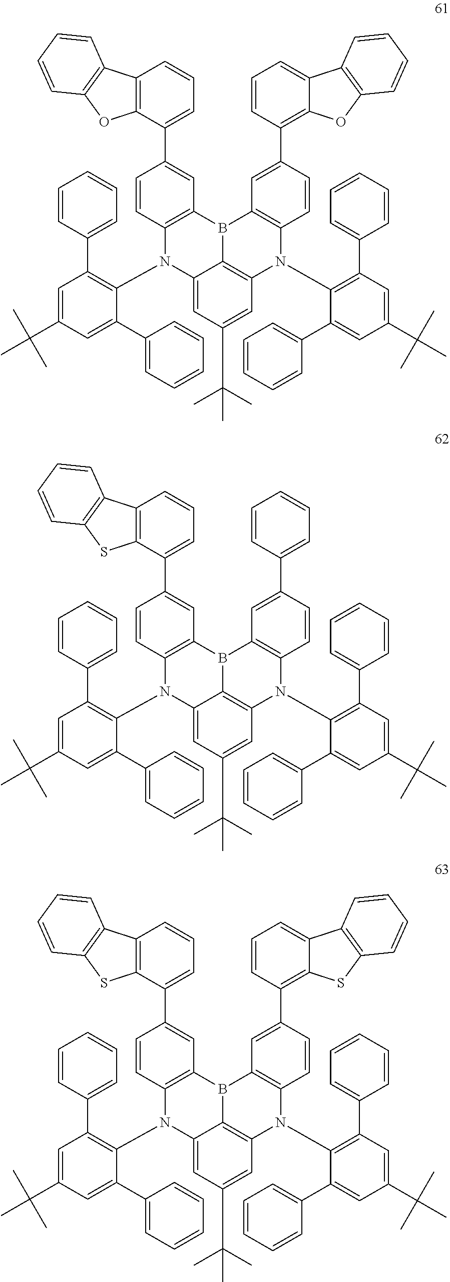

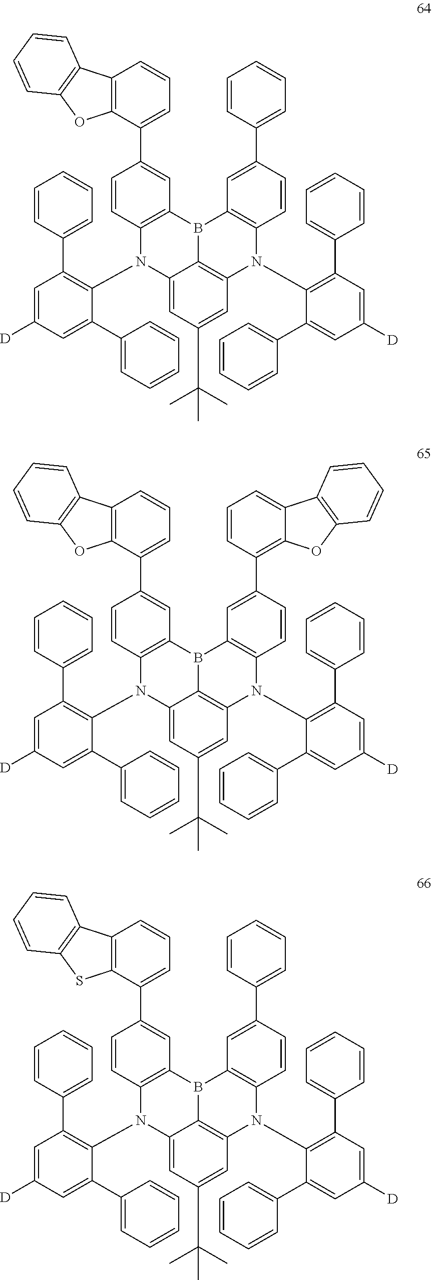 [SMILES: [2H]c1cc(-c2ccccc2)c(N2c3ccc(-c4ccccc4)cc3B3c4cc(-c5cccc6c5oc5ccccc56)ccc4N(c4c(-c5ccccc5)cc([2H])cc4-c4ccccc4)c4cc(C(C)(C)C)cc2c43)c(-c2ccccc2)c1 ; [2H]c1cc(-c2ccccc2)c(N2c3ccc(-c4cccc5c4oc4ccccc45)cc3B3c4cc(-c5cccc6c5oc5ccccc56)ccc4N(c4c(-c5ccccc5)cc([2H])cc4-c4ccccc4)c4cc(C(C)(C)C)cc2c43)c(-c2ccccc2)c1 ; [2H]c1cc(-c2ccccc2)c(N2c3ccc(-c4ccccc4)cc3B3c4cc(-c5cccc6c5sc5ccccc56)ccc4N(c4c(-c5ccccc5)cc([2H])cc4-c4ccccc4)c4cc(C(C)(C)C)cc2c43)c(-c2ccccc2)c1]

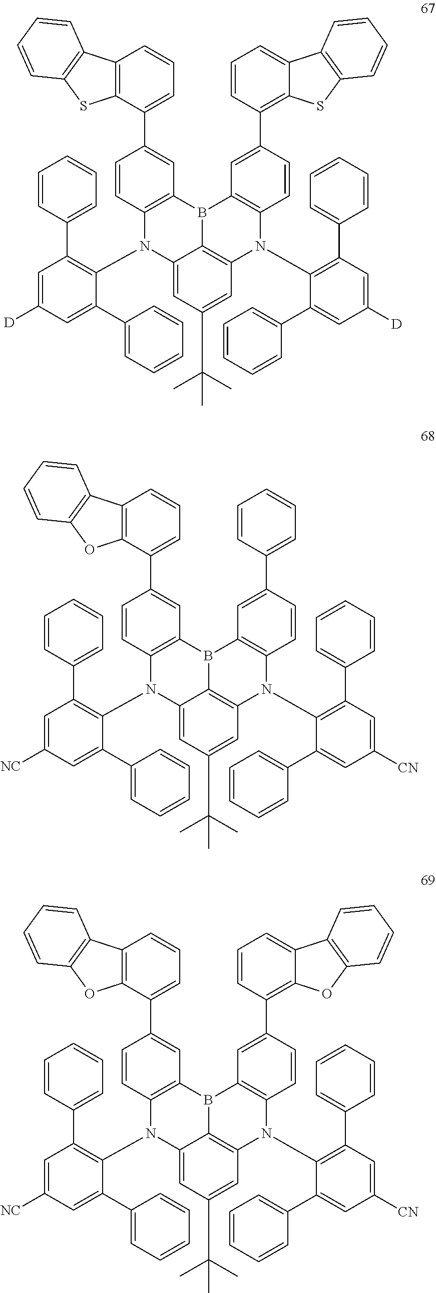 [SMILES: [2H]c1cc(-c2ccccc2)c(N2c3ccc(-c4cccc5c4sc4ccccc45)cc3B3c4cc(-c5cccc6c5sc5ccccc56)ccc4N(c4c(-c5ccccc5)cc([2H])cc4-c4ccccc4)c4cc(C(C)(C)C)cc2c43)c(-c2ccccc2)c1 ; CC(C)(C)c1cc2c3c(c1)N(c1c(-c4ccccc4)cc(C#N)cc1-c1ccccc1)c1ccc(-c4cccc5c4oc4ccccc45)cc1B3c1cc(-c3ccccc3)ccc1N2c1c(-c2ccccc2)cc(C#N)cc1-c1ccccc1 ; CC(C)(C)c1cc2c3c(c1)N(c1c(-c4ccccc4)cc(C#N)cc1-c1ccccc1)c1ccc(-c4cccc5c4oc4ccccc45)cc1B3c1cc(-c3cccc4c3oc3ccccc34)ccc1N2c1c(-c2ccccc2)cc(C#N)cc1-c1ccccc1]

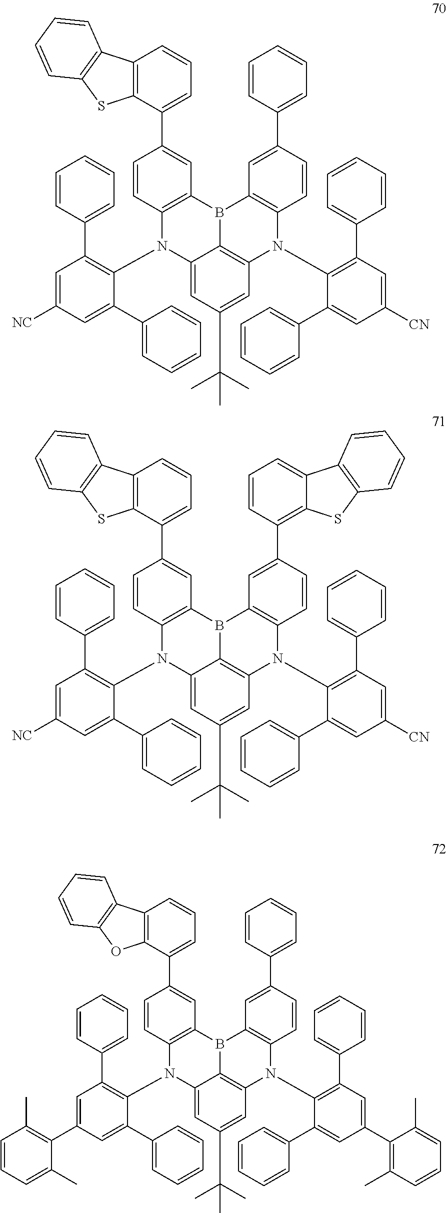 [SMILES: CC(C)(C)c1cc2c3c(c1)N(c1c(-c4ccccc4)cc(C#N)cc1-c1ccccc1)c1ccc(-c4cccc5c4sc4ccccc45)cc1B3c1cc(-c3ccccc3)ccc1N2c1c(-c2ccccc2)cc(C#N)cc1-c1ccccc1 ; CC(C)(C)c1cc2c3c(c1)N(c1c(-c4ccccc4)cc(C#N)cc1-c1ccccc1)c1ccc(-c4cccc5c4sc4ccccc45)cc1B3c1cc(-c3cccc4c3sc3ccccc34)ccc1N2c1c(-c2ccccc2)cc(C#N)cc1-c1ccccc1 ; Cc1cccc(C)c1-c1cc(-c2ccccc2)c(N2c3ccc(-c4ccccc4)cc3B3c4cc(-c5cccc6c5oc5ccccc56)ccc4N(c4c(-c5ccccc5)cc(-c5c(C)cccc5C)cc4-c4ccccc4)c4cc(C(C)(C)C)cc2c43)c(-c2ccccc2)c1]

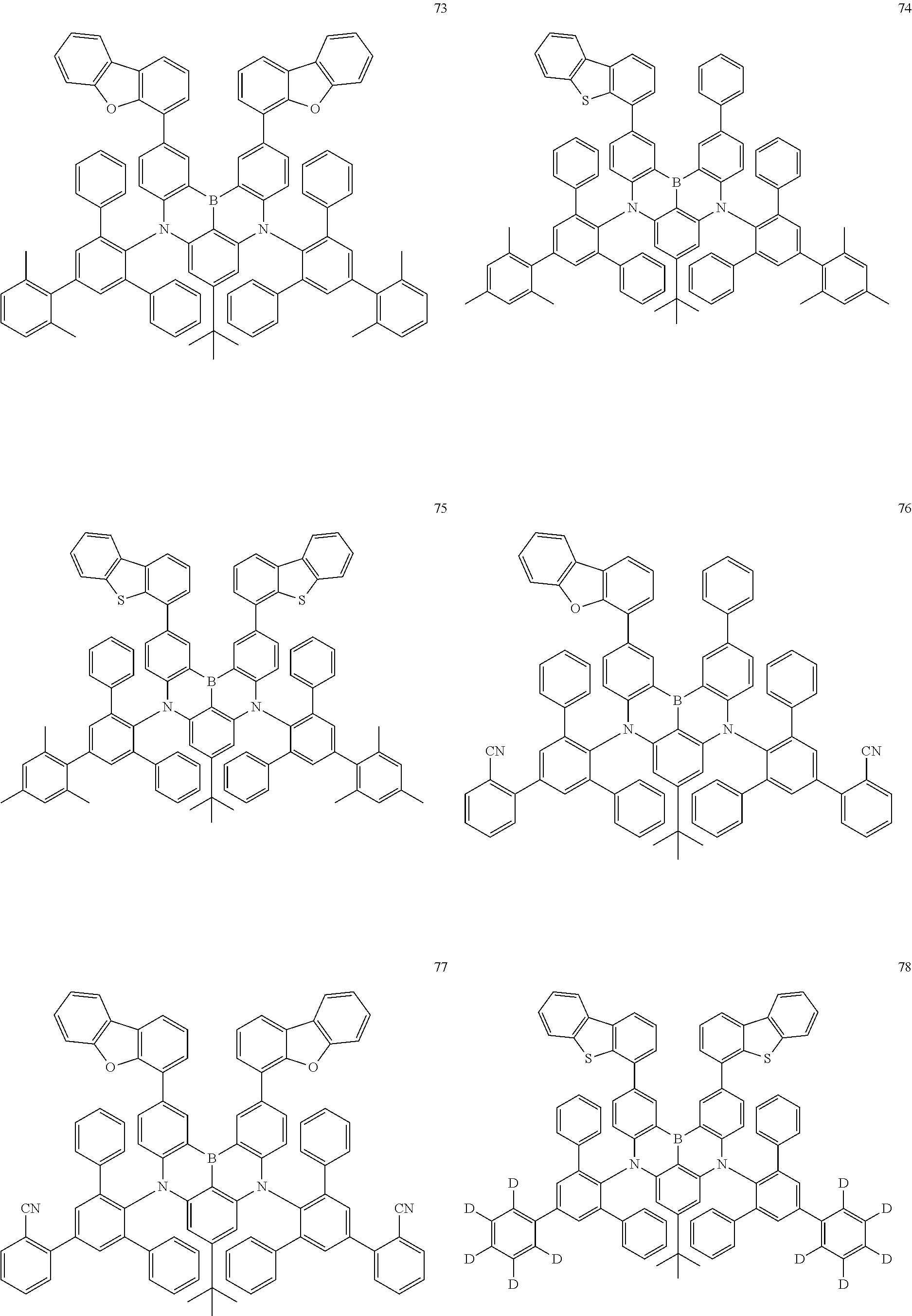

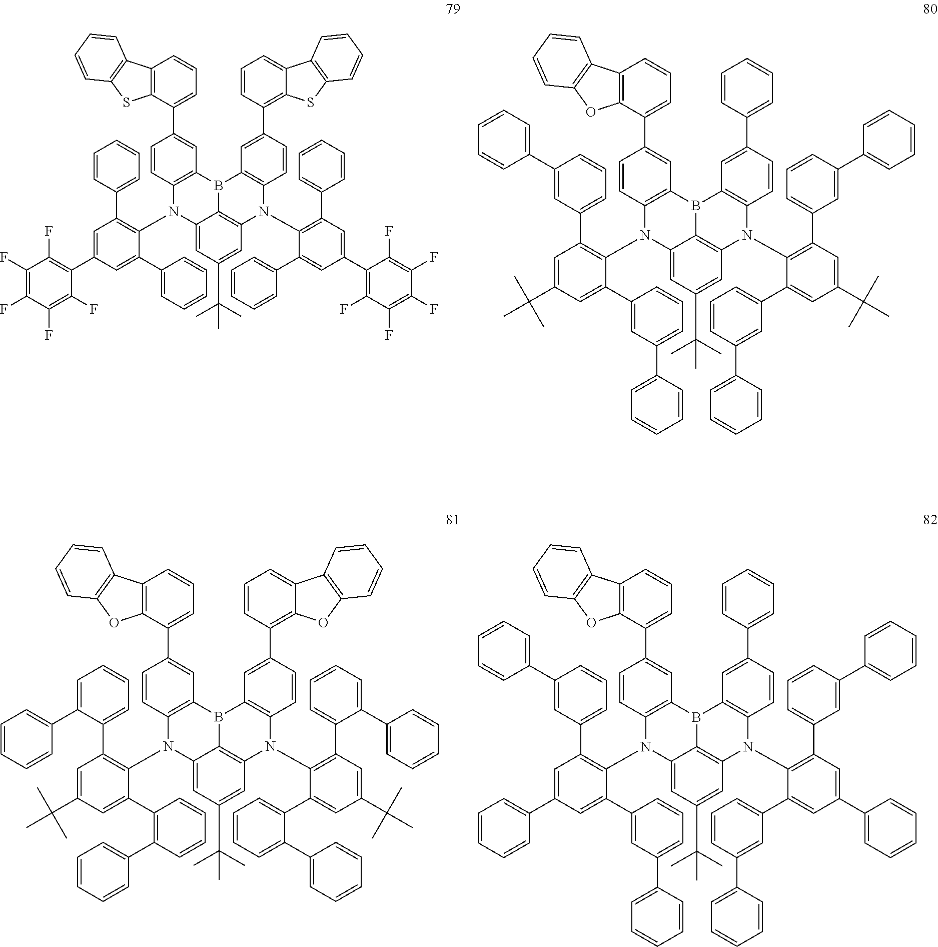

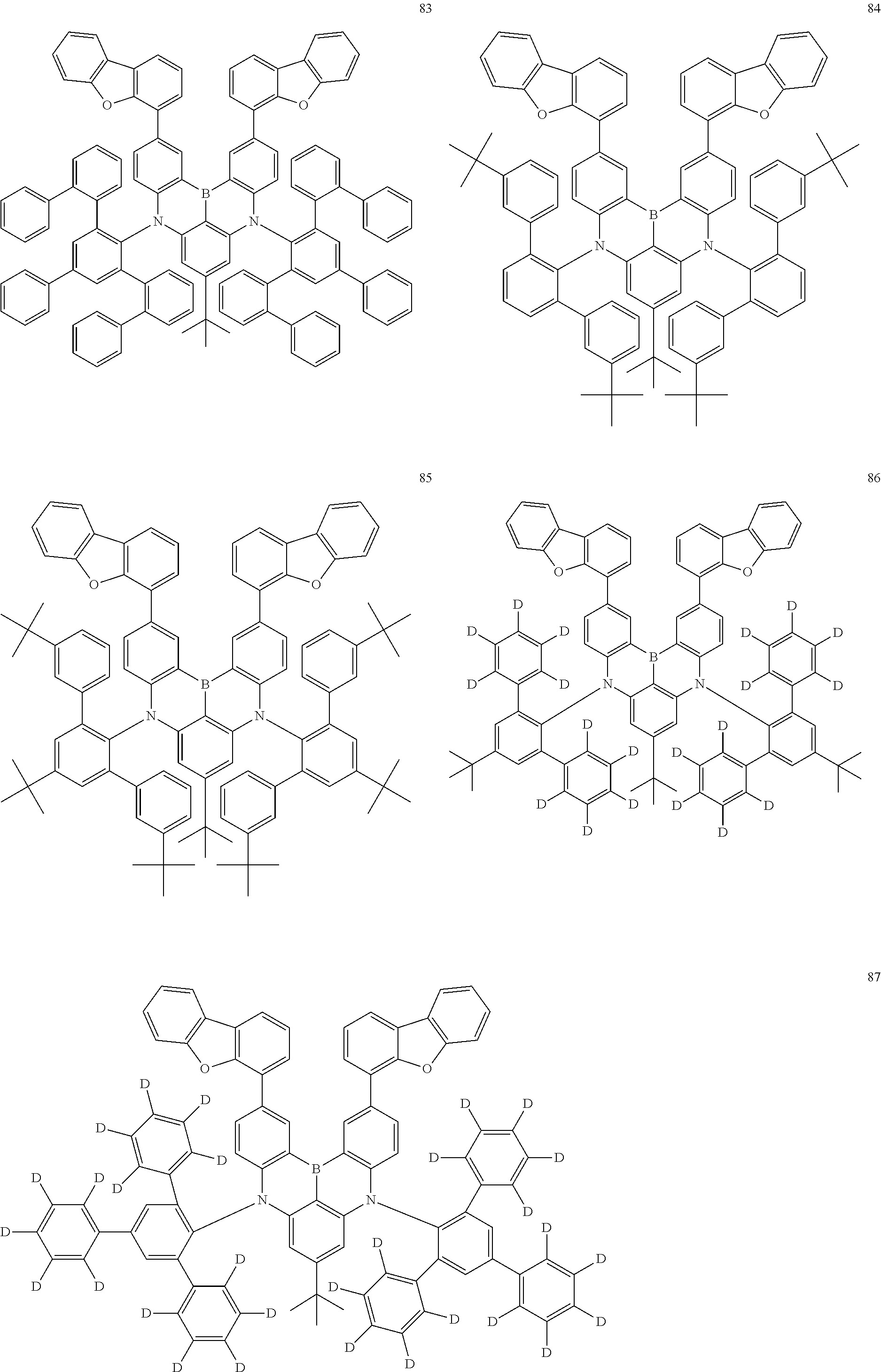

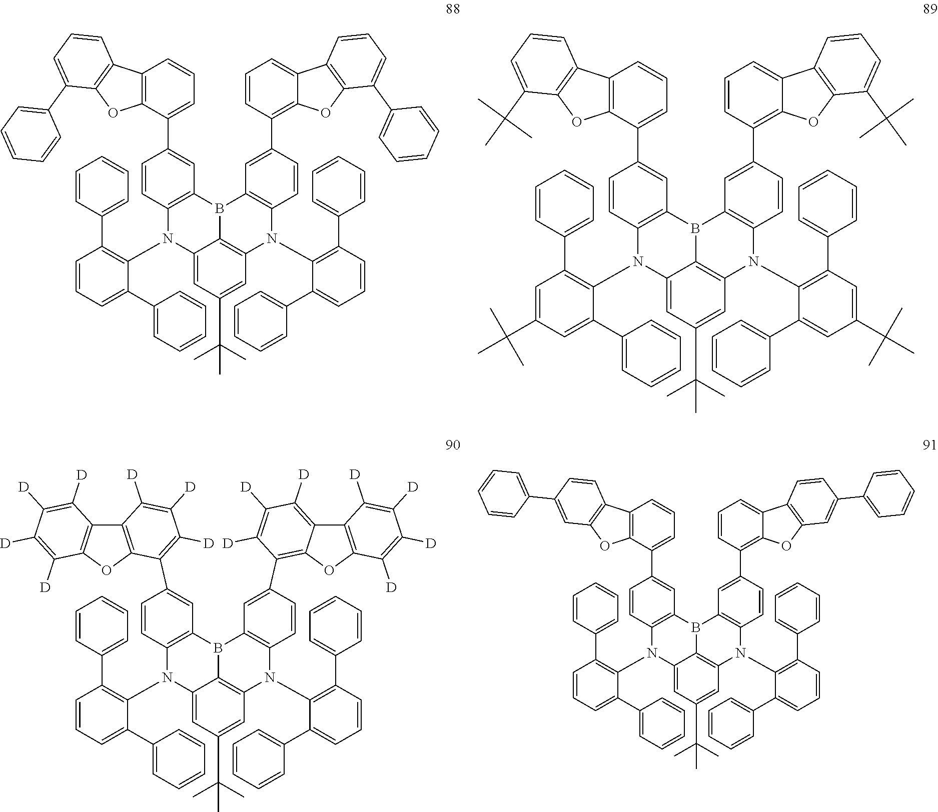

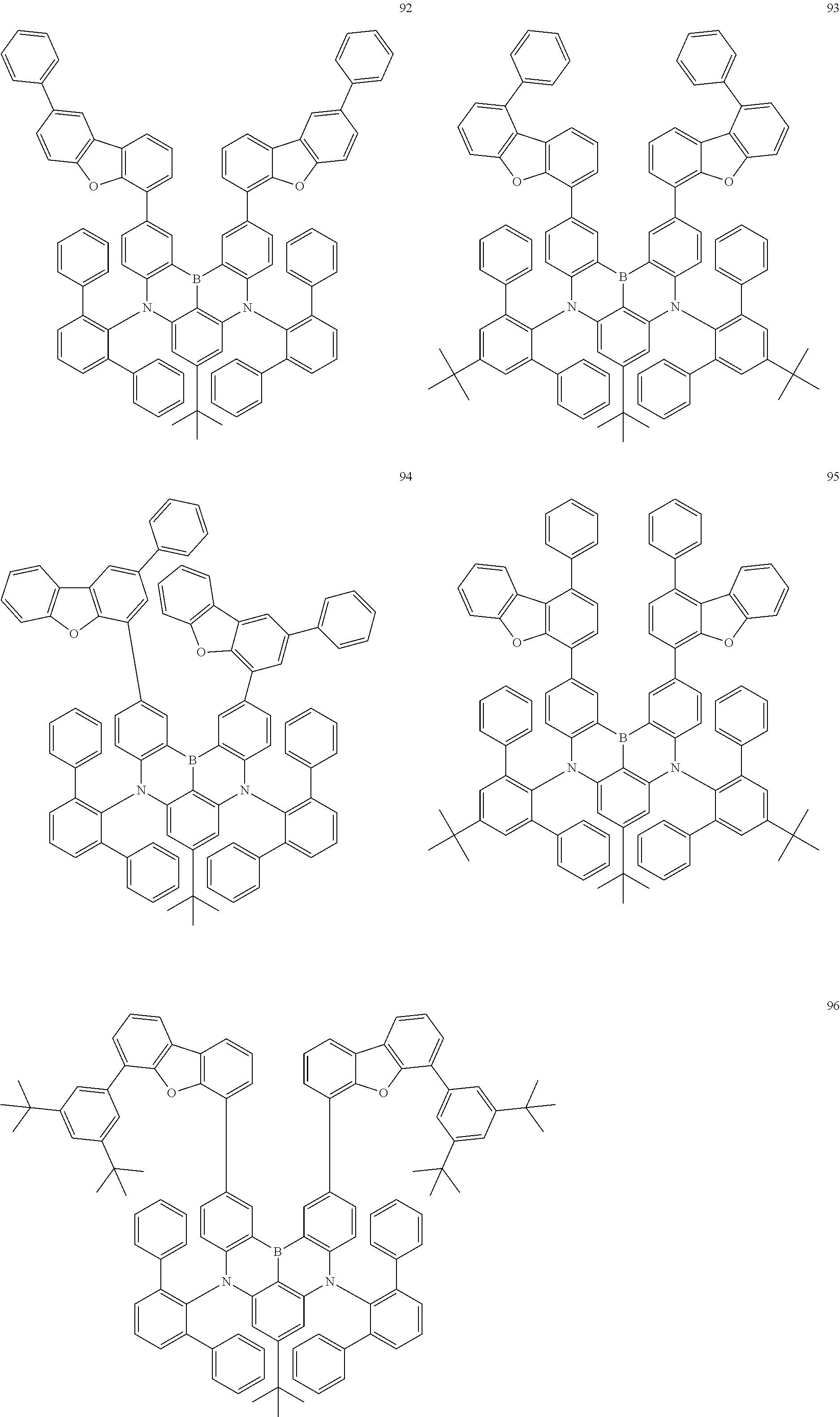

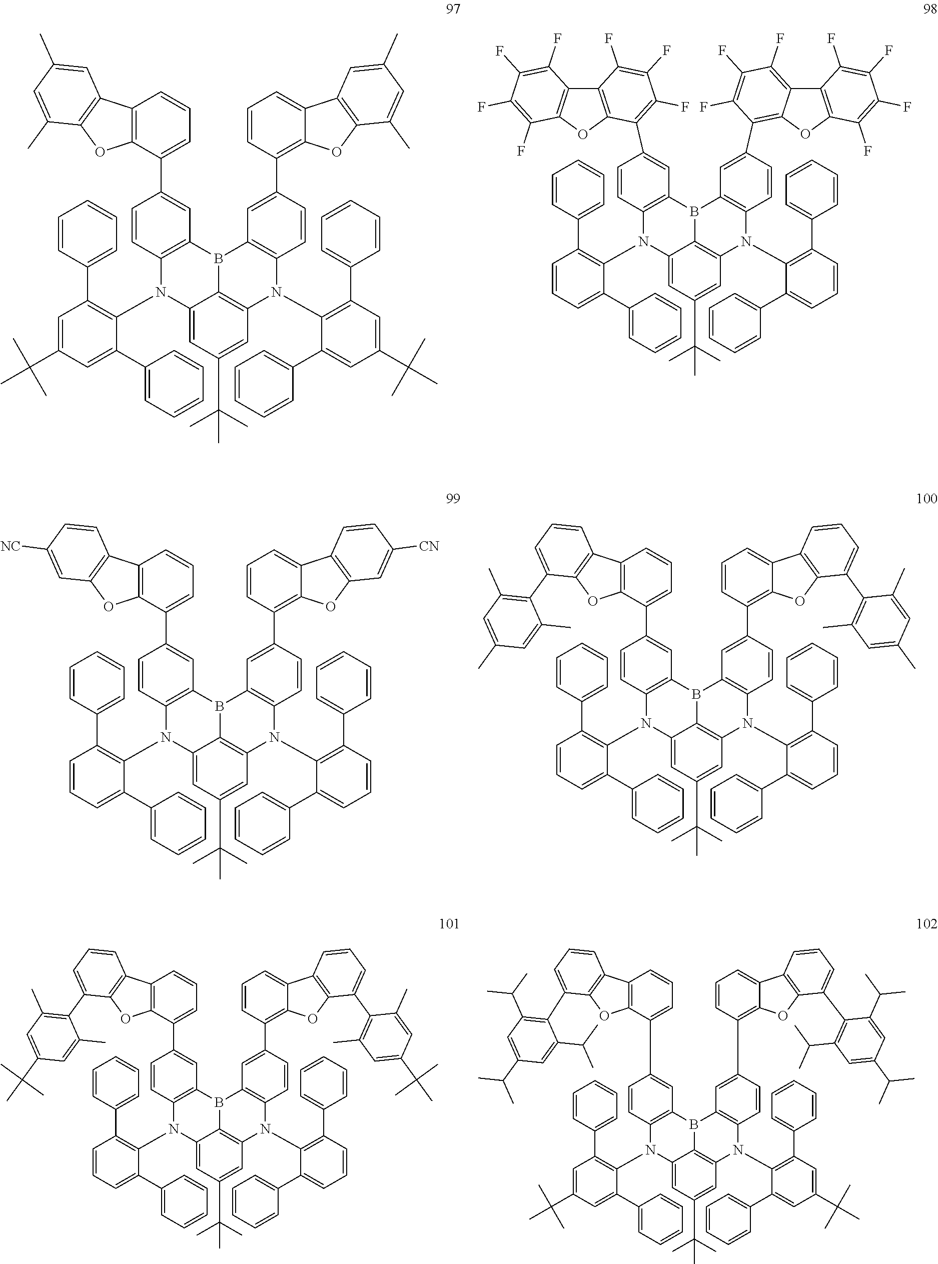

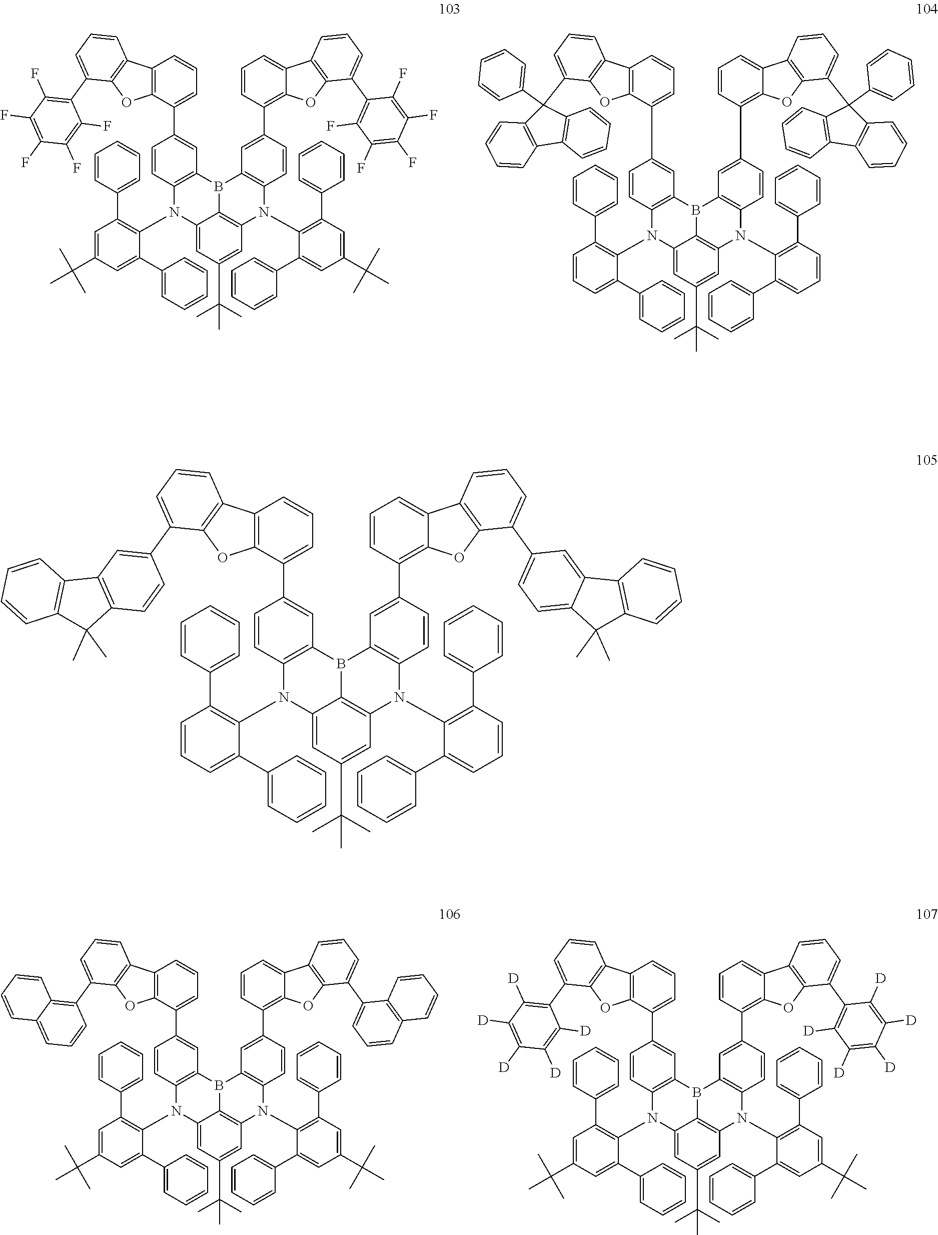

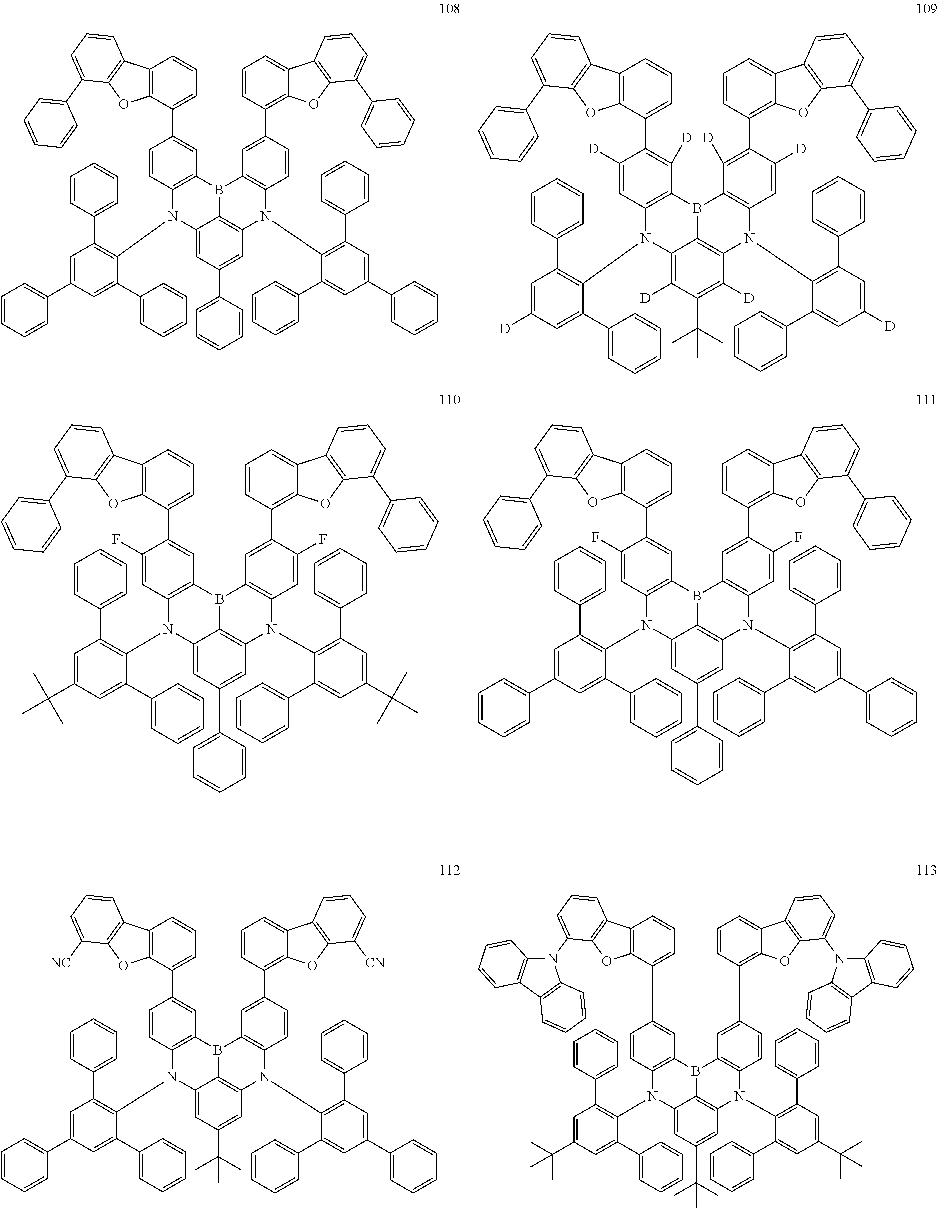

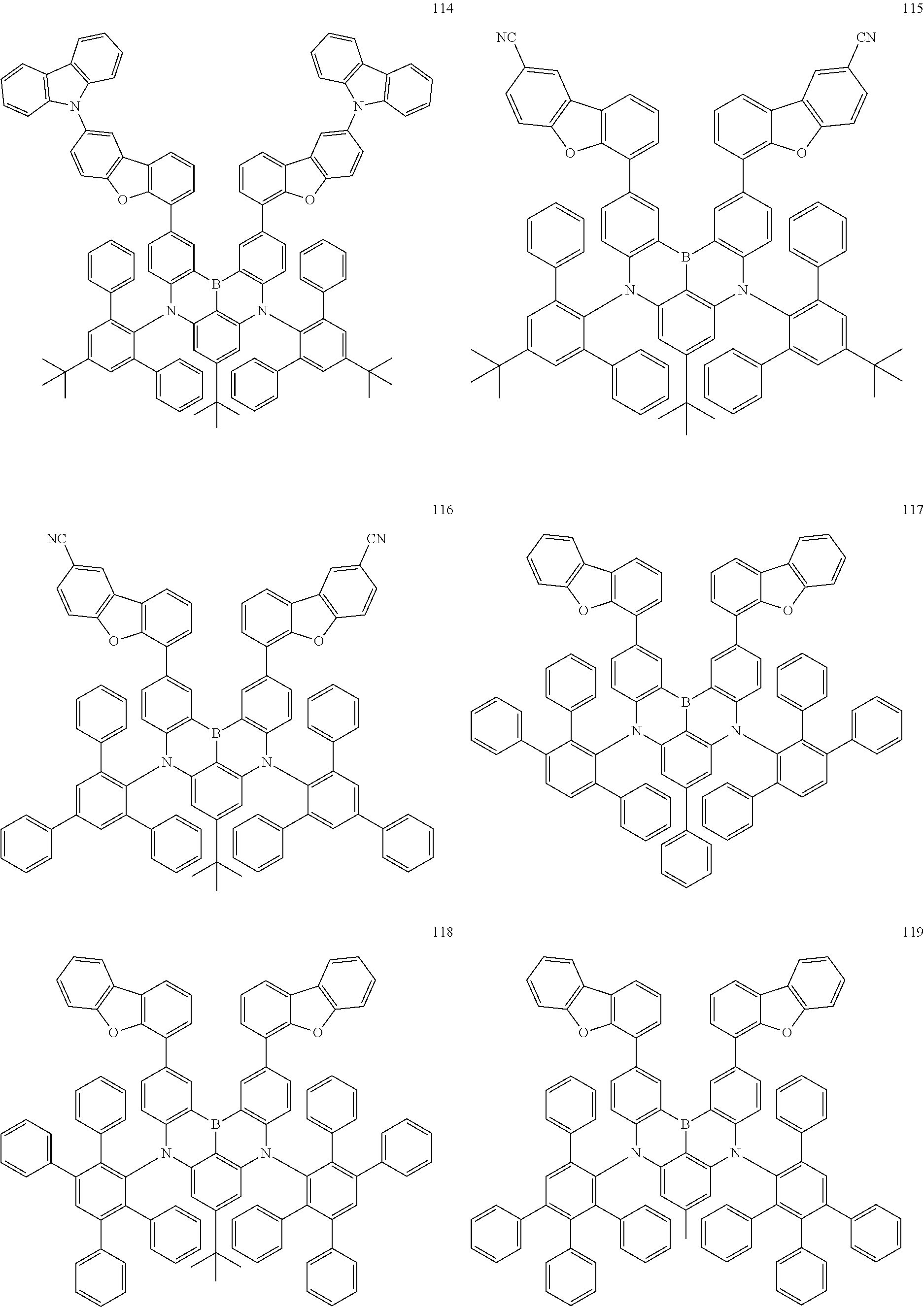

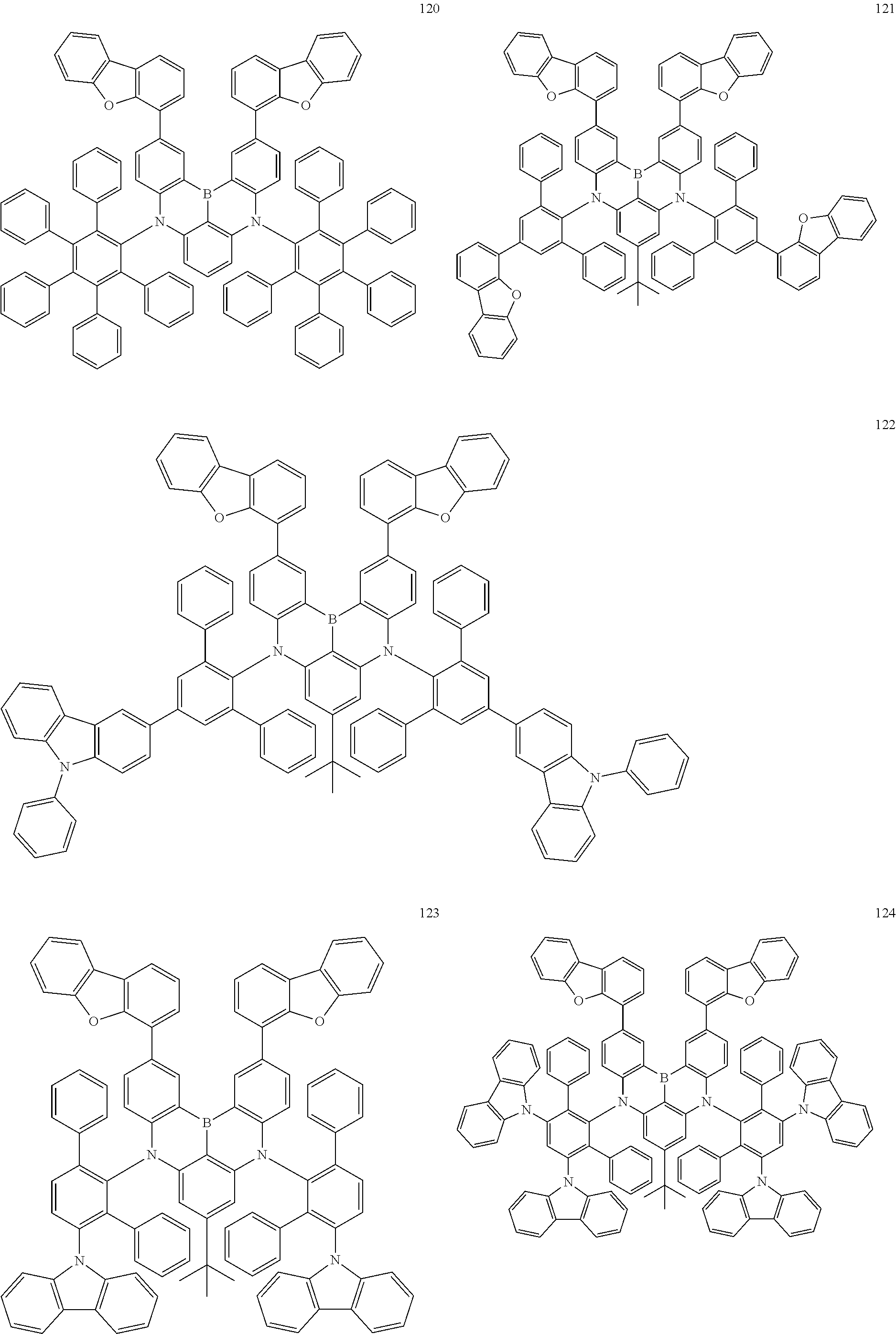

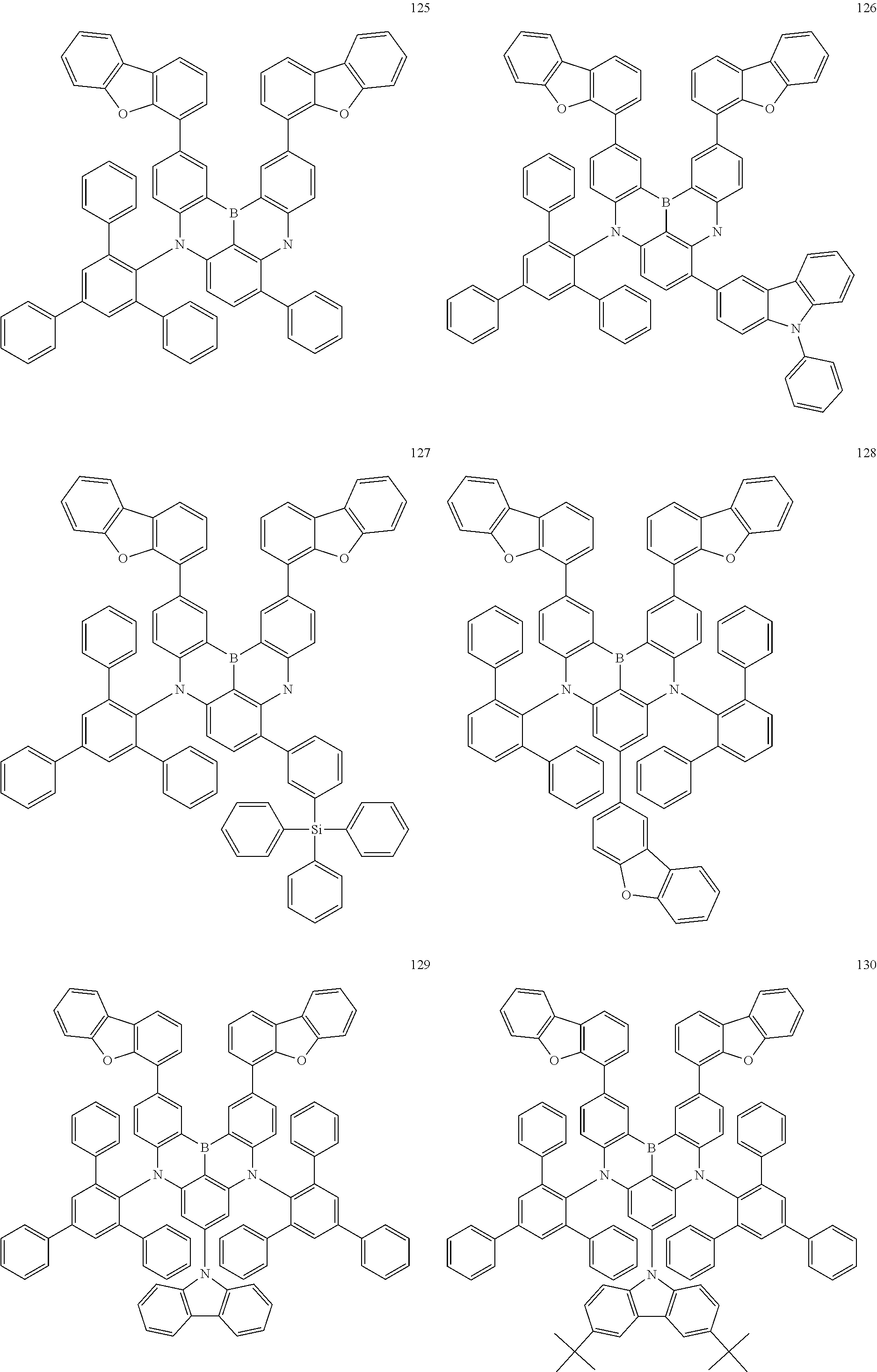

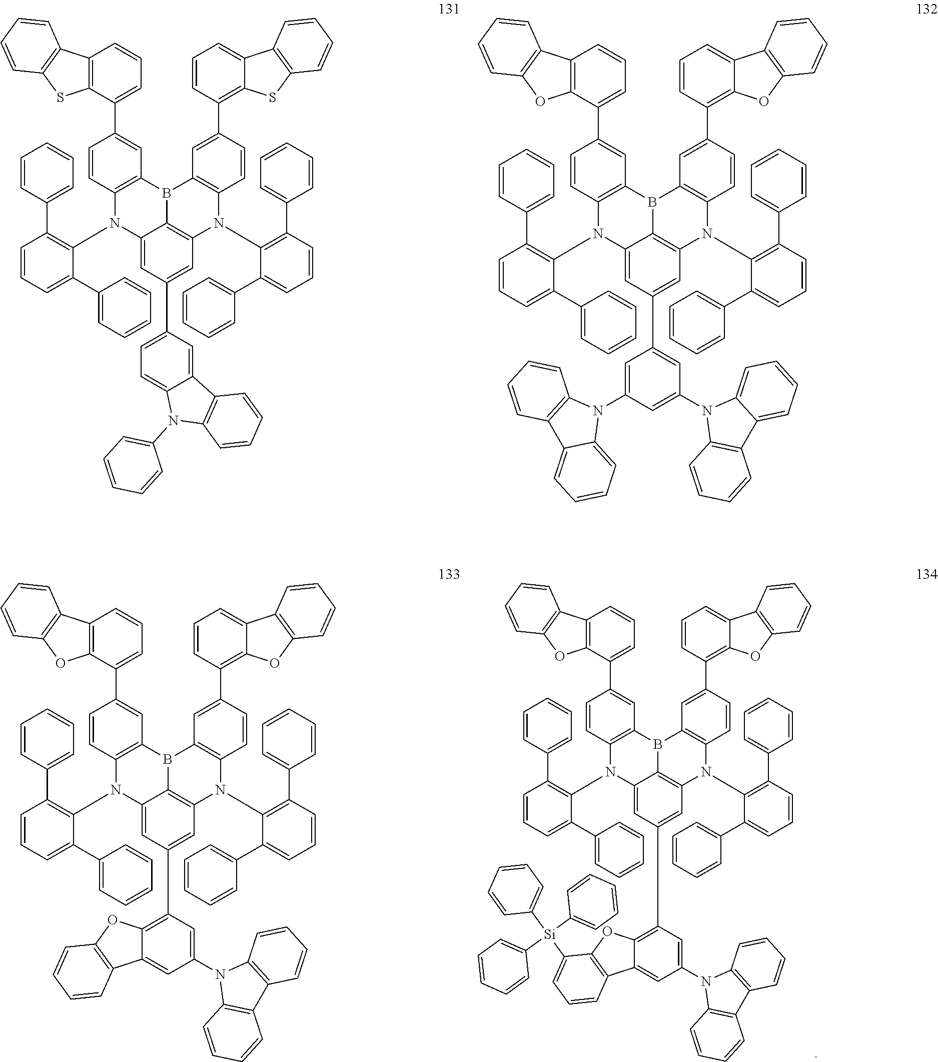

14. A fused polycyclic compound represented by Formula 1: 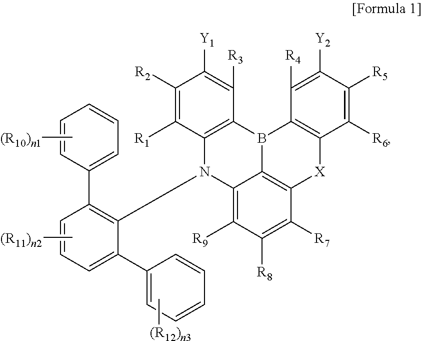
wherein, in Formula 1,
X is O, S, or NR₁₃,
R₁ to R₉ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted linear or branched alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₀ to R₁₃ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
Y₁ and Y₂ are each independently a hydrogen atom, a deuterium atom, a halogen atom, a cyano group, a hydroxy group, a substituted or unsubstituted oxy group, a substituted or unsubstituted thio group, a substituted or unsubstituted aryl group having 6 to 30 ring-forming carbon atoms, or a substituted or unsubstituted heteroaryl group having 2 to 30 ring-forming carbon atoms,
n1 and n3 are each independently an integer of 0 to 5,
n2 is an integer of 0 to 3, and
at least one of Y₁ or Y₂ is represented by Formula 2: 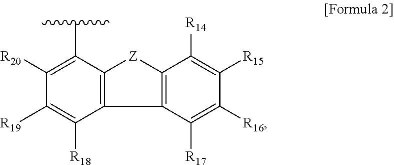
wherein, in Formula 2,
Z is O or S,
R₁₄ to R₂₀ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and 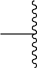
is a position linked to Formula 1.

15. The fused polycyclic compound of claim 14, wherein the fused polycyclic compound represented by Formula 1 is represented by Formula 1-1 or Formula 1-2: 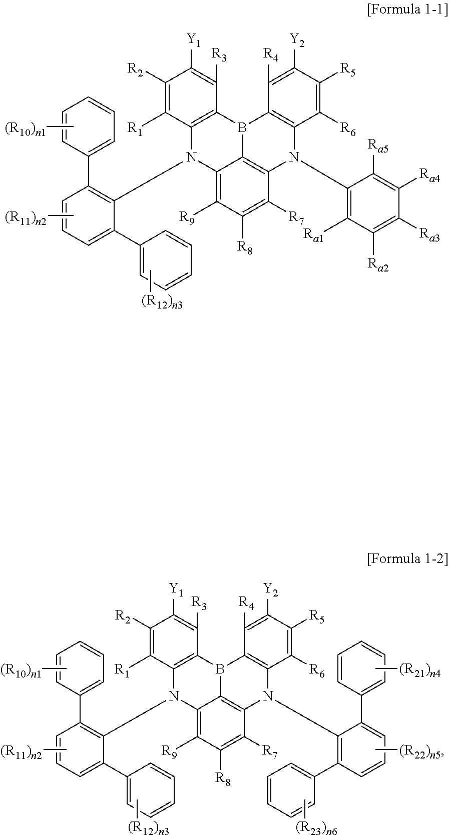
wherein, in Formula 1-1 and Formula 1-2,
Rₐ₁ to Rₐ₅ are each independently a hydrogen atom, a deuterium atom, a halogen atom, a cyano group, or a substituted or unsubstituted aryl group having 6 to 30 ring-forming carbon atoms,
R₂₁ to R₂₃ are each independently a hydrogen atom, a deuterium atom, a halogen atom, a cyano group, a hydroxy group, a substituted or unsubstituted oxy group, a substituted or unsubstituted thio group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
n4 and n6 are each independently an integer of 0 to 5,
n5 is an integer of 0 to 3, and
Y₁, Y₂, R₁ to R₁₂, and n1 to n3 are each independently the same as defined in Formula 1.

16. The fused polycyclic compound of claim 14, wherein the fused polycyclic compound represented by Formula 1 is represented by Formula 1-3 or Formula 1-4: 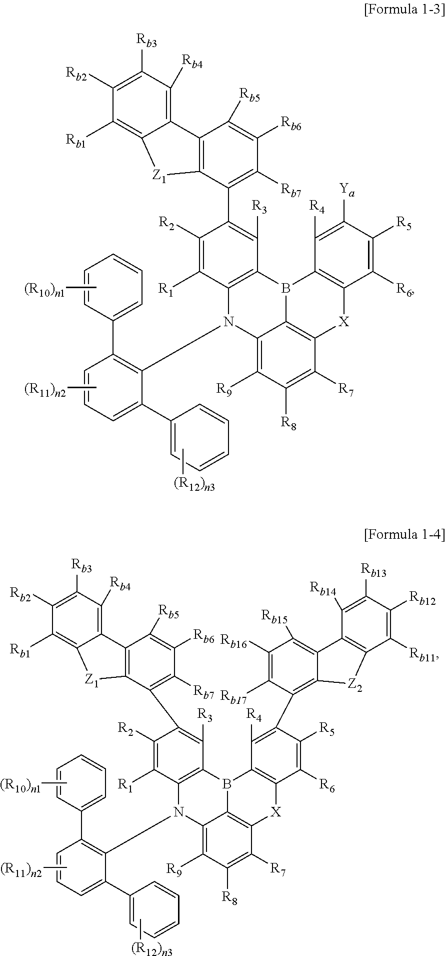
wherein, in Formula 1-3 and Formula 1-4,
Yₐ is a hydrogen atom, a substituted or unsubstituted aryl group having 6 to 30 ring-forming carbon atoms, a substituted or unsubstituted heteroaryl group having 2 to 30 ring-forming carbon atoms, or a substituent represented by Formula 2,
Z₁ and Z₂ are each independently O or S,
R_{b1} to R_{b7} and R_{b11} to R_{b17} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
X, R₁ to R₁₂, and n1 to n3 are each independently the same as defined in Formula 1.

17. The fused polycyclic compound of claim 14, wherein the fused polycyclic compound represented by Formula 1 is represented by Formula 1-5: 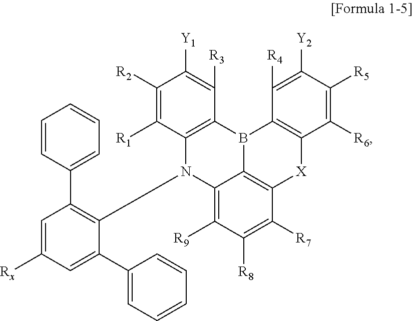
wherein, in Formula 1-5,
Rₓ is a hydrogen atom, a deuterium atom, a cyano group, a substituted or unsubstituted linear or branched alkyl group having 1 to 20 carbon atoms, or a substituted or unsubstituted aryl group having 6 to 30 ring-forming carbon atoms, and
X, R₁ to R₉, R₁₃, Y₁ and Y₂ are each independently the same as defined in Formula 1.

18. The fused polycyclic compound of claim 14, wherein the fused polycyclic compound represented by Formula 1 is represented by Formula 1-6: 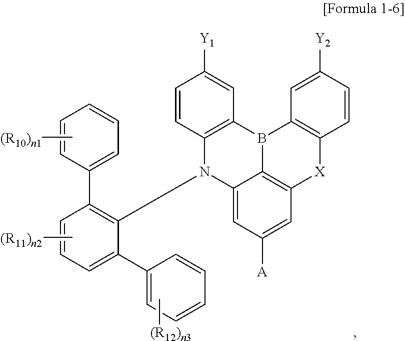
wherein, in Formula 1-6,
A is a hydrogen atom, a deuterium atom, a cyano group, a halogen atom, or a substituted or unsubstituted linear or branched alkyl group having 1 to 20 carbon atoms, and
X, R₁₀ to R₁₃, n1 to n3, Y₁ and Y₂ are each independently the same as defined in Formula 1.

19. The fused polycyclic compound of claim 18, wherein in Formula 1-6, A is a substituted or unsubstituted t-butyl group.

20. The fused polycyclic compound of claim 14, wherein the fused polycyclic compound is any one among the compounds in Compound Group 1: 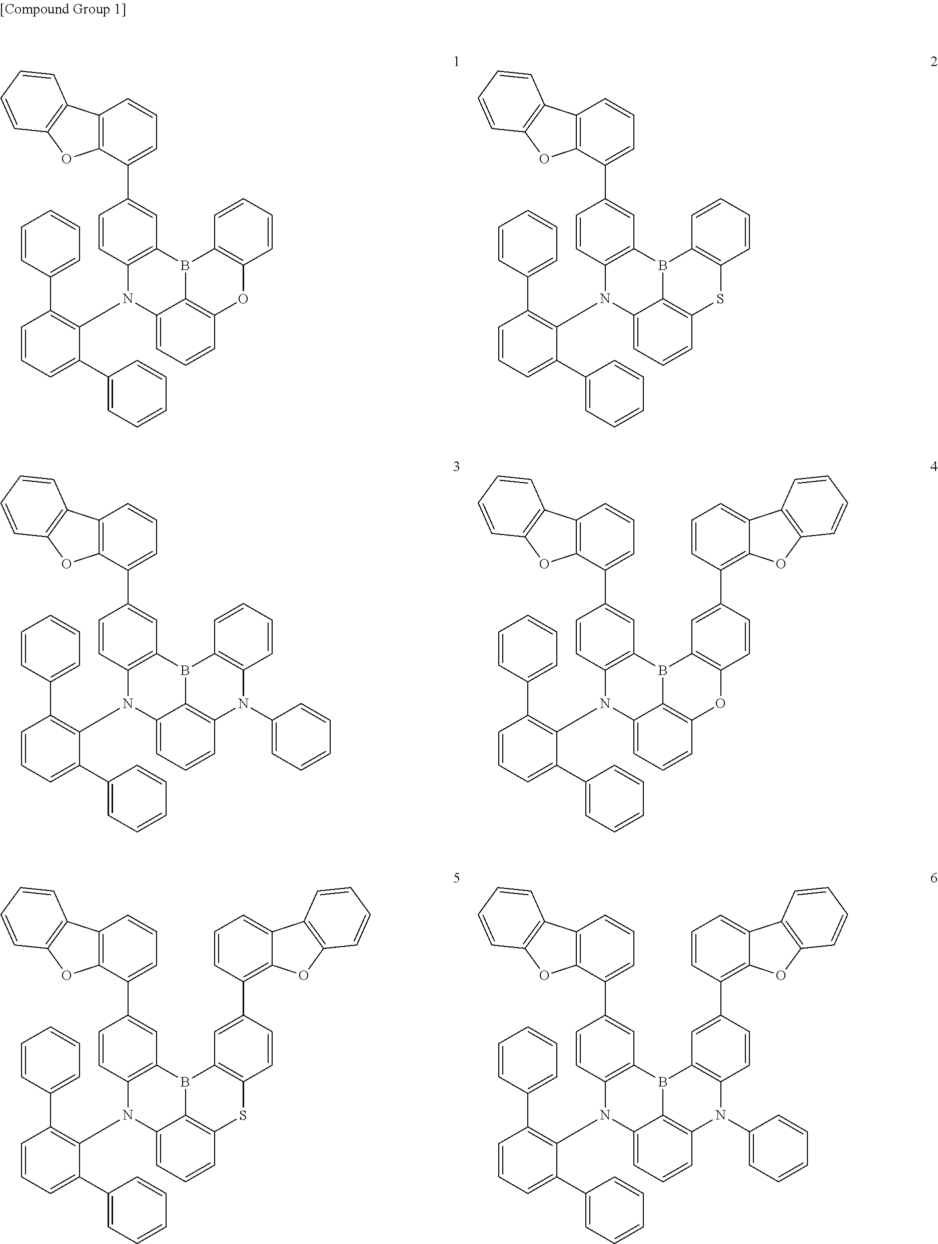 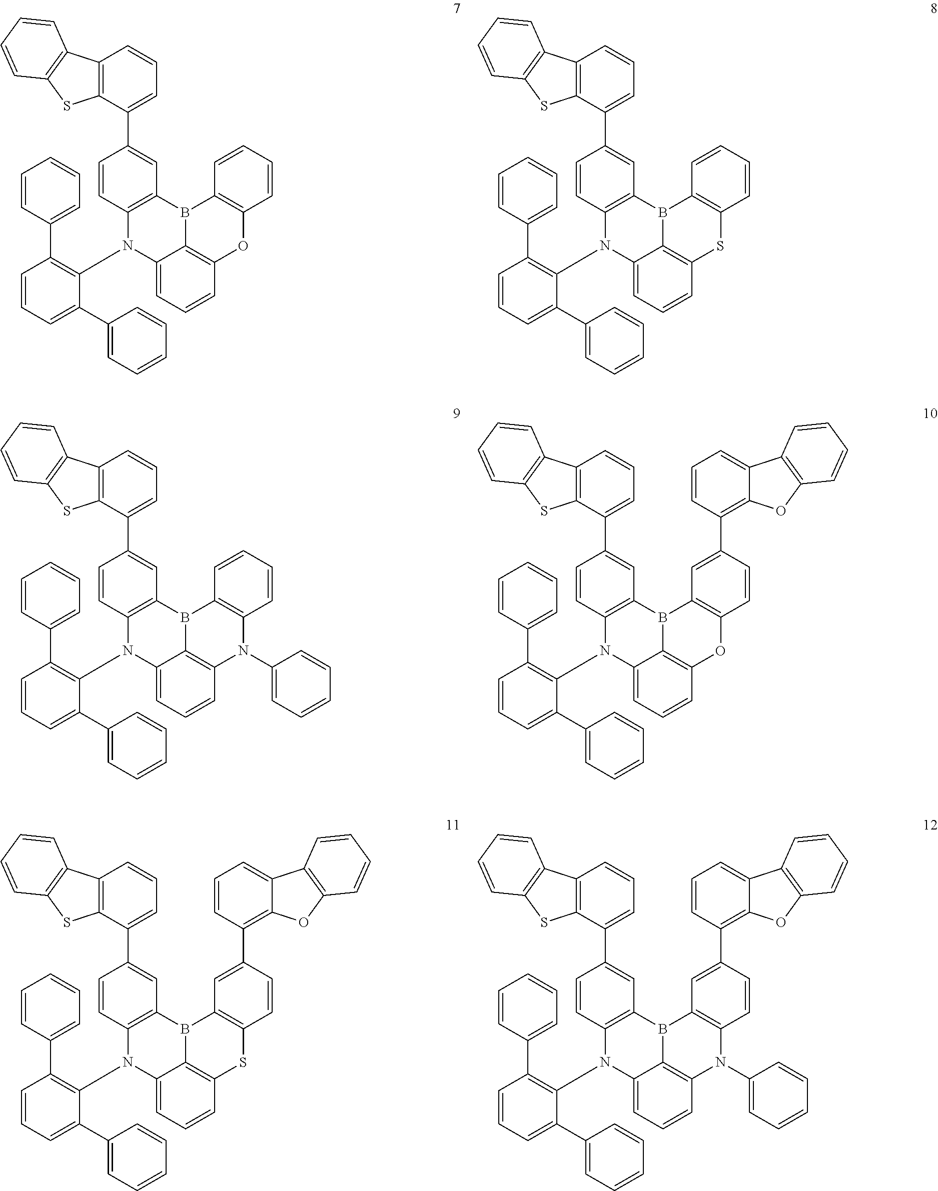 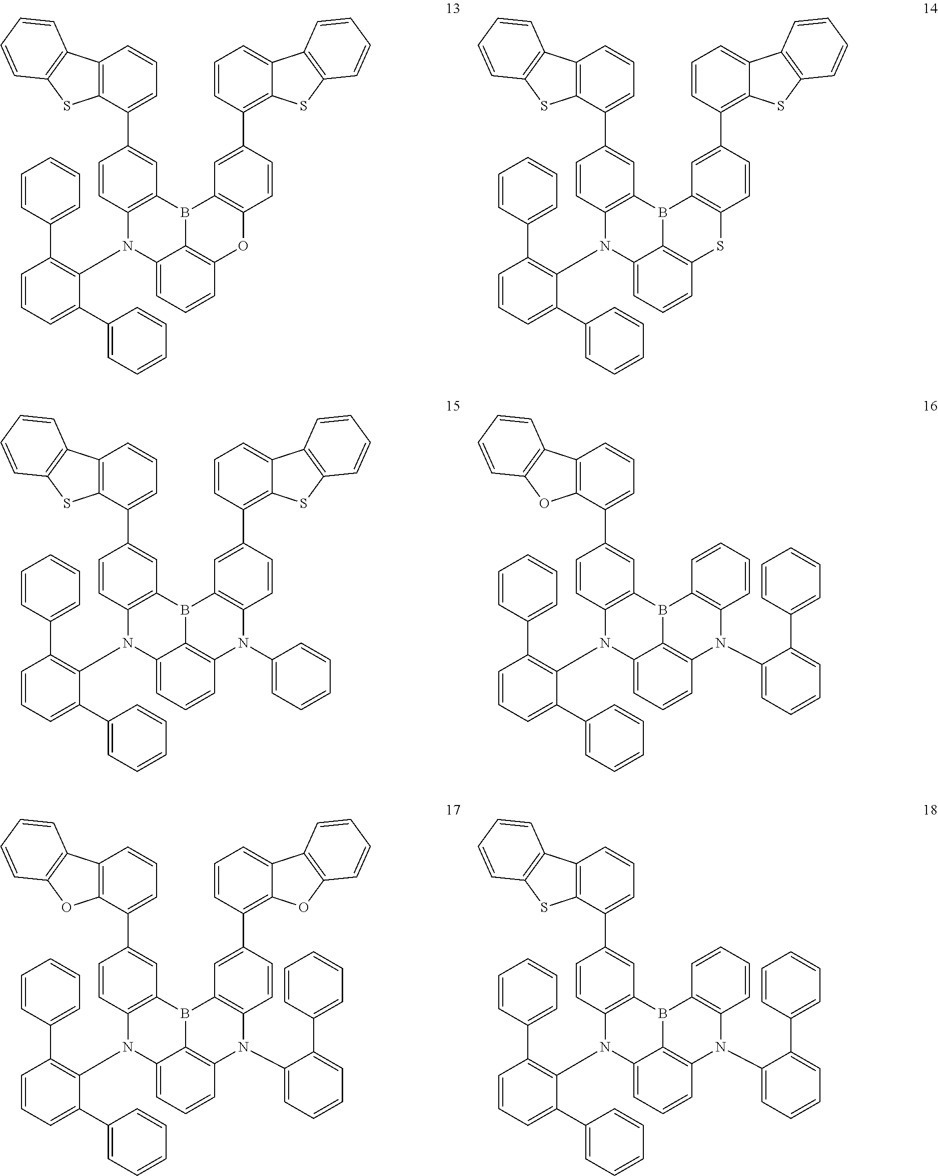 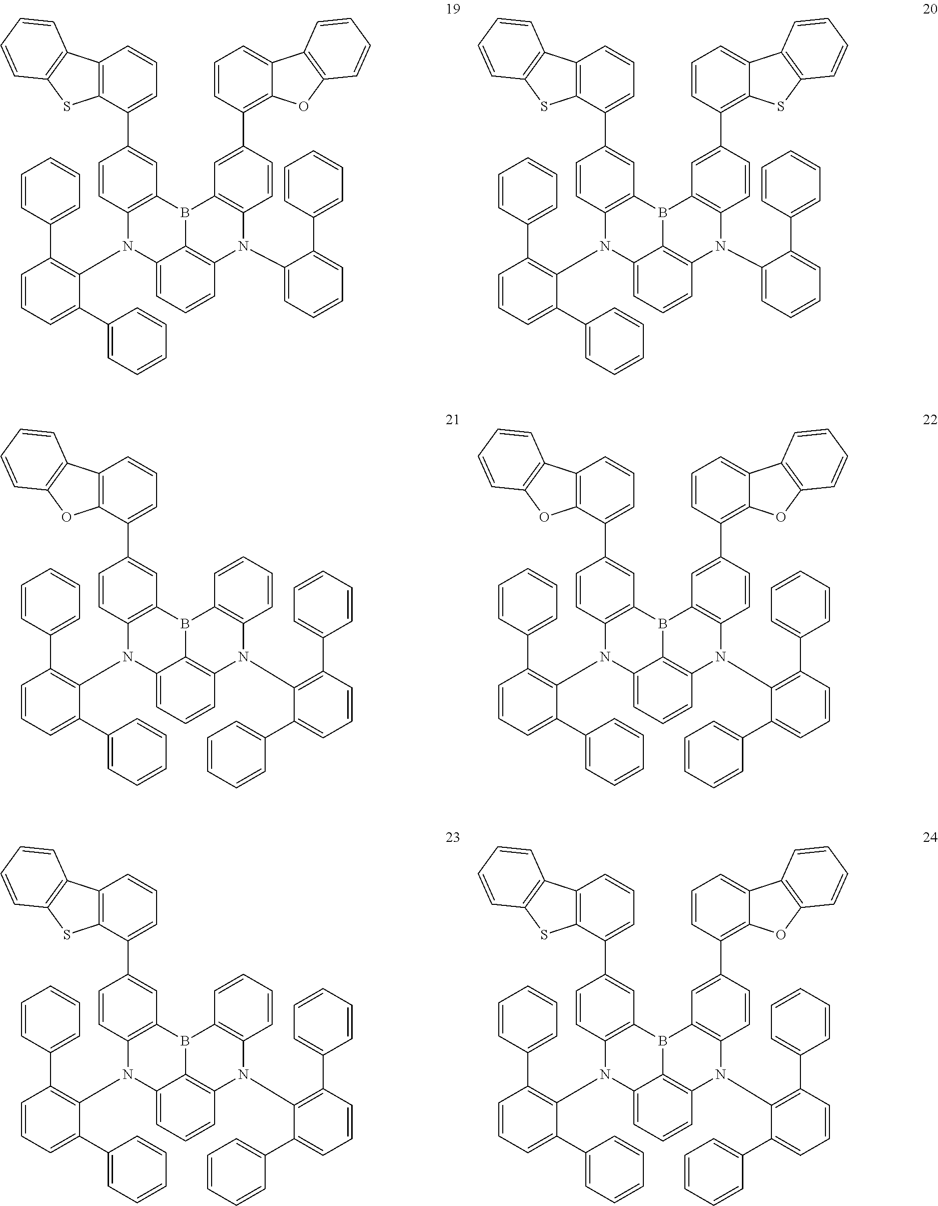 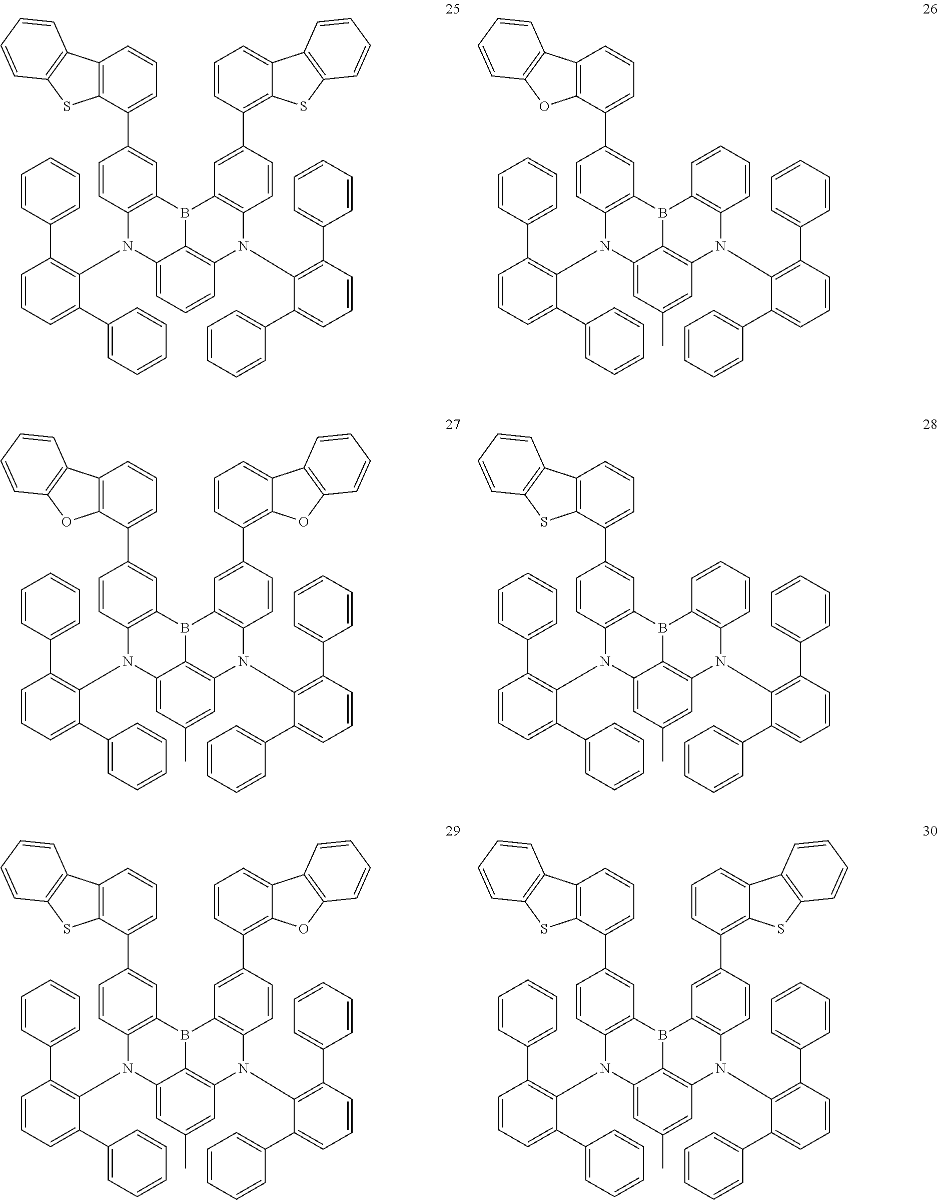 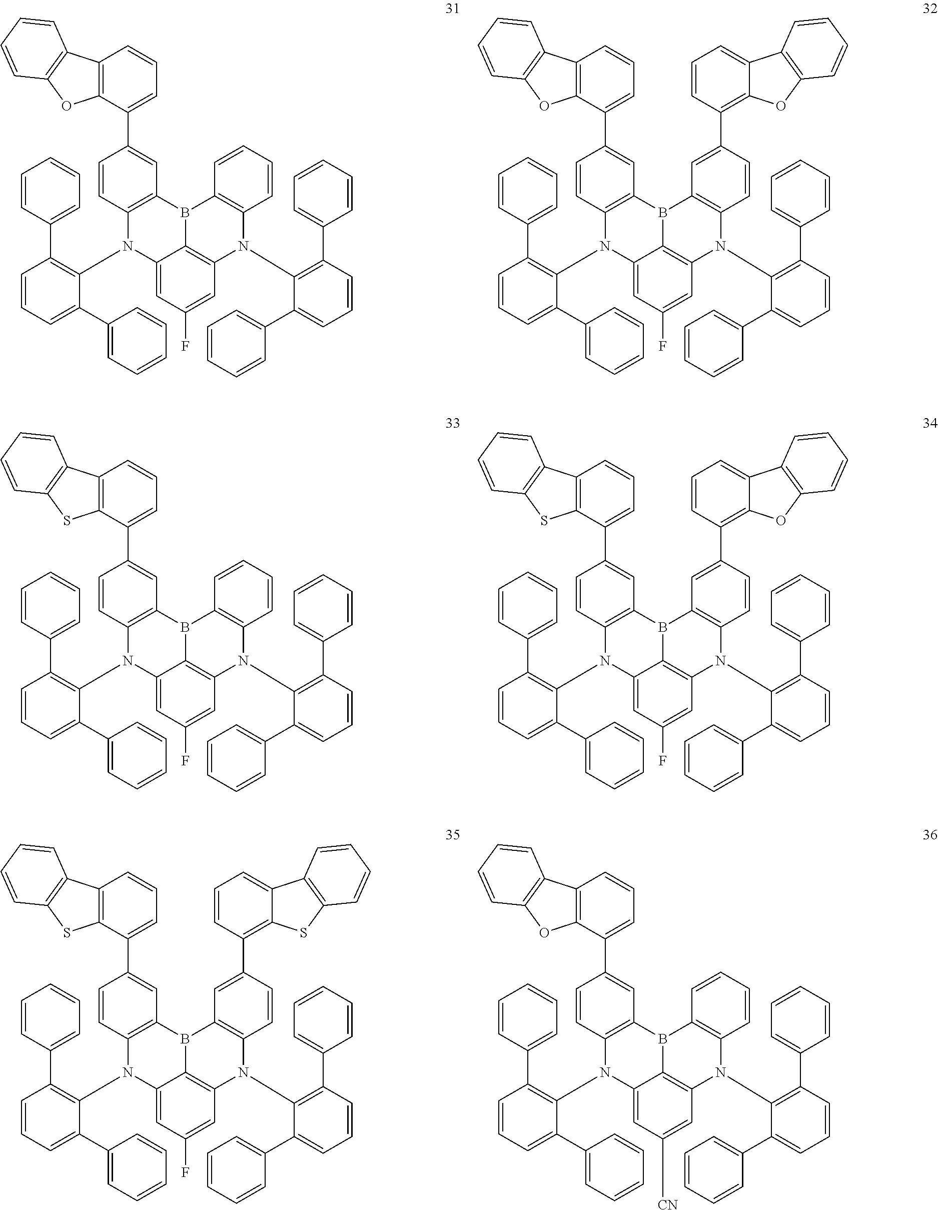 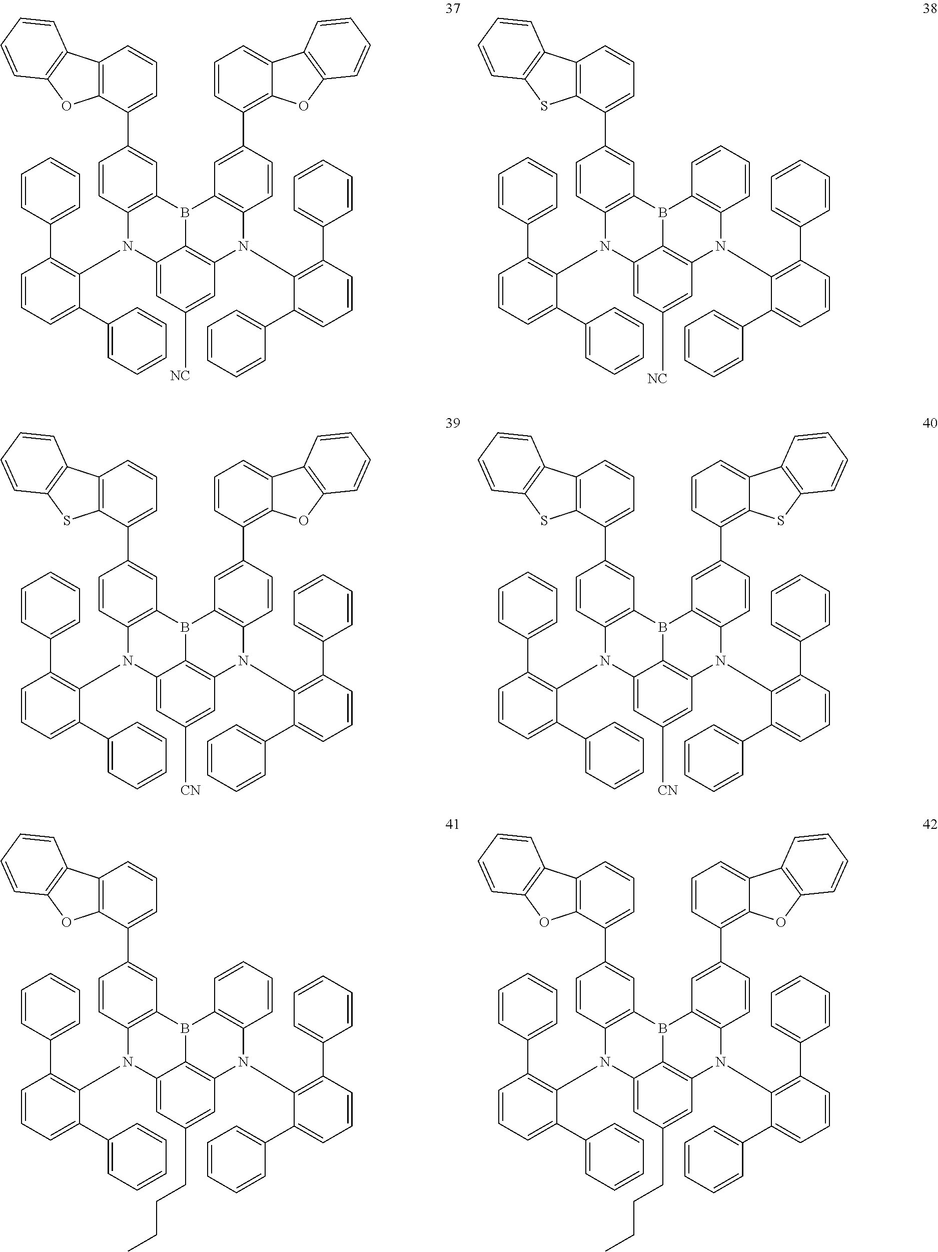 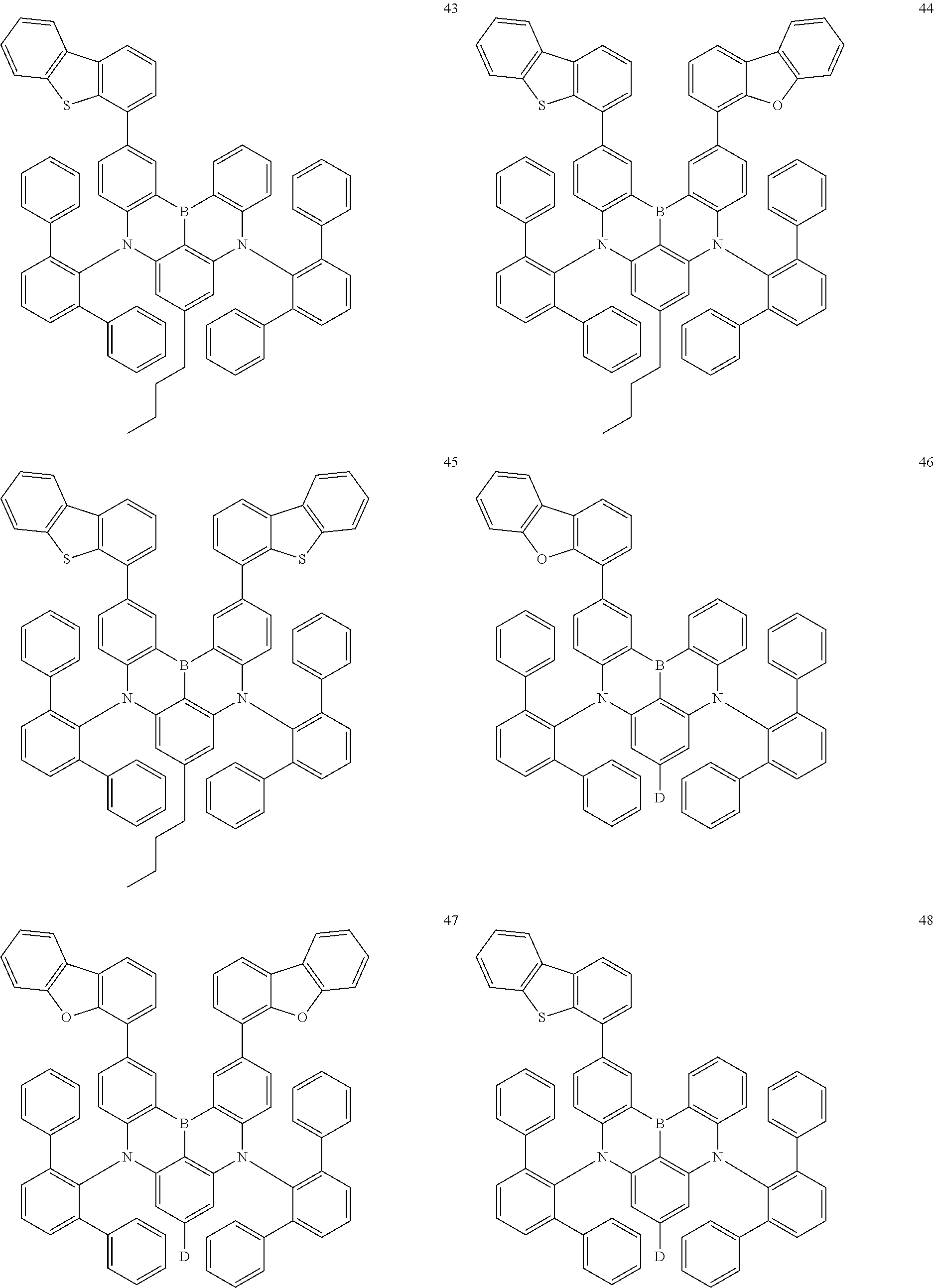 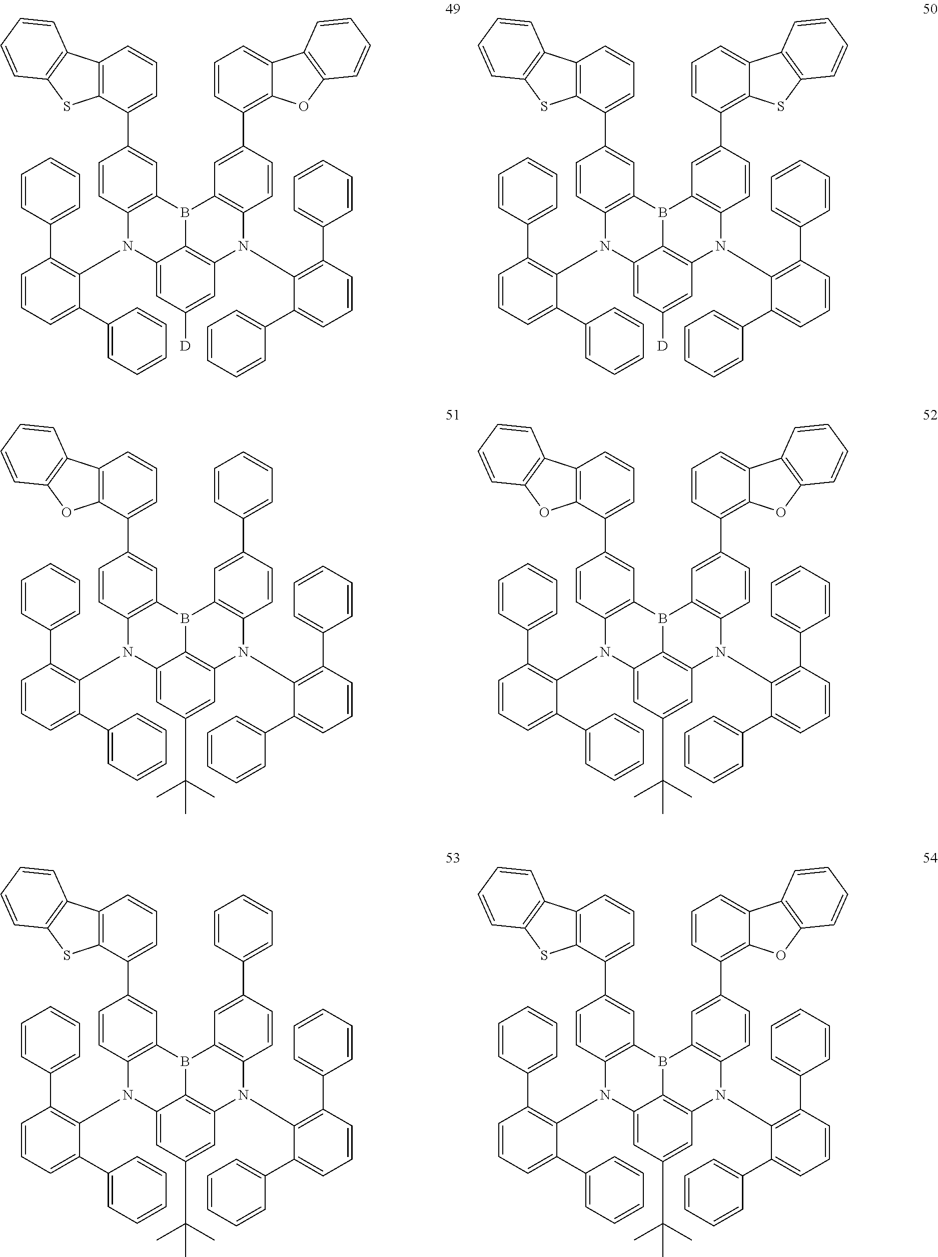 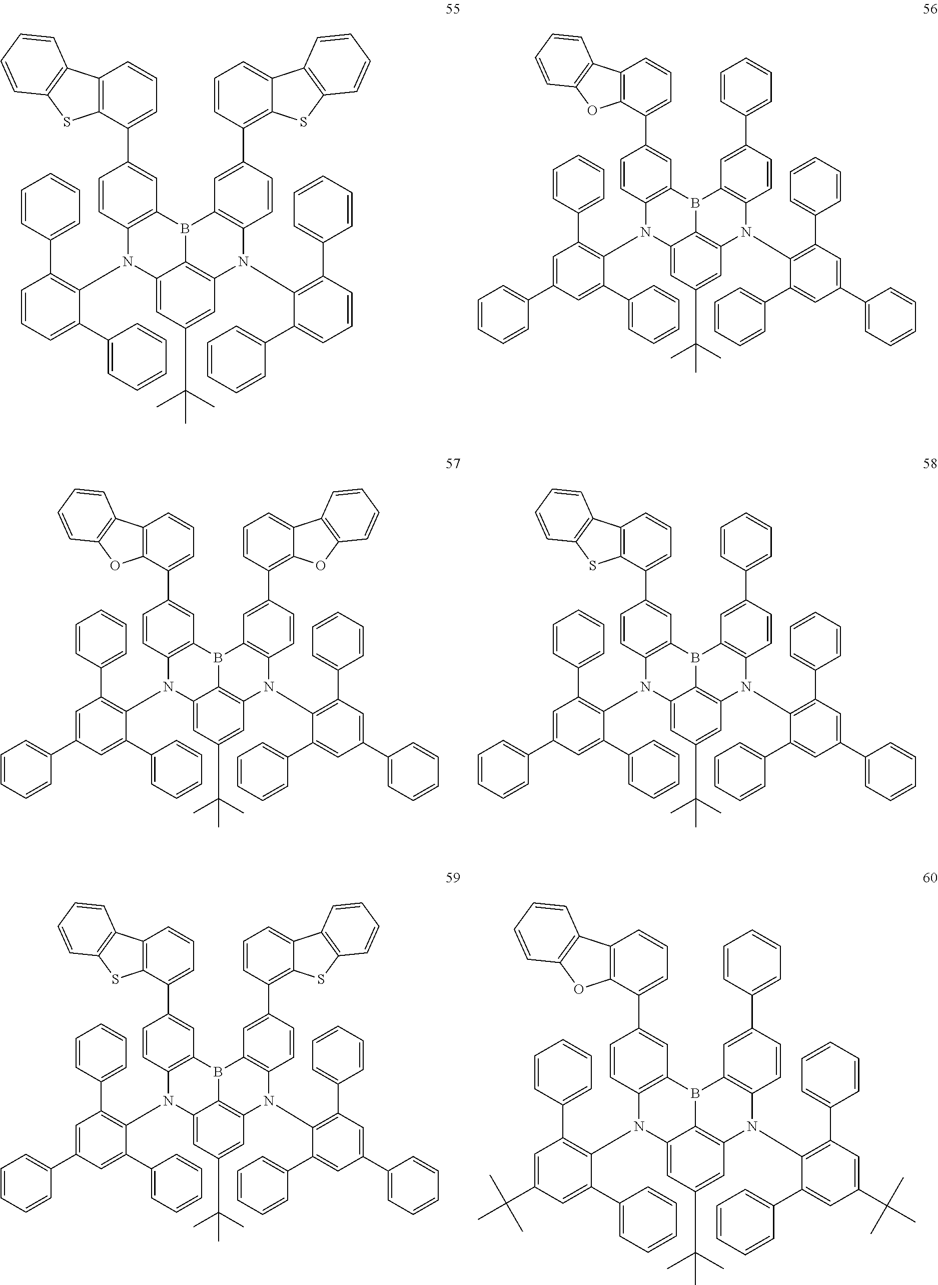 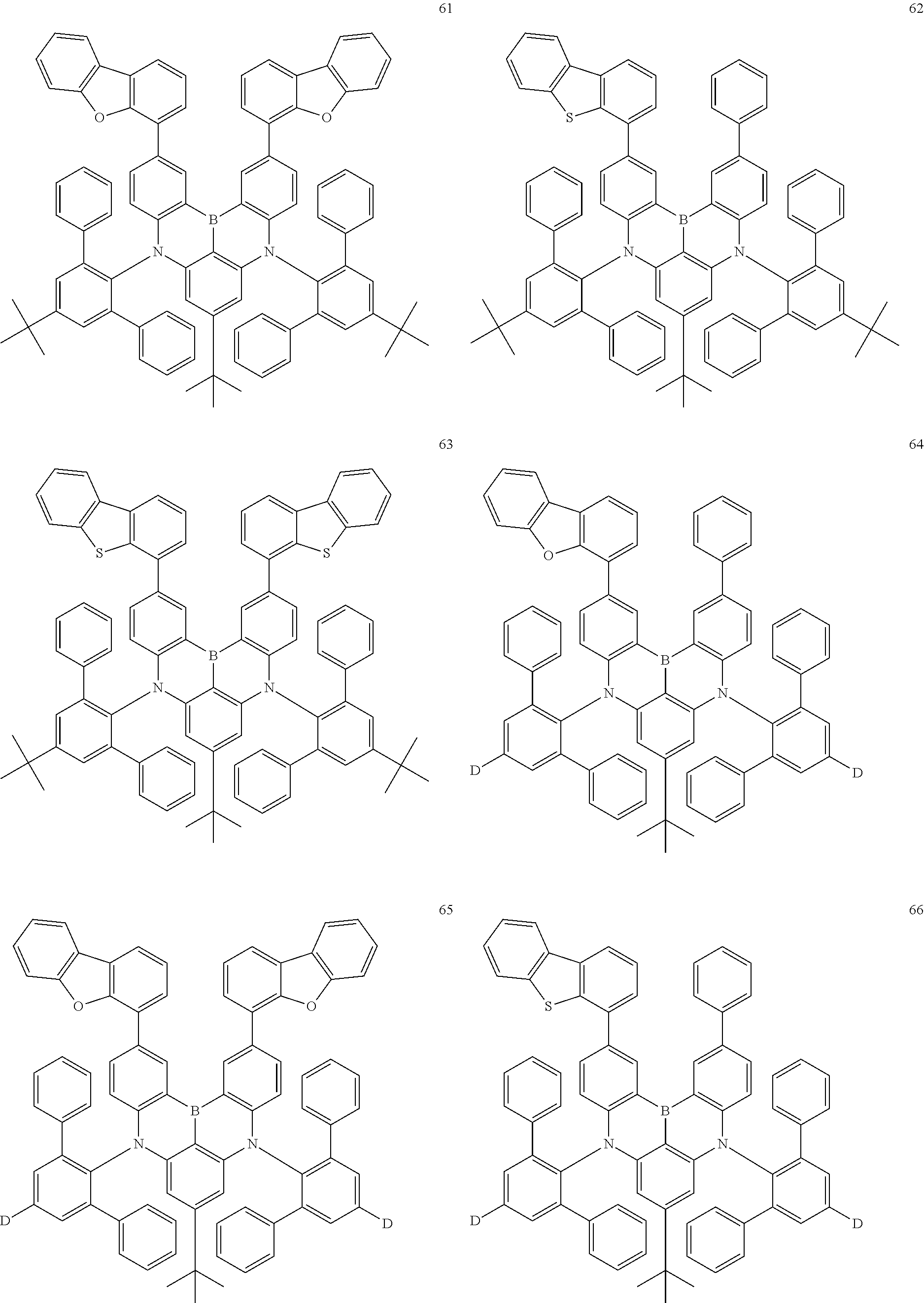 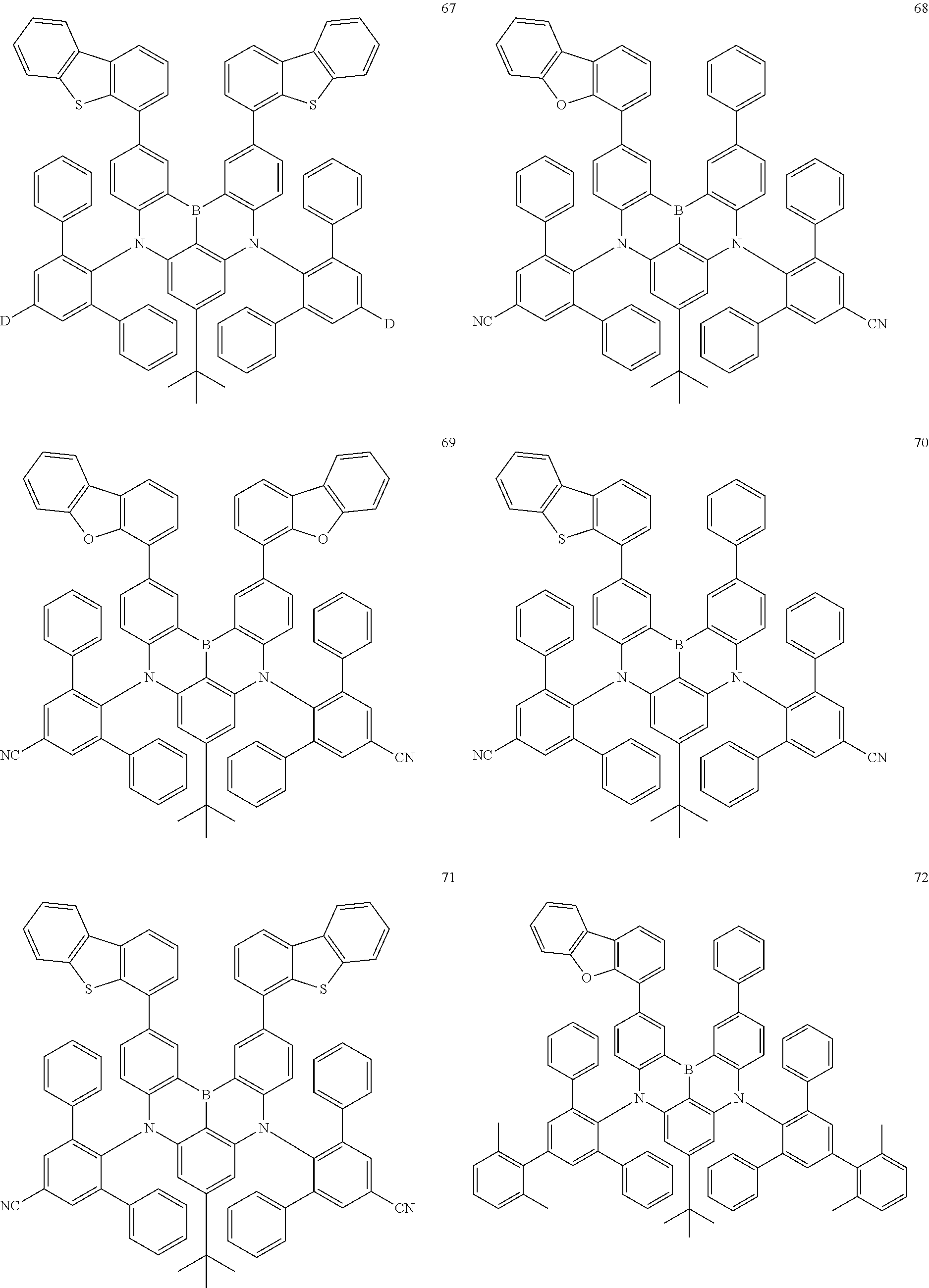 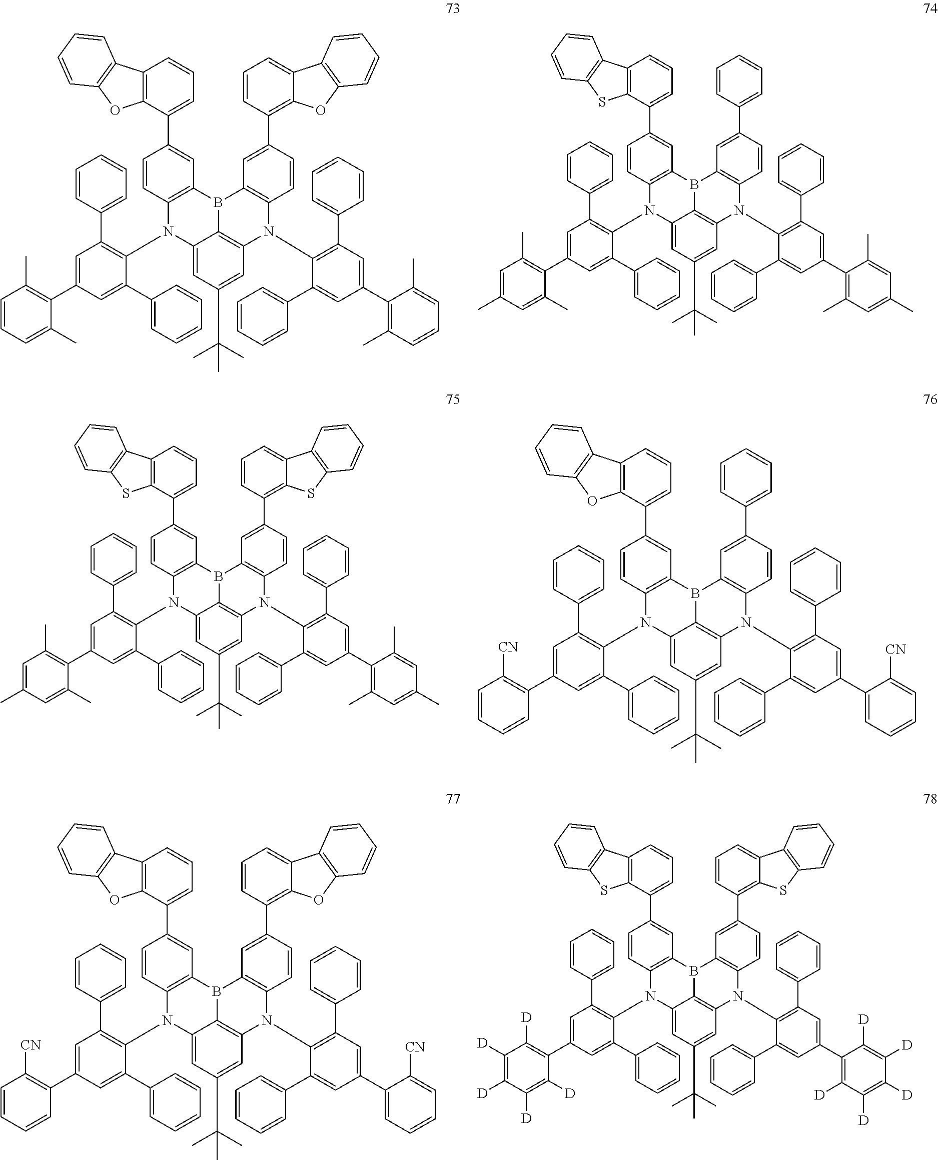 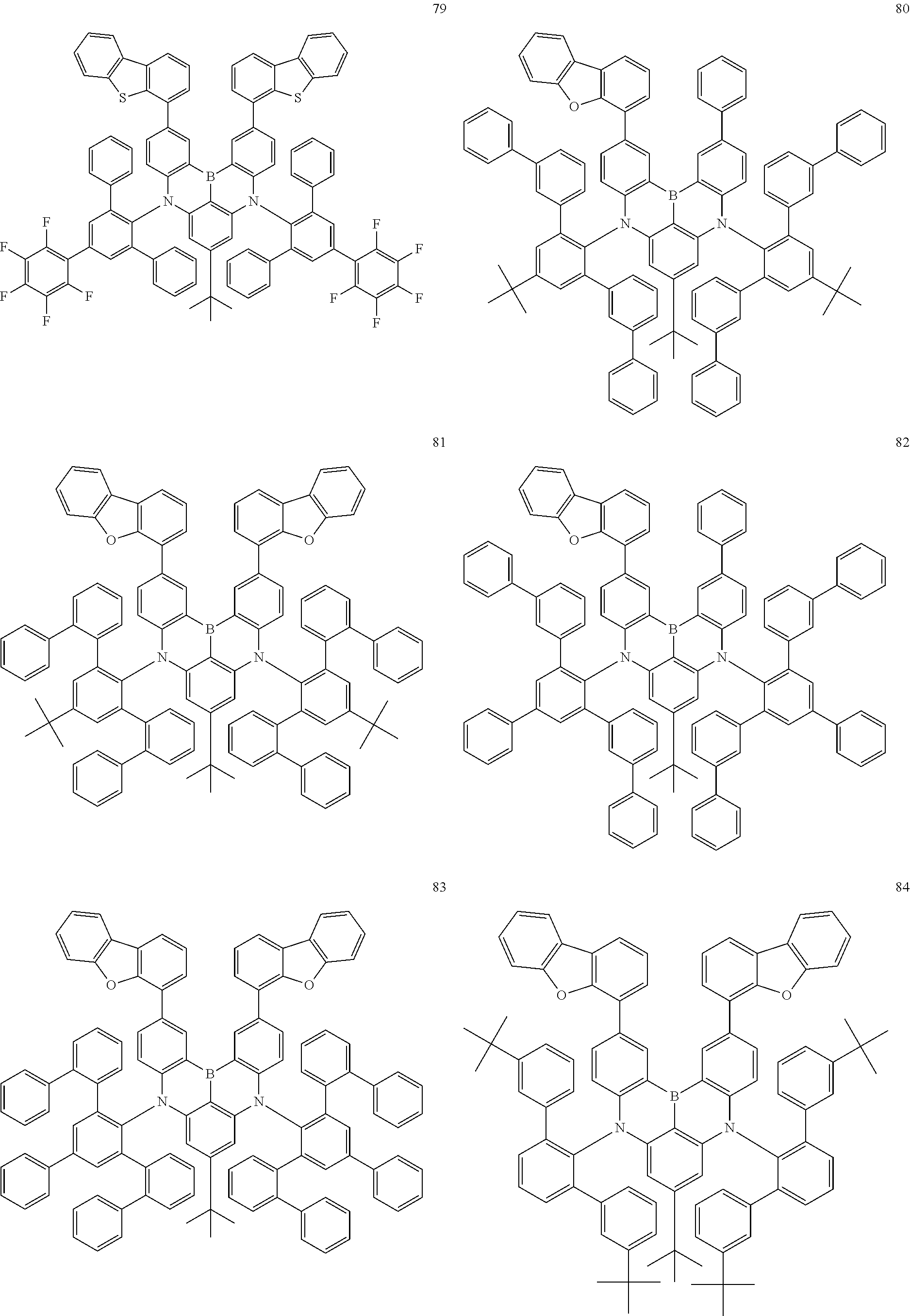 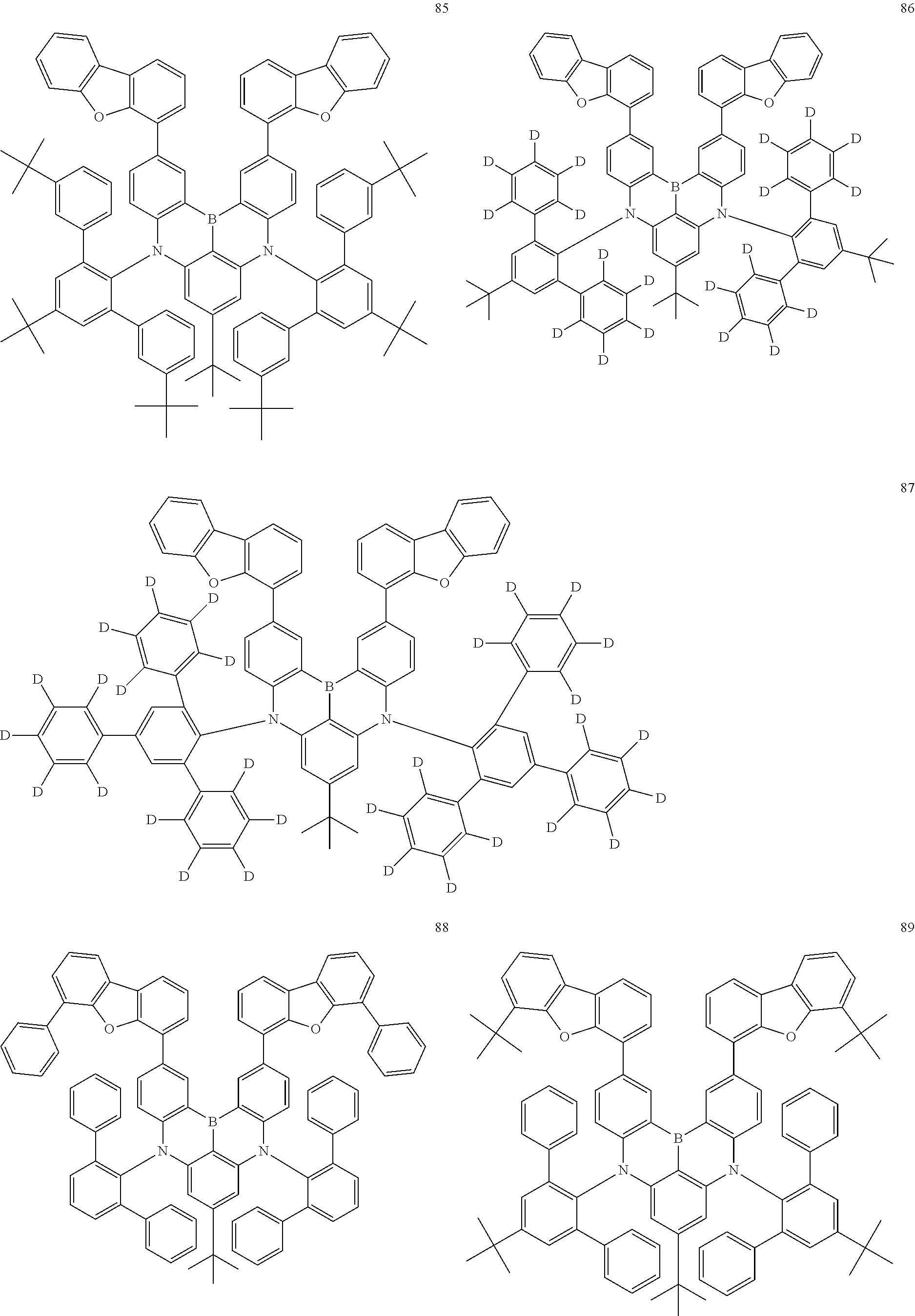 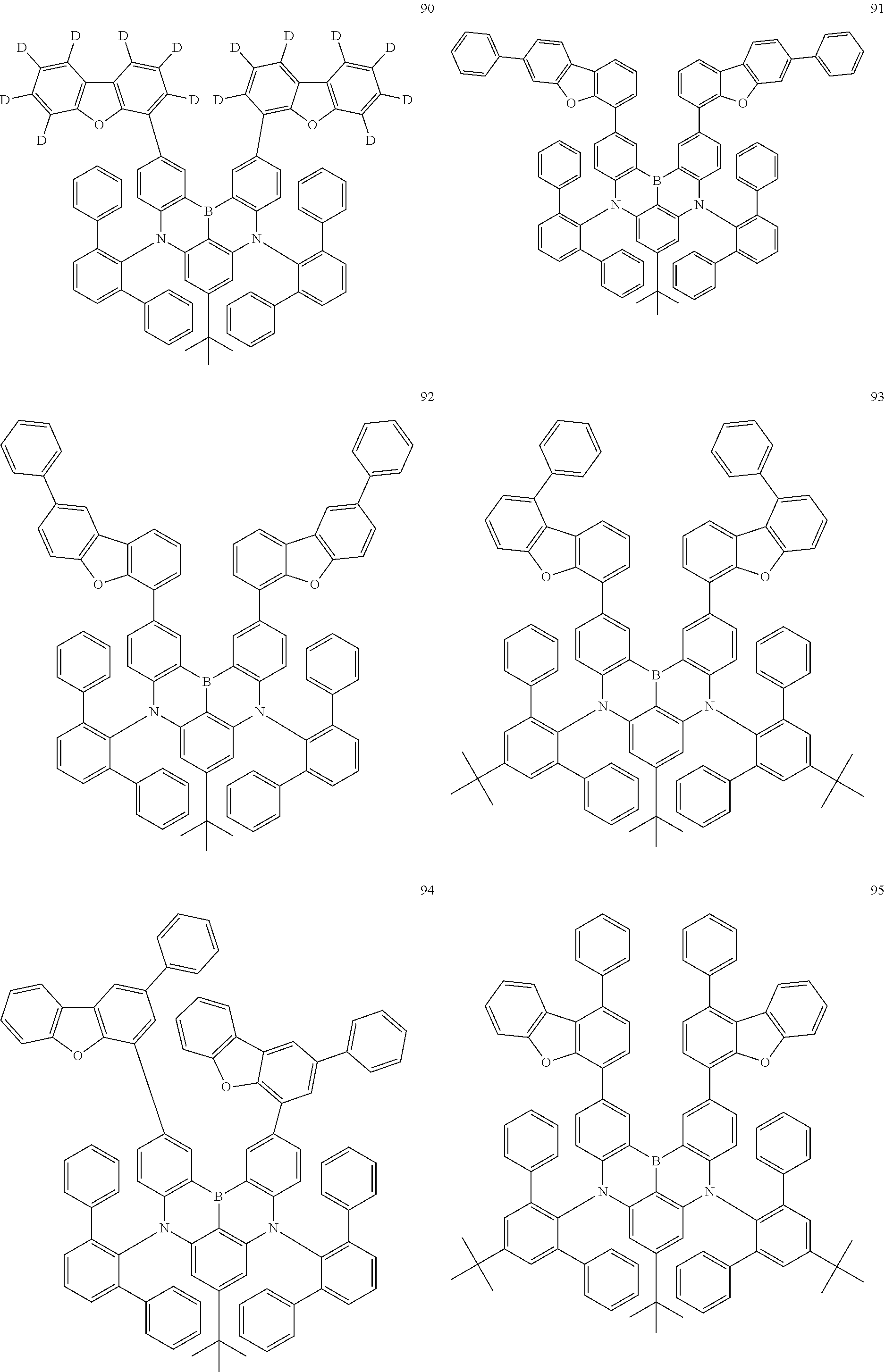 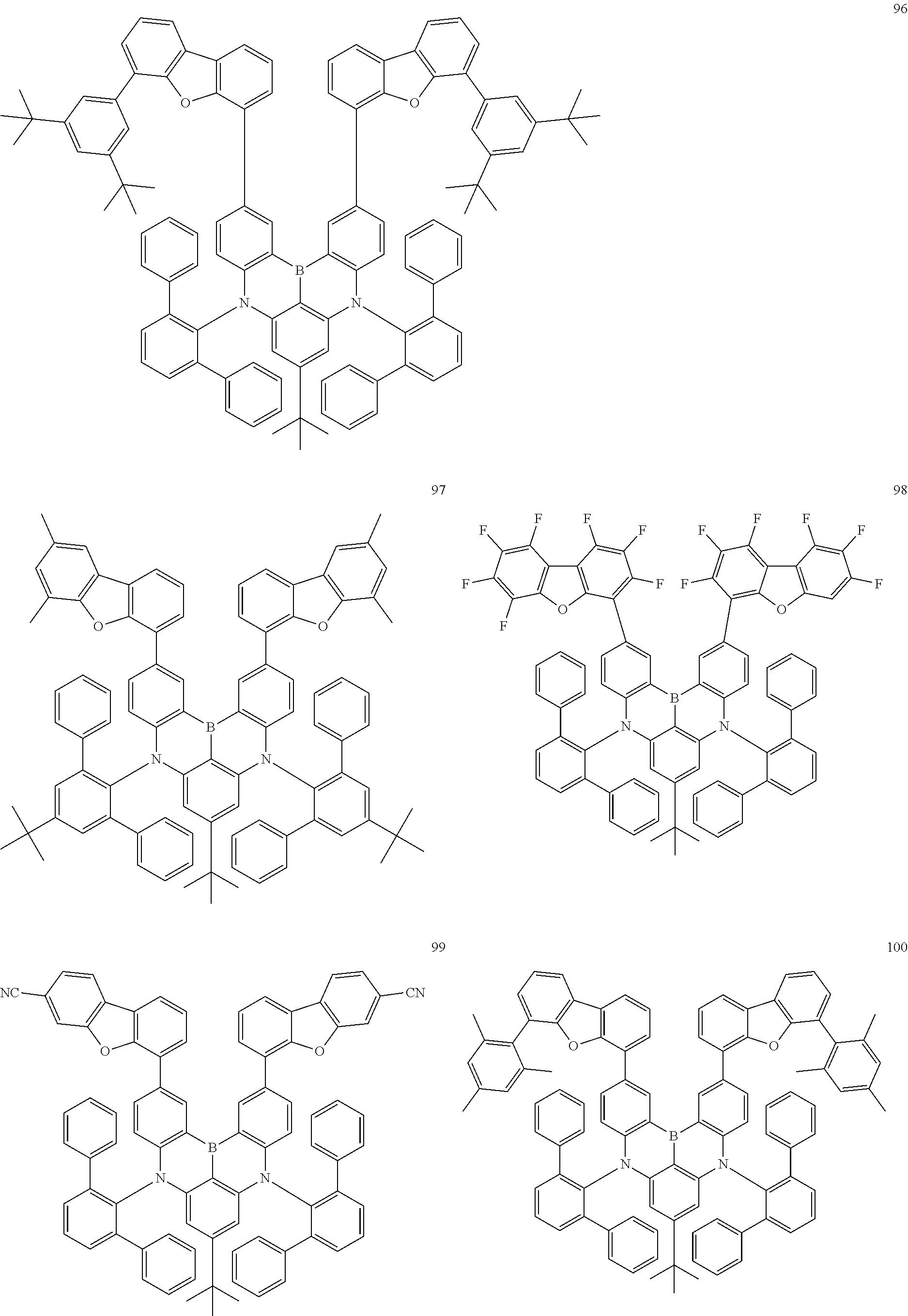 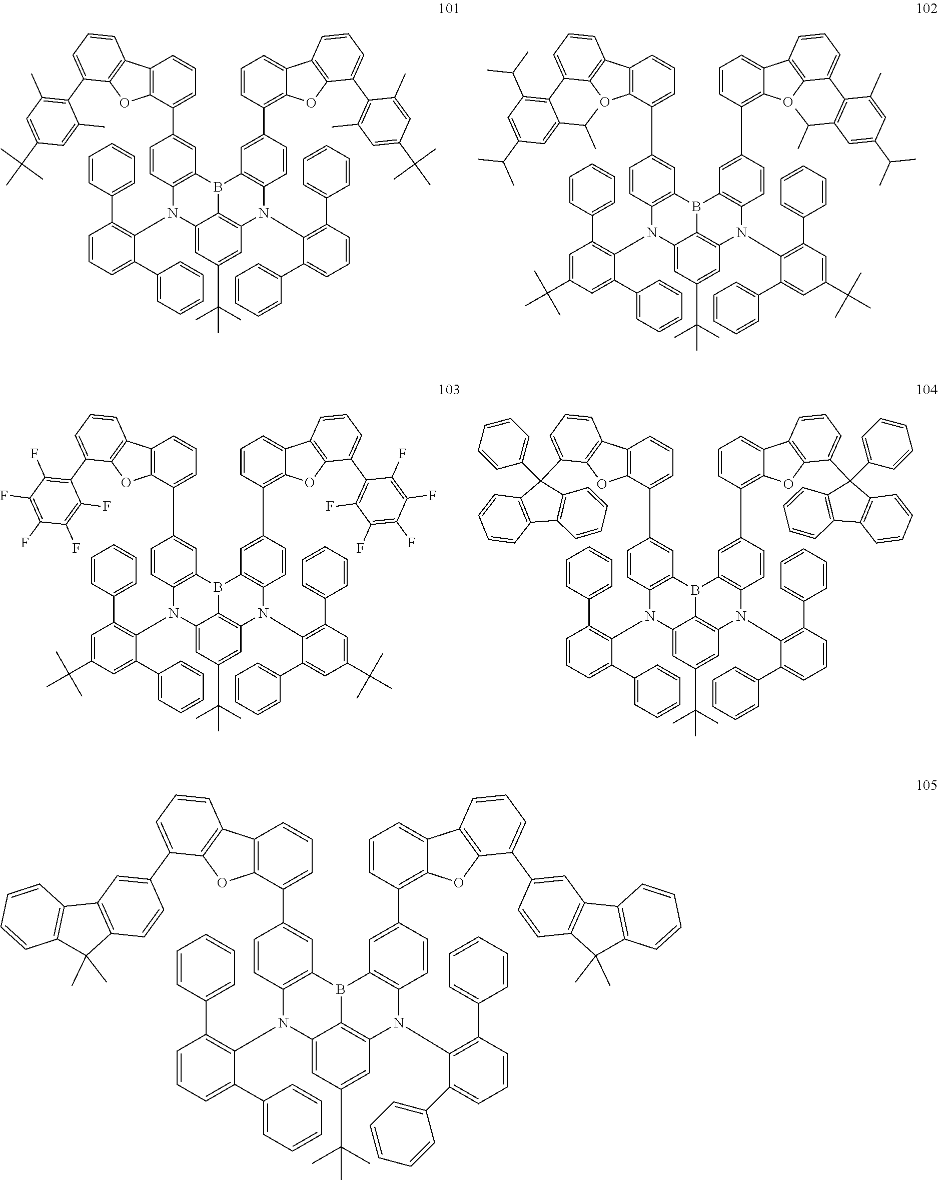 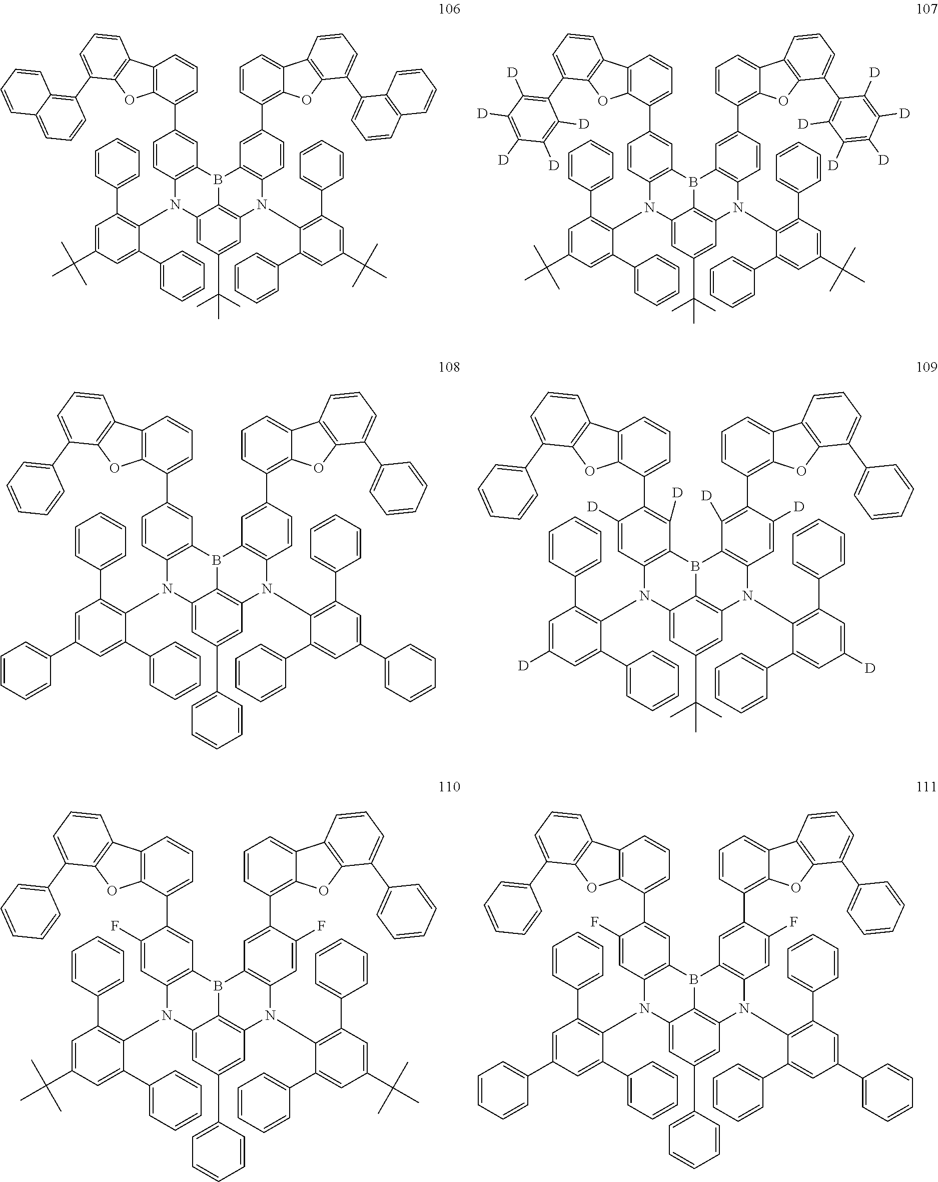 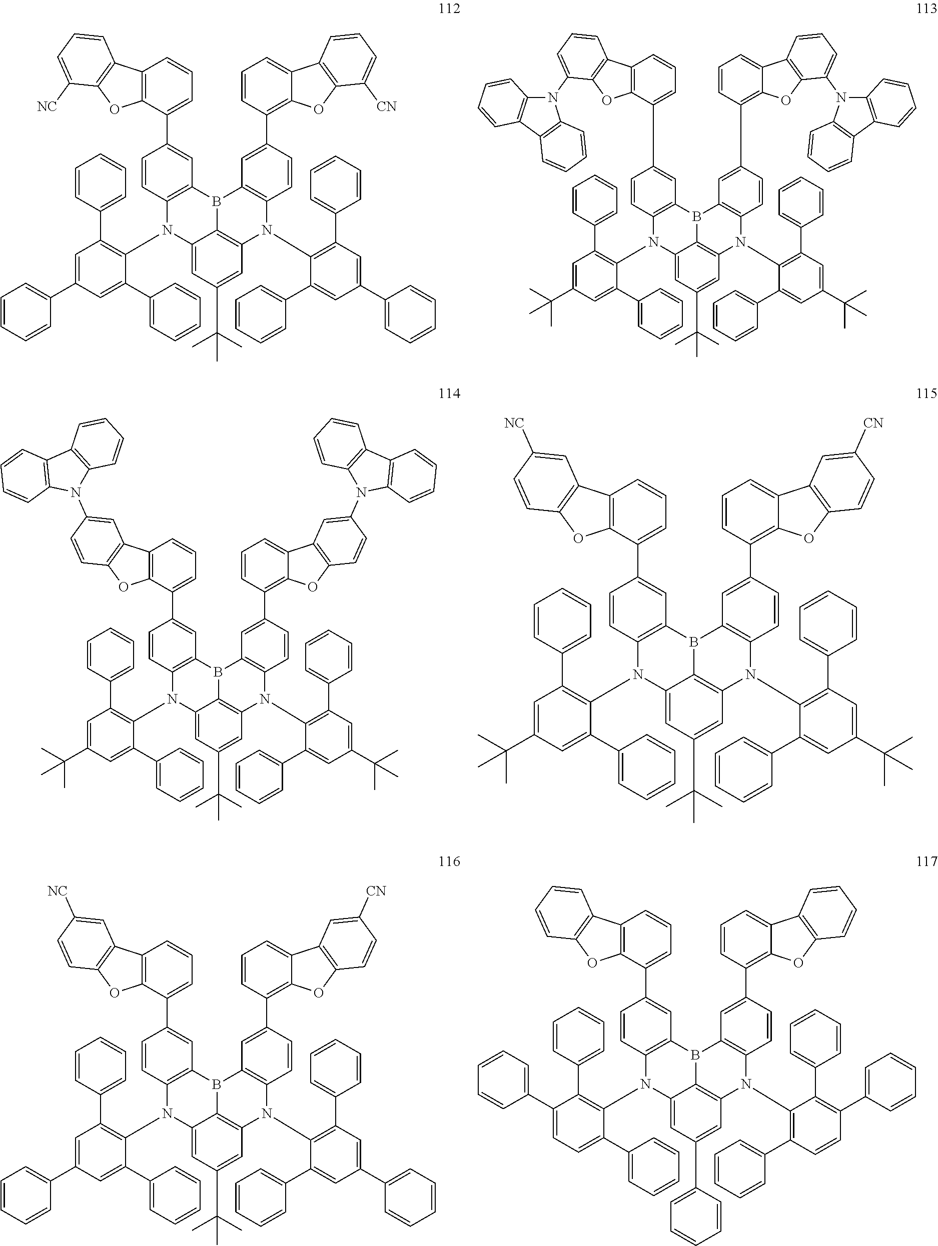 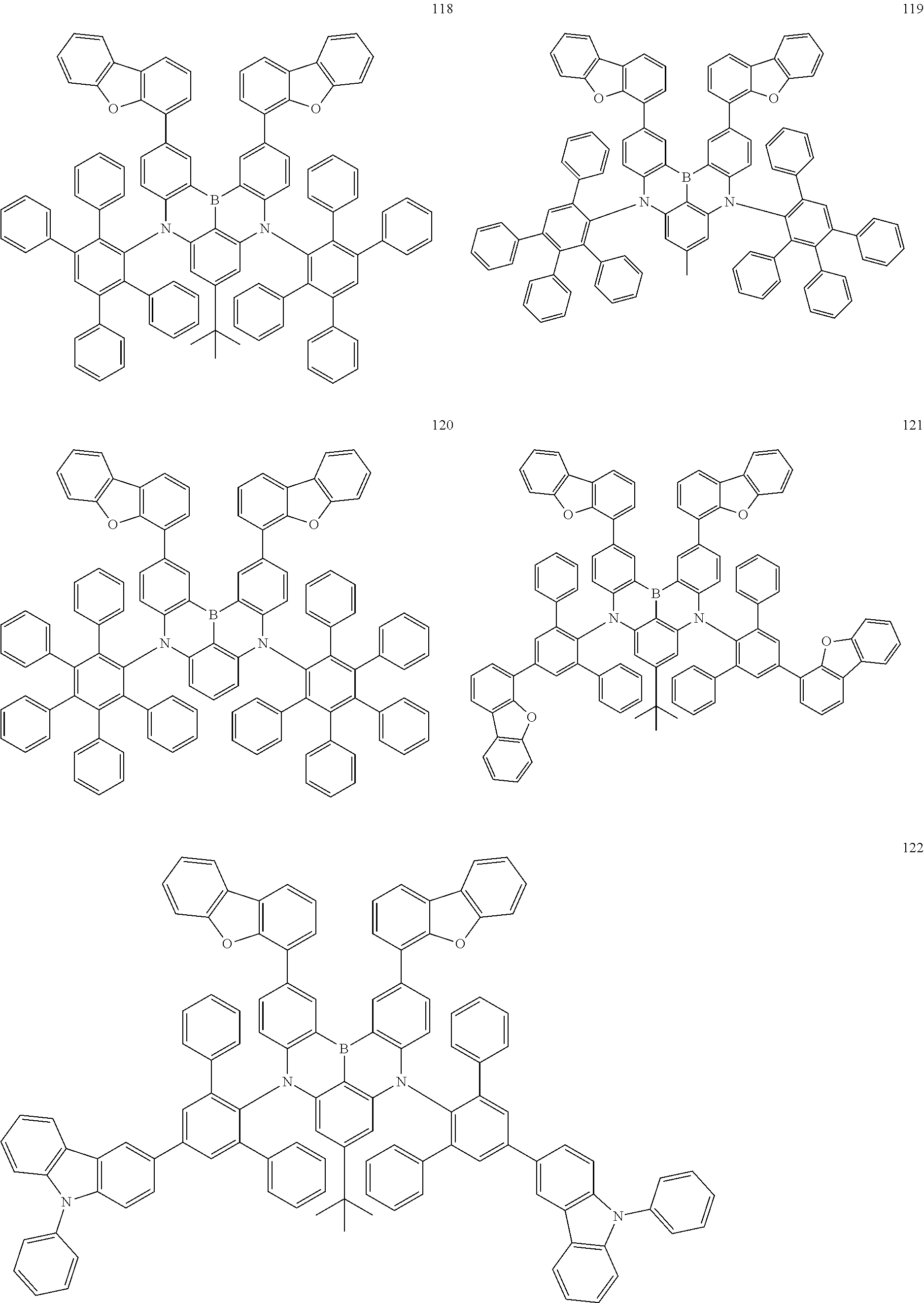 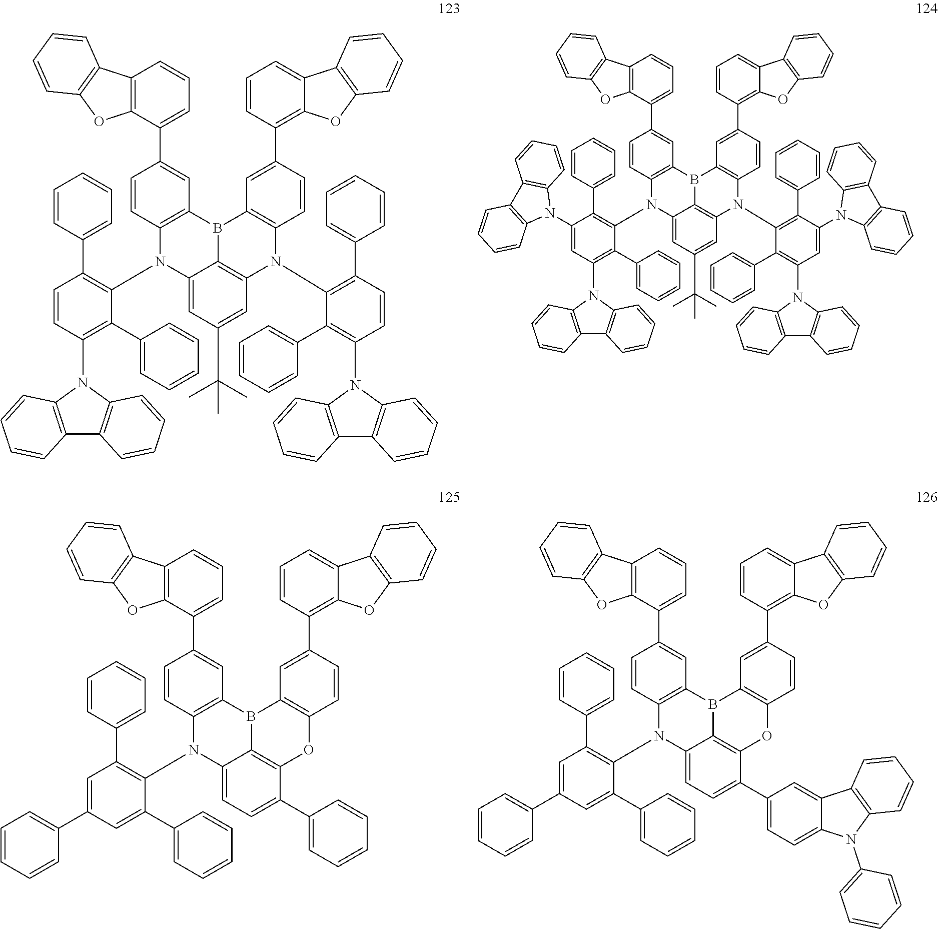 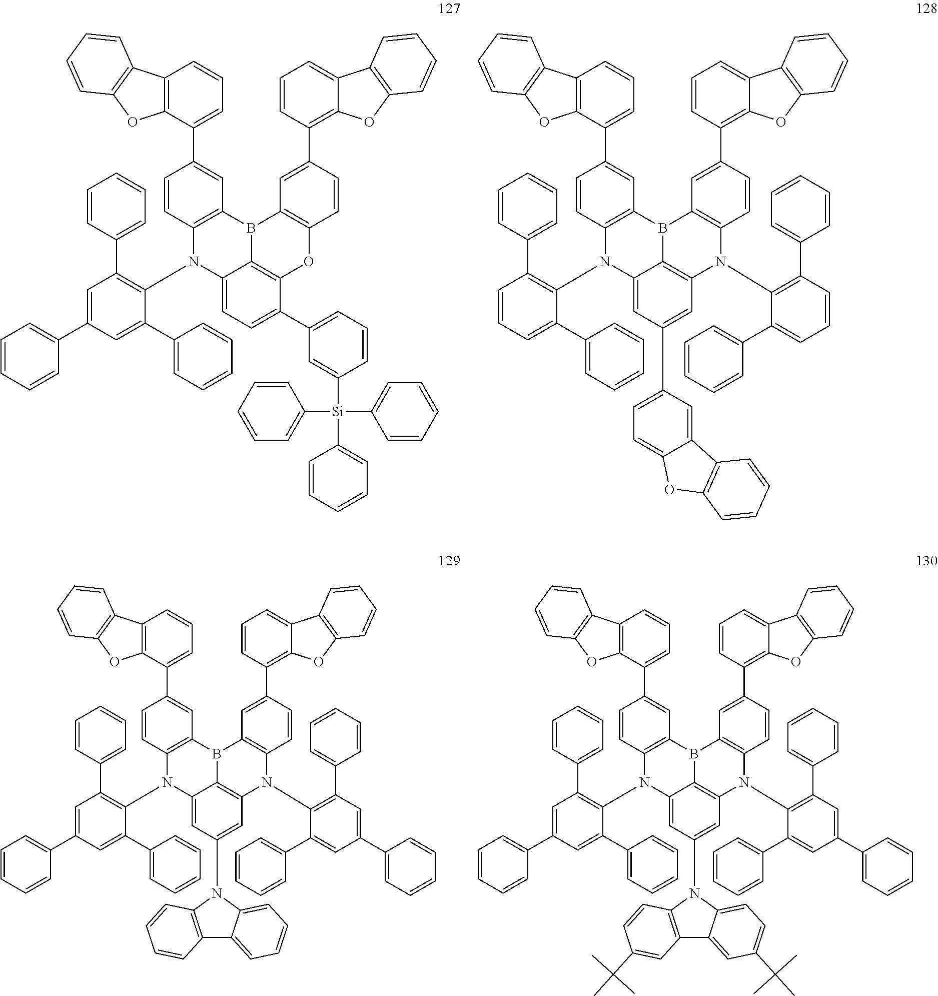 [chemical structure]
